(19) United States
(12) Patent Application Publication
(10) Pub. No.: US 2020/0058882 A1
(43) Pub. Date: Feb. 20, 2020

(54) ORGANIC ELECTROLUMINESCENT DEVICE

(71) Applicant: ROHM AND HAAS ELECTRONIC MATERIALS KOREA LTD., Chungcheongnam-do (KR)

(72) Inventors: Tae-Jin LEE, Gyeonggi-do (KR); Bitnari KIM, Gyeonggi-do (KR); Hee-Ryong KANG, Gyeonggi-do (KR); Dong-Hyung LEE, Gyeonggi-do (KR); Hong-Se OH, Gyeonggi-do (KR)

(21) Appl. No.: 16/492,632

(22) PCT Filed: Mar. 16, 2018
(86) PCT No.: PCT/KR2018/003101

§ 371 Date: Sep. 10, 2019

(30) Foreign Application Priority Data
Mar. 16, 2017 (KR) 10-2017-0033038
Mar. 7, 2018 (KR) 10-2018-0026943

(51) Int. Cl. H01L 51/00

(52) U.S. Cl. CPC H01L 51/0072; H01L 51/0067; H01L 51/0085; H01L 51/006; H01L 51/5064; H01L 51/0052; H01L 51/0074; H01L 51/0073; H01L 51/0061

(57) ABSTRACT

The present disclosure relates to an organic electroluminescent device comprising a light-emitting layer and a hole transport zone. By comprising the combination of the light-emitting layer and the hole transport zone having a certain HOMO energy value according to the present disclosure, an organic electroluminescent device of excellent luminous efficiency while maintaining excellent lifespan or driving voltage characteristic of the device can be provided.

### TECHNICAL FIELD

The present disclosure relates to an organic electroluminescent device comprising a light-emitting layer and a hole transport zone.

### BACKGROUND ART

The first low molecular green light-emitting organic electroluminescent device was developed by Tang, etc., of Eastman Kodak in 1987 by using TPD/ALq3 bi-layer consisting of a light-emitting layer and a charge transport layer. Thereafter, the development of organic EL devices was rapidly effected and the devices were currently commercialized. Current organic EL devices mostly use phosphorescent materials with excellent luminous efficiency for panel manufacture. For long-term use and high resolution of the display, a low driving voltage and high luminous efficiency are required.

Korean Patent Appln. Laying-Open No. 2015-0071685 A discloses an organic electroluminescent device using a compound comprising a carbazole and a nitrogen-containing 10-membered heteroaryl as a host. However, the reference does not disclose an organic electroluminescent device using a compound comprising a benzoindolocarbazole and a nitrogen-containing 10-membered heteroaryl as a host and comprising a compound having a HOMO (Highest Occupied Molecular Orbital) energy level of −5.0 eV to −4.6 eV between the first electrode and the light-emitting layer.

### DISCLOSURE OF THE INVENTION

### Problems to be Solved

The objective of the present disclosure is to provide an organic electroluminescent device having excellent luminous efficiency while maintaining excellent lifespan or driving voltage characteristic of the device by comprising the combination of a light-emitting layer and a hole transport zone having a certain HOMO energy value.

### Solution to Problems

There was a limit in increasing the efficiency of the light-emitting layer using conventional hole transport zones. In order to have a fast hole mobility, the hole transport zone requires high HOMO energy value. If the HOMO energy value is high, the driving voltage decreases but the efficiency of the light-emitting layer also decreases. In contrast, if the HOMO energy value is low, the efficiency of the light-emitting layer increases but the driving voltage also increases. Thus, realizing a high luminous efficiency of the device is difficult.

As a result of studies of enhancing luminous performance of an organic electroluminescent device comprising a compound represented by the following formula 1 in a light-emitting layer, the present inventors found that the aforementioned problem can be solved by a combination with a hole transport zone comprising a compound of a specific structure and having a certain HOMO energy level and completed the present disclosure.

Specifically, the aforementioned objective can be accomplished by an organic electroluminescent device comprising a first electrode; a second electrode facing the first electrode; a light-emitting layer between the first electrode and the second electrode; and a hole transport zone between the first electrode and the light-emitting layer, wherein the light-emitting layer comprises a compound represented by the following formula 1:

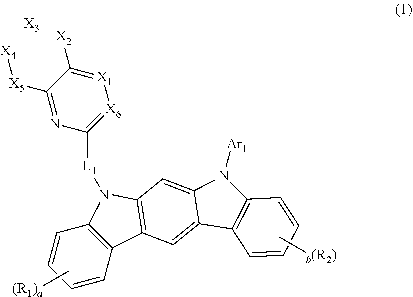

wherein

L₁ represents a single bond, a substituted or unsubstituted (C6-C30)arylene, or a substituted or unsubstituted (5- to 30-membered)heteroarylene;

X₁ to X₆ each independently represent N or CR₃, with a proviso that at least one of X₁ to X₆ represent N;

Ar₁ represents a substituted or unsubstituted (C6-C30)aryl, or a substituted or unsubstituted (5- to 30-membered)heteroaryl;

R₁ to R₃ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₁₁R₁₂, —SiR₁₃R₁₄R₁₅, —SR₁₆, —OR₁₇, a cyano, a nitro, or a hydroxyl, with a proviso that in at least one group of the adjacent two R₁'s and the adjacent two R₂'s groups, the adjacent two R₁'s or the adjacent two R₂'s each independently are linked to each other to form at least one substituted or unsubstituted benzene ring;

R₁₁ to R₁₇ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent(s) to form a substituted or unsubstituted, mono- or polycyclic, (3- to 30-membered) alicyclic or aromatic ring, or the combination thereof, whose carbon atom(s) may be replaced with at least one heteroatom selected from nitrogen, oxygen, and sulfur;

a and b each independently represent an integer of 1 to 4, where if a and b each independently are an integer of 2 or more, each of R₁ and R₂ may be the same or different;

the heteroaryl(ene) contains at least one heteroatom selected from B, N, O, S, Si, and P; and

the heterocycloalkyl contains at least one heteroatom selected from O, S, and N, and

the hole transport zone comprises an arylamine derivative comprising one carbazole or fused carbazole, and the HOMO energy value of the arylamine derivative comprising one carbazole or fused carbazole satisfies the following equation 11:

−5.0 eV≤HOMO≤−4.6 eV (11).

### Effects of the Invention

According to the present disclosure, an organic electroluminescent device of excellent luminous efficiency while maintaining excellent lifespan or driving voltage characteristic of the device can be provided, and it is possible to produce a display device or a lighting device using the same.

### EMBODIMENTS OF THE INVENTION

Hereinafter, the present disclosure will be described in detail. However, the following description is intended to explain the disclosure, and is not meant in any way to restrict the scope of the disclosure.

The term “organic electroluminescent compound” in the present disclosure means a compound that may be used in an organic electroluminescent device, and may be comprised in any layer constituting an organic electroluminescent device, as necessary.

The term “organic electroluminescent material” in the present disclosure means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material, an electron buffer material, a hole blocking material, an electron transport material, or an electron injection material.

The organic electroluminescent device of the present disclosure comprises a first electrode; a second electrode facing the first electrode; and a light-emitting layer between the first electrode and the second electrode, may comprise a hole transport zone between the first electrode and the light-emitting layer, and may comprise an electron transport zone between the light-emitting layer and the second electrode. One of the first and second electrodes may be an anode and the other may be a cathode.

The hole transport zone is meant to be a zone wherein holes are transported between the first electrode and the light-emitting layer, and may comprise, for example, one or more of a hole injection layer, a hole transport layer, a hole auxiliary layer, a light-emitting auxiliary layer, and an electron blocking layer. The hole injection layer, the hole transport layer, the hole auxiliary layer, the light-emitting auxiliary layer, and the electron blocking layer, respectively, may be a single layer, or a multi-layer in which two or more layers are stacked. According to one embodiment of the present disclosure, the hole transport zone may comprise a first hole transport layer and a second hole transport layer. The second hole transport layer may be one or more layers of the multiple hole transport layers, and may comprise one or more of a hole auxiliary layer, a light-emitting auxiliary layer, and an electron blocking layer. In addition, according to another embodiment of the present disclosure, the hole transport zone may comprise a first hole transport layer and a second hole transport layer, in which the first hole transport layer may be placed between the first electrode and the light-emitting layer and the second hole transport layer may be placed between the first hole transport layer and the light-emitting layer, and the second hole transport layer may be a layer which plays a role as a hole transport layer, a light-emitting auxiliary layer, a hole auxiliary layer, and/or an electron blocking layer.

The hole transport layer is placed between the anode (or hole injection layer) and the light-emitting layer, enables the holes transported from the anode to be transported smoothly to the light-emitting layer, and can also function so as to block the electrons transported from the cathode to stay at the light-emitting layer. The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or hole transport, or for preventing the overflow of electrons. When the light-emitting auxiliary layer is placed between the cathode and the light-emitting layer, it can be used for promoting the electron injection and/or electron transport, or for preventing the overflow of holes. Also, the hole auxiliary layer may be placed between the hole transport layer (or hole injection layer) and the light-emitting layer, and may be effective to promote or block the hole transport rate (or hole injection rate), thereby enabling the charge balance to be controlled. Further, the electron blocking layer may be placed between the hole transport layer (or hole injection layer) and the light-emitting layer, and can confine the excitons within the light-emitting layer by blocking the overflow of electrons from the light-emitting layer to prevent a light-emitting leakage. When an organic electroluminescent device includes two or more hole transport layers, the hole transport layer, which is further included, may be used as a light-emitting auxiliary layer, a hole auxiliary layer, an electron blocking layer, etc. The light-emitting auxiliary layer, the hole auxiliary layer, and/or the electron blocking layer may have an effect of improving the luminous efficiency and/or the lifespan of the organic electroluminescent device.

In the organic electroluminescent device of the present disclosure, the hole transport zone comprises an arylamine derivative comprising one carbazole or fused carbazole, and the HOMO energy value of the arylamine derivative comprising one carbazole or fused carbazole satisfies equation 11.

In order to have an appropriately low driving voltage while appropriately increasing the luminous efficiency of the device, a HOMO energy value which can harmonize the first hole transport layer and the light-emitting layer using a hole transport zone is required. For this, it is preferable that the compound comprised in the hole transport zone has a HOMO energy level of −4.6 eV to −5.0 eV. If the HOMO energy level is lower than −5.0 eV, the luminous efficiency of the device increases but there is no significant advantage in terms of power efficiency since the driving voltage also increases as the luminous efficiency increases. If the HOMO energy level is higher than −4.6 eV, the driving voltage of the device decreases but the luminous efficiency also decreases. Hence, the organic electroluminescent device wherein the compound comprised in the hole transport zone has a HOMO energy value satisfying equation 11 and the light-emitting layer comprises a compound represented by formula 1, has high luminous efficiency and an appropriately low driving voltage.

The electron transport zone may comprise one or more of an electron buffer layer, a hole blocking layer, an electron transport layer, and an electron injection layer, and preferably may comprise one or more of an electron transport layer and an electron injection layer. The electron buffer layer is a layer capable of improving the problem that the current characteristics in the device changes upon exposure to a high temperature in a panel fabrication process to cause deformation of light emission luminance, which can control the flow of charge.

The light-emitting layer emits light, which may be a single layer, or a multi-layer in which two or more layers are stacked. The doping concentration of the dopant compound to the host compound in the light-emitting layer is preferably less than 20 wt %.

In the organic electroluminescent device of the present disclosure, the light-emitting layer comprises a compound represented by formula 1.

Hereinafter, the compound represented by formula 1 will be described in detail.

In formula 1, L₁ represents a single bond, a substituted or unsubstituted (C6-C30)arylene, or a substituted or unsubstituted (5- to 30-membered)heteroarylene; preferably, a single bond, a substituted or unsubstituted (C6-C25)arylene, or a substituted or unsubstituted (5- to 25-membered)heteroarylene; more preferably, a single bond, a substituted or unsubstituted (C6-C18)arylene, or a substituted or unsubstituted (5- to 18-membered)heteroarylene; and for example, a single bond, an unsubstituted phenylene, an unsubstituted naphthylene, or an unsubstituted pyridinylene.

In formula 1, X₁ to X₆ each independently represent N or CR₃, with a proviso that at least one of X₁ to X₆ represent N. At least one of X₁ and X₆ may represent N, and X₂ to X₅ may represent CR₃.

In formula 1, the structure of

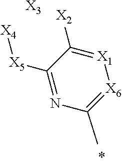

may represent a substituted or unsubstituted quinoxalinyl, a substituted or unsubstituted quinazolinyl, a substituted or unsubstituted naphthyridinyl, a substituted or unsubstituted pyridopyrimidinyl, or a substituted or unsubstituted pyridopyrazinyl; preferably, a substituted or unsubstituted quinoxalinyl, or a substituted or unsubstituted quinazolinyl, and wherein, * represents a bonding site with L₁.

In formula 1, Ar₁ represents a substituted or unsubstituted (C6-C30)aryl, or a substituted or unsubstituted (5- to 30-membered)heteroaryl; preferably, a substituted or unsubstituted (C6-C25)aryl, or a substituted or unsubstituted (5- to 25-membered)heteroaryl; more preferably, a substituted or unsubstituted (C6-C18)aryl, or a substituted or unsubstituted (5- to 18-membered)heteroaryl; and for example, an unsubstituted phenyl, an unsubstituted naphthyl, an unsubstituted biphenyl, a fluorenyl substituted with dimethyl, an unsubstituted phenanthrenyl, or an unsubstituted pyridinyl.

In formula 1, R₁ to R₃ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₁₁R₁₂, —SiR₁₃R₁₄R₁₅, —SR₁₆, —OR₁₇, a cyano, a nitro, or a hydroxyl; preferably, hydrogen, or a substituted or unsubstituted (C6-C25)aryl; and more preferably, hydrogen, or a substituted or unsubstituted (C6-C18)aryl. According to one embodiment of the present disclosure, R₁ and R₂ each independently may represent hydrogen, or an unsubstituted phenyl, and R₃ may represent hydrogen, a phenyl unsubstituted or substituted with at least one methyl, an unsubstituted naphthyl, an unsubstituted biphenyl, an unsubstituted naphthylphenyl, a fluorenyl substituted with dimethyl, or an unsubstituted phenanthrenyl. There is a proviso that in at least one group of the adjacent two R₁'s and the adjacent two R₂'s, the adjacent two R₁'s or the adjacent two R₂'s each independently are linked to each other to form at least one substituted or unsubstituted benzene ring. Also, the adjacent two R₁'s or the adjacent two R₂'s each independently may be linked to each other to form one substituted or unsubstituted benzene ring, and preferably, an unsubstituted benzene ring. When X₁ or X₆ represents CR₃, R₃ may represent a substituted or unsubstituted (C6-C18)aryl. Also, when X₂ to X₅ represent CR₃, R₃ may represent hydrogen. R₁₁ to R₁₇ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent(s) to form a substituted or unsubstituted, mono- or polycyclic, (3- to 30-membered) alicyclic or aromatic ring, or the combination thereof, whose carbon atom(s) may be replaced with at least one heteroatom selected from nitrogen, oxygen, and sulfur.

In formula 1, a and b each independently represent an integer of 1 to 4, and preferably an integer of 1 to 3. If a and b each independently are an integer of 2 or more, each of R₁ and R₂ may be the same or different.

Formula 1 may be represented by any one of the following formulas 2 to 7.

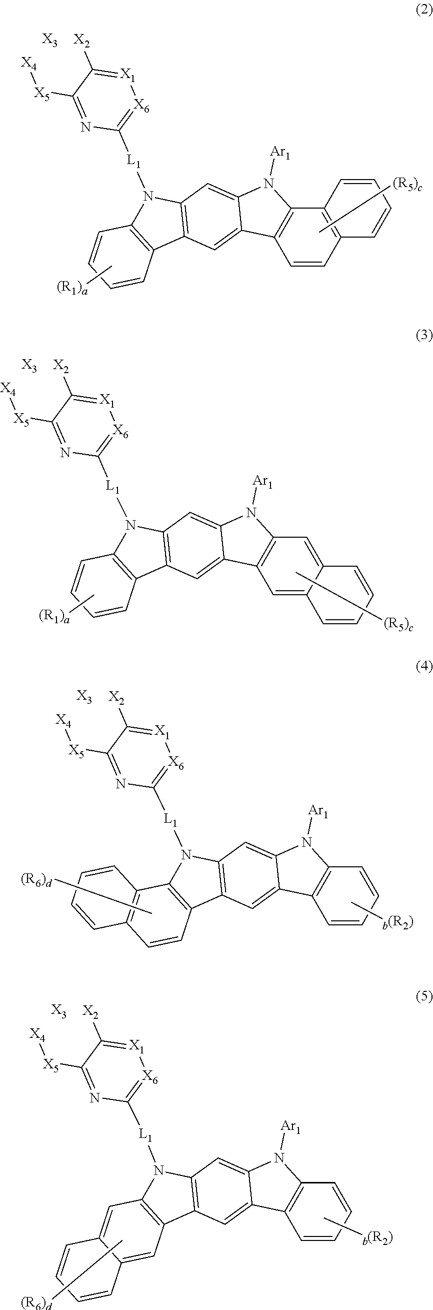

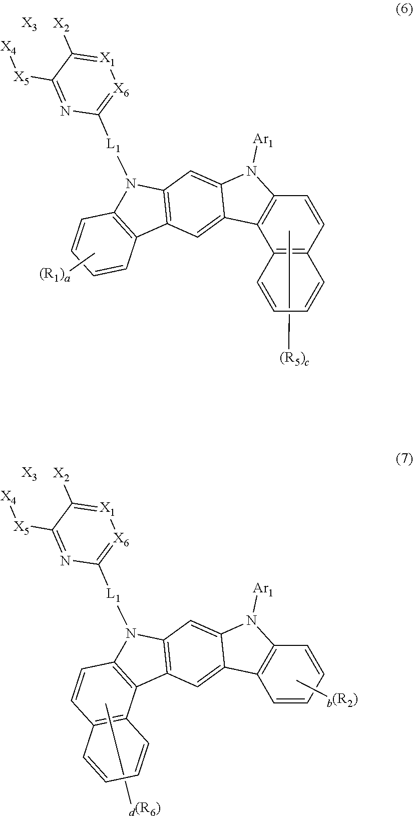

In formulas 2 to 7, L₁, Ar₁, R₁, R₂, X₁ to X₆, a, and b are as defined in formula 1, and R₅ and R₆ are each independently identical to the definition of R₁.

In formulas 2 to 7, c and d each independently represent an integer of 1 to 6; preferably 1 or 2; and more preferably 1. If c and d each independently are an integer of 2 or more, each of R₅ and R₆ may be the same or different.

According to one embodiment of the present disclosure, the arylamine derivative comprising one carbazole or fused carbazole comprised in the hole transport zone of the present disclosure, for example, one or more of a light-emitting auxiliary layer and a hole auxiliary layer, and the second hole transport layer may comprise at least one compound represented by the following formula 11 or 12:

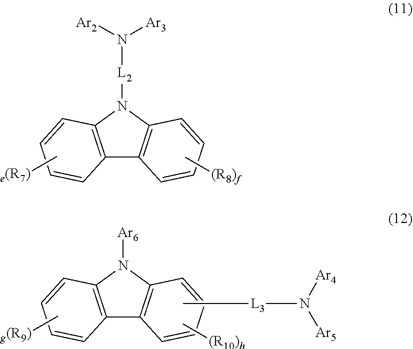

In formulas 11 and 12, Ar₂ to Ar₆ each independently represent a substituted or unsubstituted (C6-C30)aryl, or a substituted or unsubstituted (5- to 30-membered)heteroaryl, preferably, a substituted or unsubstituted (C6-C25)aryl, or a substituted or unsubstituted (5- to 25-membered)heteroaryl, and more preferably, a substituted or unsubstituted (C6-C18)aryl, or a substituted or unsubstituted (5- to 18-membered)heteroaryl. According to one embodiment of the present disclosure, Ar₂ to Ar₅ each independently may represent a phenyl unsubstituted or substituted with a dibenzothiophenyl(s), an unsubstituted naphthyl, a biphenyl unsubstituted or substituted with a dibenzothiophenyl(s), an unsubstituted naphthylphenyl, an unsubstituted terphenyl, a fluorenyl substituted with dimethyl, a benzofluorenyl substituted with dimethyl, or an unsubstituted dibenzothiophenyl, and Ar₆ may represent a phenyl unsubstituted or substituted with a dibenzothiophenyl(s), or an unsubstituted biphenyl.

In formulas 11 and 12, L₂ and L₃ each independently represent a single bond, or a substituted or unsubstituted (C6-C30)arylene, preferably, a single bond, or a substituted or unsubstituted (C6-C25)arylene, and more preferably, a single bond, or a substituted or unsubstituted (C6-C18)arylene. According to one embodiment of the present disclosure, L₂ and L₃ each independently may represent a single bond, a phenylene unsubstituted or substituted with a dibenzothiophenyl(s) or a diphenylamino(s), an unsubstituted biphenylene, an unsubstituted terphenylene, or a fluorenylene substituted with dimethyl.

In formulas 11 and 12, R₇ to R₁₀ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₁₁R₁₂, —SiR₁₃R₁₄R₁₅, —SR₁₆, —OR₁₇, a cyano, a nitro, or a hydroxyl; or may be linked to an adjacent substituent(s) to form a substituted or unsubstituted, mono- or polycyclic, (3- to 30-membered) alicyclic or aromatic ring, or the combination thereof, whose carbon atom(s) may be replaced with at least one heteroatom selected from nitrogen, oxygen, and sulfur, preferably, hydrogen, a substituted or unsubstituted (C6-C18)aryl, a substituted or unsubstituted (5- to 25-membered)heteroaryl, or —NR₁₁R₁₂; or may be linked to an adjacent substituent(s) to form a substituted or unsubstituted, mono- or polycyclic, (5- to 20-membered) alicyclic or aromatic ring, or the combination thereof, whose carbon atom(s) may be replaced with at least one heteroatom selected from nitrogen, oxygen, and sulfur. According to one embodiment of the present disclosure, R₇ to R₁₀ each independently may represent a fluorenyl substituted with dimethyl, an unsubstituted dibenzofuranyl, an unsubstituted dibenzothiophenyl, an unsubstituted benzofuranocarbazolyl, or an unsubstituted diphenylamino; or may be linked to an adjacent substituent(s) to form a benzene ring, a benzofuran ring unsubstituted or substituted with a phenyl(s), a benzothiophene ring unsubstituted or substituted with a phenyl(s), an indene ring substituted with dimethyl, or an indole ring substituted with a phenyl(s).

In formulas 11 and 12, R₁₁ to R₁₇ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent(s) to form a substituted or unsubstituted, mono- or polycyclic, (3- to 30-membered) alicyclic or aromatic ring, or the combination thereof, whose carbon atom(s) may be replaced with at least one heteroatom selected from nitrogen, oxygen, and sulfur. According to one embodiment of the present disclosure, R₁₁ and R₁₂ each independently may represent an unsubstituted phenyl.

In formulas 11 and 12, e to g each independently represent an integer of 1 to 4, and h represents an integer of 1 to 3. If e to h each independently are an integer of 2 or more, each of R₇ to R₁₀ may be the same or different.

Herein, “(C1-C30)alkyl” is meant to be a linear or branched alkyl having 1 to 30 carbon atoms constituting the chain, in which the number of carbon atoms is preferably 1 to 20, more preferably 1 to 10, and includes methyl, ethyl, n-propyl, isopropyl, n-butyl, isobutyl, tert-butyl, etc. “(C2-C30)alkenyl” is meant to be a linear or branched alkenyl having 2 to 30 carbon atoms constituting the chain, in which the number of carbon atoms is preferably 2 to 20, more preferably 2 to 10, and includes vinyl, 1-propenyl, 2-propenyl, 1-butenyl, 2-butenyl, 3-butenyl, 2-methylbut-2-enyl, etc. “(C2-C30)alkynyl” is a linear or branched alkynyl having 2 to 30 carbon atoms constituting the chain, in which the number of carbon atoms is preferably 2 to 20, more preferably 2 to 10, and includes ethynyl, 1-propynyl, 2-propynyl, 1-butynyl, 2-butynyl, 3-butynyl, 1-methylpent-2-ynyl, etc. “(C3-C30)cycloalkyl” is a mono- or polycyclic hydrocarbon having 3 to 30 ring backbone carbon atoms, in which the number of carbon atoms is preferably 3 to 20, more preferably 3 to 7, and includes cyclopropyl, cyclobutyl, cyclopentyl, cyclohexyl, etc. “(3- to 7-membered)heterocycloalkyl” is a cycloalkyl having at least one heteroatom selected from the group consisting of B, N, O, S, Si, and P, preferably O, S, and N, and 3 to 7, preferably 5 to 7 ring backbone atoms, and includes tetrahydrofuran, pyrrolidine, thiolan, tetrahydropyran, etc. “(C6-C30)aryl(ene)” is a monocyclic or fused ring-type radical derived from an aromatic hydrocarbon having 6 to 30 ring backbone carbon atoms, in which the number of ring backbone carbon atoms is preferably 6 to 25, more preferably 6 to 18, may be partially saturated, may comprise a spiro structure, and includes phenyl, biphenyl, terphenyl, naphthyl, binaphthyl, phenylnaphthyl, naphthylphenyl, phenylterphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, spirobifluorenyl, etc. “(5- to 30-membered)heteroaryl(ene)” is an aryl group having at least one, preferably 1 to 4 heteroatoms selected from the group consisting of B, N, O, S, Si, and P, and 5 to 30 ring backbone atoms; is a monocyclic ring, or a fused ring condensed with at least one benzene ring; may be partially saturated; may be one formed by linking at least one heteroaryl or aryl group to a heteroaryl group via a single bond(s); may comprise a spiro structure; and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzimidazolyl, benzothiazolyl, benzoisothiazolyl, benzoisoxazolyl, benzoxazolyl, isoindolyl, indolyl, benzoindolyl, indazolyl, benzothiadiazolyl, quinolyl, isoquinolyl, cinnolinyl, quinazolinyl, benzoquinazolinyl, quinoxalinyl, benzoquinoxalinyl, naphthyridinyl, carbazolyl, benzocarbazolyl, dibenzocarbazolyl, phenoxazinyl, phenothiazinyl, phenanthridinyl, benzodioxolyl, dihydroacrydinyl, etc. “Halogen” includes F, Cl, Br, and I.

Herein, “substituted” in the expression “substituted or unsubstituted” means that a hydrogen atom in a certain functional group is replaced with another atom or functional group, i.e., a substituent. The substituents of the substituted alkyl, the substituted aryl(ene), the substituted heteroaryl(ene), the substituted cycloalkyl, the substituted heterocycloalkyl, the substituted arylalkyl, the substituted benzene ring, and the substituted mono- or polycyclic, alicyclic or aromatic ring, or the combination thereof in L₁ to L₃, Ar₁ to Ar₆, R₁ to R₃, and R₅ to R₁₇ in formulas 1, 11, and 12, each independently are at least one selected from the group consisting of deuterium; a halogen; a cyano; a carboxyl; a nitro; a hydroxyl; a (C1-C30)alkyl; a halo(C1-C30)alkyl; a (C2-C30) alkenyl; a (C2-C30) alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (5- to 30-membered)heteroaryl unsubstituted or substituted with a (C6-C30)aryl; a (C6-C30)aryl unsubstituted or substituted with a (5- to 30-membered)heteroaryl; a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di-(C1-C30)alkylamino; a mono- or di-(C6-C30)arylamino; a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl, and for example, may be methyl, phenyl, naphthyl, dibenzothiophenyl, or diphenylamino.

The compound represented by formula 1 includes the following compounds, but is not limited thereto:

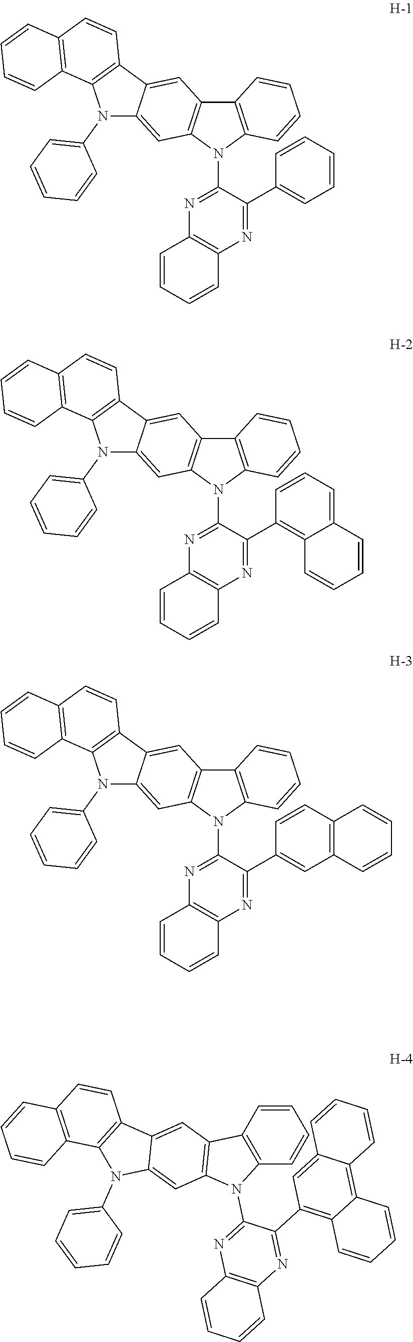 [SMILES: c1ccc(-c2nc3ccccc3nc2-n2c3ccccc3c3cc4c5ccc6ccccc6c5n(-c5ccccc5)c4cc32)cc1 ; c1ccc(-n2c3cc4c(cc3c3ccc5ccccc5c32)c2ccccc2n4-c2nc3ccccc3nc2-c2cccc3ccccc23)cc1 ; c1ccc(-n2c3cc4c(cc3c3ccc5ccccc5c32)c2ccccc2n4-c2nc3ccccc3nc2-c2ccc3ccccc3c2)cc1 ; c1ccc(-n2c3cc4c(cc3c3ccc5ccccc5c32)c2ccccc2n4-c2nc3ccccc3nc2-c2cc3ccccc3c3ccccc23)cc1]

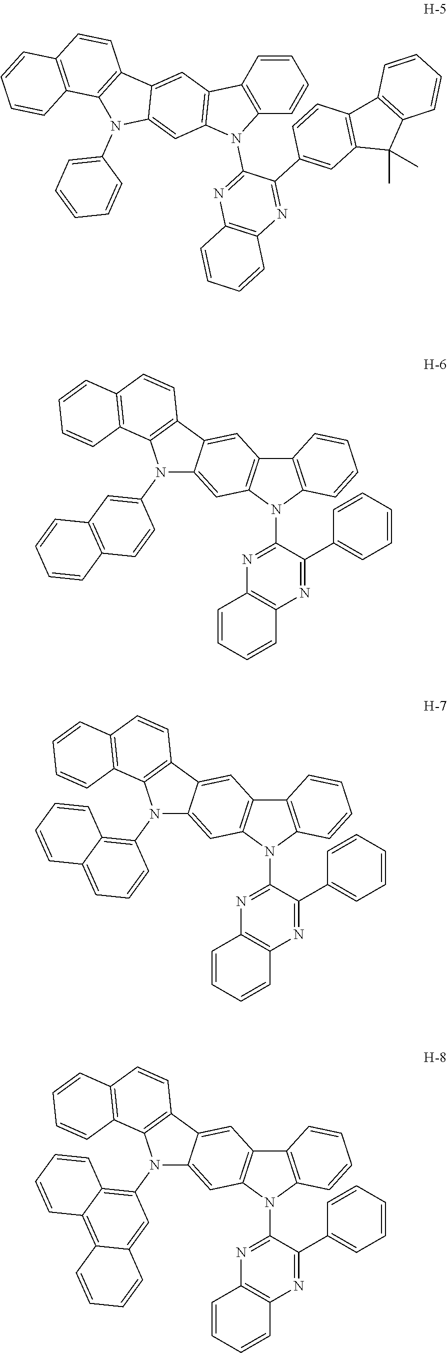 [SMILES: CC1(C)c2ccccc2-c2ccc(-c3nc4ccccc4nc3-n3c4ccccc4c4cc5c6ccc7ccccc7c6n(-c6ccccc6)c5cc43)cc21 ; c1ccc(-c2nc3ccccc3nc2-n2c3ccccc3c3cc4c5ccc6ccccc6c5n(-c5ccc6ccccc6c5)c4cc32)cc1 ; c1ccc(-c2nc3ccccc3nc2-n2c3ccccc3c3cc4c5ccc6ccccc6c5n(-c5cccc6ccccc56)c4cc32)cc1 ; c1ccc(-c2nc3ccccc3nc2-n2c3ccccc3c3cc4c5ccc6ccccc6c5n(-c5cc6ccccc6c6ccccc56)c4cc32)cc1]

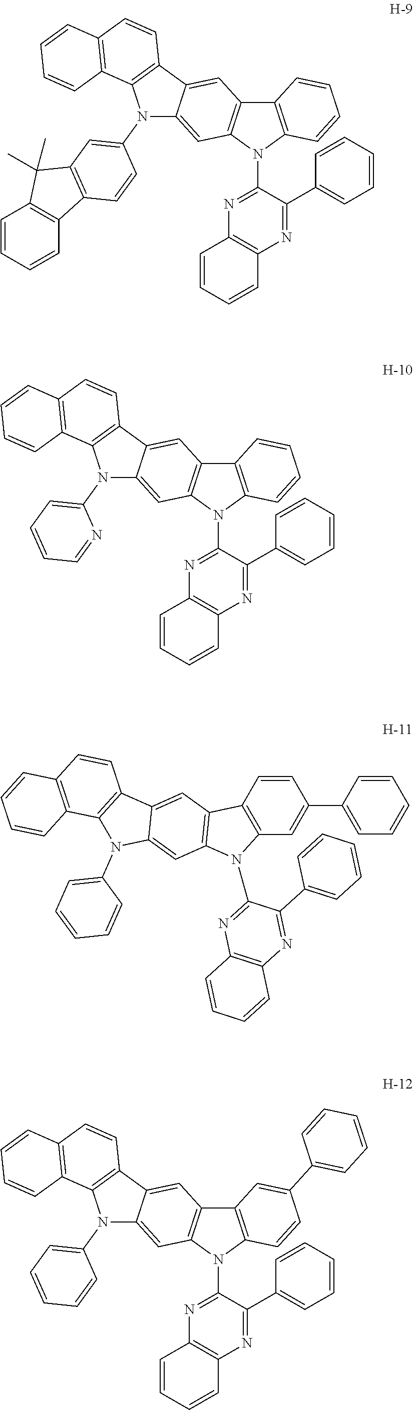 [SMILES: CC1(C)c2ccccc2-c2ccc(-n3c4cc5c(cc4c4ccc6ccccc6c43)c3ccccc3n5-c3nc4ccccc4nc3-c3ccccc3)cc21 ; c1ccc(-c2nc3ccccc3nc2-n2c3ccccc3c3cc4c5ccc6ccccc6c5n(-c5ccccn5)c4cc32)cc1 ; c1ccc(-c2ccc3c4cc5c6ccc7ccccc7c6n(-c6ccccc6)c5cc4n(-c4nc5ccccc5nc4-c4ccccc4)c3c2)cc1 ; c1ccc(-c2ccc3c(c2)c2cc4c5ccc6ccccc6c5n(-c5ccccc5)c4cc2n3-c2nc3ccccc3nc2-c2ccccc2)cc1]

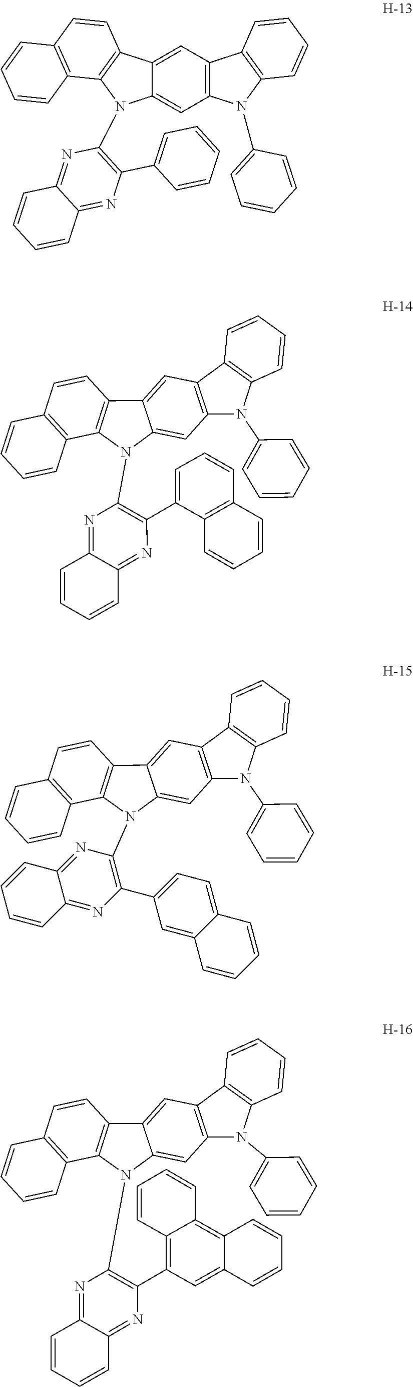 [SMILES: c1ccc(-c2nc3ccccc3nc2-n2c3cc4c(cc3c3ccc5ccccc5c32)c2ccccc2n4-c2ccccc2)cc1 ; c1ccc(-n2c3ccccc3c3cc4c5ccc6ccccc6c5n(-c5nc6ccccc6nc5-c5cccc6ccccc56)c4cc32)cc1 ; c1ccc(-n2c3ccccc3c3cc4c5ccc6ccccc6c5n(-c5nc6ccccc6nc5-c5ccc6ccccc6c5)c4cc32)cc1 ; c1ccc(-n2c3ccccc3c3cc4c5ccc6ccccc6c5n(-c5nc6ccccc6nc5-c5cc6ccccc6c6ccccc56)c4cc32)cc1]

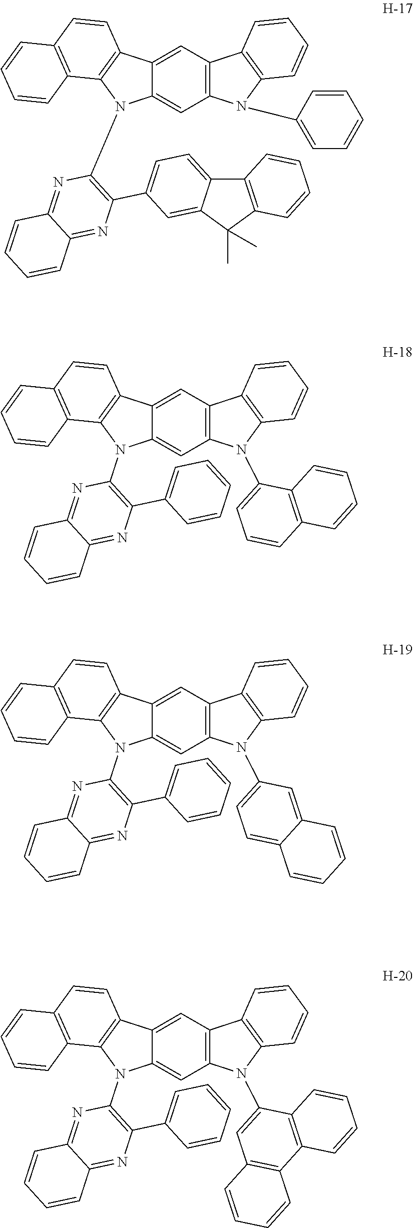 [SMILES: CC1(C)c2ccccc2-c2ccc(-c3nc4ccccc4nc3-n3c4cc5c(cc4c4ccc6ccccc6c43)c3ccccc3n5-c3ccccc3)cc21 ; c1ccc(-c2nc3ccccc3nc2-n2c3cc4c(cc3c3ccc5ccccc5c32)c2ccccc2n4-c2cccc3ccccc23)cc1 ; c1ccc(-c2nc3ccccc3nc2-n2c3cc4c(cc3c3ccc5ccccc5c32)c2ccccc2n4-c2ccc3ccccc3c2)cc1 ; c1ccc(-c2nc3ccccc3nc2-n2c3cc4c(cc3c3ccc5ccccc5c32)c2ccccc2n4-c2cc3ccccc3c3ccccc23)cc1]

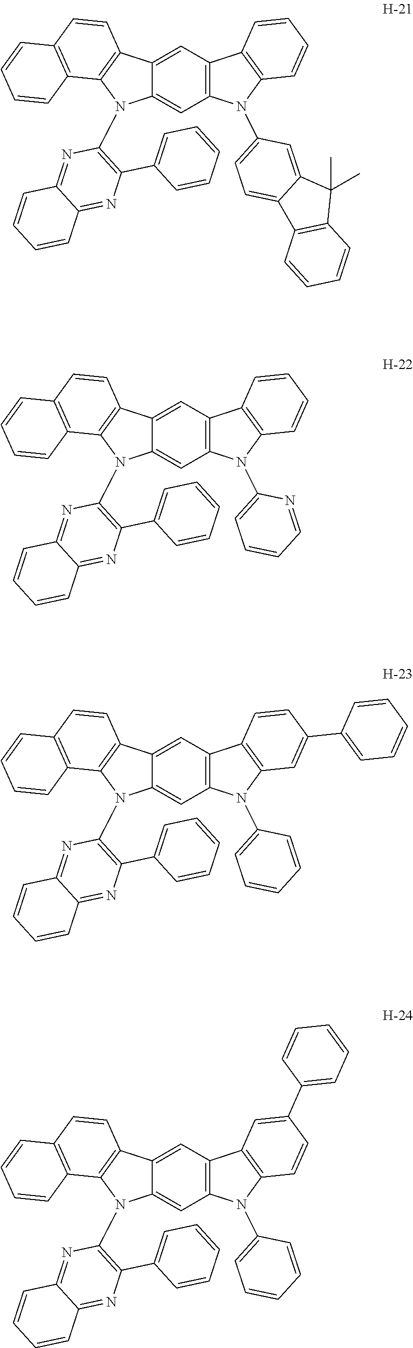 [SMILES: CC1(C)c2ccccc2-c2ccc(-n3c4ccccc4c4cc5c6ccc7ccccc7c6n(-c6nc7ccccc7nc6-c6ccccc6)c5cc43)cc21 ; c1ccc(-c2nc3ccccc3nc2-n2c3cc4c(cc3c3ccc5ccccc5c32)c2ccccc2n4-c2ccccn2)cc1 ; c1ccc(-c2ccc3c4cc5c6ccc7ccccc7c6n(-c6nc7ccccc7nc6-c6ccccc6)c5cc4n(-c4ccccc4)c3c2)cc1 ; c1ccc(-c2ccc3c(c2)c2cc4c5ccc6ccccc6c5n(-c5nc6ccccc6nc5-c5ccccc5)c4cc2n3-c2ccccc2)cc1]

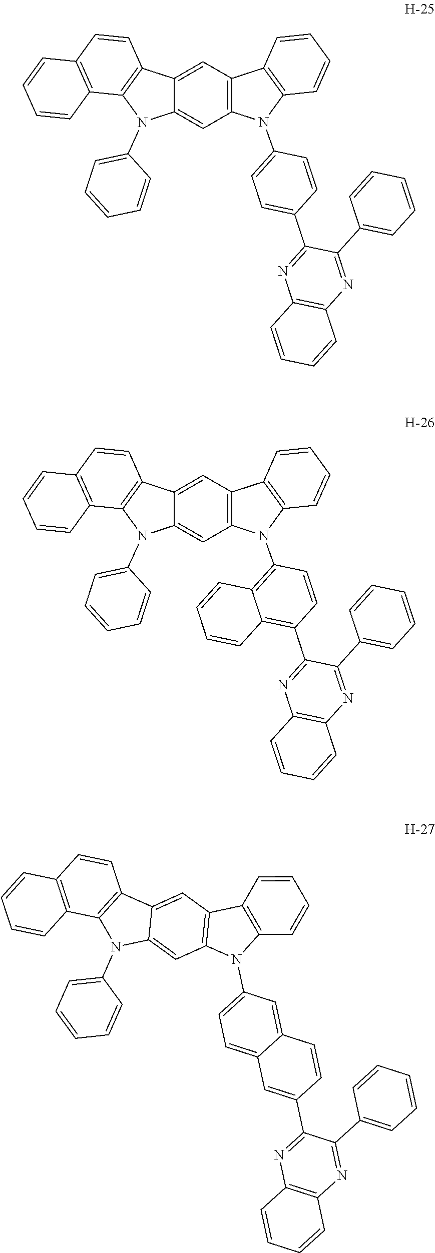 [SMILES: c1ccc(-c2nc3ccccc3nc2-c2ccc(-n3c4ccccc4c4cc5c6ccc7ccccc7c6n(-c6ccccc6)c5cc43)cc2)cc1 ; c1ccc(-c2nc3ccccc3nc2-c2ccc(-n3c4ccccc4c4cc5c6ccc7ccccc7c6n(-c6ccccc6)c5cc43)c3ccccc23)cc1 ; c1ccc(-c2nc3ccccc3nc2-c2ccc3cc(-n4c5ccccc5c5cc6c7ccc8ccccc8c7n(-c7ccccc7)c6cc54)ccc3c2)cc1]

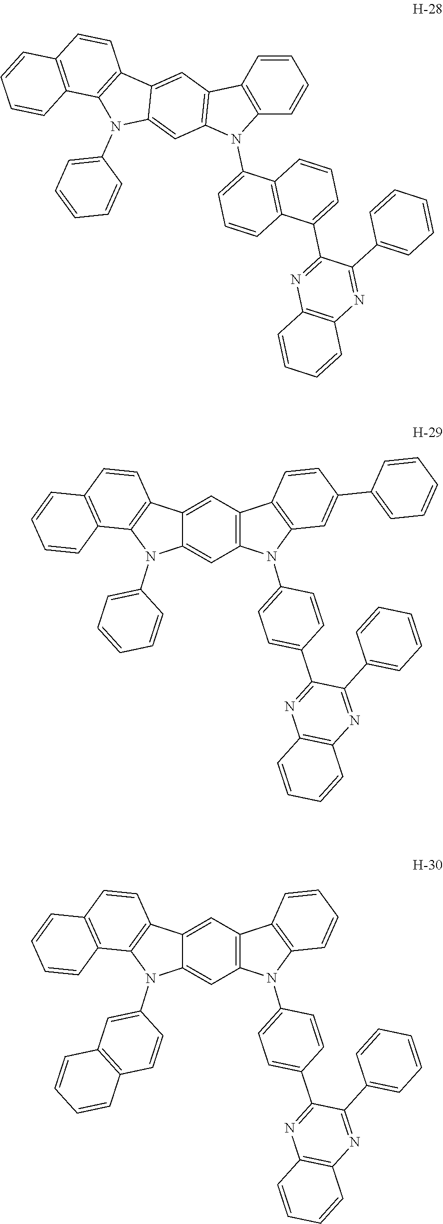 [SMILES: c1ccc(-c2nc3ccccc3nc2-c2cccc3c(-n4c5ccccc5c5cc6c7ccc8ccccc8c7n(-c7ccccc7)c6cc54)cccc23)cc1 ; c1ccc(-c2ccc3c4cc5c6ccc7ccccc7c6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6ccc7ccccc7c6n(-c6ccc7ccccc7c6)c5cc43)cc2)cc1]

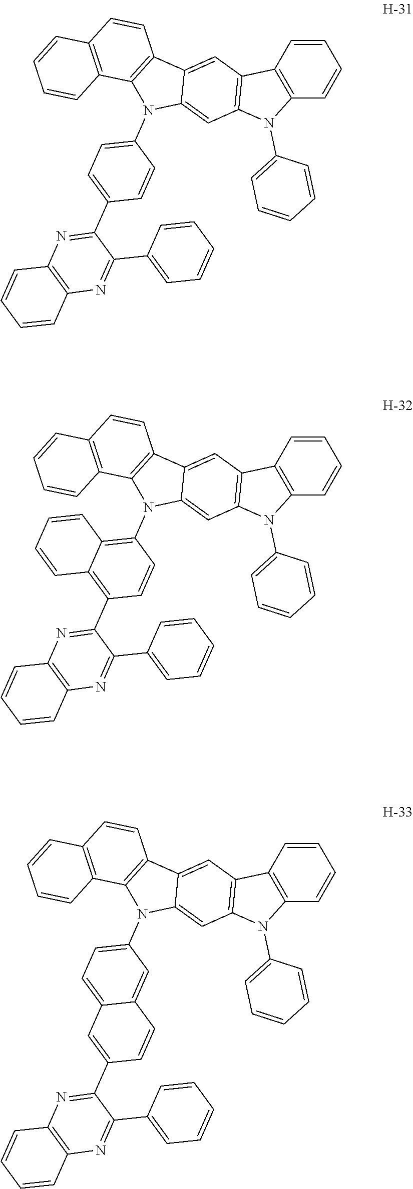 [SMILES: c1ccc(-c2nc3ccccc3nc2-c2ccc(-n3c4cc5c(cc4c4ccc6ccccc6c43)c3ccccc3n5-c3ccccc3)cc2)cc1 ; c1ccc(-c2nc3ccccc3nc2-c2ccc(-n3c4cc5c(cc4c4ccc6ccccc6c43)c3ccccc3n5-c3ccccc3)c3ccccc23)cc1 ; c1ccc(-c2nc3ccccc3nc2-c2ccc3cc(-n4c5cc6c(cc5c5ccc7ccccc7c54)c4ccccc4n6-c4ccccc4)ccc3c2)cc1]

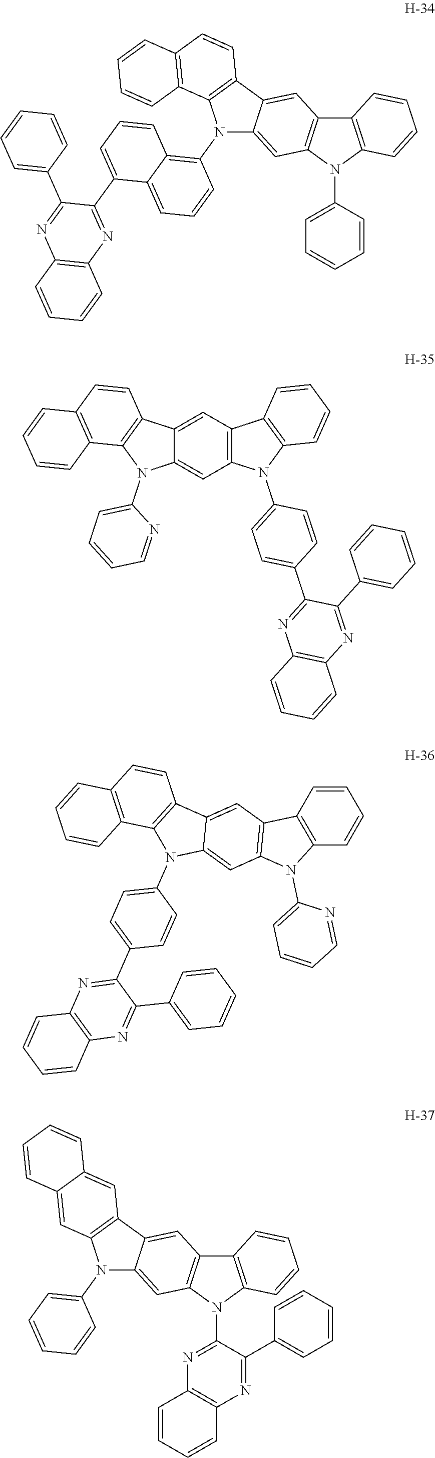 [SMILES: c1ccc(-c2nc3ccccc3nc2-c2cccc3c(-n4c5cc6c(cc5c5ccc7ccccc7c54)c4ccccc4n6-c4ccccc4)cccc23)cc1 ; c1ccc(-c2nc3ccccc3nc2-c2ccc(-n3c4ccccc4c4cc5c6ccc7ccccc7c6n(-c6ccccn6)c5cc43)cc2)cc1 ; c1ccc(-c2nc3ccccc3nc2-c2ccc(-n3c4cc5c(cc4c4ccc6ccccc6c43)c3ccccc3n5-c3ccccn3)cc2)cc1 ; c1ccc(-c2nc3ccccc3nc2-n2c3ccccc3c3cc4c5cc6ccccc6cc5n(-c5ccccc5)c4cc32)cc1]

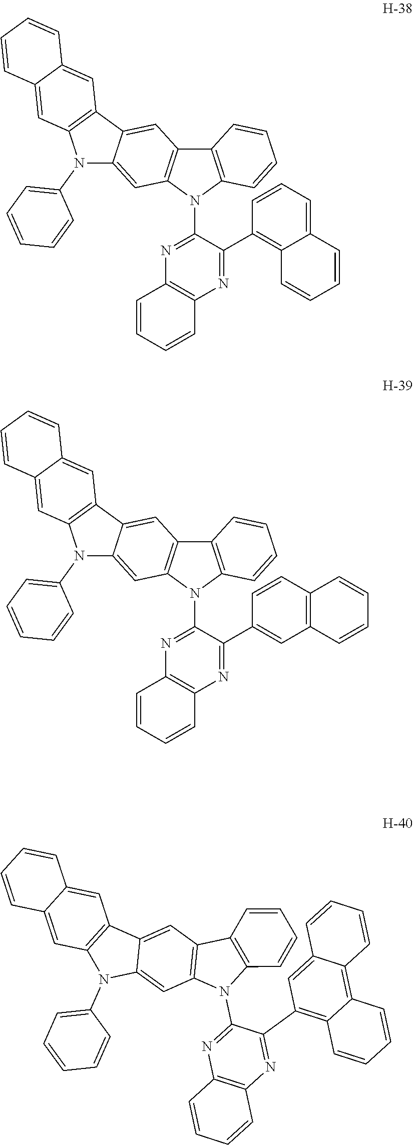 [SMILES: c1ccc(-n2c3cc4ccccc4cc3c3cc4c5ccccc5n(-c5nc6ccccc6nc5-c5cccc6ccccc56)c4cc32)cc1 ; c1ccc(-n2c3cc4ccccc4cc3c3cc4c5ccccc5n(-c5nc6ccccc6nc5-c5ccc6ccccc6c5)c4cc32)cc1 ; c1ccc(-n2c3cc4ccccc4cc3c3cc4c5ccccc5n(-c5nc6ccccc6nc5-c5cc6ccccc6c6ccccc56)c4cc32)cc1]

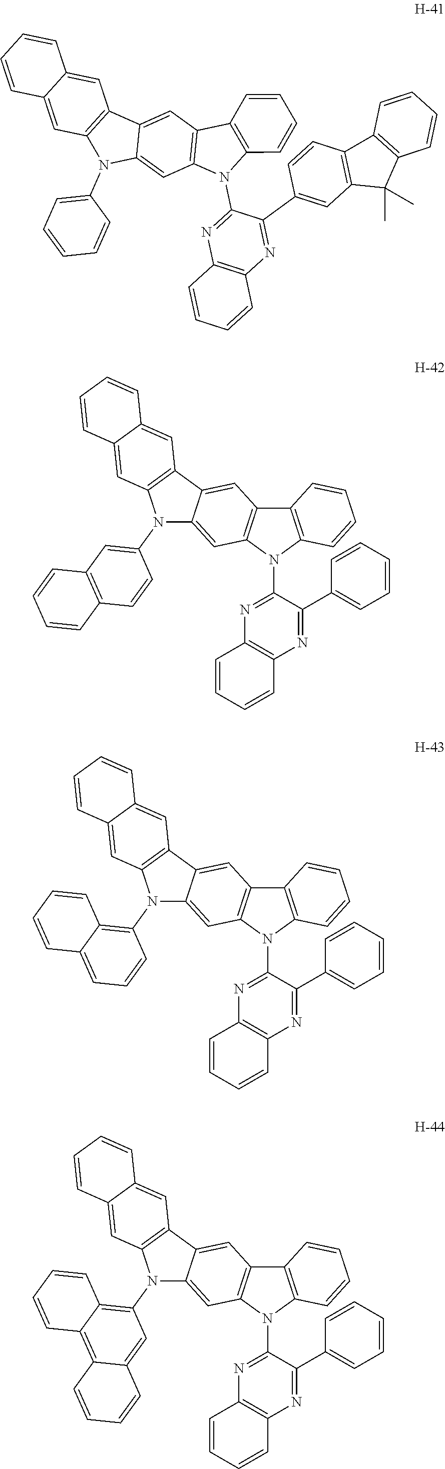 [SMILES: CC1(C)c2ccccc2-c2ccc(-c3nc4ccccc4nc3-n3c4ccccc4c4cc5c6cc7ccccc7cc6n(-c6ccccc6)c5cc43)cc21 ; c1ccc(-c2nc3ccccc3nc2-n2c3ccccc3c3cc4c5cc6ccccc6cc5n(-c5ccc6ccccc6c5)c4cc32)cc1 ; c1ccc(-c2nc3ccccc3nc2-n2c3ccccc3c3cc4c5cc6ccccc6cc5n(-c5cccc6ccccc56)c4cc32)cc1 ; c1ccc(-c2nc3ccccc3nc2-n2c3ccccc3c3cc4c5cc6ccccc6cc5n(-c5cc6ccccc6c6ccccc56)c4cc32)cc1]

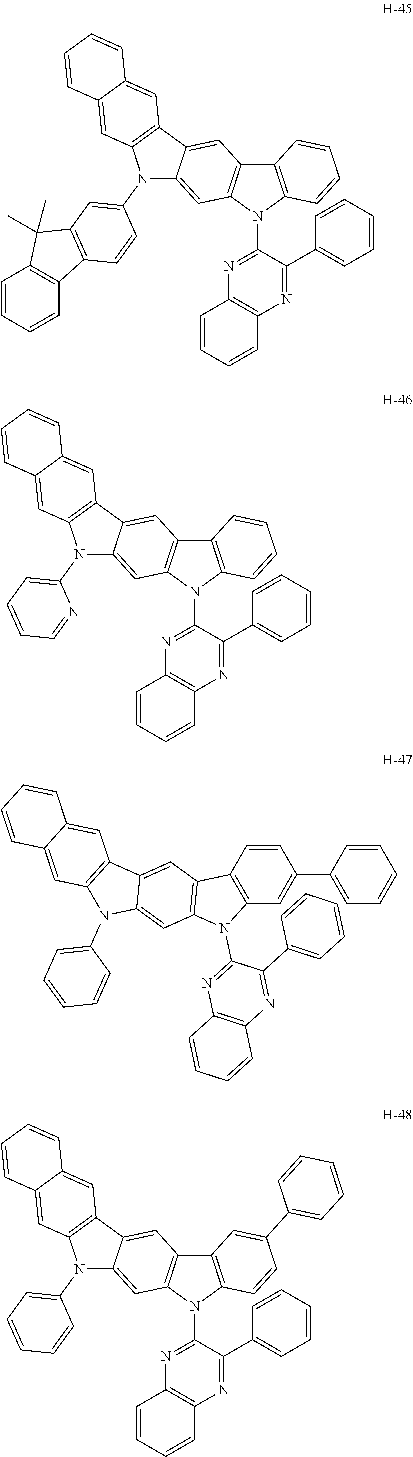 [SMILES: CC1(C)c2ccccc2-c2ccc(-n3c4cc5ccccc5cc4c4cc5c6ccccc6n(-c6nc7ccccc7nc6-c6ccccc6)c5cc43)cc21 ; c1ccc(-c2nc3ccccc3nc2-n2c3ccccc3c3cc4c5cc6ccccc6cc5n(-c5ccccn5)c4cc32)cc1 ; c1ccc(-c2ccc3c4cc5c6cc7ccccc7cc6n(-c6ccccc6)c5cc4n(-c4nc5ccccc5nc4-c4ccccc4)c3c2)cc1 ; c1ccc(-c2ccc3c(c2)c2cc4c5cc6ccccc6cc5n(-c5ccccc5)c4cc2n3-c2nc3ccccc3nc2-c2ccccc2)cc1]

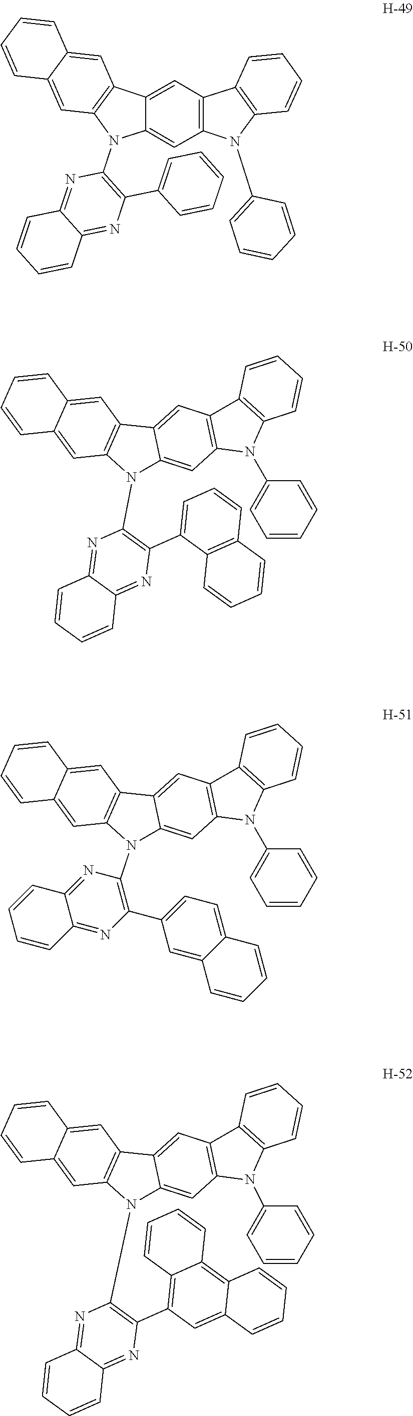 [SMILES: c1ccc(-c2nc3ccccc3nc2-n2c3cc4ccccc4cc3c3cc4c5ccccc5n(-c5ccccc5)c4cc32)cc1 ; c1ccc(-n2c3ccccc3c3cc4c5cc6ccccc6cc5n(-c5nc6ccccc6nc5-c5cccc6ccccc56)c4cc32)cc1 ; c1ccc(-n2c3ccccc3c3cc4c5cc6ccccc6cc5n(-c5nc6ccccc6nc5-c5ccc6ccccc6c5)c4cc32)cc1 ; c1ccc(-n2c3ccccc3c3cc4c5cc6ccccc6cc5n(-c5nc6ccccc6nc5-c5cc6ccccc6c6ccccc56)c4cc32)cc1]

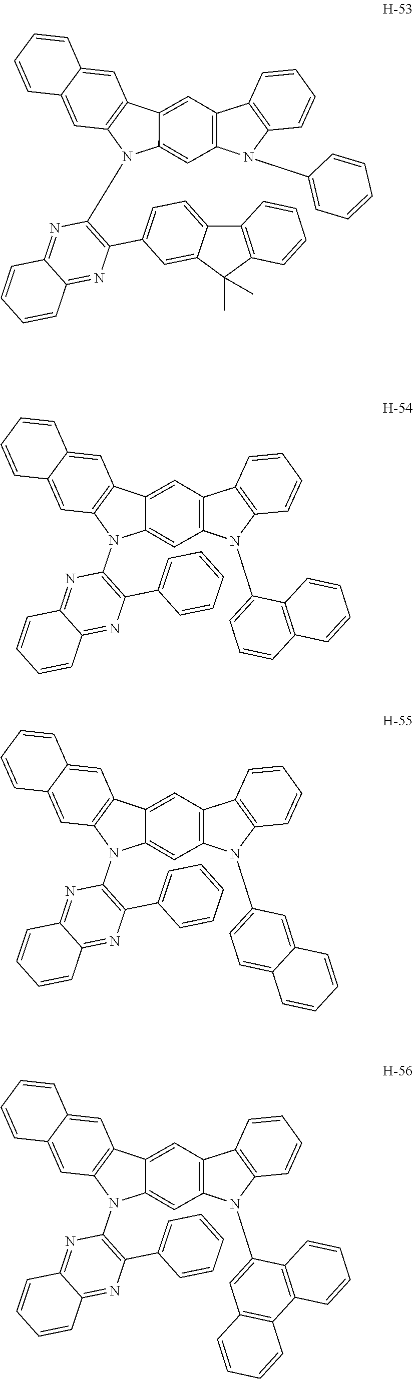 [SMILES: CC1(C)c2ccccc2-c2ccc(-c3nc4ccccc4nc3-n3c4cc5ccccc5cc4c4cc5c6ccccc6n(-c6ccccc6)c5cc43)cc21 ; c1ccc(-c2nc3ccccc3nc2-n2c3cc4ccccc4cc3c3cc4c5ccccc5n(-c5cccc6ccccc56)c4cc32)cc1 ; c1ccc(-c2nc3ccccc3nc2-n2c3cc4ccccc4cc3c3cc4c5ccccc5n(-c5ccc6ccccc6c5)c4cc32)cc1 ; c1ccc(-c2nc3ccccc3nc2-n2c3cc4ccccc4cc3c3cc4c5ccccc5n(-c5cc6ccccc6c6ccccc56)c4cc32)cc1]

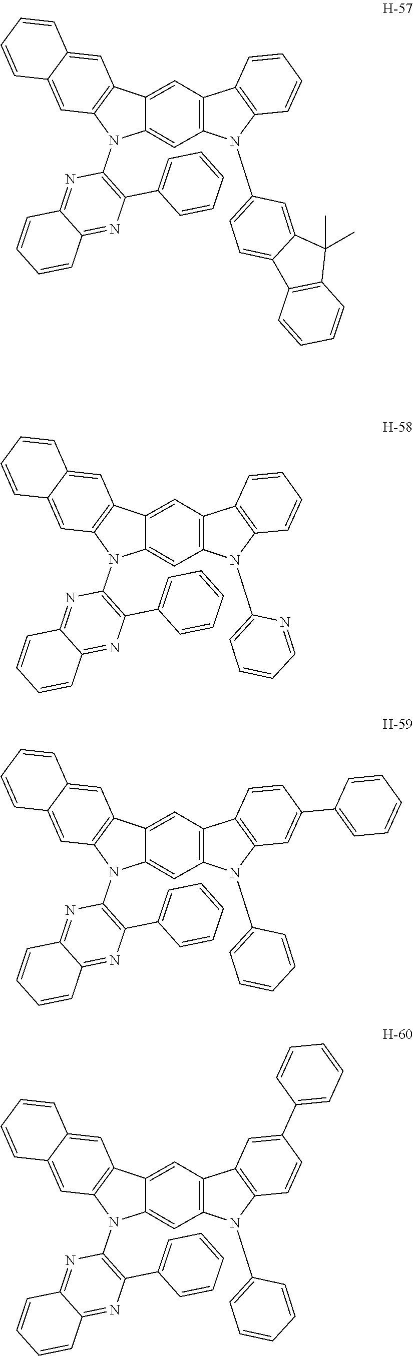 [SMILES: CC1(C)c2ccccc2-c2ccc(-n3c4ccccc4c4cc5c6cc7ccccc7cc6n(-c6nc7ccccc7nc6-c6ccccc6)c5cc43)cc21 ; c1ccc(-c2nc3ccccc3nc2-n2c3cc4ccccc4cc3c3cc4c5ccccc5n(-c5ccccn5)c4cc32)cc1 ; c1ccc(-c2ccc3c4cc5c6cc7ccccc7cc6n(-c6nc7ccccc7nc6-c6ccccc6)c5cc4n(-c4ccccc4)c3c2)cc1 ; c1ccc(-c2ccc3c(c2)c2cc4c5cc6ccccc6cc5n(-c5nc6ccccc6nc5-c5ccccc5)c4cc2n3-c2ccccc2)cc1]

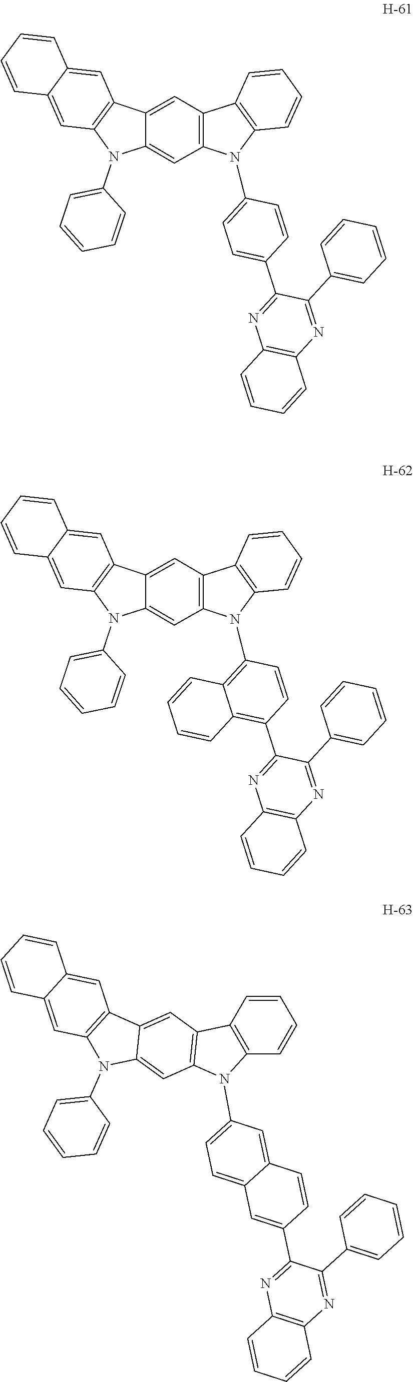 [SMILES: c1ccc(-c2nc3ccccc3nc2-c2ccc(-n3c4ccccc4c4cc5c6cc7ccccc7cc6n(-c6ccccc6)c5cc43)cc2)cc1 ; c1ccc(-c2nc3ccccc3nc2-c2ccc(-n3c4ccccc4c4cc5c6cc7ccccc7cc6n(-c6ccccc6)c5cc43)c3ccccc23)cc1 ; c1ccc(-c2nc3ccccc3nc2-c2ccc3cc(-n4c5ccccc5c5cc6c7cc8ccccc8cc7n(-c7ccccc7)c6cc54)ccc3c2)cc1]

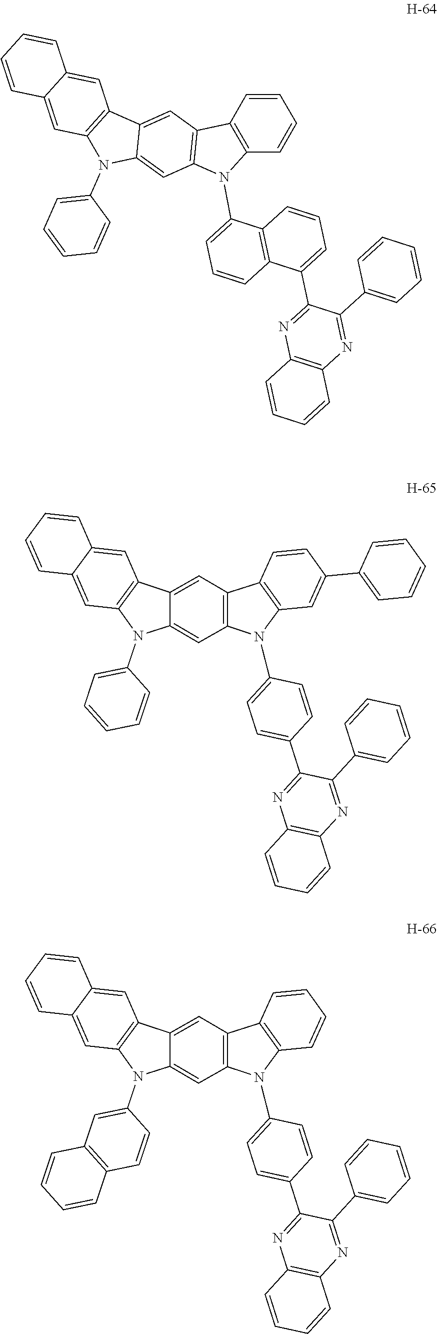 [SMILES: c1ccc(-c2nc3ccccc3nc2-c2cccc3c(-n4c5ccccc5c5cc6c7cc8ccccc8cc7n(-c7ccccc7)c6cc54)cccc23)cc1 ; c1ccc(-c2ccc3c4cc5c6cc7ccccc7cc6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6cc7ccccc7cc6n(-c6ccc7ccccc7c6)c5cc43)cc2)cc1]

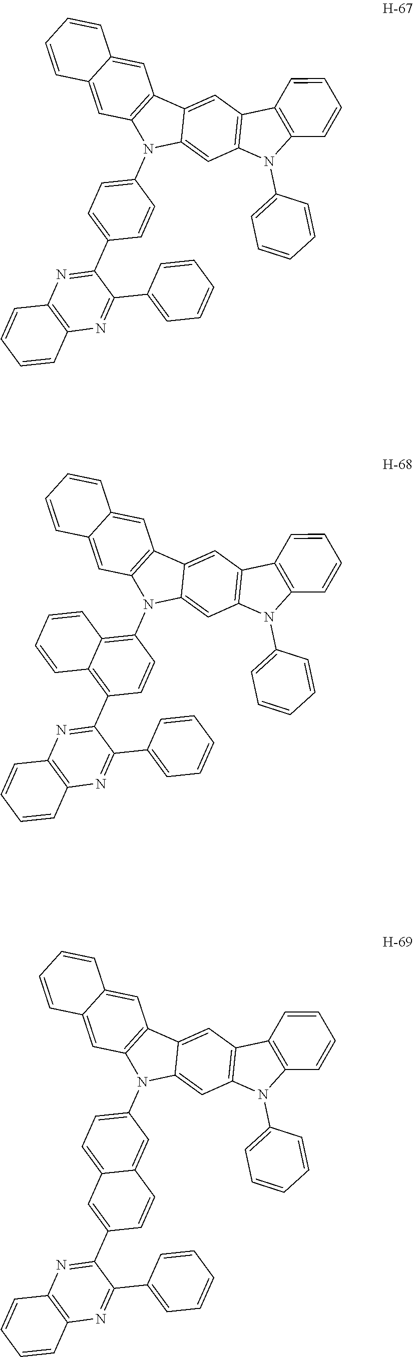 [SMILES: c1ccc(-c2nc3ccccc3nc2-c2ccc(-n3c4cc5ccccc5cc4c4cc5c6ccccc6n(-c6ccccc6)c5cc43)cc2)cc1 ; c1ccc(-c2nc3ccccc3nc2-c2ccc(-n3c4cc5ccccc5cc4c4cc5c6ccccc6n(-c6ccccc6)c5cc43)c3ccccc23)cc1 ; c1ccc(-c2nc3ccccc3nc2-c2ccc3cc(-n4c5cc6ccccc6cc5c5cc6c7ccccc7n(-c7ccccc7)c6cc54)ccc3c2)cc1]

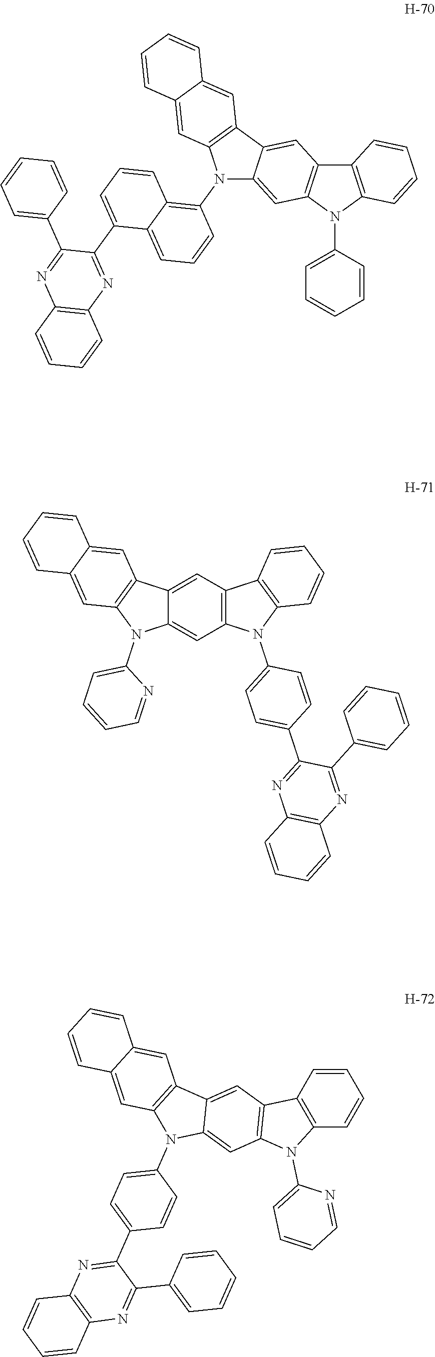 [SMILES: c1ccc(-c2nc3ccccc3nc2-c2cccc3c(-n4c5cc6ccccc6cc5c5cc6c7ccccc7n(-c7ccccc7)c6cc54)cccc23)cc1 ; c1ccc(-c2nc3ccccc3nc2-c2ccc(-n3c4ccccc4c4cc5c6cc7ccccc7cc6n(-c6ccccn6)c5cc43)cc2)cc1 ; c1ccc(-c2nc3ccccc3nc2-c2ccc(-n3c4cc5ccccc5cc4c4cc5c6ccccc6n(-c6ccccn6)c5cc43)cc2)cc1]

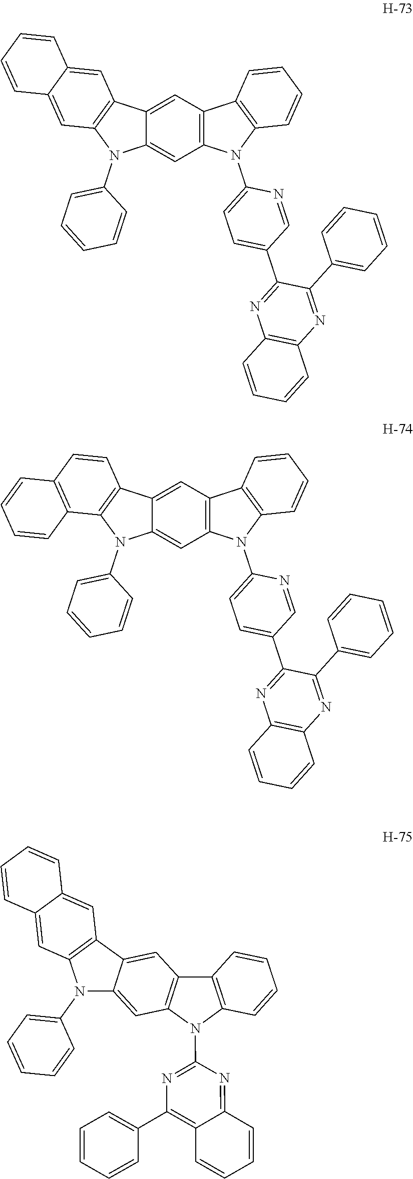 [SMILES: c1ccc(-c2nc3ccccc3nc2-c2ccc(-n3c4ccccc4c4cc5c6cc7ccccc7cc6n(-c6ccccc6)c5cc43)nc2)cc1 ; c1ccc(-c2nc3ccccc3nc2-c2ccc(-n3c4ccccc4c4cc5c6ccc7ccccc7c6n(-c6ccccc6)c5cc43)nc2)cc1 ; c1ccc(-c2nc(-n3c4ccccc4c4cc5c6cc7ccccc7cc6n(-c6ccccc6)c5cc43)nc3ccccc23)cc1]

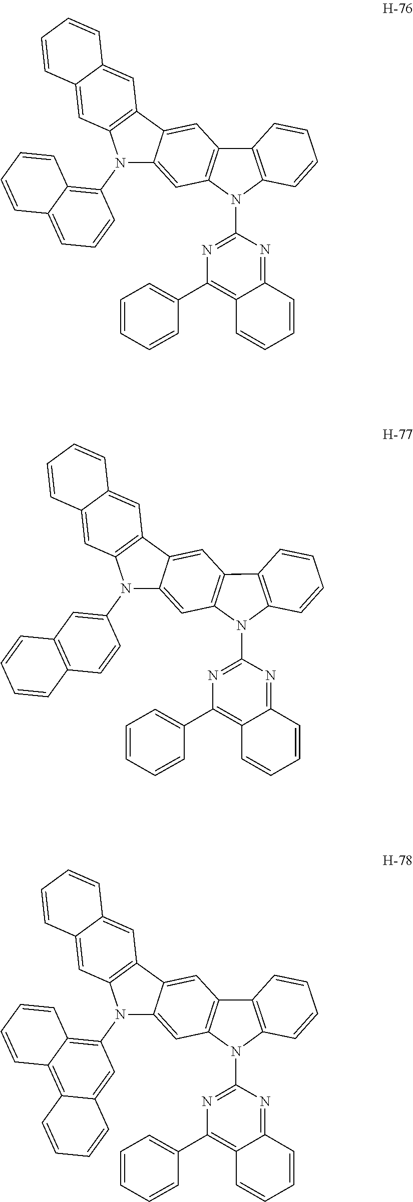 [SMILES: c1ccc(-c2nc(-n3c4ccccc4c4cc5c6cc7ccccc7cc6n(-c6cccc7ccccc67)c5cc43)nc3ccccc23)cc1 ; c1ccc(-c2nc(-n3c4ccccc4c4cc5c6cc7ccccc7cc6n(-c6ccc7ccccc7c6)c5cc43)nc3ccccc23)cc1 ; c1ccc(-c2nc(-n3c4ccccc4c4cc5c6cc7ccccc7cc6n(-c6cc7ccccc7c7ccccc67)c5cc43)nc3ccccc23)cc1]

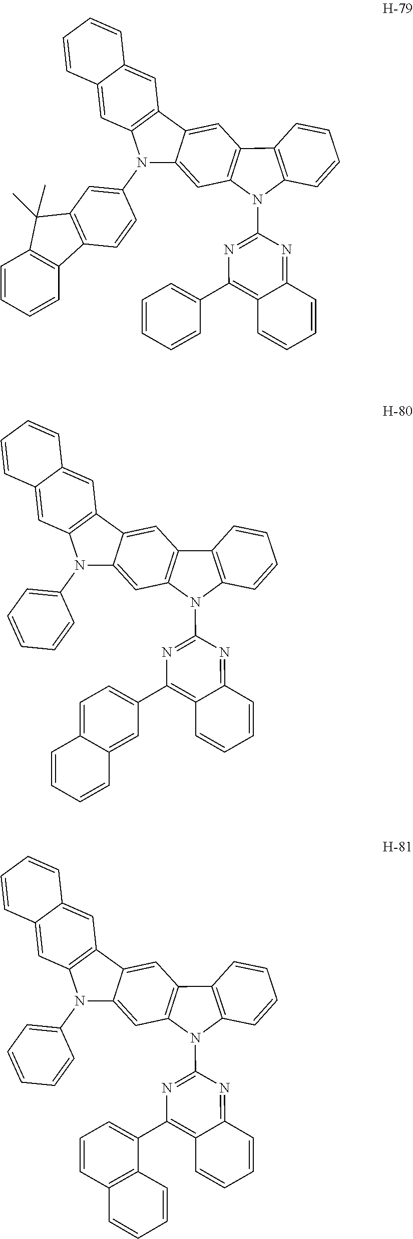 [SMILES: CC1(C)c2ccccc2-c2ccc(-n3c4cc5ccccc5cc4c4cc5c6ccccc6n(-c6nc(-c7ccccc7)c7ccccc7n6)c5cc43)cc21 ; c1ccc(-n2c3cc4ccccc4cc3c3cc4c5ccccc5n(-c5nc(-c6ccc7ccccc7c6)c6ccccc6n5)c4cc32)cc1 ; c1ccc(-n2c3cc4ccccc4cc3c3cc4c5ccccc5n(-c5nc(-c6cccc7ccccc67)c6ccccc6n5)c4cc32)cc1]

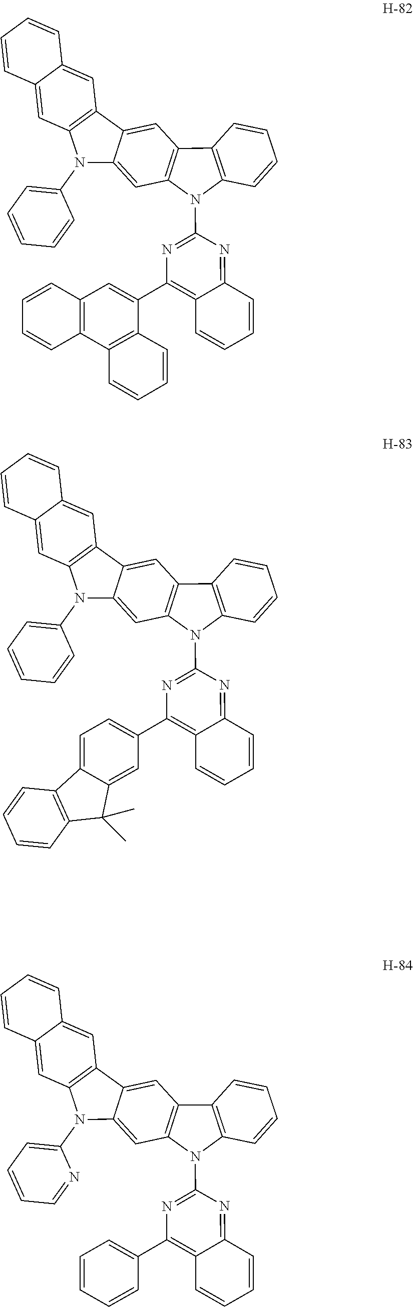 [SMILES: c1ccc(-n2c3cc4ccccc4cc3c3cc4c5ccccc5n(-c5nc(-c6cc7ccccc7c7ccccc67)c6ccccc6n5)c4cc32)cc1 ; CC1(C)c2ccccc2-c2ccc(-c3nc(-n4c5ccccc5c5cc6c7cc8ccccc8cc7n(-c7ccccc7)c6cc54)nc4ccccc34)cc21 ; c1ccc(-c2nc(-n3c4ccccc4c4cc5c6cc7ccccc7cc6n(-c6ccccn6)c5cc43)nc3ccccc23)cc1]

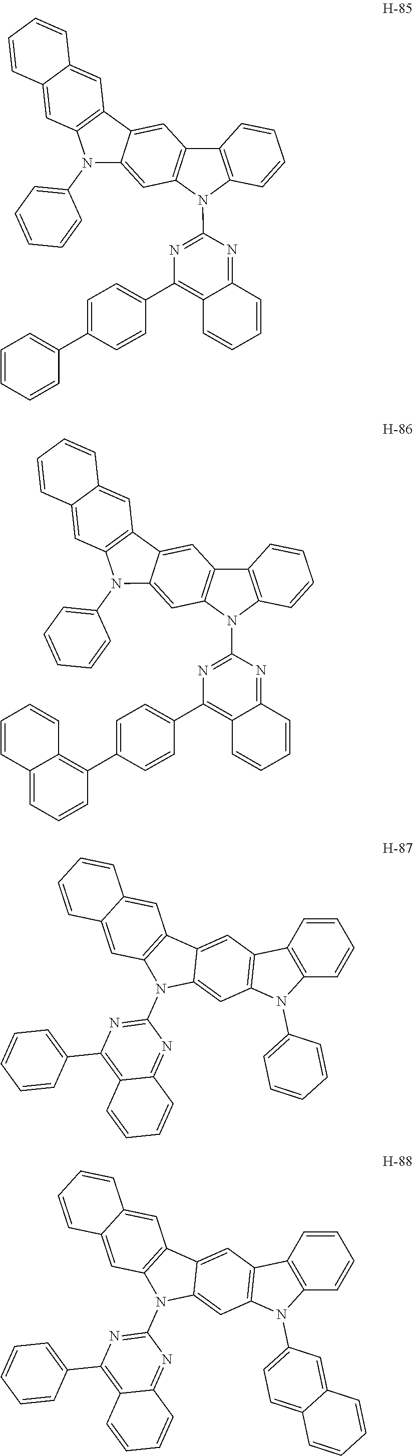

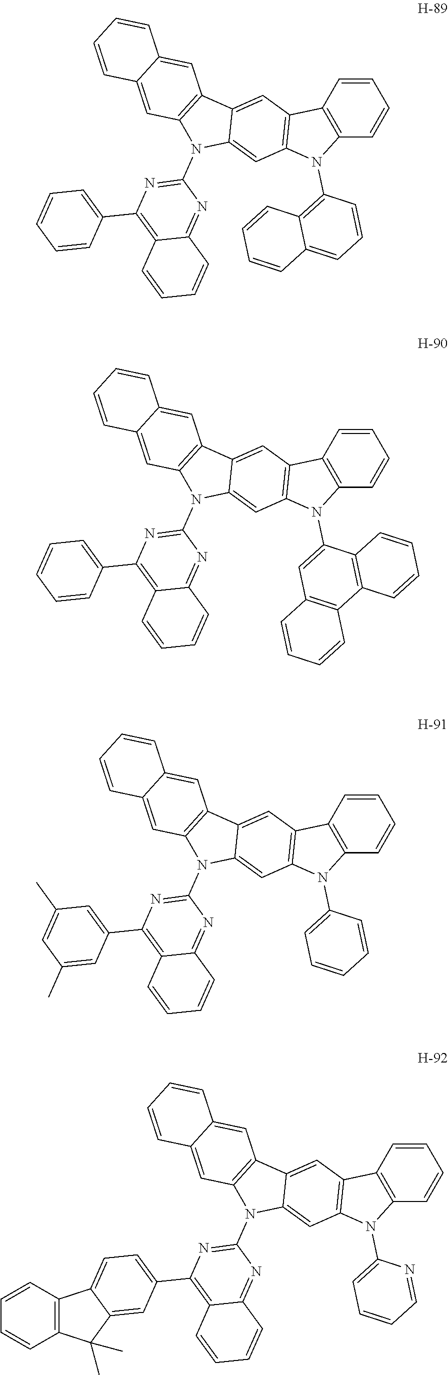 [SMILES: c1ccc(-c2nc(-n3c4cc5ccccc5cc4c4cc5c6ccccc6n(-c6cccc7ccccc67)c5cc43)nc3ccccc23)cc1 ; c1ccc(-c2nc(-n3c4cc5ccccc5cc4c4cc5c6ccccc6n(-c6cc7ccccc7c7ccccc67)c5cc43)nc3ccccc23)cc1 ; Cc1cc(C)cc(-c2nc(-n3c4cc5ccccc5cc4c4cc5c6ccccc6n(-c6ccccc6)c5cc43)nc3ccccc23)c1 ; CC1(C)c2ccccc2-c2ccc(-c3nc(-n4c5cc6ccccc6cc5c5cc6c7ccccc7n(-c7ccccn7)c6cc54)nc4ccccc34)cc21]

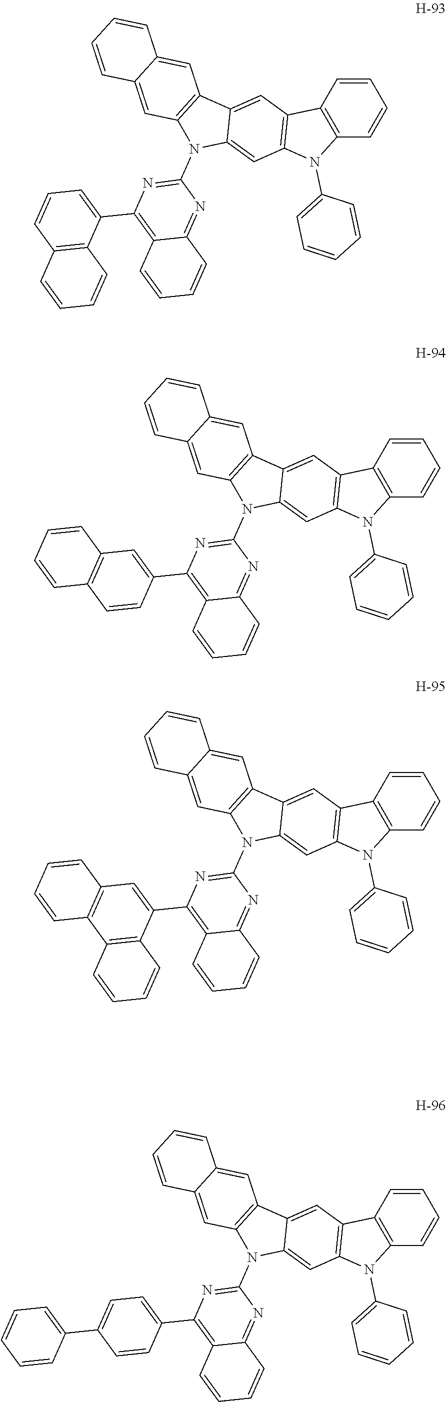 [SMILES: c1ccc(-n2c3ccccc3c3cc4c5cc6ccccc6cc5n(-c5nc(-c6cccc7ccccc67)c6ccccc6n5)c4cc32)cc1 ; c1ccc(-n2c3ccccc3c3cc4c5cc6ccccc6cc5n(-c5nc(-c6ccc7ccccc7c6)c6ccccc6n5)c4cc32)cc1 ; c1ccc(-n2c3ccccc3c3cc4c5cc6ccccc6cc5n(-c5nc(-c6cc7ccccc7c7ccccc67)c6ccccc6n5)c4cc32)cc1 ; c1ccc(-c2ccc(-c3nc(-n4c5cc6ccccc6cc5c5cc6c7ccccc7n(-c7ccccc7)c6cc54)nc4ccccc34)cc2)cc1]

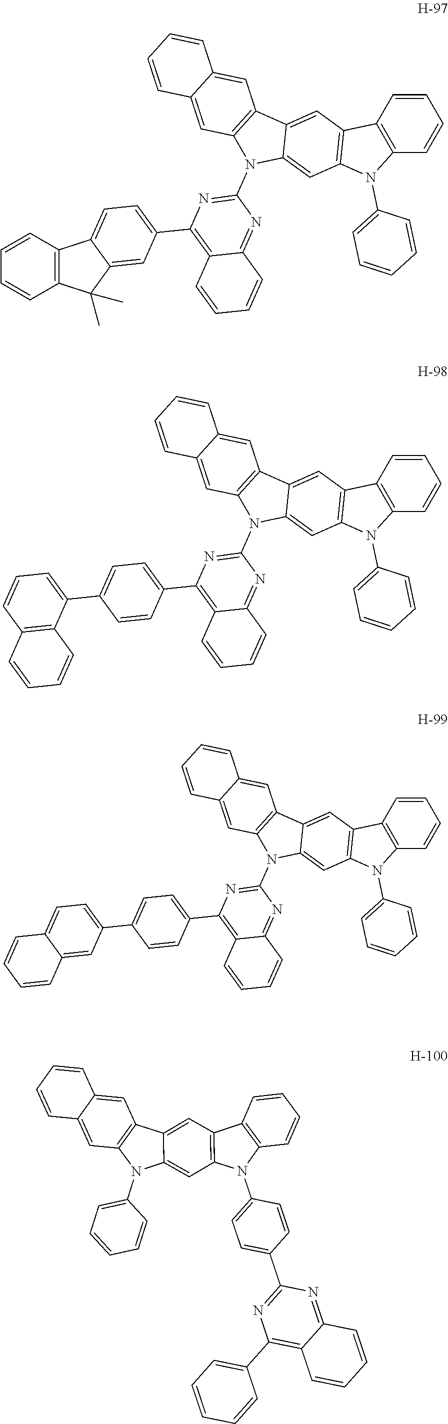 [SMILES: CC1(C)c2ccccc2-c2ccc(-c3nc(-n4c5cc6ccccc6cc5c5cc6c7ccccc7n(-c7ccccc7)c6cc54)nc4ccccc34)cc21 ; c1ccc(-n2c3ccccc3c3cc4c5cc6ccccc6cc5n(-c5nc(-c6ccc(-c7cccc8ccccc78)cc6)c6ccccc6n5)c4cc32)cc1 ; c1ccc(-n2c3ccccc3c3cc4c5cc6ccccc6cc5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7cc8ccccc8cc7n(-c7ccccc7)c6cc54)cc3)nc3ccccc23)cc1]

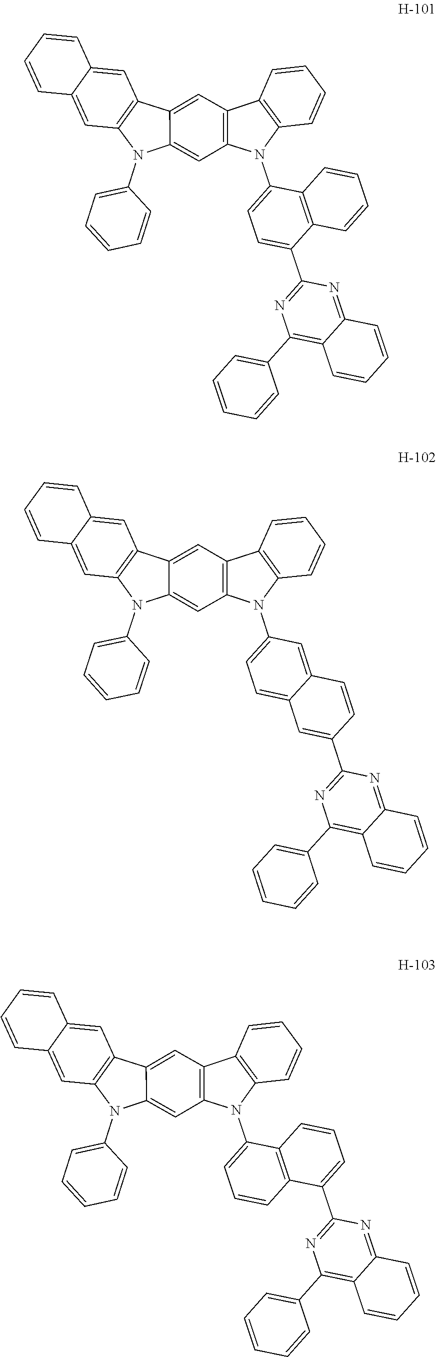 [SMILES: c1ccc(-c2nc(-c3ccc(-n4c5ccccc5c5cc6c7cc8ccccc8cc7n(-c7ccccc7)c6cc54)c4ccccc34)nc3ccccc23)cc1 ; c1ccc(-c2nc(-c3ccc4cc(-n5c6ccccc6c6cc7c8cc9ccccc9cc8n(-c8ccccc8)c7cc65)ccc4c3)nc3ccccc23)cc1 ; c1ccc(-c2nc(-c3cccc4c(-n5c6ccccc6c6cc7c8cc9ccccc9cc8n(-c8ccccc8)c7cc65)cccc34)nc3ccccc23)cc1]

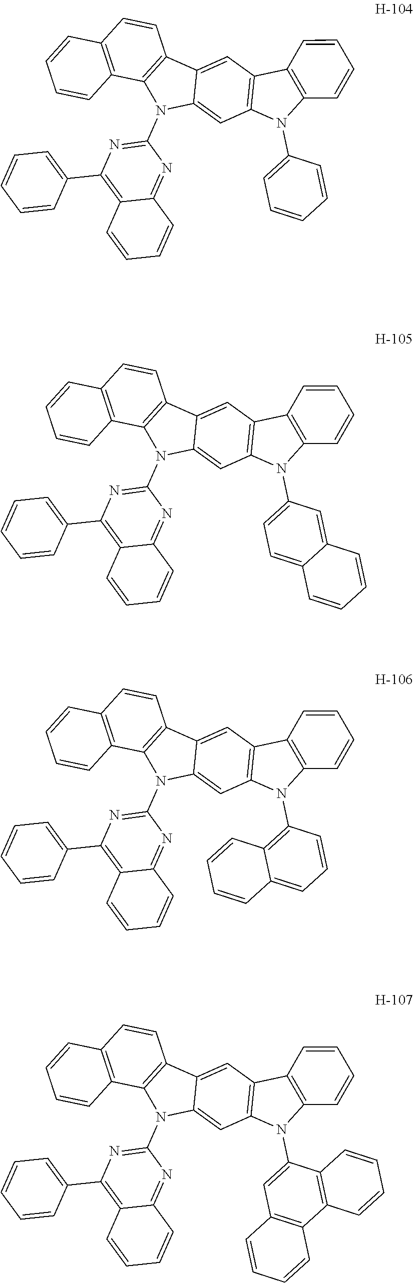 [SMILES: c1ccc(-c2nc(-n3c4cc5c(cc4c4ccc6ccccc6c43)c3ccccc3n5-c3ccccc3)nc3ccccc23)cc1 ; c1ccc(-c2nc(-n3c4cc5c(cc4c4ccc6ccccc6c43)c3ccccc3n5-c3ccc4ccccc4c3)nc3ccccc23)cc1 ; c1ccc(-c2nc(-n3c4cc5c(cc4c4ccc6ccccc6c43)c3ccccc3n5-c3cccc4ccccc34)nc3ccccc23)cc1 ; c1ccc(-c2nc(-n3c4cc5c(cc4c4ccc6ccccc6c43)c3ccccc3n5-c3cc4ccccc4c4ccccc34)nc3ccccc23)cc1]

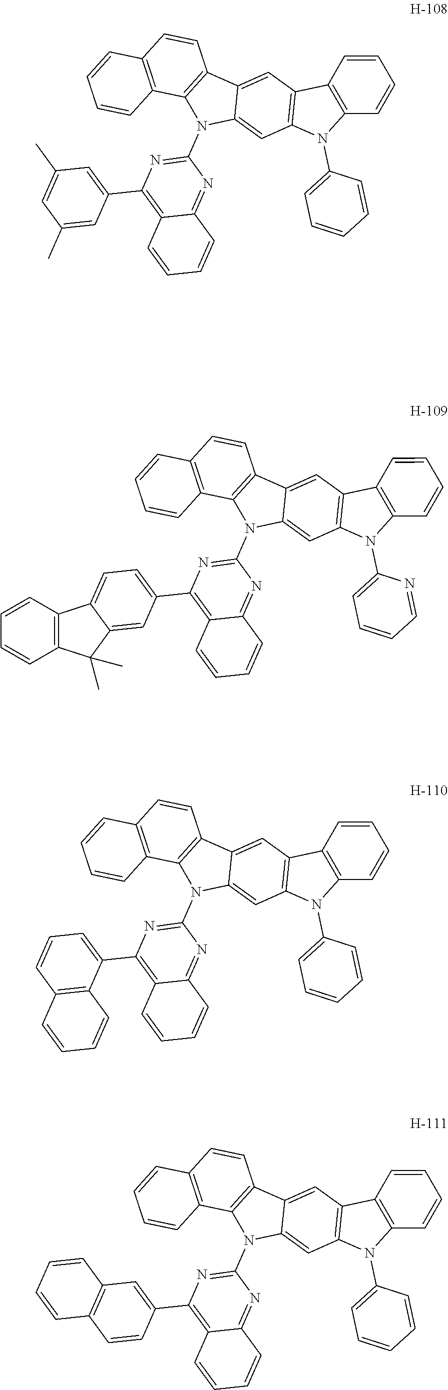 [SMILES: Cc1cc(C)cc(-c2nc(-n3c4cc5c(cc4c4ccc6ccccc6c43)c3ccccc3n5-c3ccccc3)nc3ccccc23)c1 ; CC1(C)c2ccccc2-c2ccc(-c3nc(-n4c5cc6c(cc5c5ccc7ccccc7c54)c4ccccc4n6-c4ccccn4)nc4ccccc34)cc21 ; c1ccc(-n2c3ccccc3c3cc4c5ccc6ccccc6c5n(-c5nc(-c6cccc7ccccc67)c6ccccc6n5)c4cc32)cc1 ; c1ccc(-n2c3ccccc3c3cc4c5ccc6ccccc6c5n(-c5nc(-c6ccc7ccccc7c6)c6ccccc6n5)c4cc32)cc1]

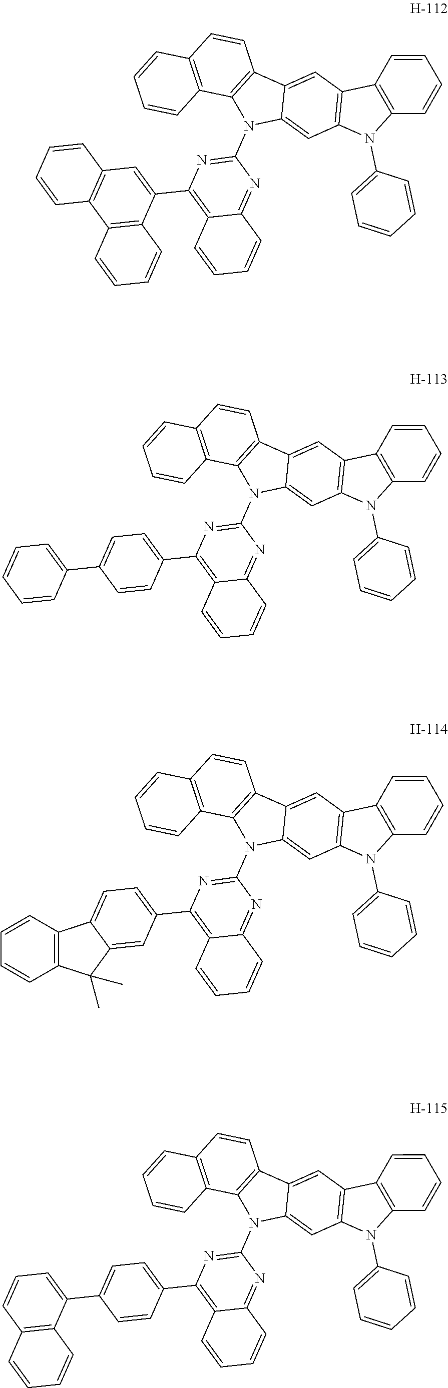 [SMILES: c1ccc(-n2c3ccccc3c3cc4c5ccc6ccccc6c5n(-c5nc(-c6cc7ccccc7c7ccccc67)c6ccccc6n5)c4cc32)cc1 ; c1ccc(-c2ccc(-c3nc(-n4c5cc6c(cc5c5ccc7ccccc7c54)c4ccccc4n6-c4ccccc4)nc4ccccc34)cc2)cc1 ; CC1(C)c2ccccc2-c2ccc(-c3nc(-n4c5cc6c(cc5c5ccc7ccccc7c54)c4ccccc4n6-c4ccccc4)nc4ccccc34)cc21 ; c1ccc(-n2c3ccccc3c3cc4c5ccc6ccccc6c5n(-c5nc(-c6ccc(-c7cccc8ccccc78)cc6)c6ccccc6n5)c4cc32)cc1]

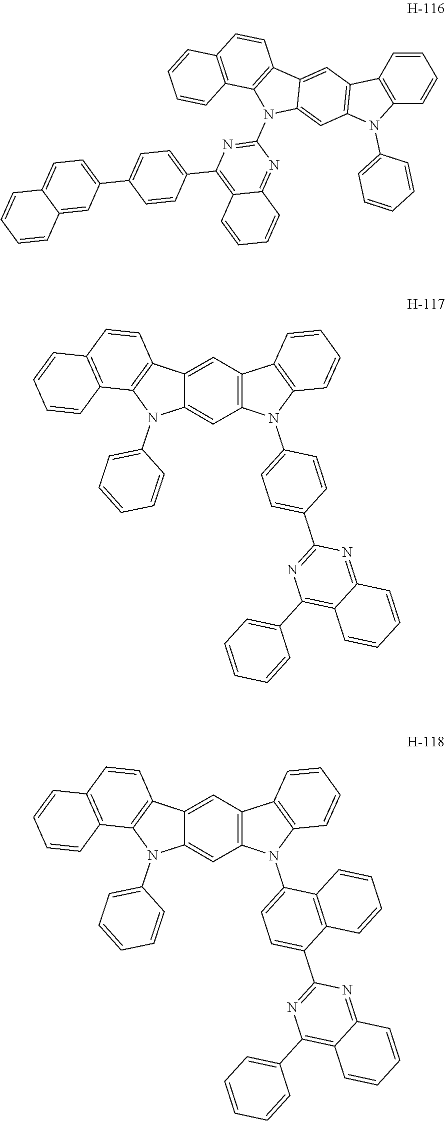 [SMILES: c1ccc(-n2c3ccccc3c3cc4c5ccc6ccccc6c5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7ccc8ccccc8c7n(-c7ccccc7)c6cc54)cc3)nc3ccccc23)cc1 ; c1ccc(-c2nc(-c3ccc(-n4c5ccccc5c5cc6c7ccc8ccccc8c7n(-c7ccccc7)c6cc54)c4ccccc34)nc3ccccc23)cc1]

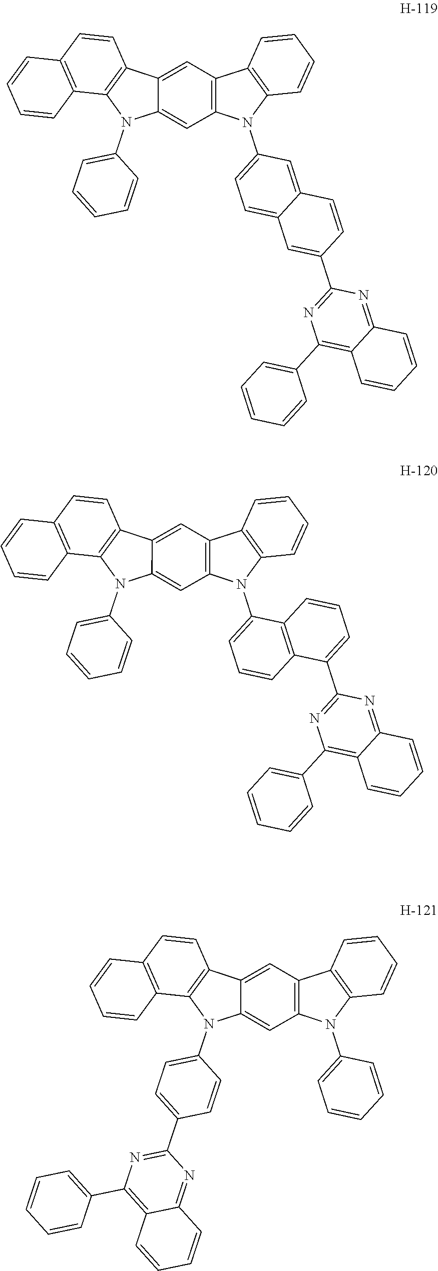 [SMILES: c1ccc(-c2nc(-c3ccc4cc(-n5c6ccccc6c6cc7c8ccc9ccccc9c8n(-c8ccccc8)c7cc65)ccc4c3)nc3ccccc23)cc1 ; c1ccc(-c2nc(-c3cccc4c(-n5c6ccccc6c6cc7c8ccc9ccccc9c8n(-c8ccccc8)c7cc65)cccc34)nc3ccccc23)cc1 ; c1ccc(-c2nc(-c3ccc(-n4c5cc6c(cc5c5ccc7ccccc7c54)c4ccccc4n6-c4ccccc4)cc3)nc3ccccc23)cc1]

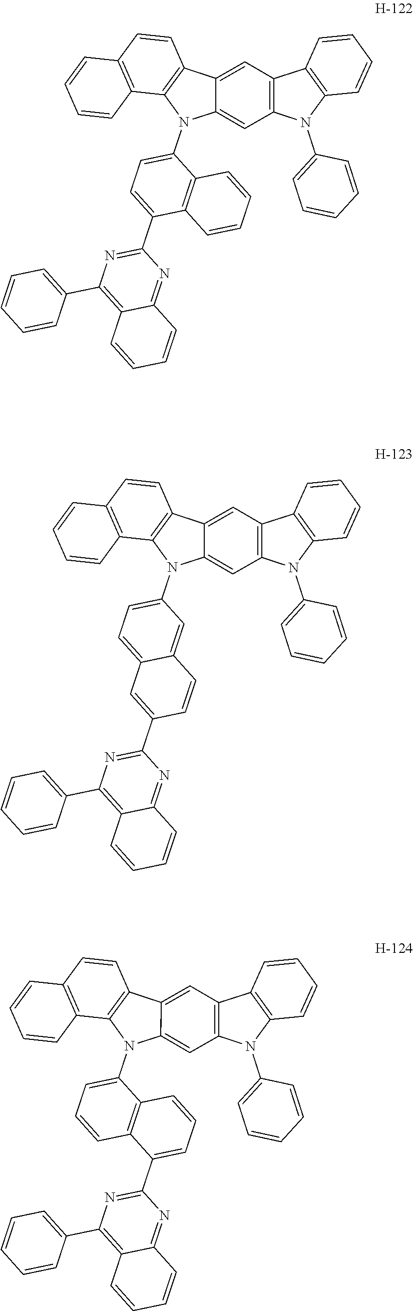 [SMILES: c1ccc(-c2nc(-c3ccc(-n4c5cc6c(cc5c5ccc7ccccc7c54)c4ccccc4n6-c4ccccc4)c4ccccc34)nc3ccccc23)cc1 ; c1ccc(-c2nc(-c3ccc4cc(-n5c6cc7c(cc6c6ccc8ccccc8c65)c5ccccc5n7-c5ccccc5)ccc4c3)nc3ccccc23)cc1 ; c1ccc(-c2nc(-c3cccc4c(-n5c6cc7c(cc6c6ccc8ccccc8c65)c5ccccc5n7-c5ccccc5)cccc34)nc3ccccc23)cc1]

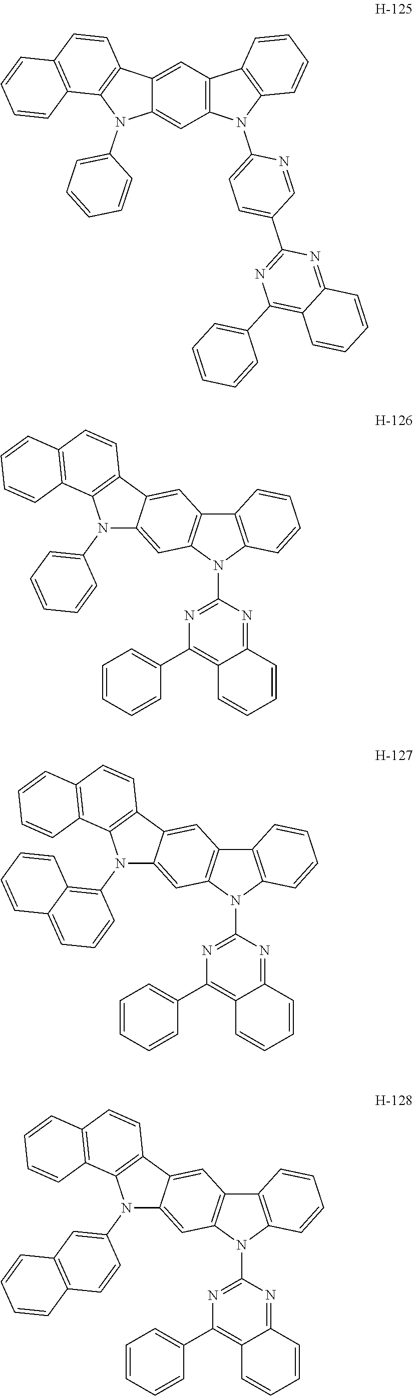 [SMILES: c1ccc(-c2nc(-c3ccc(-n4c5ccccc5c5cc6c7ccc8ccccc8c7n(-c7ccccc7)c6cc54)nc3)nc3ccccc23)cc1 ; c1ccc(-c2nc(-n3c4ccccc4c4cc5c6ccc7ccccc7c6n(-c6ccccc6)c5cc43)nc3ccccc23)cc1 ; c1ccc(-c2nc(-n3c4ccccc4c4cc5c6ccc7ccccc7c6n(-c6cccc7ccccc67)c5cc43)nc3ccccc23)cc1 ; c1ccc(-c2nc(-n3c4ccccc4c4cc5c6ccc7ccccc7c6n(-c6ccc7ccccc7c6)c5cc43)nc3ccccc23)cc1]

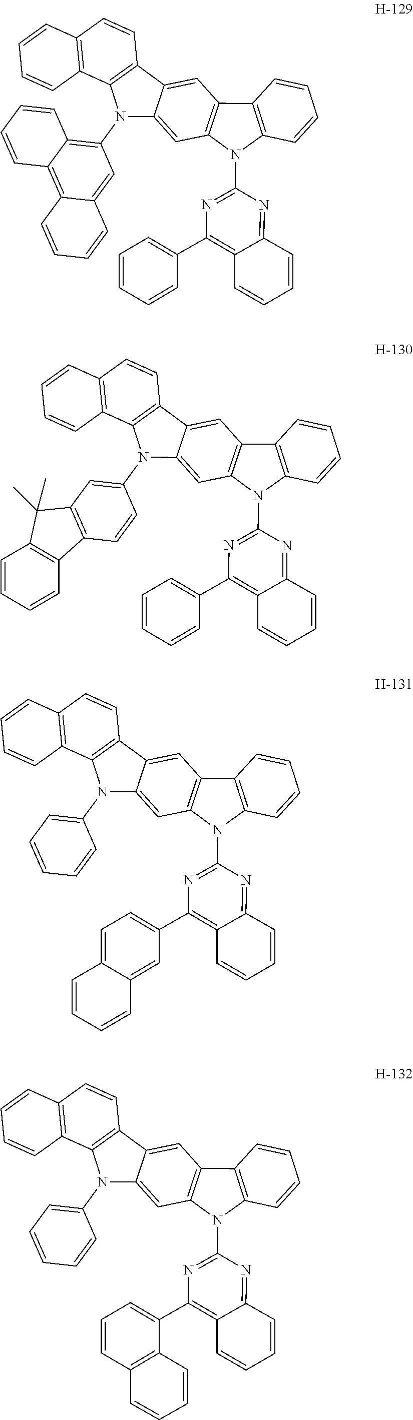 [SMILES: c1ccc(-c2nc(-n3c4ccccc4c4cc5c6ccc7ccccc7c6n(-c6cc7ccccc7c7ccccc67)c5cc43)nc3ccccc23)cc1 ; CC1(C)c2ccccc2-c2ccc(-n3c4cc5c(cc4c4ccc6ccccc6c43)c3ccccc3n5-c3nc(-c4ccccc4)c4ccccc4n3)cc21 ; c1ccc(-n2c3cc4c(cc3c3ccc5ccccc5c32)c2ccccc2n4-c2nc(-c3ccc4ccccc4c3)c3ccccc3n2)cc1 ; c1ccc(-n2c3cc4c(cc3c3ccc5ccccc5c32)c2ccccc2n4-c2nc(-c3cccc4ccccc34)c3ccccc3n2)cc1]

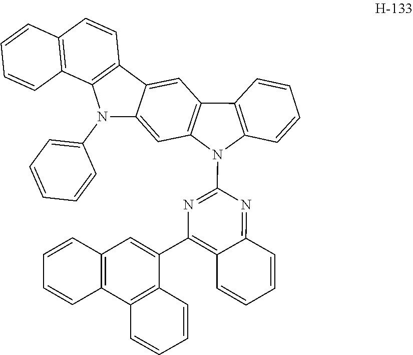 [SMILES: c1ccc(-n2c3cc4c(cc3c3ccc5ccccc5c32)c2ccccc2n4-c2nc(-c3cc4ccccc4c4ccccc34)c3ccccc3n2)cc1]

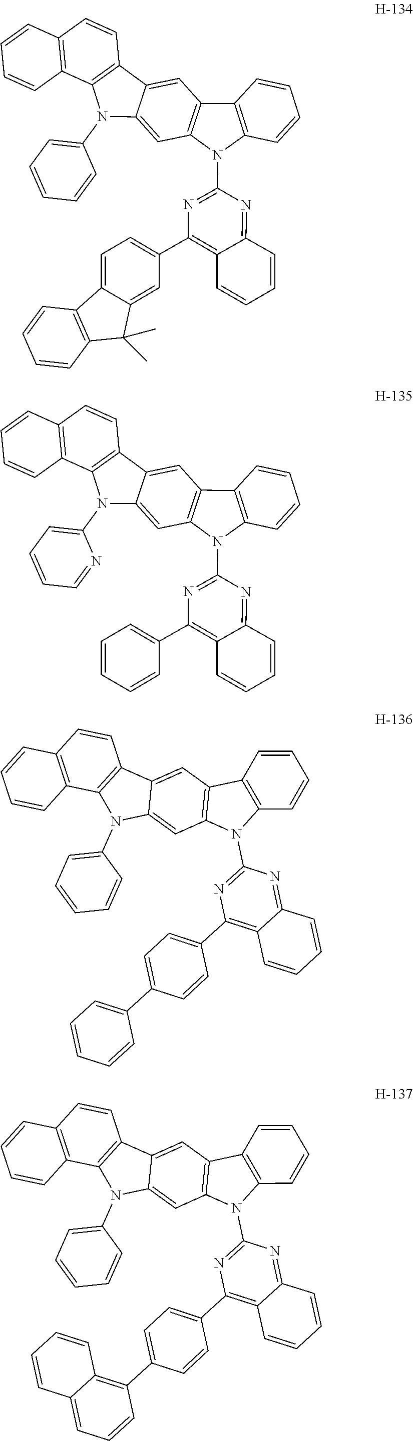

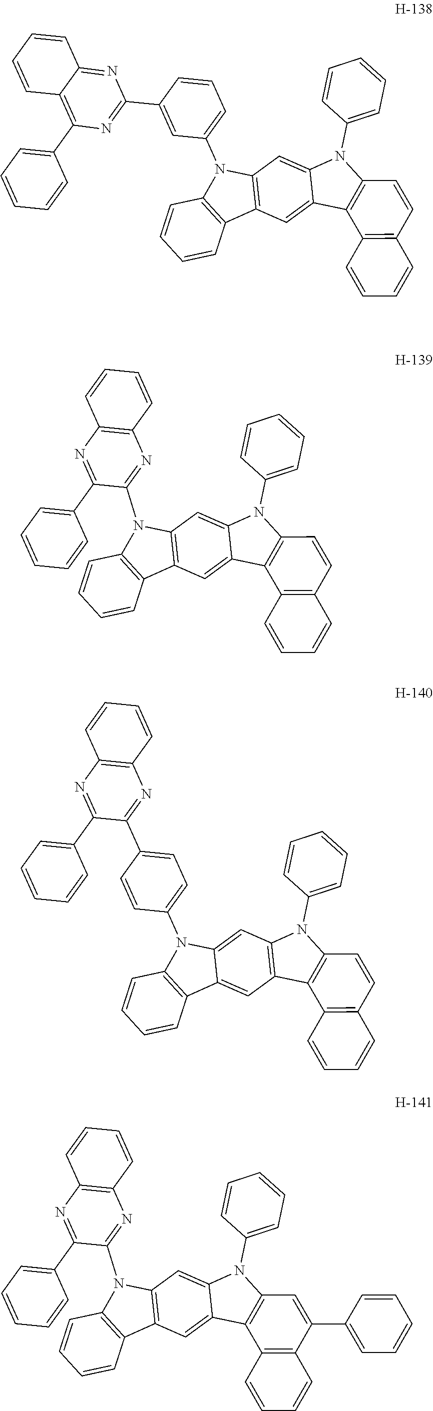 [SMILES: c1ccc(-c2nc(-c3cccc(-n4c5ccccc5c5cc6c7c8ccccc8ccc7n(-c7ccccc7)c6cc54)c3)nc3ccccc23)cc1 ; c1ccc(-c2nc3ccccc3nc2-n2c3ccccc3c3cc4c5c6ccccc6ccc5n(-c5ccccc5)c4cc32)cc1 ; c1ccc(-c2nc3ccccc3nc2-c2ccc(-n3c4ccccc4c4cc5c6c7ccccc7ccc6n(-c6ccccc6)c5cc43)cc2)cc1 ; c1ccc(-c2nc3ccccc3nc2-n2c3ccccc3c3cc4c5c6ccccc6c(-c6ccccc6)cc5n(-c5ccccc5)c4cc32)cc1]

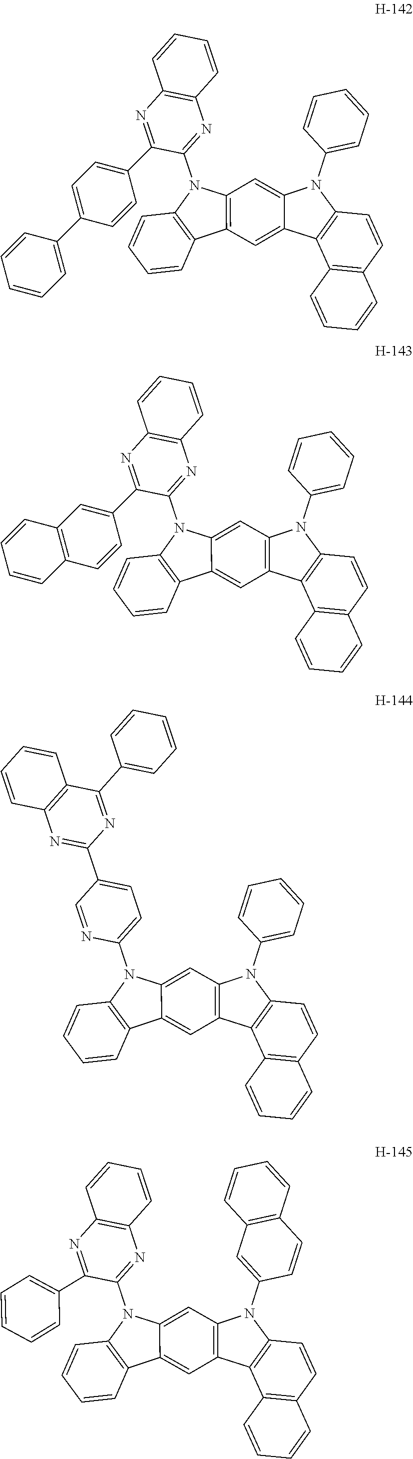

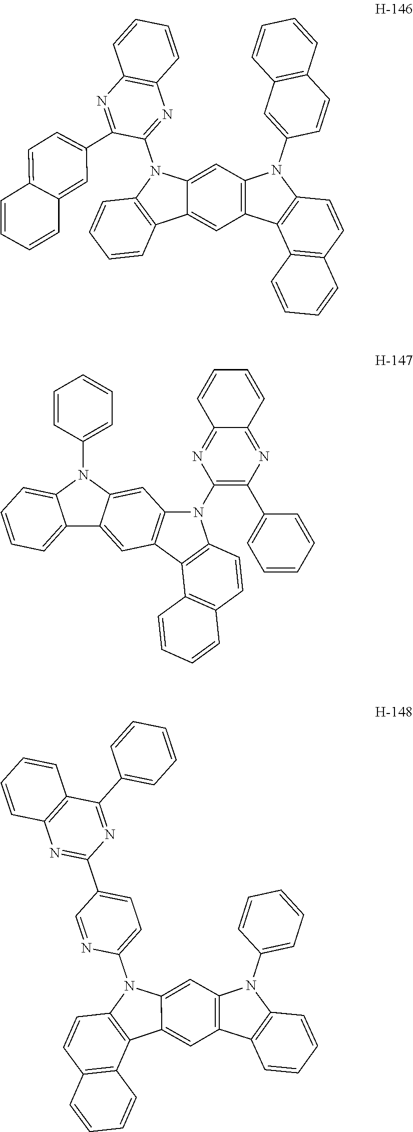 [SMILES: c1ccc2cc(-c3nc4ccccc4nc3-n3c4ccccc4c4cc5c6c7ccccc7ccc6n(-c6ccc7ccccc7c6)c5cc43)ccc2c1 ; c1ccc(-c2nc3ccccc3nc2-n2c3cc4c(cc3c3c5ccccc5ccc32)c2ccccc2n4-c2ccccc2)cc1 ; c1ccc(-c2nc(-c3ccc(-n4c5cc6c(cc5c5c7ccccc7ccc54)c4ccccc4n6-c4ccccc4)nc3)nc3ccccc23)cc1]

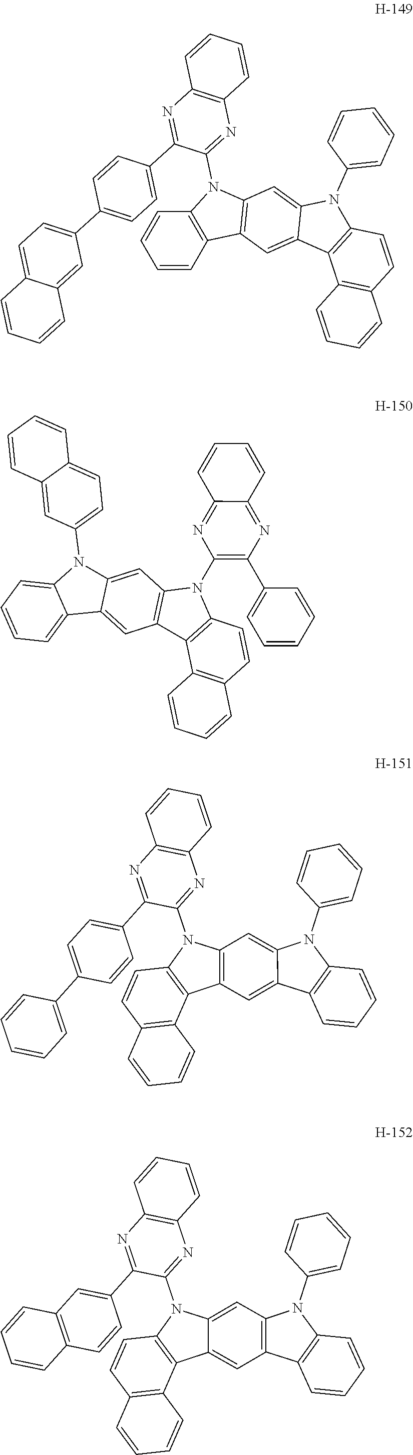 [SMILES: c1ccc(-n2c3cc4c(cc3c3c5ccccc5ccc32)c2ccccc2n4-c2nc3ccccc3nc2-c2ccc(-c3ccc4ccccc4c3)cc2)cc1 ; c1ccc(-c2nc3ccccc3nc2-n2c3cc4c(cc3c3c5ccccc5ccc32)c2ccccc2n4-c2ccc3ccccc3c2)cc1 ; c1ccc(-c2ccc(-c3nc4ccccc4nc3-n3c4cc5c(cc4c4c6ccccc6ccc43)c3ccccc3n5-c3ccccc3)cc2)cc1 ; c1ccc(-n2c3ccccc3c3cc4c5c6ccccc6ccc5n(-c5nc6ccccc6nc5-c5ccc6ccccc6c5)c4cc32)cc1]

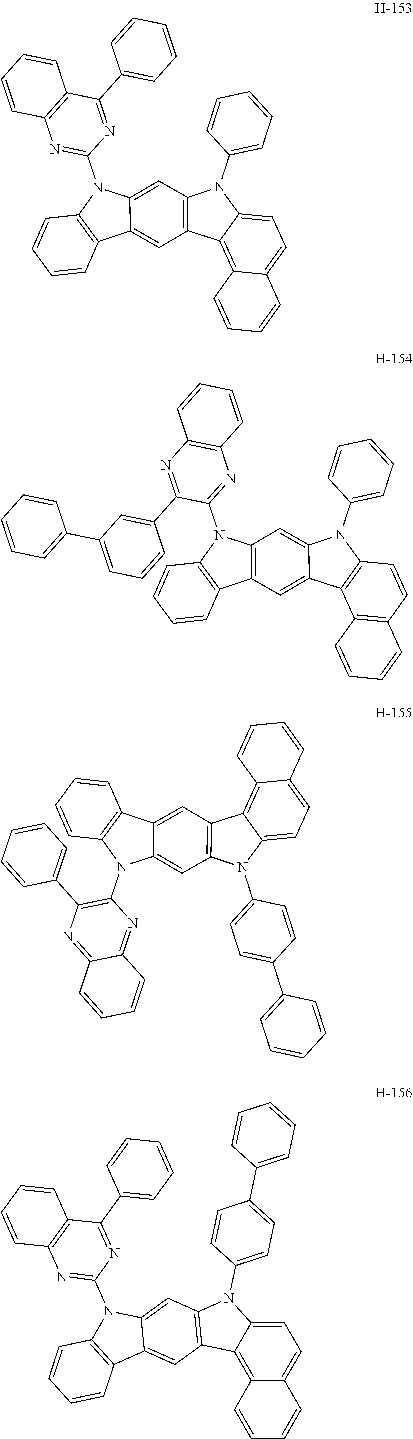 [SMILES: c1ccc(-c2nc(-n3c4ccccc4c4cc5c6c7ccccc7ccc6n(-c6ccccc6)c5cc43)nc3ccccc23)cc1 ; c1ccc(-c2cccc(-c3nc4ccccc4nc3-n3c4ccccc4c4cc5c6c7ccccc7ccc6n(-c6ccccc6)c5cc43)c2)cc1 ; c1ccc(-c2ccc(-n3c4cc5c(cc4c4c6ccccc6ccc43)c3ccccc3n5-c3nc4ccccc4nc3-c3ccccc3)cc2)cc1 ; c1ccc(-c2ccc(-n3c4cc5c(cc4c4c6ccccc6ccc43)c3ccccc3n5-c3nc(-c4ccccc4)c4ccccc4n3)cc2)cc1]

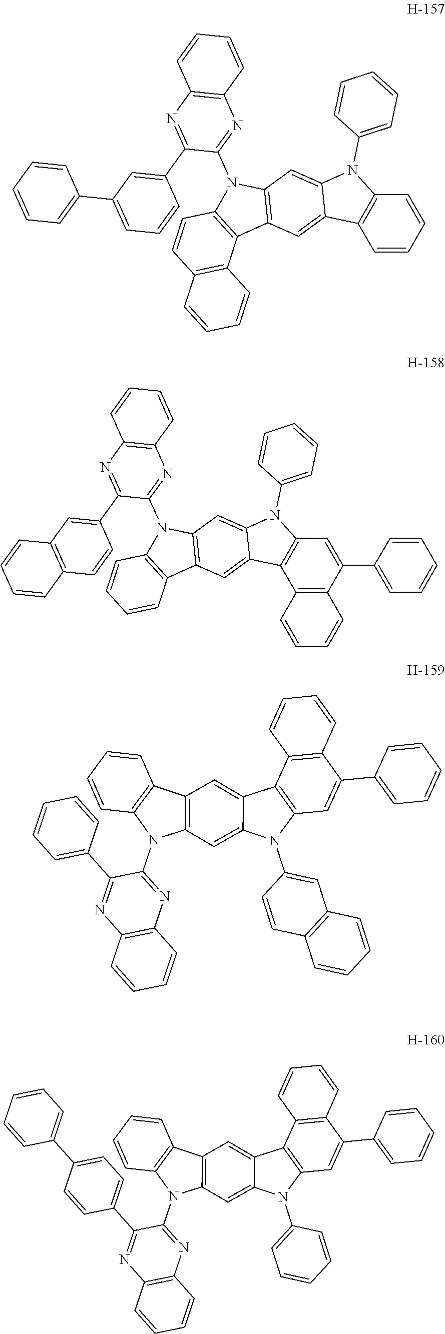 [SMILES: c1ccc(-c2cccc(-c3nc4ccccc4nc3-n3c4cc5c(cc4c4c6ccccc6ccc43)c3ccccc3n5-c3ccccc3)c2)cc1 ; c1ccc(-c2cc3c(c4ccccc24)c2cc4c5ccccc5n(-c5nc6ccccc6nc5-c5ccc6ccccc6c5)c4cc2n3-c2ccccc2)cc1 ; c1ccc(-c2nc3ccccc3nc2-n2c3ccccc3c3cc4c5c6ccccc6c(-c6ccccc6)cc5n(-c5ccc6ccccc6c5)c4cc32)cc1 ; c1ccc(-c2ccc(-c3nc4ccccc4nc3-n3c4ccccc4c4cc5c6c7ccccc7c(-c7ccccc7)cc6n(-c6ccccc6)c5cc43)cc2)cc1]

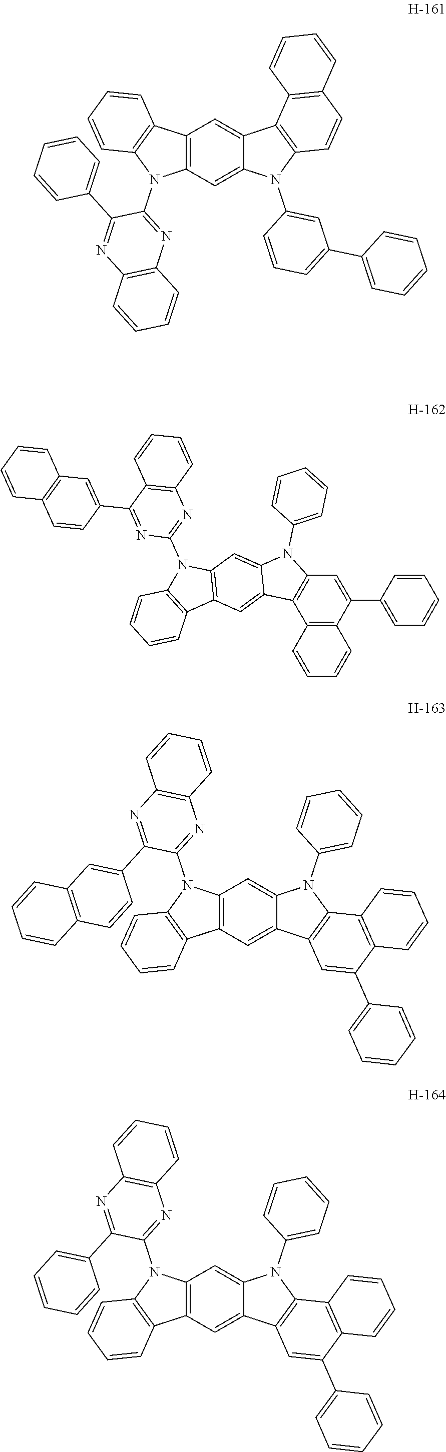 [SMILES: c1ccc(-c2cccc(-n3c4cc5c(cc4c4c6ccccc6ccc43)c3ccccc3n5-c3nc4ccccc4nc3-c3ccccc3)c2)cc1 ; c1ccc(-c2cc3c(c4ccccc24)c2cc4c5ccccc5n(-c5nc(-c6ccc7ccccc7c6)c6ccccc6n5)c4cc2n3-c2ccccc2)cc1 ; c1ccc(-c2cc3c4cc5c6ccccc6n(-c6nc7ccccc7nc6-c6ccc7ccccc7c6)c5cc4n(-c4ccccc4)c3c3ccccc23)cc1 ; c1ccc(-c2nc3ccccc3nc2-n2c3ccccc3c3cc4c5cc(-c6ccccc6)c6ccccc6c5n(-c5ccccc5)c4cc32)cc1]

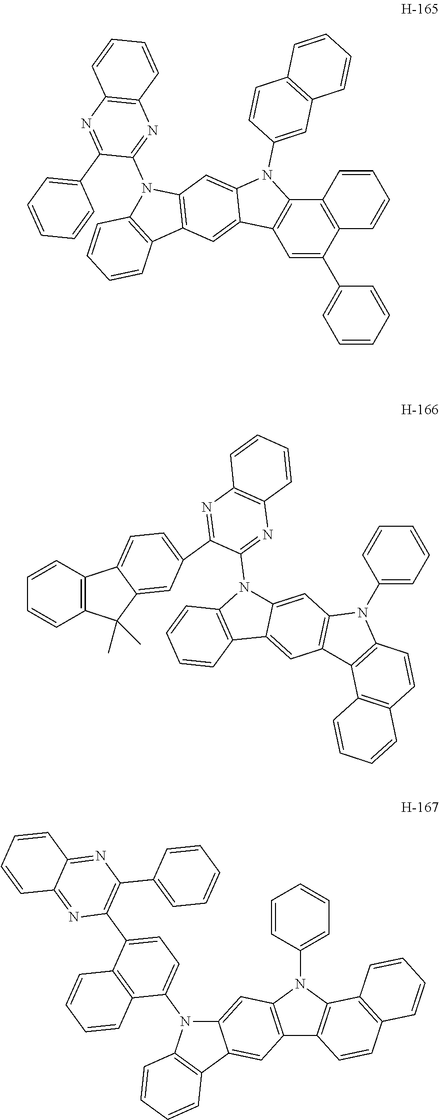 [SMILES: c1ccc(-c2nc3ccccc3nc2-n2c3ccccc3c3cc4c5cc(-c6ccccc6)c6ccccc6c5n(-c5ccc6ccccc6c5)c4cc32)cc1 ; CC1(C)c2ccccc2-c2ccc(-c3nc4ccccc4nc3-n3c4ccccc4c4cc5c6c7ccccc7ccc6n(-c6ccccc6)c5cc43)cc21 ; c1ccc(-c2nc3ccccc3nc2-c2ccc(-n3c4ccccc4c4cc5c6ccc7ccccc7c6n(-c6ccccc6)c5cc43)c3ccccc23)cc1]

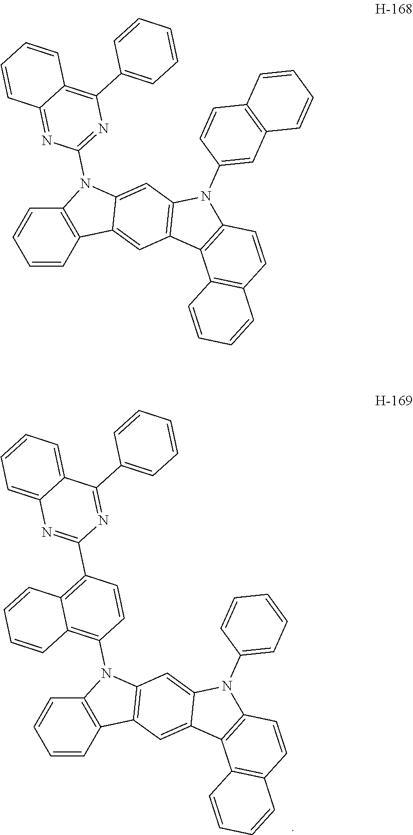 [SMILES: c1ccc(-c2nc(-n3c4ccccc4c4cc5c6c7ccccc7ccc6n(-c6ccc7ccccc7c6)c5cc43)nc3ccccc23)cc1 ; c1ccc(-c2nc(-c3ccc(-n4c5ccccc5c5cc6c7c8ccccc8ccc7n(-c7ccccc7)c6cc54)c4ccccc34)nc3ccccc23)cc1]

The compound represented by formula 11 or 12 includes the following compounds, but is not limited thereto:

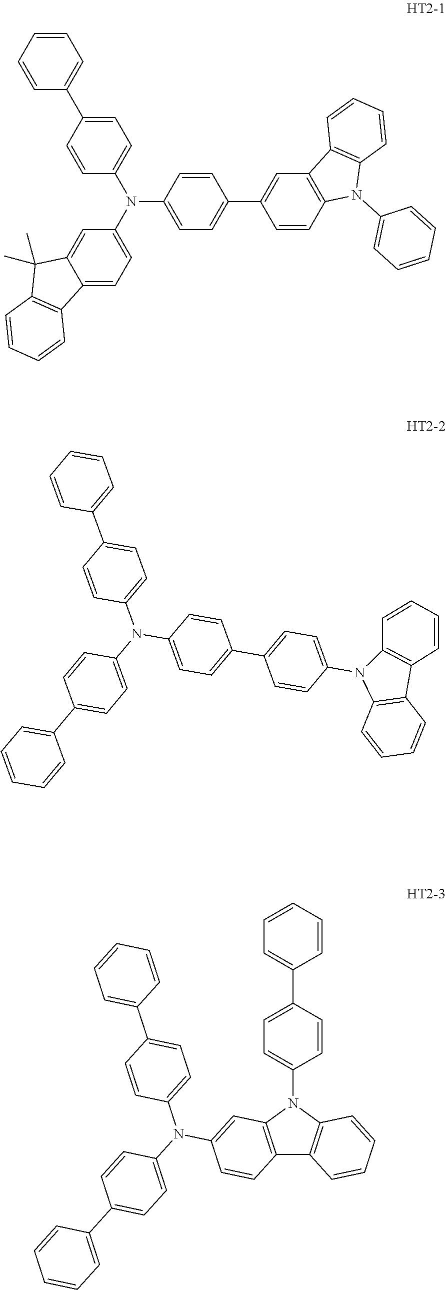 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc4c5ccccc5n(-c5ccc(-c6ccccc6)cc5)c4c3)cc2)cc1]

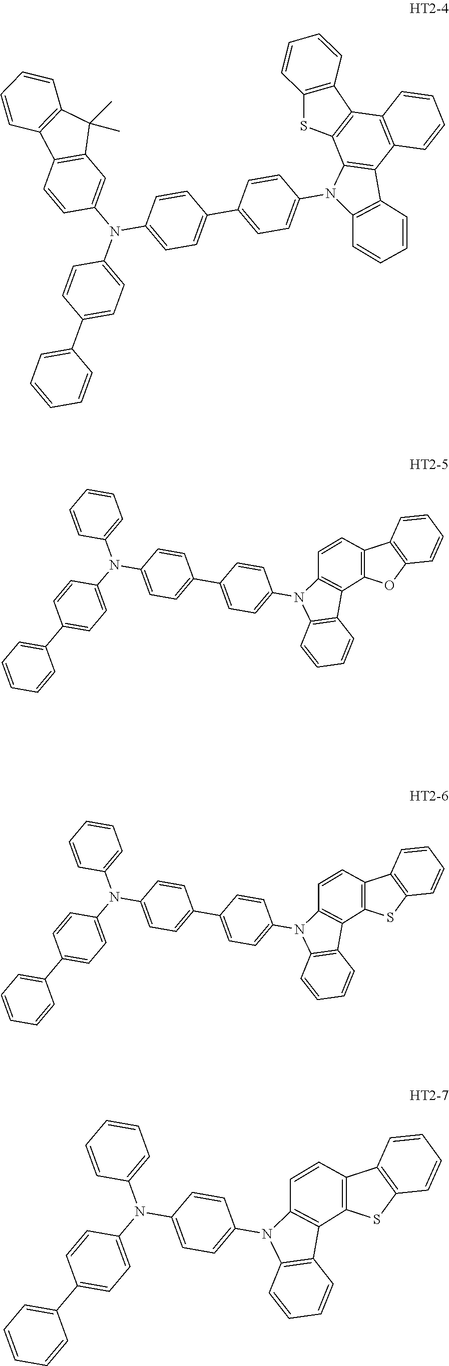 [SMILES: CC1(C)c2ccccc2-c2ccc(N(c3ccc(-c4ccccc4)cc3)c3ccc(-c4ccc(-n5c6ccccc6c6c7ccccc7c7c8ccccc8sc7c65)cc4)cc3)cc21 ; c1ccc(-c2ccc(N(c3ccccc3)c3ccc(-c4ccc(-n5c6ccccc6c6c7oc8ccccc8c7ccc65)cc4)cc3)cc2)cc1 ; c1ccc(-c2ccc(N(c3ccccc3)c3ccc(-c4ccc(-n5c6ccccc6c6c7sc8ccccc8c7ccc65)cc4)cc3)cc2)cc1 ; c1ccc(-c2ccc(N(c3ccccc3)c3ccc(-n4c5ccccc5c5c6sc7ccccc7c6ccc54)cc3)cc2)cc1]

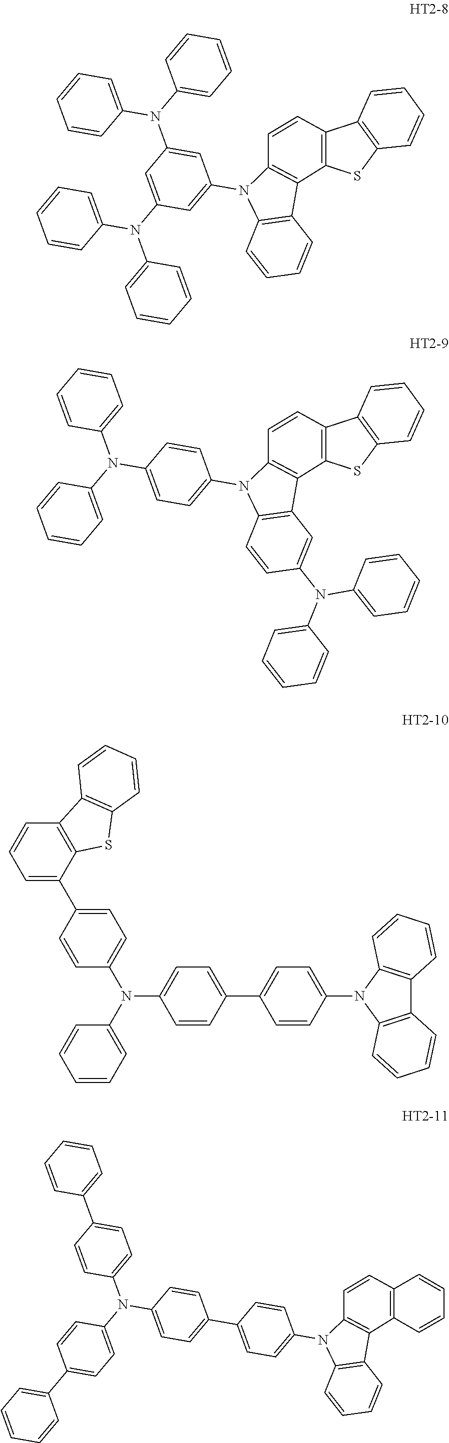 [SMILES: c1ccc(N(c2ccccc2)c2cc(N(c3ccccc3)c3ccccc3)cc(-n3c4ccccc4c4c5sc6ccccc6c5ccc43)c2)cc1 ; c1ccc(N(c2ccccc2)c2ccc(-n3c4ccc(N(c5ccccc5)c5ccccc5)cc4c4c5sc6ccccc6c5ccc43)cc2)cc1 ; c1ccc(N(c2ccc(-c3ccc(-n4c5ccccc5c5ccccc54)cc3)cc2)c2ccc(-c3cccc4c3sc3ccccc34)cc2)cc1 ; c1ccc(-c2ccc(N(c3ccc(-c4ccccc4)cc3)c3ccc(-c4ccc(-n5c6ccccc6c6c7ccccc7ccc65)cc4)cc3)cc2)cc1]

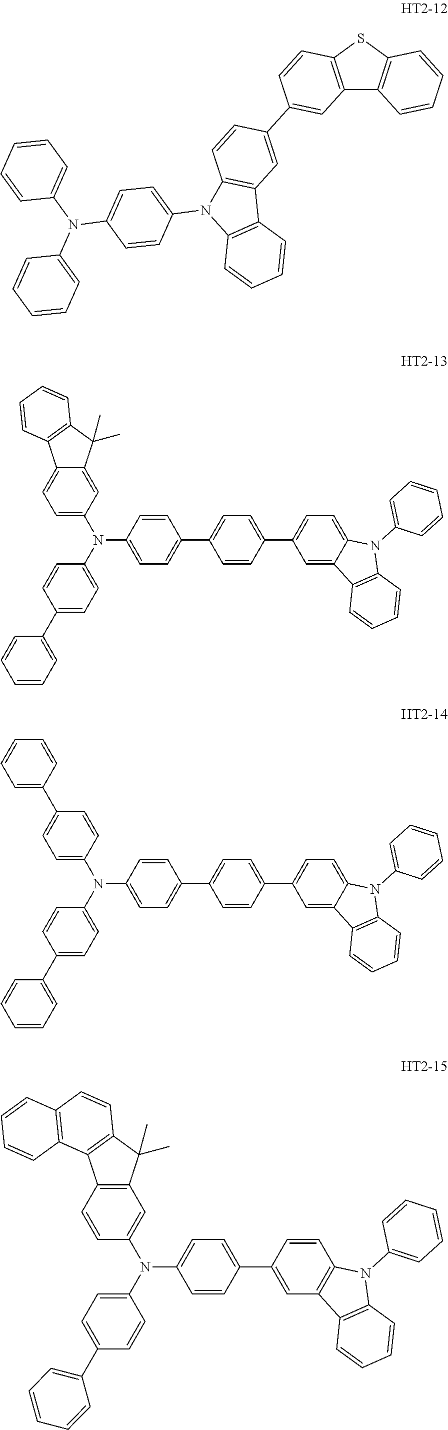 [SMILES: c1ccc(N(c2ccccc2)c2ccc(-n3c4ccccc4c4cc(-c5ccc6sc7ccccc7c6c5)ccc43)cc2)cc1 ; CC1(C)c2ccccc2-c2ccc(N(c3ccc(-c4ccccc4)cc3)c3ccc(-c4ccc(-c5ccc6c(c5)c5ccccc5n6-c5ccccc5)cc4)cc3)cc21 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; CC1(C)c2cc(N(c3ccc(-c4ccccc4)cc3)c3ccc(-c4ccc5c(c4)c4ccccc4n5-c4ccccc4)cc3)ccc2-c2c1ccc1ccccc21]

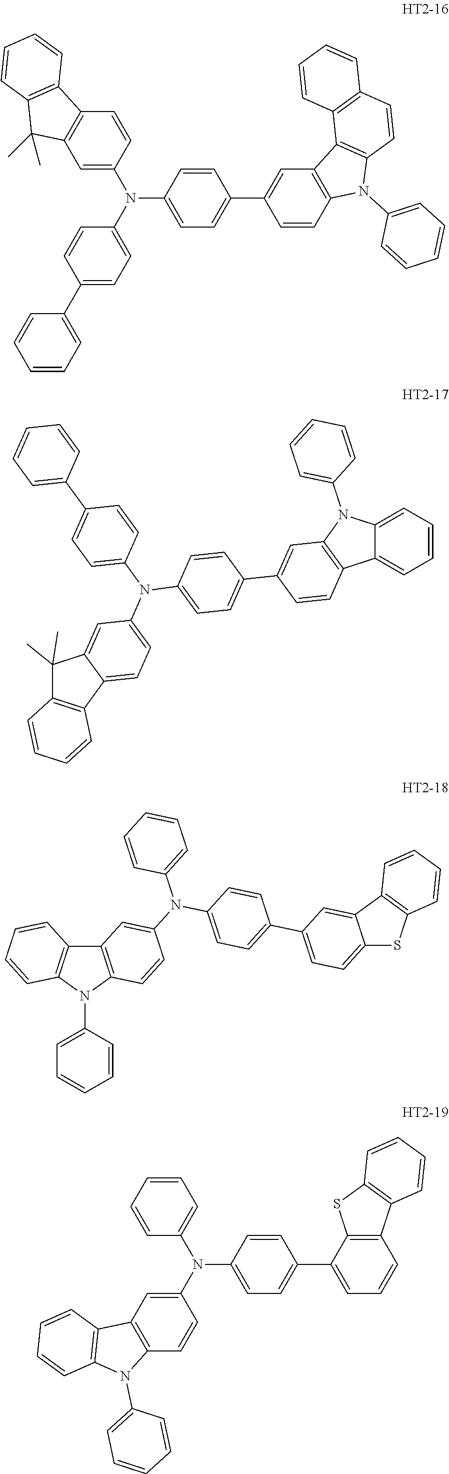 [SMILES: CC1(C)c2ccccc2-c2ccc(N(c3ccc(-c4ccccc4)cc3)c3ccc(-c4ccc5c(c4)c4c6ccccc6ccc4n5-c4ccccc4)cc3)cc21 ; CC1(C)c2ccccc2-c2ccc(N(c3ccc(-c4ccccc4)cc3)c3ccc(-c4ccc5c6ccccc6n(-c6ccccc6)c5c4)cc3)cc21 ; c1ccc(N(c2ccc(-c3ccc4sc5ccccc5c4c3)cc2)c2ccc3c(c2)c2ccccc2n3-c2ccccc2)cc1 ; c1ccc(N(c2ccc(-c3cccc4c3sc3ccccc34)cc2)c2ccc3c(c2)c2ccccc2n3-c2ccccc2)cc1]

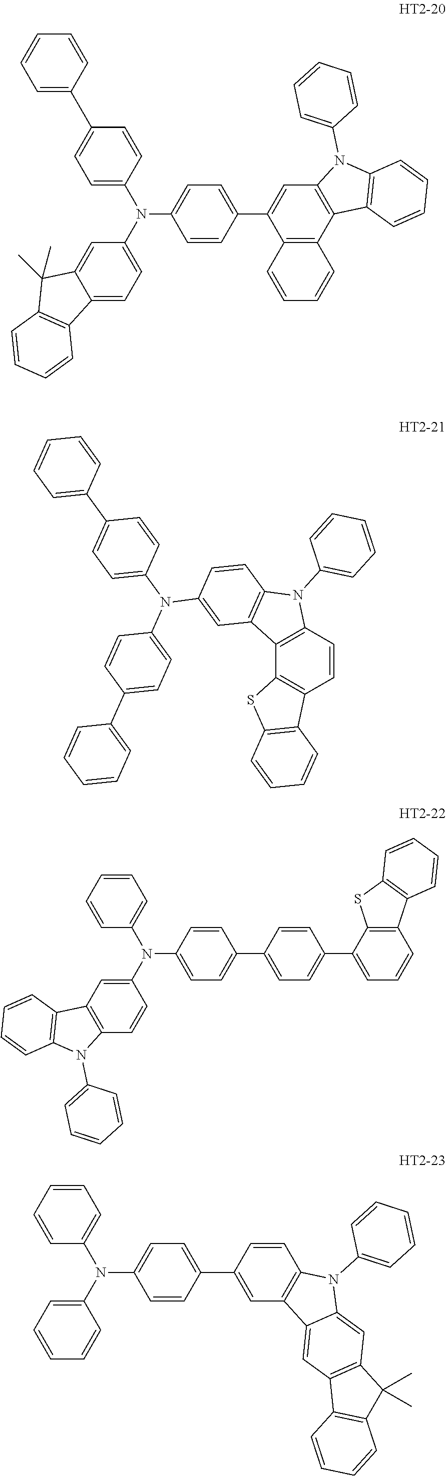

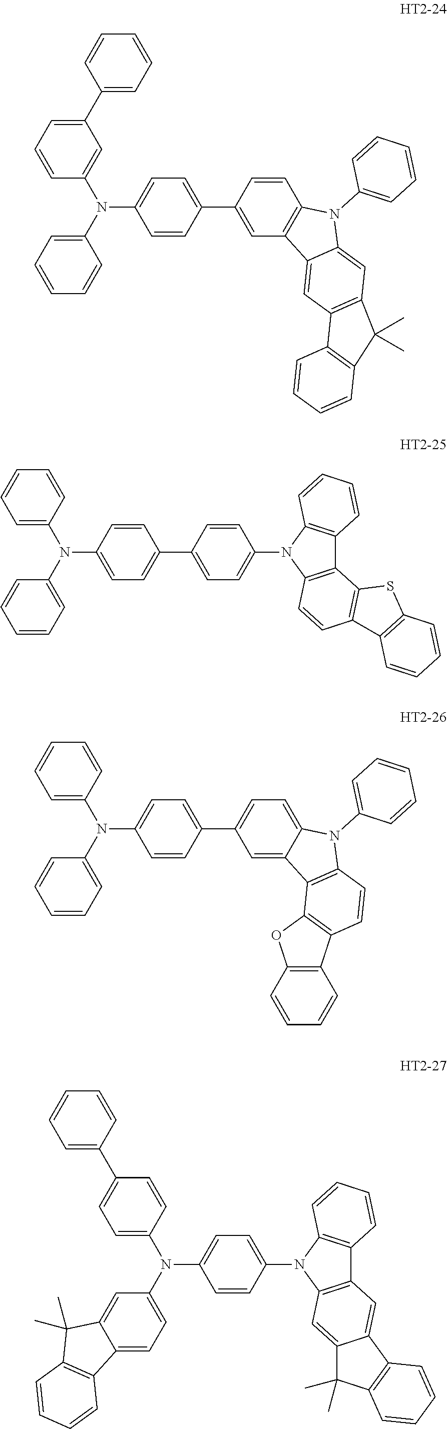 [SMILES: CC1(C)c2ccccc2-c2cc3c4cc(-c5ccc(N(c6ccccc6)c6cccc(-c7ccccc7)c6)cc5)ccc4n(-c4ccccc4)c3cc21 ; c1ccc(N(c2ccccc2)c2ccc(-c3ccc(-n4c5ccccc5c5c6sc7ccccc7c6ccc54)cc3)cc2)cc1 ; c1ccc(N(c2ccccc2)c2ccc(-c3ccc4c(c3)c3c5oc6ccccc6c5ccc3n4-c3ccccc3)cc2)cc1 ; CC1(C)c2ccccc2-c2ccc(N(c3ccc(-c4ccccc4)cc3)c3ccc(-n4c5ccccc5c5cc6c(cc54)C(C)(C)c4ccccc4-6)cc3)cc21]

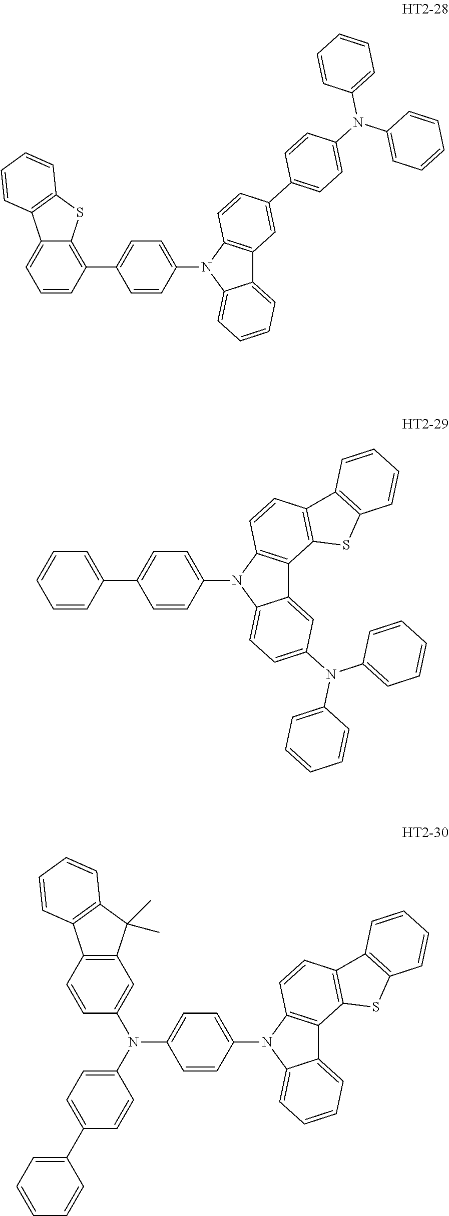 [SMILES: c1ccc(N(c2ccccc2)c2ccc(-c3ccc4c(c3)c3ccccc3n4-c3ccc(-c4cccc5c4sc4ccccc45)cc3)cc2)cc1 ; c1ccc(-c2ccc(-n3c4ccc(N(c5ccccc5)c5ccccc5)cc4c4c5sc6ccccc6c5ccc43)cc2)cc1 ; CC1(C)c2ccccc2-c2ccc(N(c3ccc(-c4ccccc4)cc3)c3ccc(-n4c5ccccc5c5c6sc7ccccc7c6ccc54)cc3)cc21]

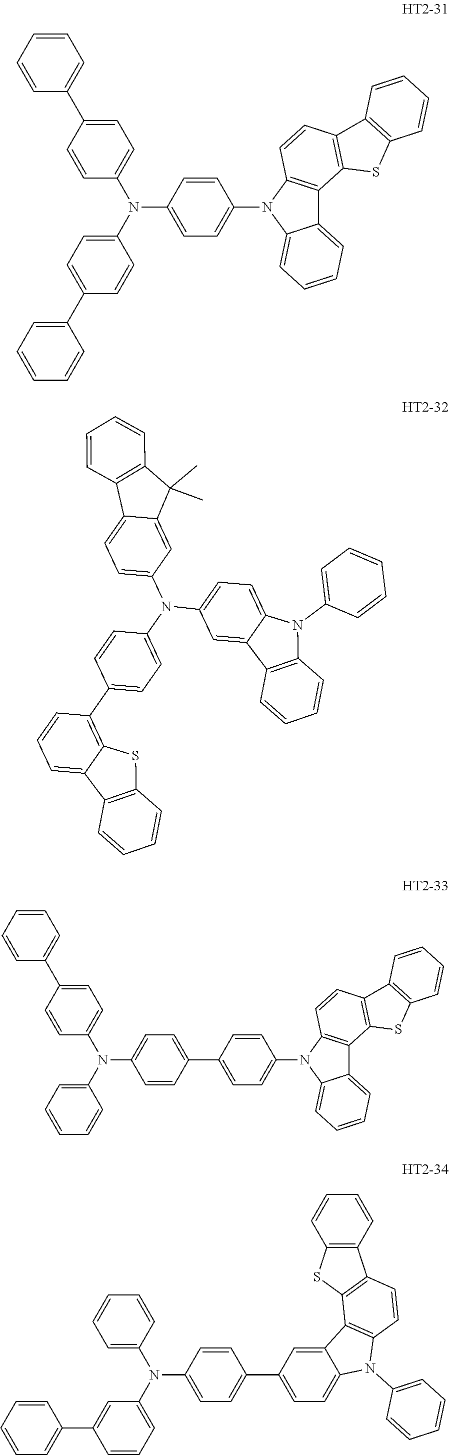 [SMILES: c1ccc(-c2ccc(N(c3ccc(-c4ccccc4)cc3)c3ccc(-n4c5ccccc5c5c6sc7ccccc7c6ccc54)cc3)cc2)cc1 ; CC1(C)c2ccccc2-c2ccc(N(c3ccc(-c4cccc5c4sc4ccccc45)cc3)c3ccc4c(c3)c3ccccc3n4-c3ccccc3)cc21 ; c1ccc(-c2ccc(N(c3ccccc3)c3ccc(-c4ccc(-n5c6ccccc6c6c7sc8ccccc8c7ccc65)cc4)cc3)cc2)cc1 ; c1ccc(-c2cccc(N(c3ccccc3)c3ccc(-c4ccc5c(c4)c4c6sc7ccccc7c6ccc4n5-c4ccccc4)cc3)c2)cc1]

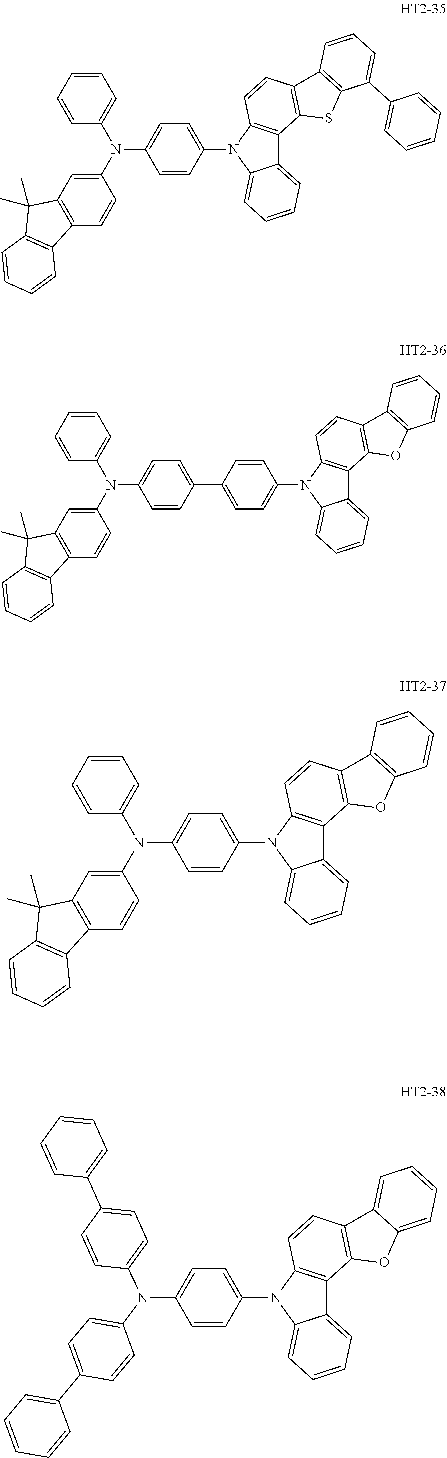 [SMILES: CC1(C)c2ccccc2-c2ccc(N(c3ccccc3)c3ccc(-n4c5ccccc5c5c6sc7c(-c8ccccc8)cccc7c6ccc54)cc3)cc21 ; CC1(C)c2ccccc2-c2ccc(N(c3ccccc3)c3ccc(-c4ccc(-n5c6ccccc6c6c7oc8ccccc8c7ccc65)cc4)cc3)cc21 ; CC1(C)c2ccccc2-c2ccc(N(c3ccccc3)c3ccc(-n4c5ccccc5c5c6oc7ccccc7c6ccc54)cc3)cc21 ; c1ccc(-c2ccc(N(c3ccc(-c4ccccc4)cc3)c3ccc(-n4c5ccccc5c5c6oc7ccccc7c6ccc54)cc3)cc2)cc1]

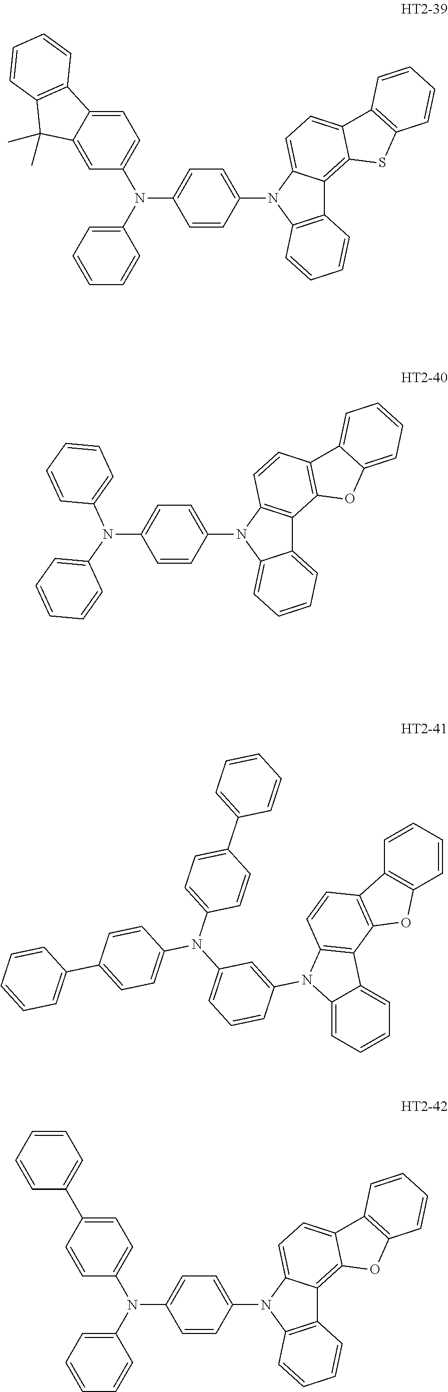 [SMILES: CC1(C)c2ccccc2-c2ccc(N(c3ccccc3)c3ccc(-n4c5ccccc5c5c6sc7ccccc7c6ccc54)cc3)cc21 ; c1ccc(N(c2ccccc2)c2ccc(-n3c4ccccc4c4c5oc6ccccc6c5ccc43)cc2)cc1 ; c1ccc(-c2ccc(N(c3ccc(-c4ccccc4)cc3)c3cccc(-n4c5ccccc5c5c6oc7ccccc7c6ccc54)c3)cc2)cc1 ; c1ccc(-c2ccc(N(c3ccccc3)c3ccc(-n4c5ccccc5c5c6oc7ccccc7c6ccc54)cc3)cc2)cc1]

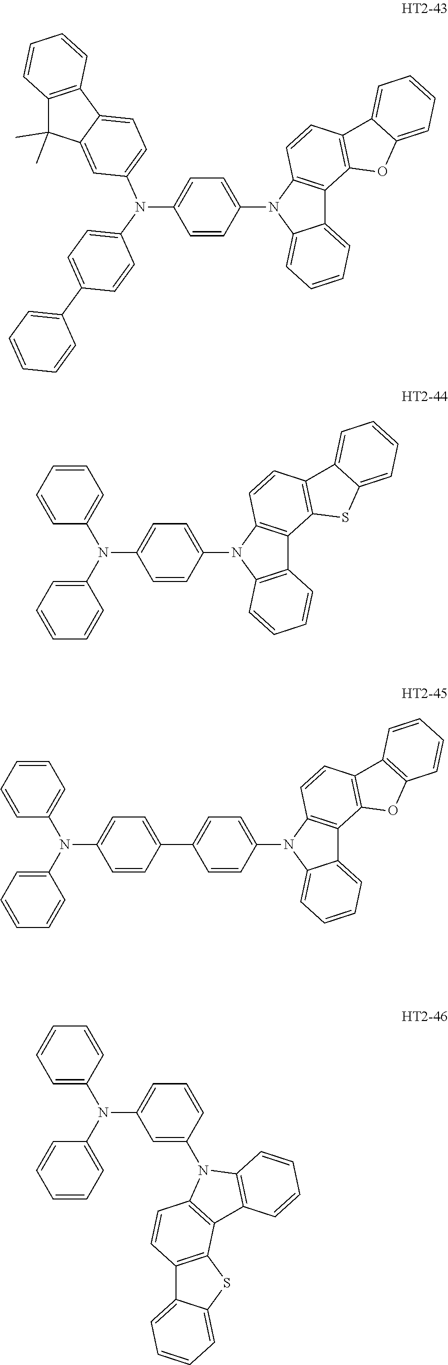 [SMILES: CC1(C)c2ccccc2-c2ccc(N(c3ccc(-c4ccccc4)cc3)c3ccc(-n4c5ccccc5c5c6oc7ccccc7c6ccc54)cc3)cc21 ; c1ccc(N(c2ccccc2)c2ccc(-n3c4ccccc4c4c5sc6ccccc6c5ccc43)cc2)cc1 ; c1ccc(N(c2ccccc2)c2ccc(-c3ccc(-n4c5ccccc5c5c6oc7ccccc7c6ccc54)cc3)cc2)cc1 ; c1ccc(N(c2ccccc2)c2cccc(-n3c4ccccc4c4c5sc6ccccc6c5ccc43)c2)cc1]

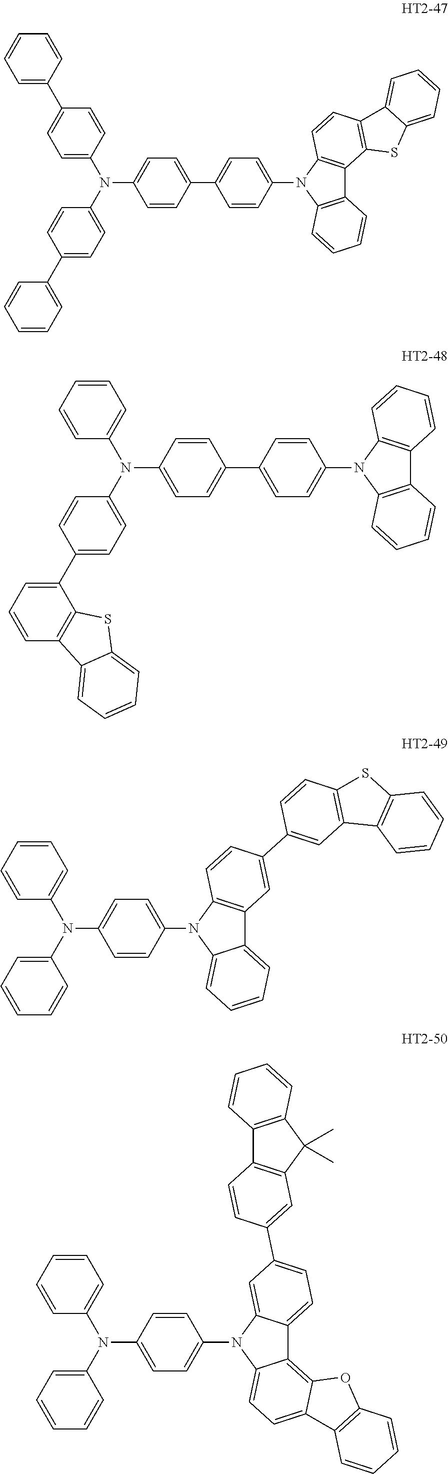 [SMILES: c1ccc(-c2ccc(N(c3ccc(-c4ccccc4)cc3)c3ccc(-c4ccc(-n5c6ccccc6c6c7sc8ccccc8c7ccc65)cc4)cc3)cc2)cc1 ; c1ccc(N(c2ccc(-c3ccc(-n4c5ccccc5c5ccccc54)cc3)cc2)c2ccc(-c3cccc4c3sc3ccccc34)cc2)cc1 ; c1ccc(N(c2ccccc2)c2ccc(-n3c4ccccc4c4cc(-c5ccc6sc7ccccc7c6c5)ccc43)cc2)cc1 ; CC1(C)c2ccccc2-c2ccc(-c3ccc4c5c6oc7ccccc7c6ccc5n(-c5ccc(N(c6ccccc6)c6ccccc6)cc5)c4c3)cc21]

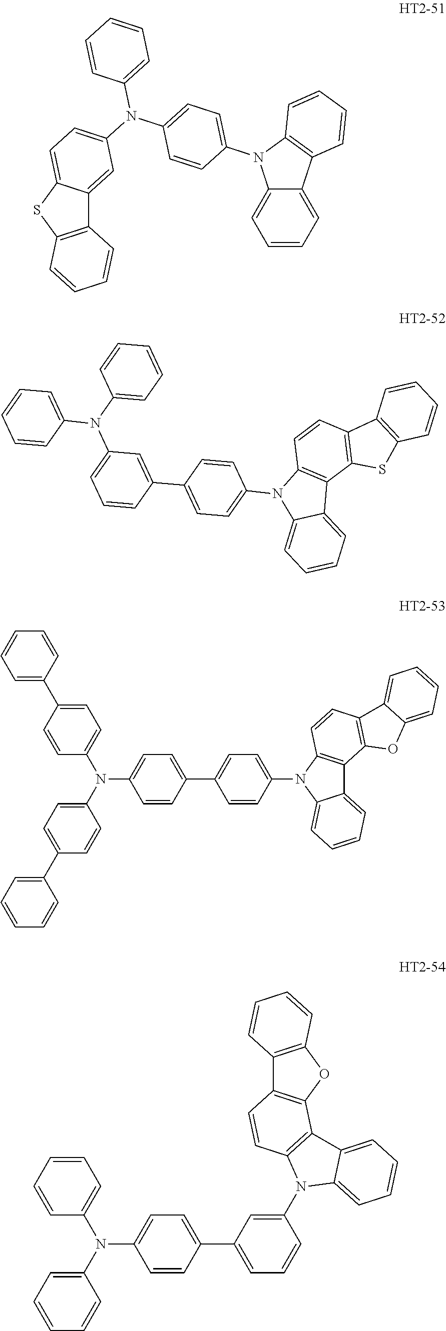 [SMILES: c1ccc(N(c2ccc(-n3c4ccccc4c4ccccc43)cc2)c2ccc3sc4ccccc4c3c2)cc1 ; c1ccc(N(c2ccccc2)c2cccc(-c3ccc(-n4c5ccccc5c5c6sc7ccccc7c6ccc54)cc3)c2)cc1 ; c1ccc(-c2ccc(N(c3ccc(-c4ccccc4)cc3)c3ccc(-c4ccc(-n5c6ccccc6c6c7oc8ccccc8c7ccc65)cc4)cc3)cc2)cc1 ; c1ccc(N(c2ccccc2)c2ccc(-c3cccc(-n4c5ccccc5c5c6oc7ccccc7c6ccc54)c3)cc2)cc1]

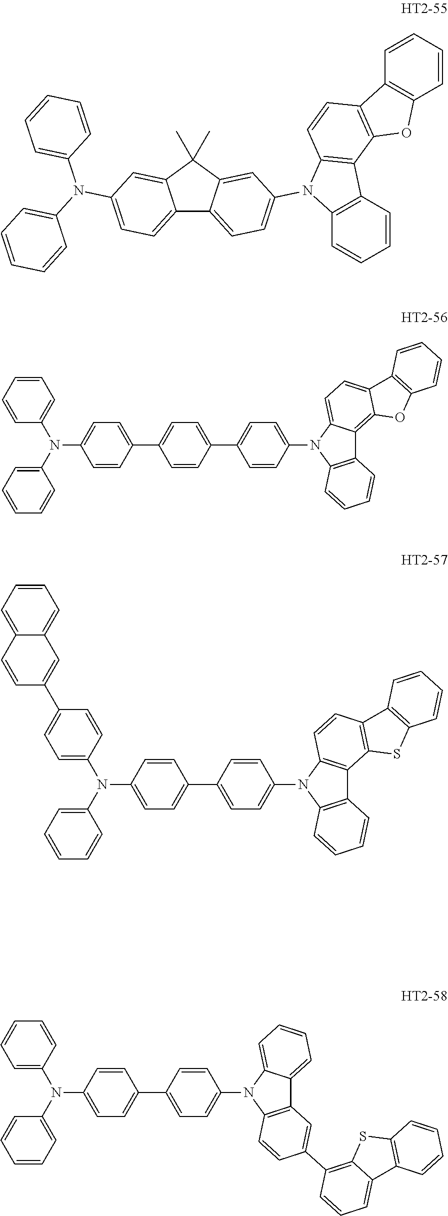 [SMILES: CC1(C)c2cc(N(c3ccccc3)c3ccccc3)ccc2-c2ccc(-n3c4ccccc4c4c5oc6ccccc6c5ccc43)cc21 ; c1ccc(N(c2ccccc2)c2ccc(-c3ccc(-c4ccc(-n5c6ccccc6c6c7oc8ccccc8c7ccc65)cc4)cc3)cc2)cc1 ; c1ccc(N(c2ccc(-c3ccc(-n4c5ccccc5c5c6sc7ccccc7c6ccc54)cc3)cc2)c2ccc(-c3ccc4ccccc4c3)cc2)cc1 ; c1ccc(N(c2ccccc2)c2ccc(-c3ccc(-n4c5ccccc5c5cc(-c6cccc7c6sc6ccccc67)ccc54)cc3)cc2)cc1]

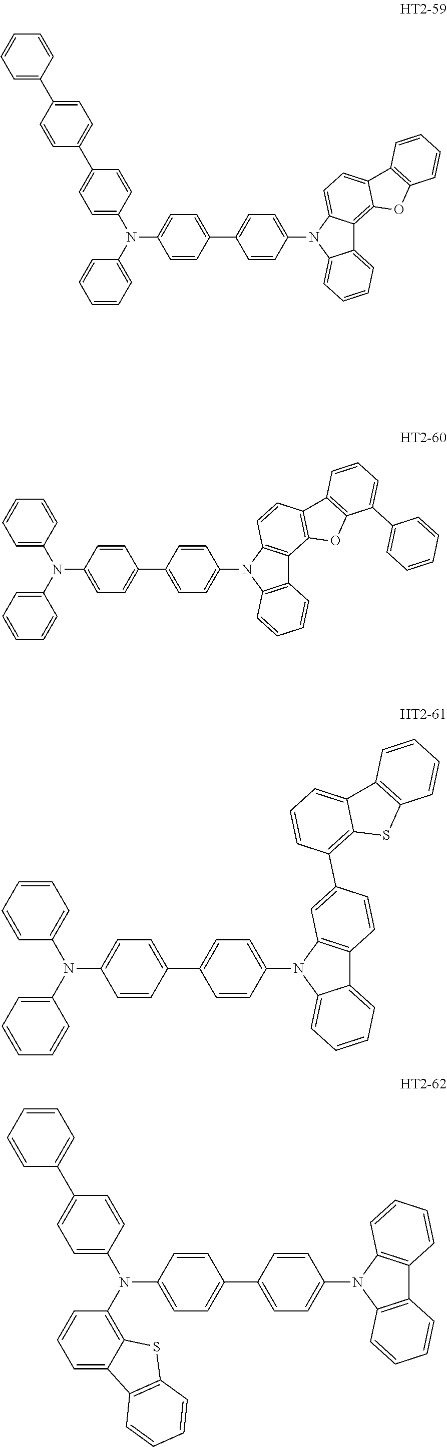 [SMILES: c1ccc(-c2ccc(-c3ccc(N(c4ccccc4)c4ccc(-c5ccc(-n6c7ccccc7c7c8oc9ccccc9c8ccc76)cc5)cc4)cc3)cc2)cc1 ; c1ccc(-c2cccc3c2oc2c3ccc3c2c2ccccc2n3-c2ccc(-c3ccc(N(c4ccccc4)c4ccccc4)cc3)cc2)cc1 ; c1ccc(N(c2ccccc2)c2ccc(-c3ccc(-n4c5ccccc5c5ccc(-c6cccc7c6sc6ccccc67)cc54)cc3)cc2)cc1 ; c1ccc(-c2ccc(N(c3ccc(-c4ccc(-n5c6ccccc6c6ccccc65)cc4)cc3)c3cccc4c3sc3ccccc34)cc2)cc1]

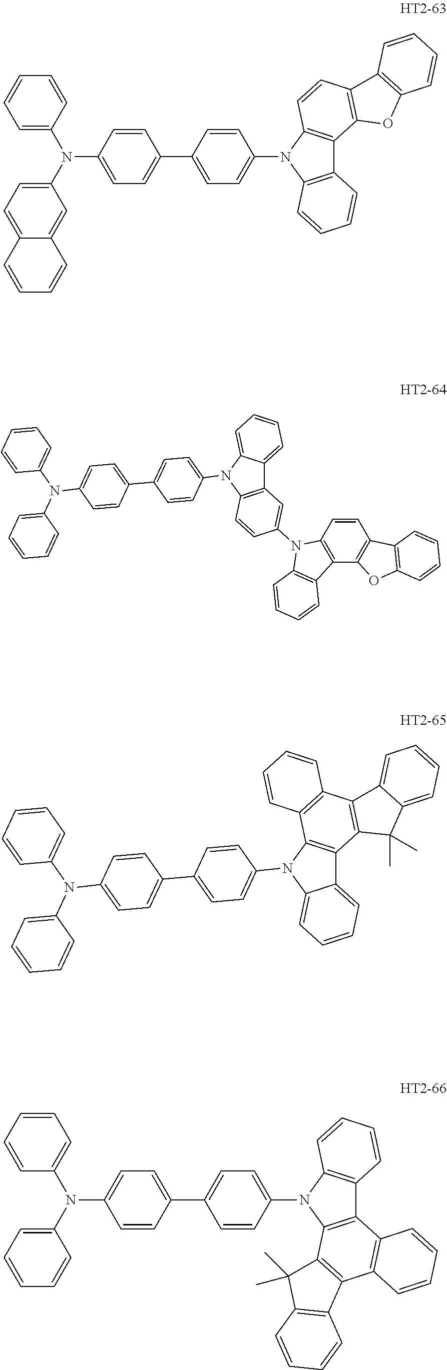 [SMILES: c1ccc(N(c2ccc(-c3ccc(-n4c5ccccc5c5c6oc7ccccc7c6ccc54)cc3)cc2)c2ccc3ccccc3c2)cc1 ; c1ccc(N(c2ccccc2)c2ccc(-c3ccc(-n4c5ccccc5c5cc(-n6c7ccccc7c7c8oc9ccccc9c8ccc76)ccc54)cc3)cc2)cc1 ; CC1(C)c2ccccc2-c2c1c1c3ccccc3n(-c3ccc(-c4ccc(N(c5ccccc5)c5ccccc5)cc4)cc3)c1c1ccccc21 ; CC1(C)c2ccccc2-c2c1c1c(c3ccccc23)c2ccccc2n1-c1ccc(-c2ccc(N(c3ccccc3)c3ccccc3)cc2)cc1]

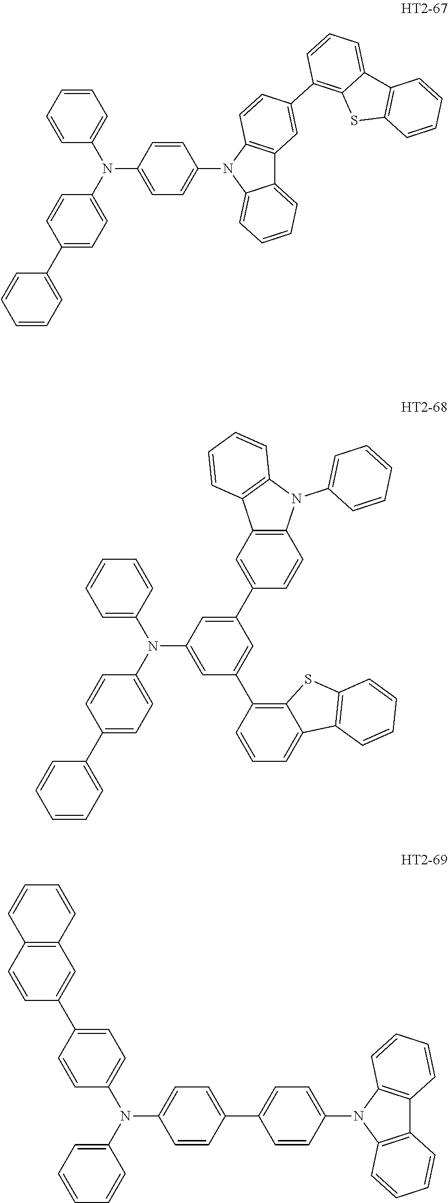 [SMILES: c1ccc(-c2ccc(N(c3ccccc3)c3ccc(-n4c5ccccc5c5cc(-c6cccc7c6sc6ccccc67)ccc54)cc3)cc2)cc1 ; c1ccc(-c2ccc(N(c3ccccc3)c3cc(-c4ccc5c(c4)c4ccccc4n5-c4ccccc4)cc(-c4cccc5c4sc4ccccc45)c3)cc2)cc1 ; c1ccc(N(c2ccc(-c3ccc(-n4c5ccccc5c5ccccc54)cc3)cc2)c2ccc(-c3ccc4ccccc4c3)cc2)cc1]

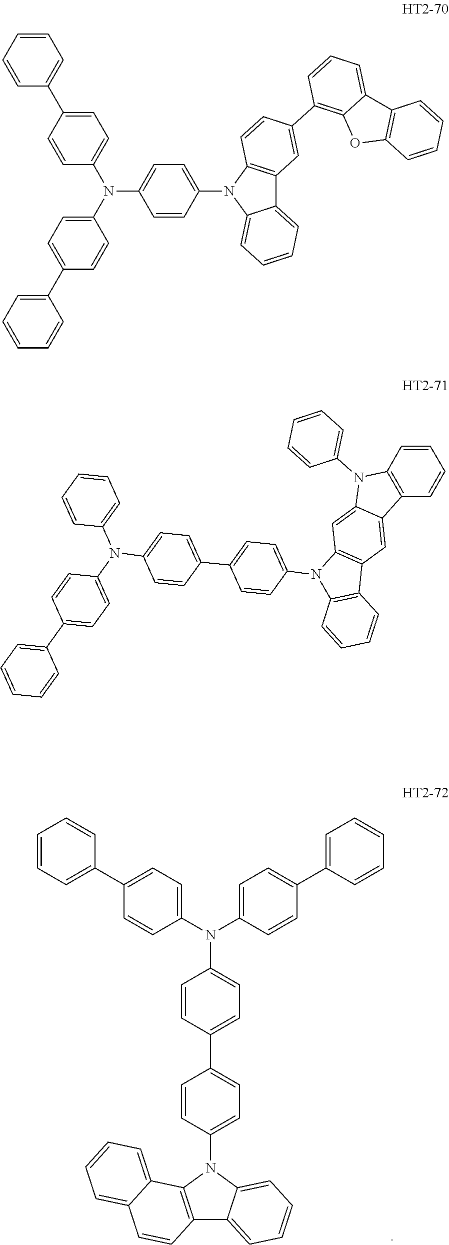 [SMILES: c1ccc(-c2ccc(N(c3ccc(-c4ccccc4)cc3)c3ccc(-n4c5ccccc5c5cc(-c6cccc7c6oc6ccccc67)ccc54)cc3)cc2)cc1 ; c1ccc(-c2ccc(N(c3ccccc3)c3ccc(-c4ccc(-n5c6ccccc6c6cc7c8ccccc8n(-c8ccccc8)c7cc65)cc4)cc3)cc2)cc1 ; c1ccc(-c2ccc(N(c3ccc(-c4ccccc4)cc3)c3ccc(-c4ccc(-n5c6ccccc6c6ccc7ccccc7c65)cc4)cc3)cc2)cc1]

The compound of formula 1 of the present disclosure can be prepared by a synthetic method known to a person skilled in the art, for example, according to the following reaction schemes, but is not limited thereto.

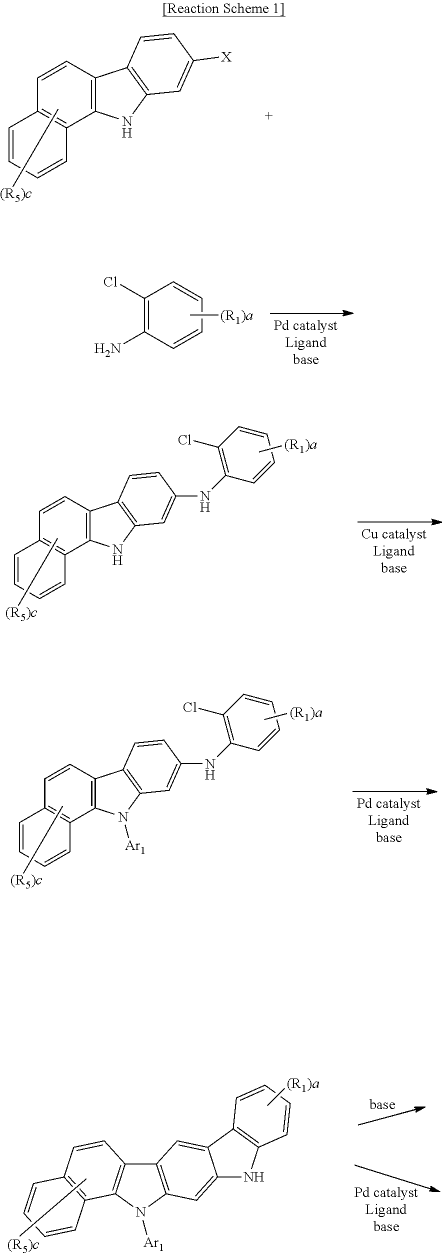

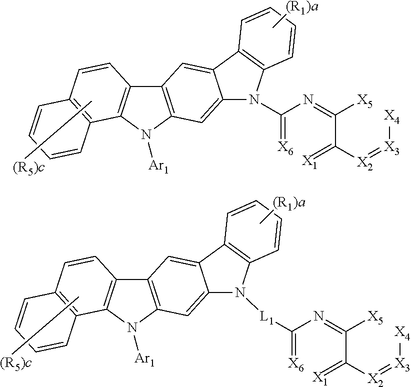

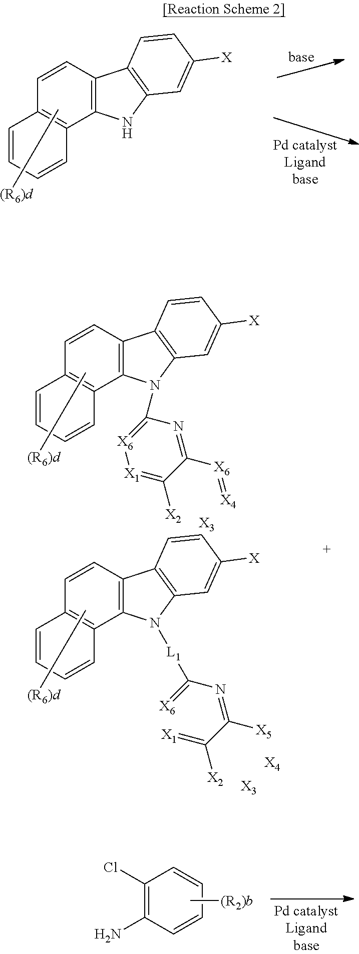

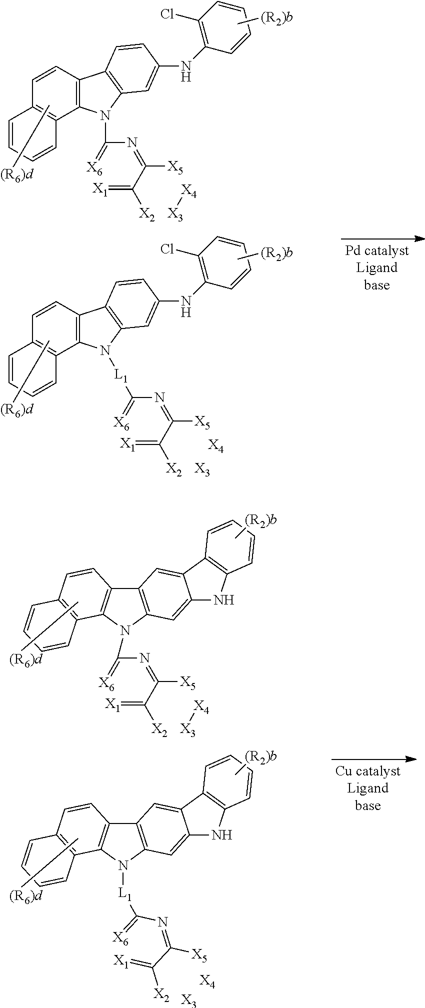

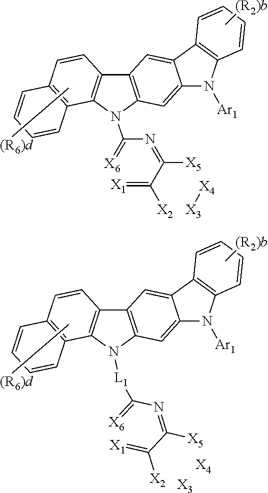

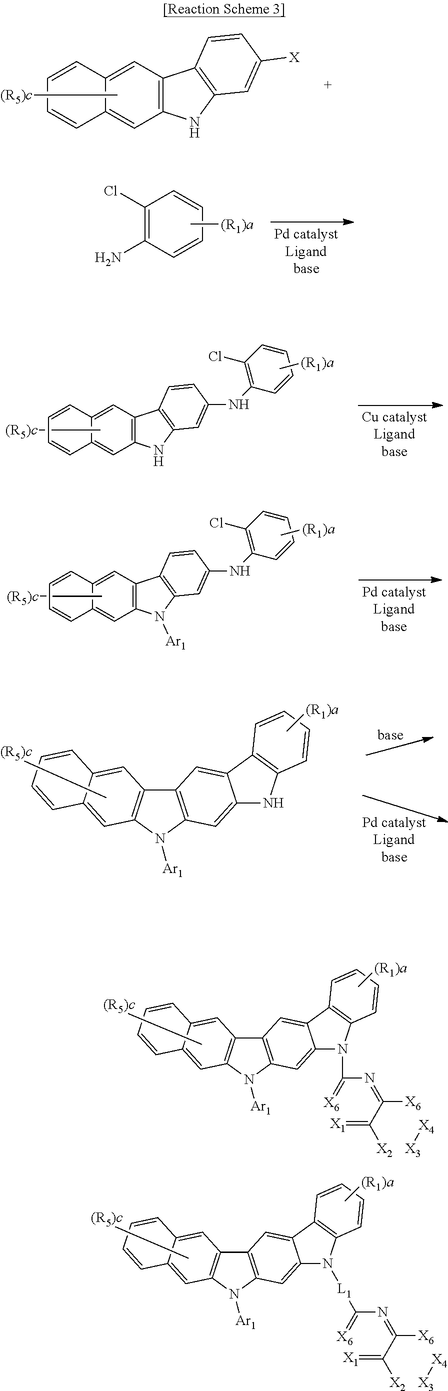

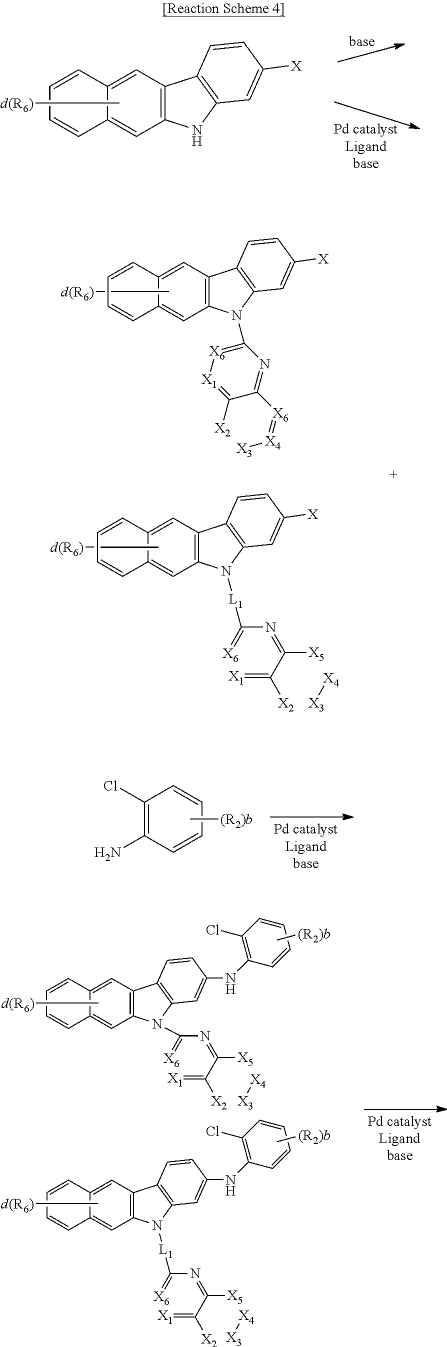

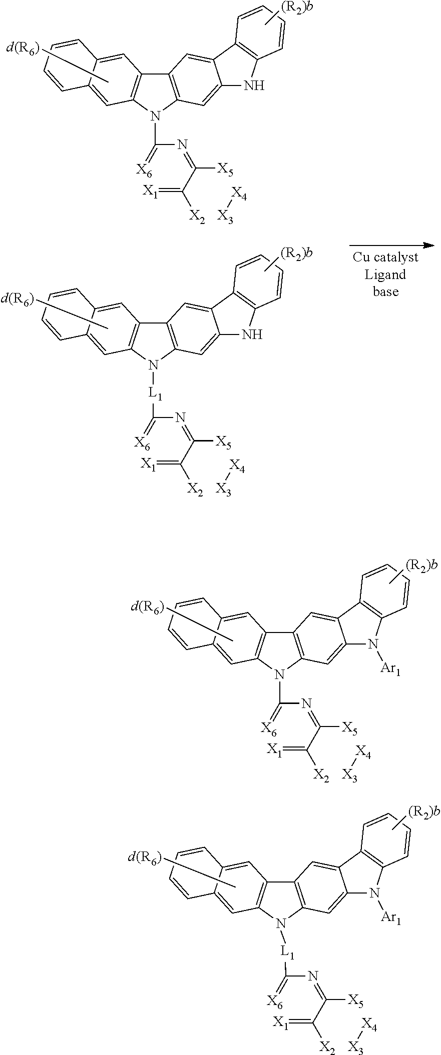

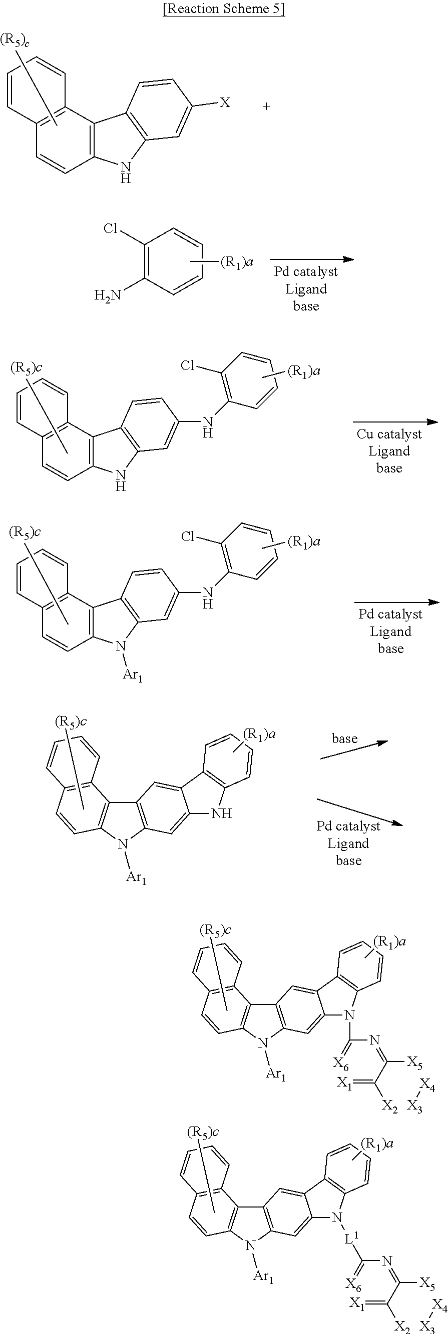

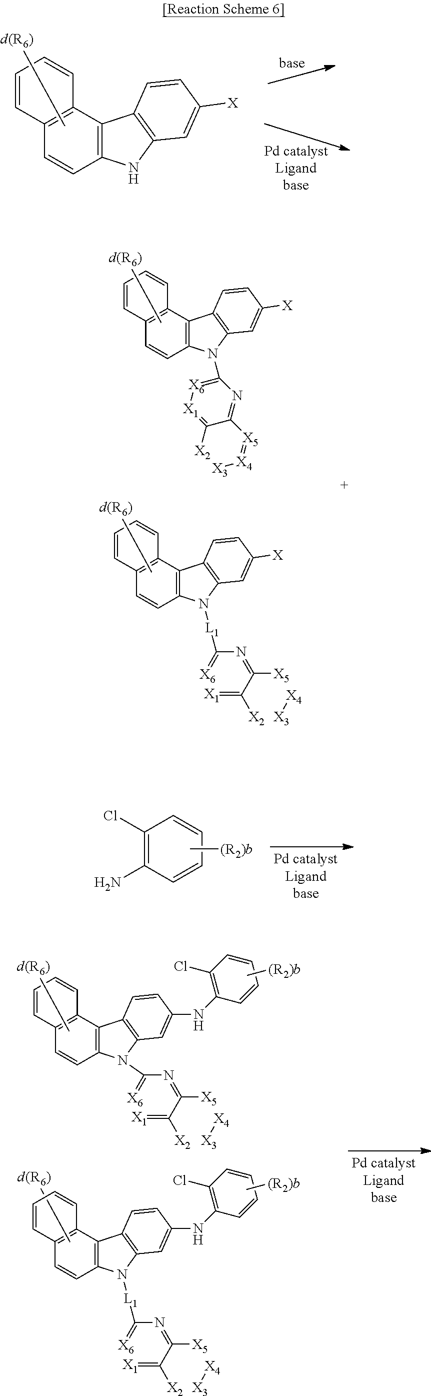

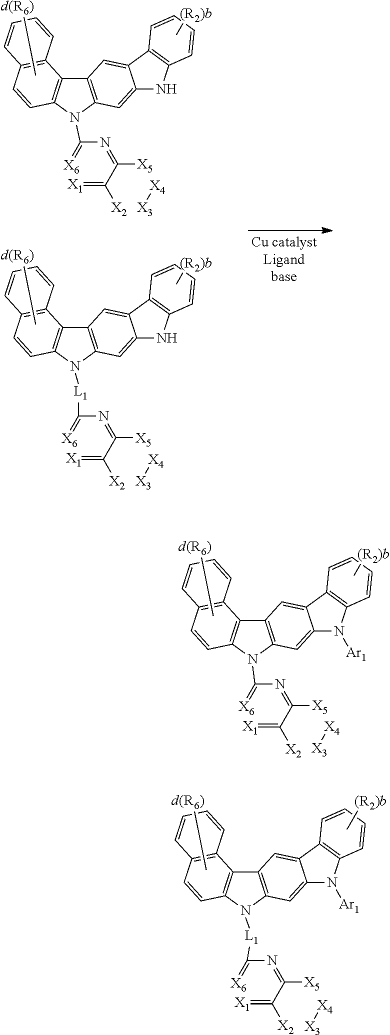

wherein L₁, Ar₁, R₁, R₂, R₅, R₆, X₁ to X₆, a, b, c, and d are as defined in formulas 1 to 7, and X represents halogen.

The compounds of formulas 11 and 12 of the present disclosure can be prepared by a synthetic method known to a person skilled in the art, for example, using or modifying the synthesis method disclosed in KR 2013-0106255 A, KR 2010-0106014 A, KR 2014-0043224 A, etc.

The dopant comprised in the organic electroluminescent device according to the present disclosure may be at least one phosphorescent or fluorescent dopant, and preferably a phosphorescent dopant. The phosphorescent dopant materials applied to the organic electroluminescent device according to the present disclosure are not particularly limited, but may be selected from metallated complex compounds of iridium (Ir), osmium (Os), copper (Cu), and platinum (Pt), more preferably selected from ortho-metallated complex compounds of iridium (Ir), osmium (Os), copper (Cu), and platinum (Pt), and even more preferably an ortho-metallated iridium complex compound.

The dopant comprised in the organic electroluminescent device of the present disclosure may be a compound represented by formula 101 below, but is not limited thereto.

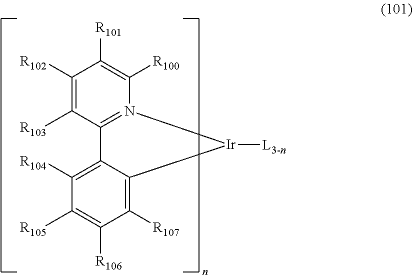

wherein L is selected from the following structures 1 and 2:

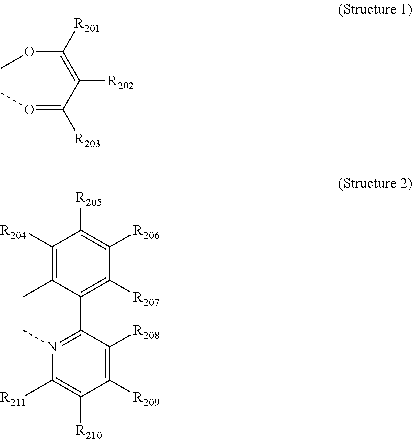

R₁₀₀ to R₁₀₃ each independently represent hydrogen, deuterium, a halogen, a (C1-C30)alkyl unsubstituted or substituted with a halogen(s), a substituted or unsubstituted (C3-C30)cycloalkyl, a substituted or unsubstituted (C6-C30)aryl, a cyano, a substituted or unsubstituted (3- to 30-membered)heteroaryl, or a substituted or unsubstituted (C1-C30)alkoxy; or adjacent substituents of R₁₀₀ to R₁₀₃ may be linked to each other to form a substituted or unsubstituted fused ring together with the pyridine, e.g., a substituted or unsubstituted quinoline, a substituted or unsubstituted isoquinoline, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline;

R₁₀₄ to R₁₀₇ each independently represent hydrogen, deuterium, a halogen, a (C1-C30)alkyl unsubstituted or substituted with a halogen(s), a substituted or unsubstituted (C3-C30)cycloalkyl, a substituted or unsubstituted (C6-C30)aryl, a substituted or unsubstituted (3- to 30-membered)heteroaryl, a cyano, or a substituted or unsubstituted (C1-C30)alkoxy; or adjacent substituents of R₁₀₄ to R₁₀₇ may be linked to each other to form a substituted or unsubstituted fused ring together with the benzene, e.g., a substituted or unsubstituted naphthyl, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine;

R₂₀₁ to R₂₁₁ each independently represent hydrogen, deuterium, a halogen, a (C1-C30)alkyl unsubstituted or substituted with a halogen(s), a substituted or unsubstituted (C3-C30)cycloalkyl, or a substituted or unsubstituted (C6-C30)aryl; or adjacent substituents of R₂₀₁ to R₂₁₁ may be linked to each other to form a substituted or unsubstituted fused ring; and

n represents an integer of 1 to 3.

The specific examples of the dopant compound are as follows, but are not limited thereto.

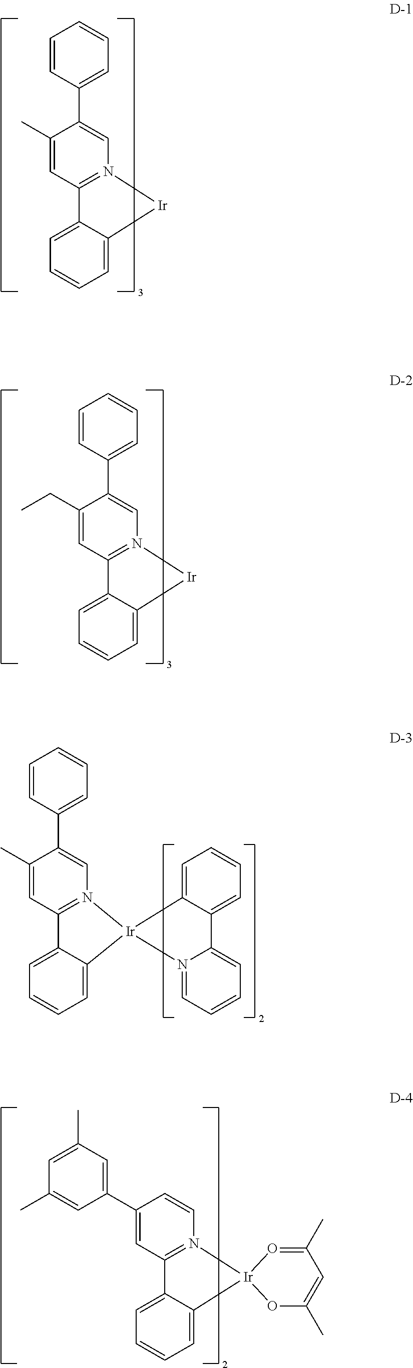

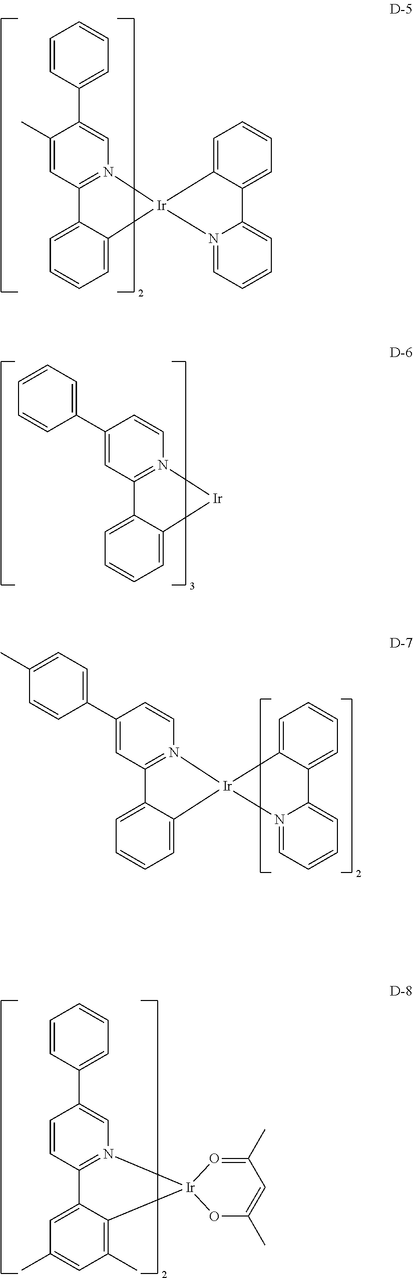

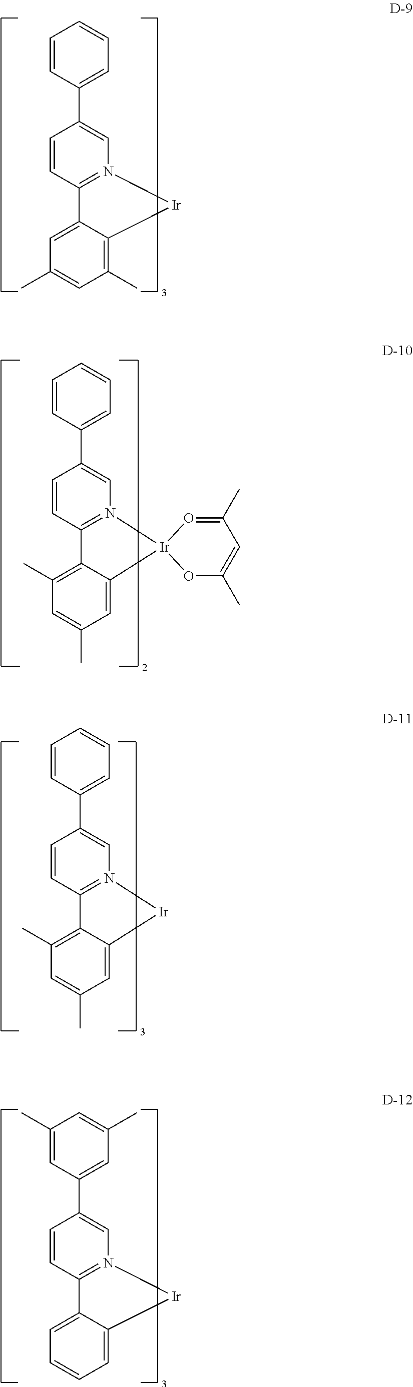

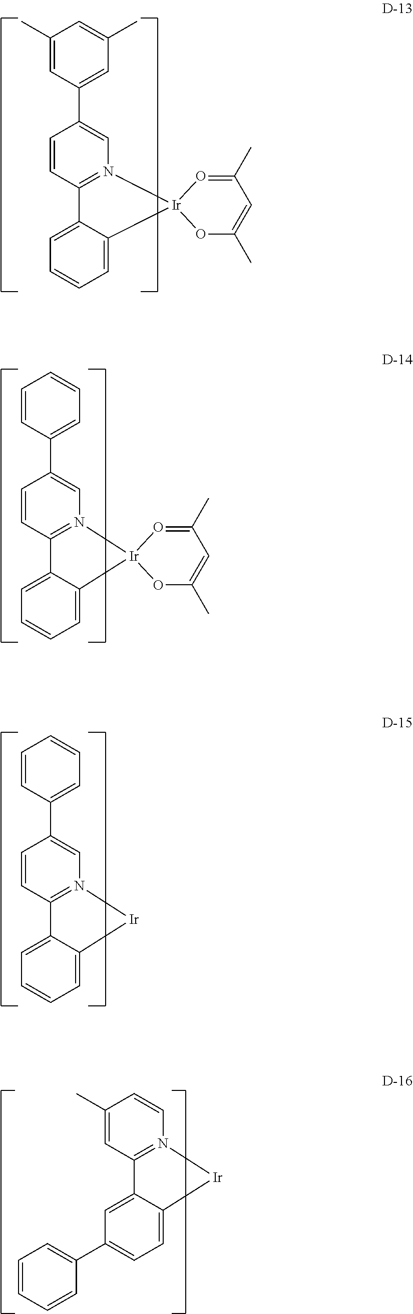

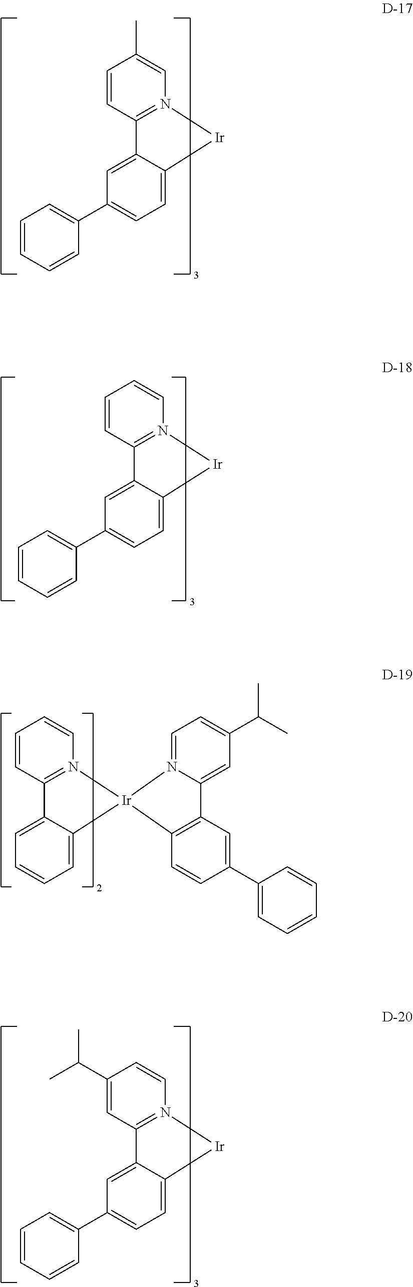

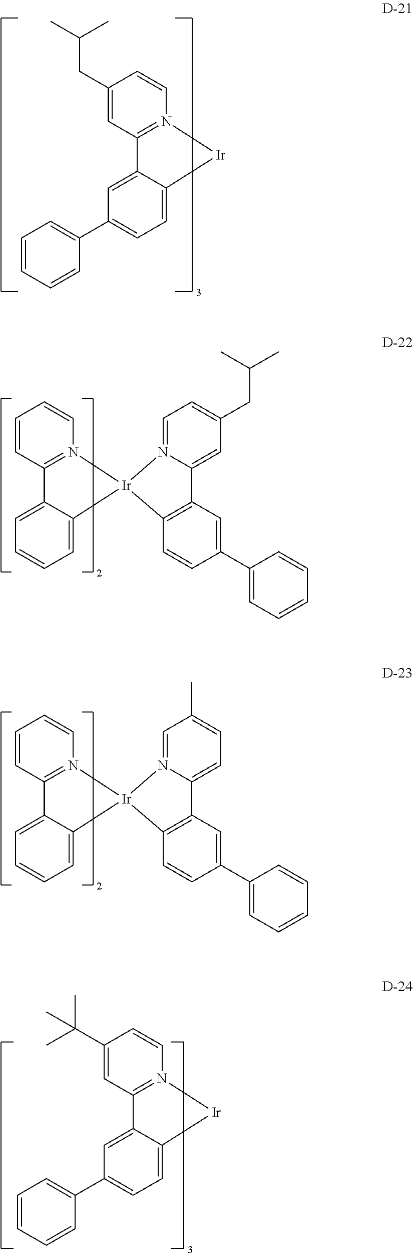

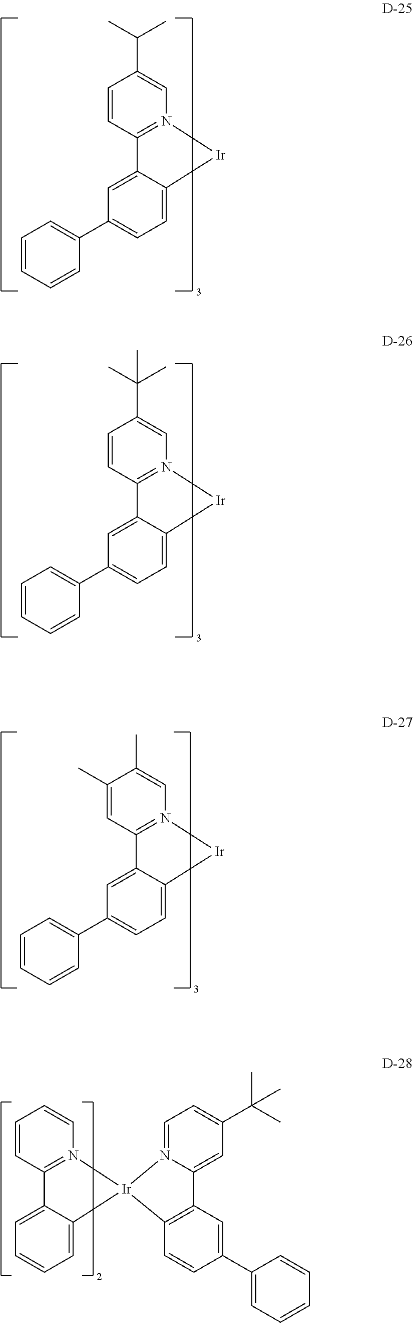

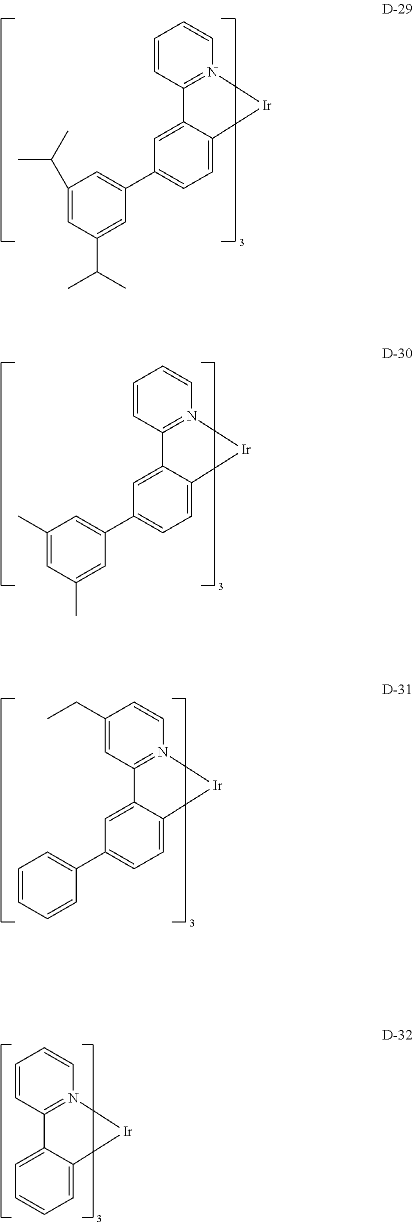

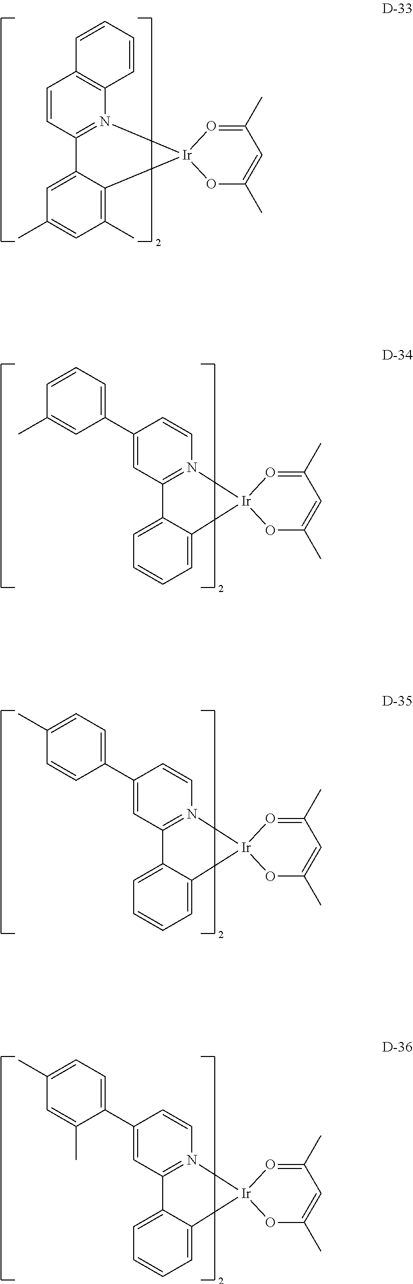

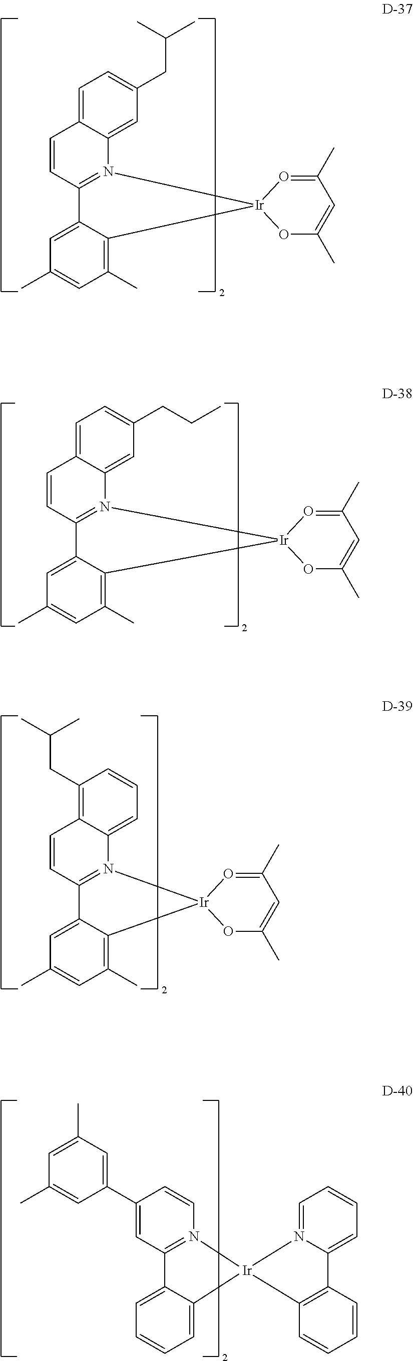

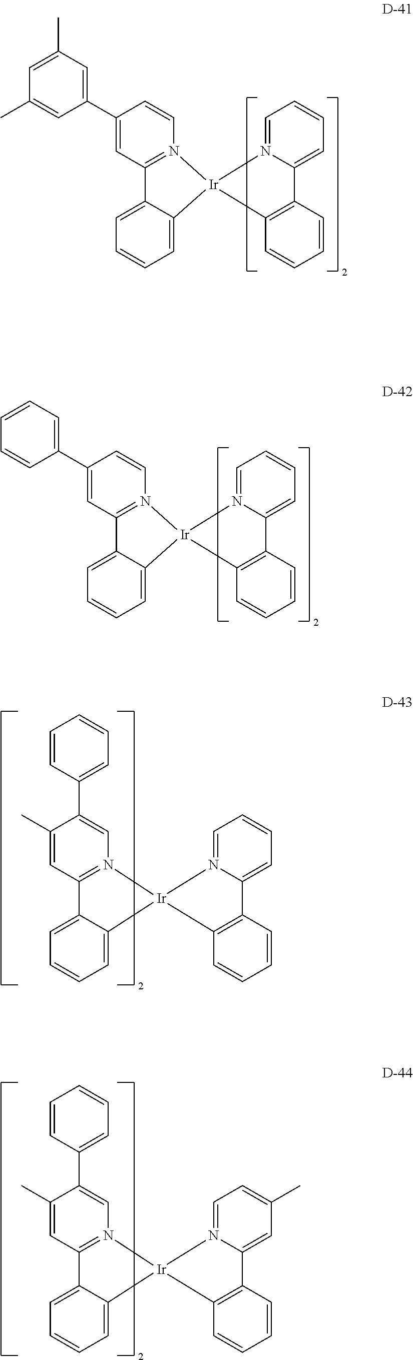

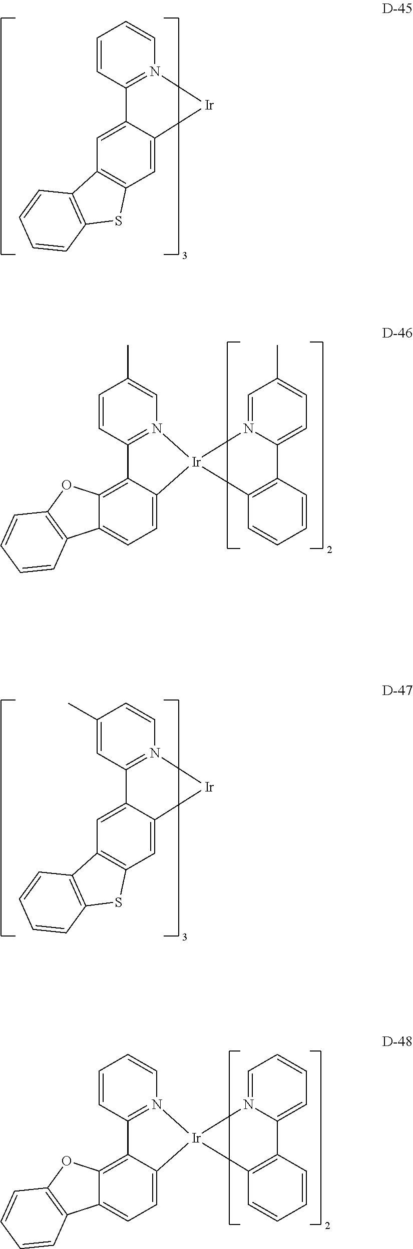

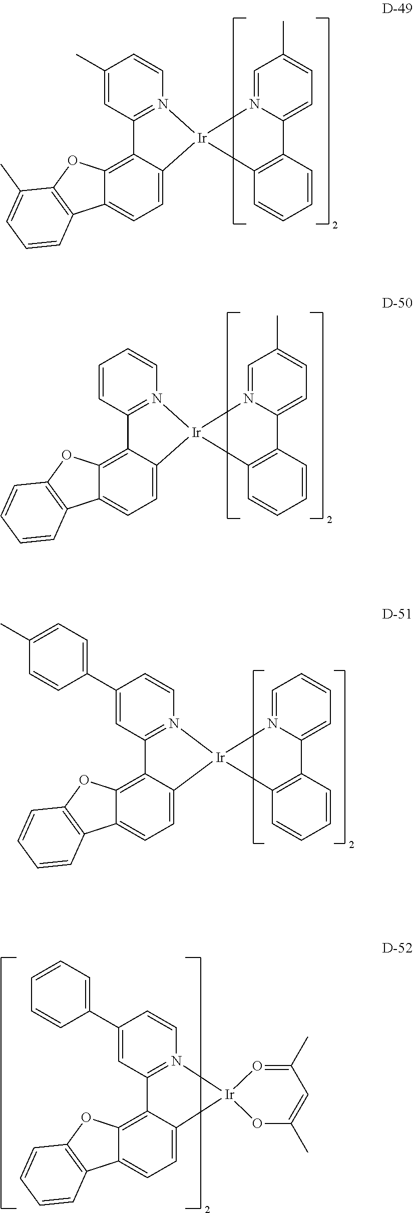

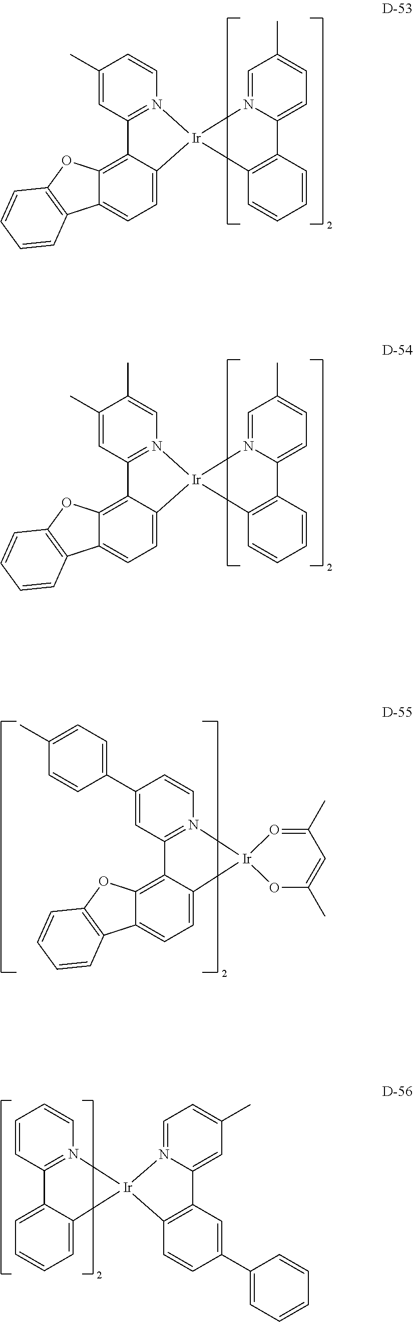

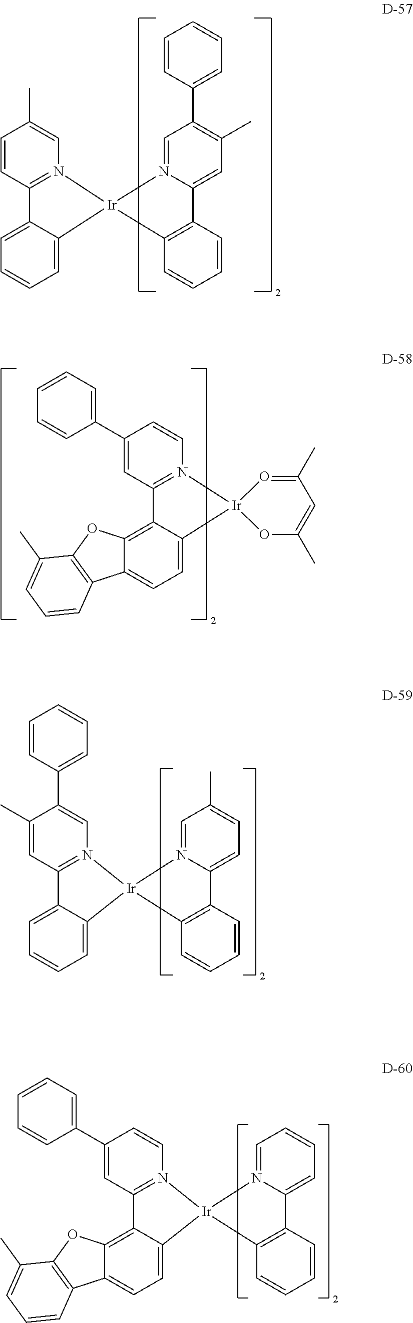

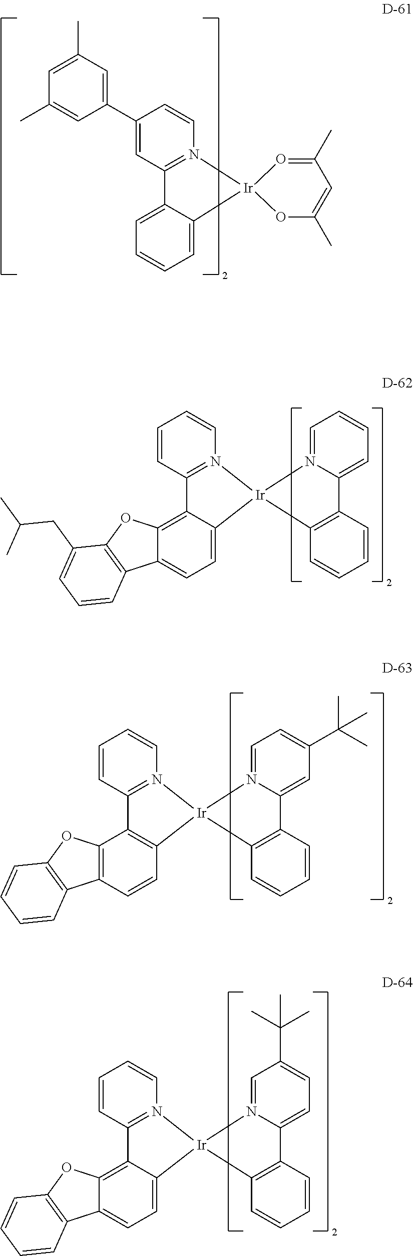

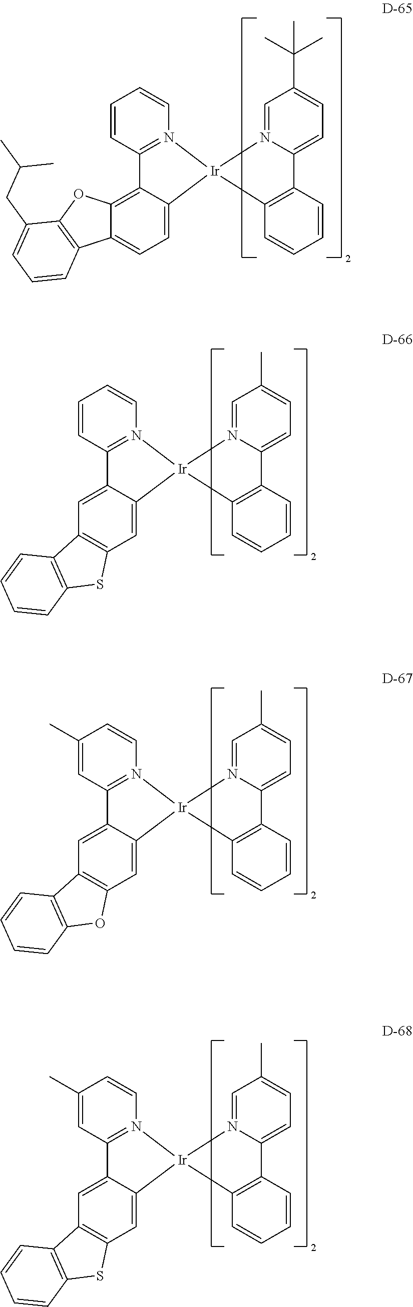

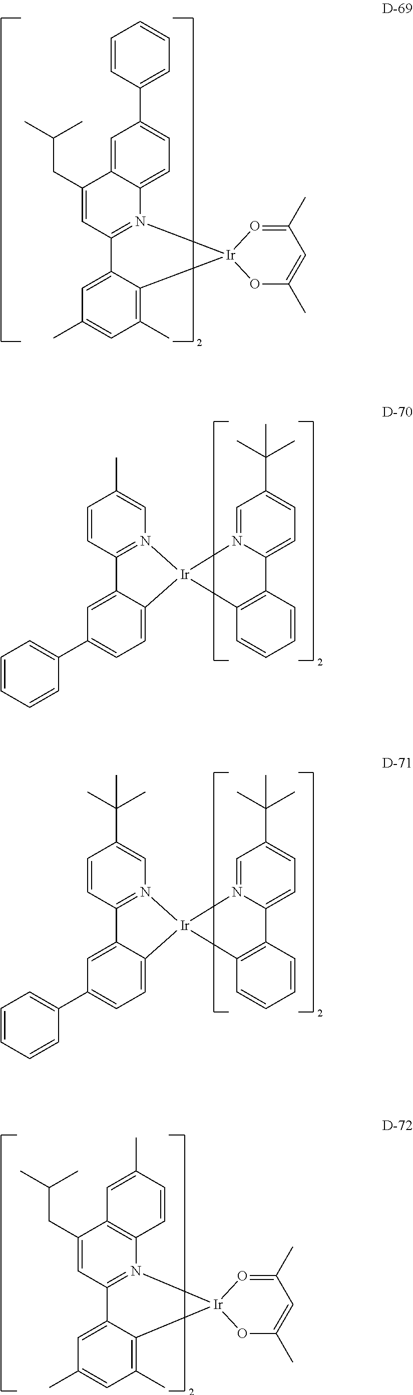

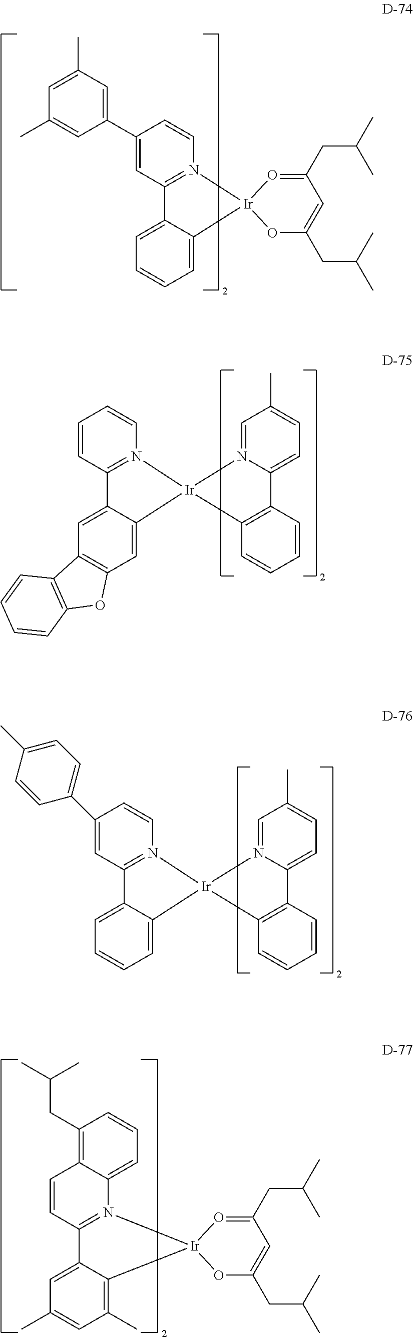

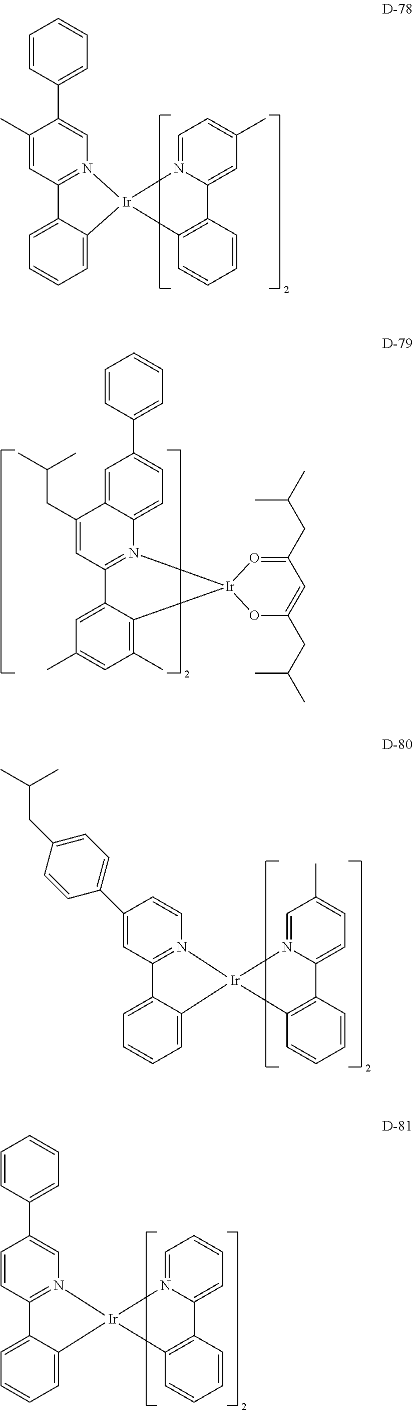

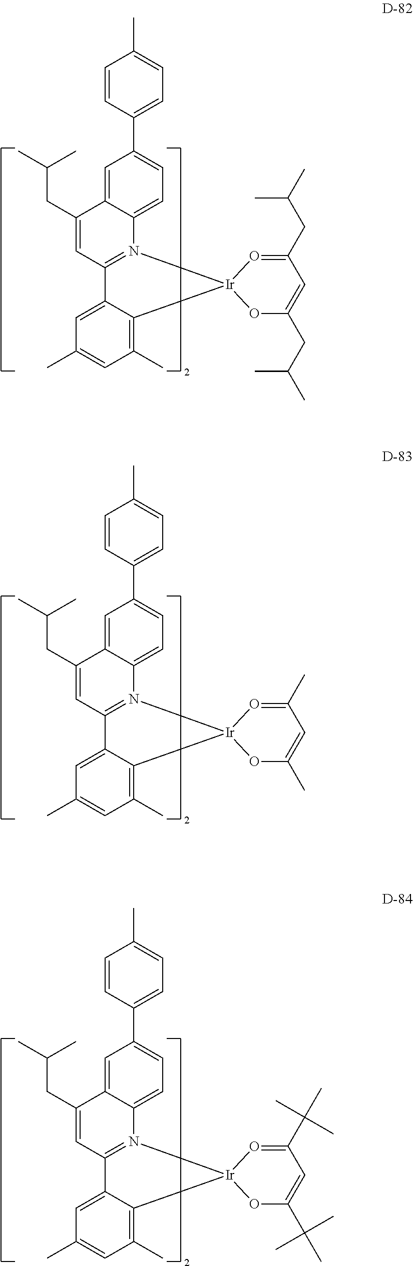

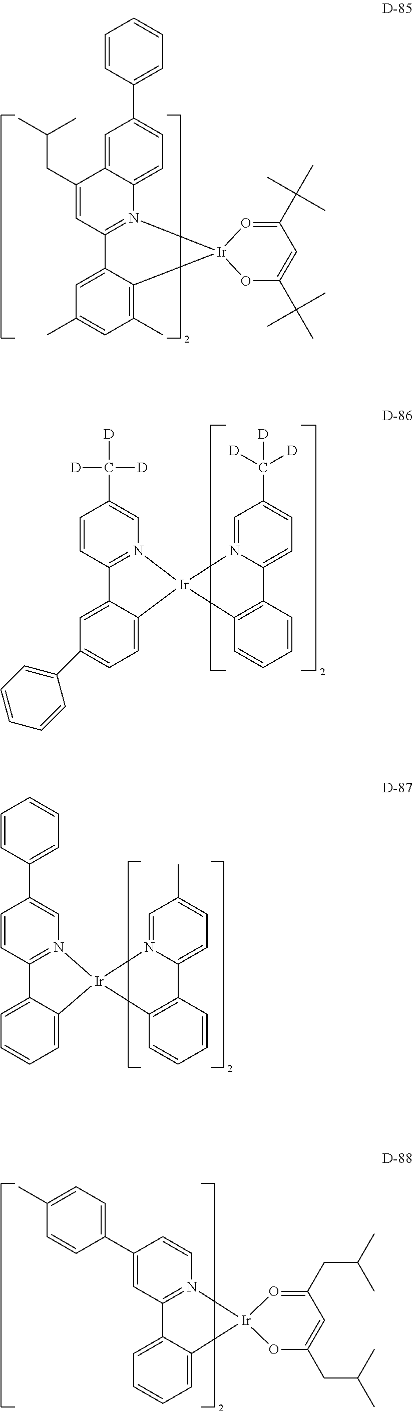

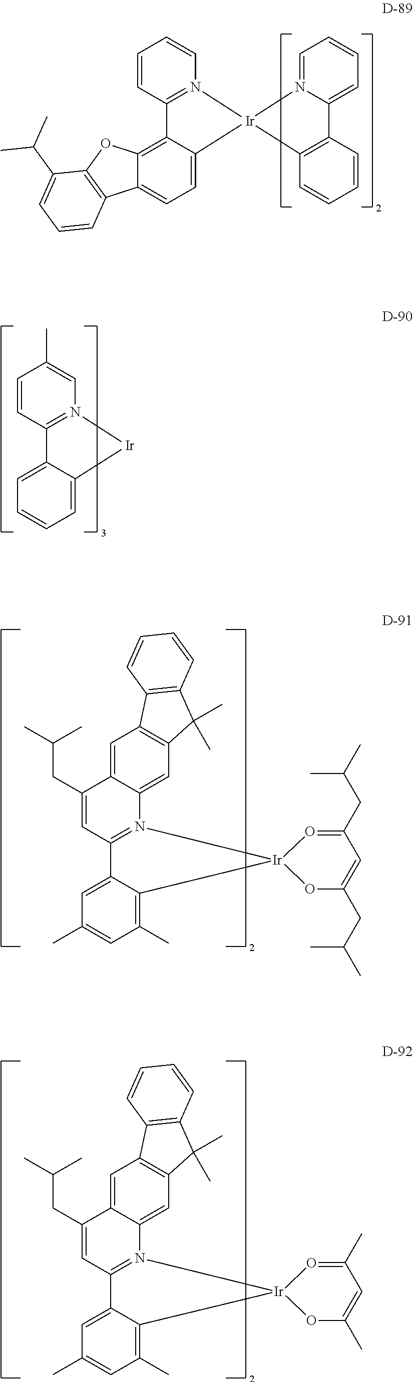

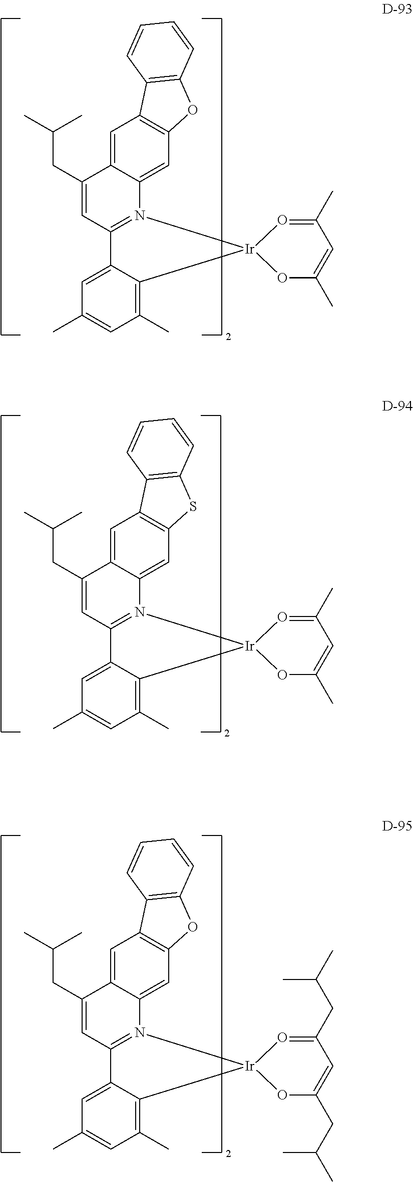

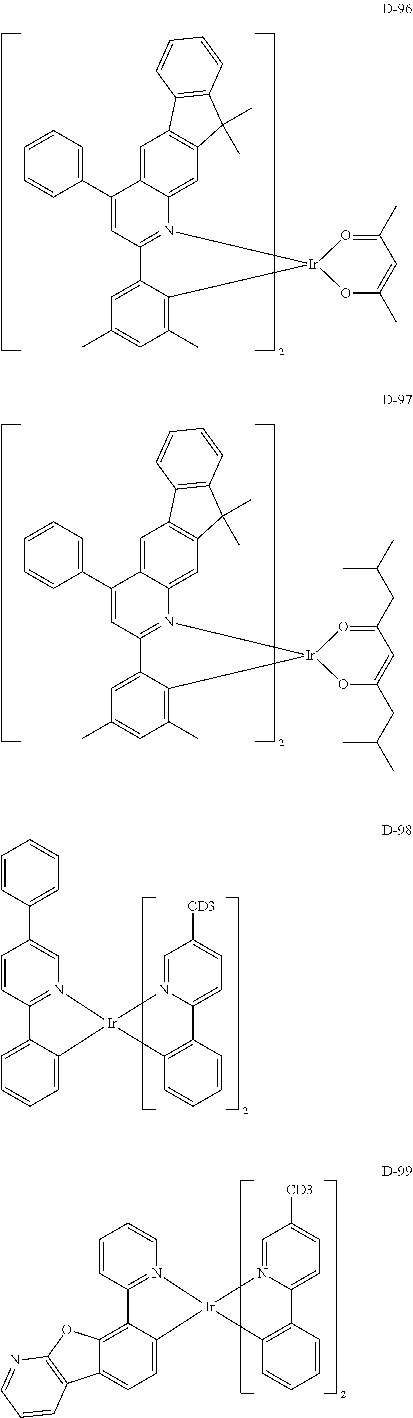

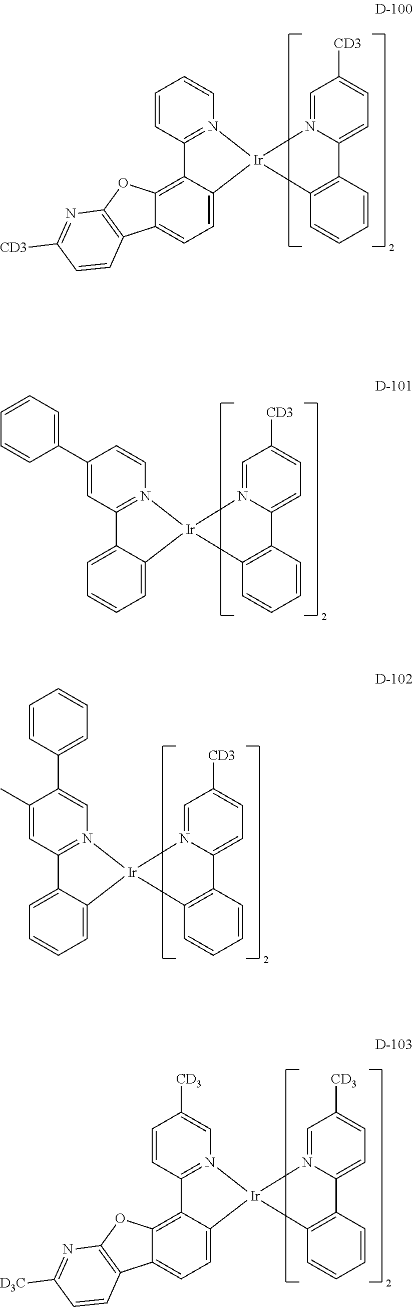

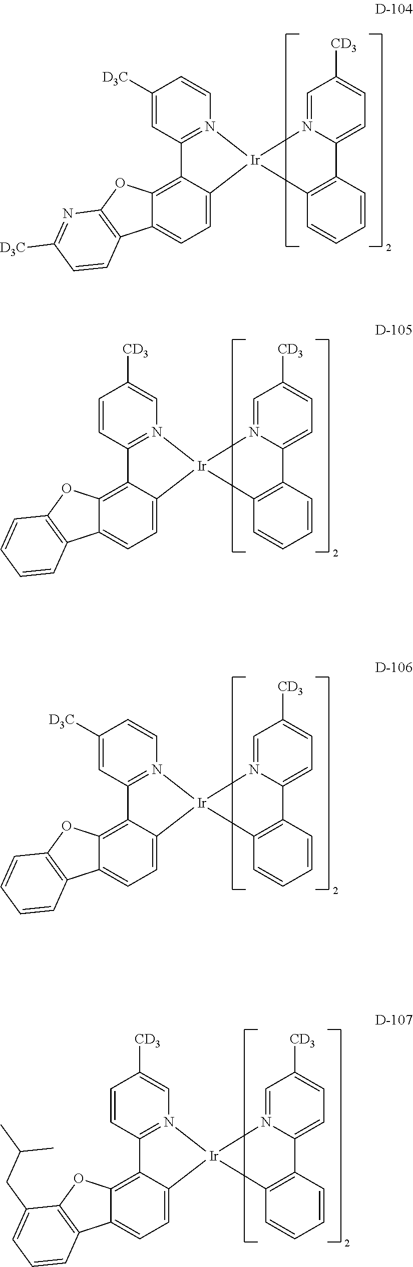

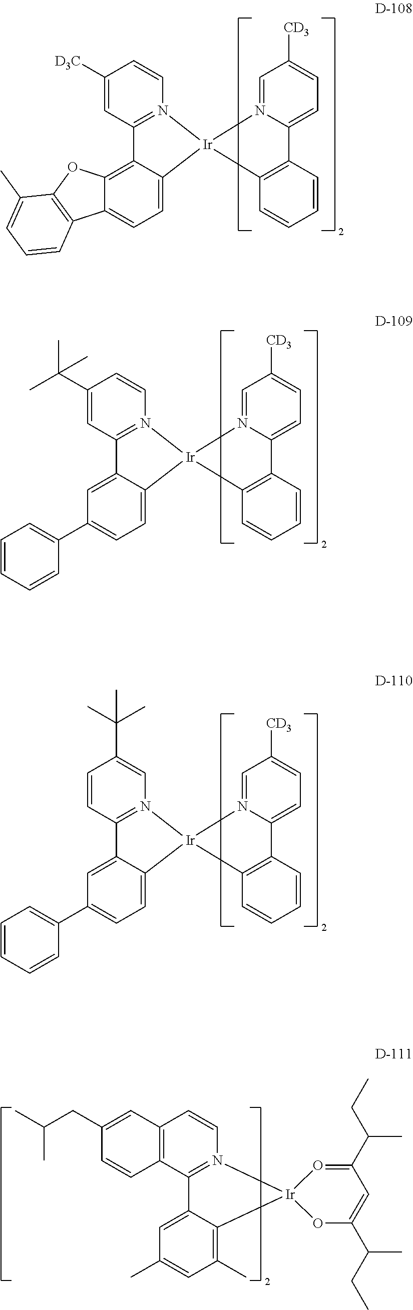

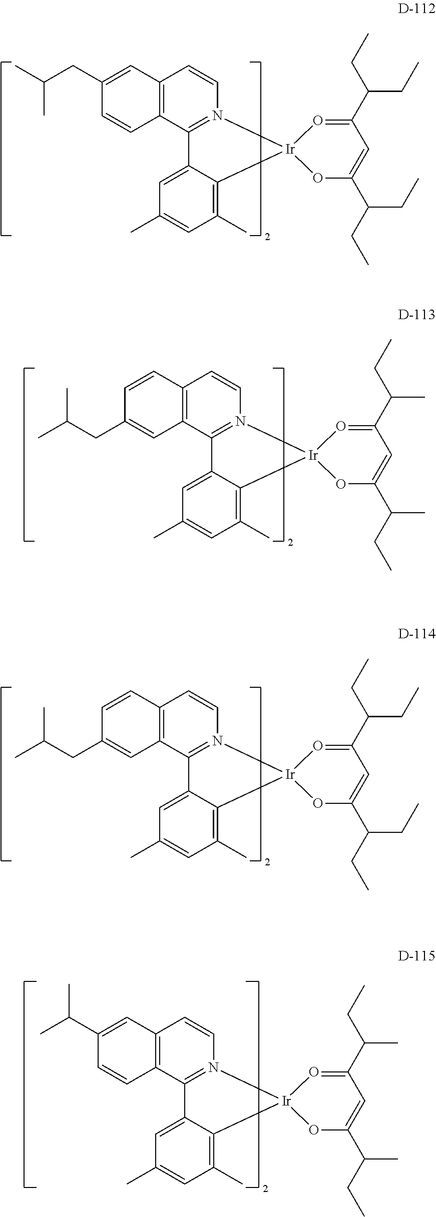

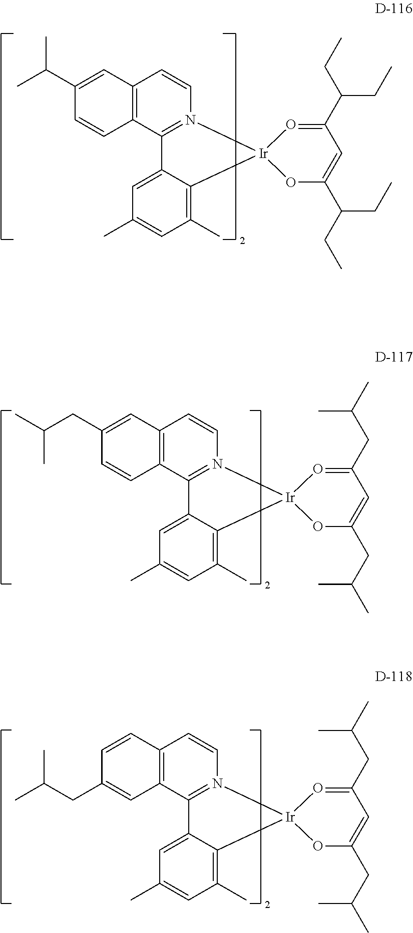

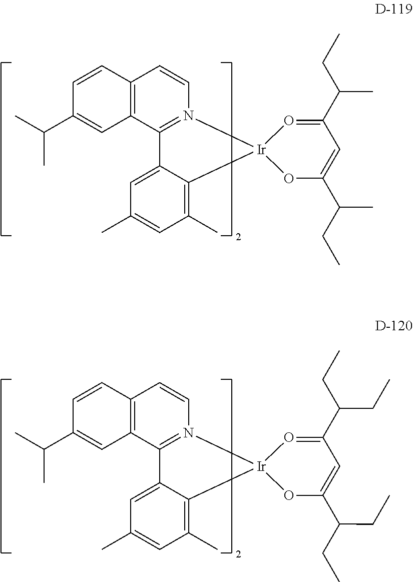

The organic electroluminescent device according to the present disclosure comprises a hole transport zone between the first electrode and the light-emitting layer, wherein the hole transport zone comprises an arylamine derivative comprising one carbazole or fused carbazole, and the HOMO energy value of the arylamine derivative comprising one carbazole or fused carbazole satisfies equation 11 below. According to one embodiment of the present disclosure, the first hole transport layer may be comprised between the first electrode and the light-emitting layer, the second hole transport layer may be comprised between the first hole transport layer and the light-emitting layer, the second hole transport layer may comprise an arylamine derivative comprising one carbazole or fused carbazole, and the HOMO energy value of the arylamine derivative comprising one carbazole or fused carbazole may satisfy equation 11 below. Herein, the second hole transport layer may be a single layer or a multi-layer, and the second hole transport layer may be a layer which plays a role as a hole transport layer, a light-emitting auxiliary layer, a hole auxiliary layer, and/or an electron blocking layer.

−5.0 eV≤HOMO≤−4.6 eV (11)

According to one embodiment of the present disclosure, the HOMO energy value of the arylamine derivative comprising one carbazole or fused carbazole may satisfy the following equation 12.

−5.0 eV≤HOMO≤−4.65 eV (12)

According to one embodiment of the present disclosure, the HOMO energy value of the arylamine derivative comprising one carbazole or fused carbazole may satisfy the following equation 13.

−5.0 eV≤HOMO≤−4.7 eV (13)

If the HOMO energy value exceeds the upper limit of the above, the hole injection and/or transport from the first electrode to the second hole transport layer is not so smooth that the problem of unsatisfactory luminous efficiency of the device may occur, and if the HOMO energy value is lower than the lower limit of the above, the luminous efficiency of the device increases but there is no significant advantage in terms of power efficiency since the driving voltage also increases as the luminous efficiency increases.

By using the organic electroluminescent device of the present disclosure, a display device, for example, for smartphones, tablets, notebooks, PCs, TVs, or vehicles, or a lighting device, for example, an indoor or outdoor lighting device can be produced.

The organic electroluminescent device of the present disclosure is intended to explain one embodiment of the present disclosure, and is not meant in any way to restrict the scope of the invention. The organic electroluminescent device may be embodied in another way.

The HOMO and LUMO energy levels of the present disclosure were measured by using the density functional theory (DFT) in the program of Gaussian 03 of Gaussian, Inc. Specifically, the HOMO and LUMO energy values of the Examples and the Comparative Examples of the present disclosure were extracted from the structure having the lowest energy among the calculated energies of the conformational isomers after structurally optimizing the structures of all of the possible conformational isomers at the level of B3LYP/6-31g*.

Hereinafter, it is discussed whether it is possible to improve the efficiency of the OLED device by using the combination of the host compound of formula 1 and the hole transport zone comprising an arylamine derivative comprising one carbazole or fused carbazole having a certain HOMO energy value. However, the following Examples are intended to explain the performance of the OLED device of the present disclosure, and the present disclosure is not limited thereto.

### Device Examples 1 to 4: Production of an OLED Device According to the Present Disclosure

An OLED device according to the present disclosure was produced as follows. A transparent electrode indium tin oxide (ITO) thin film (10 Ω/sq) on a glass substrate for an organic light-emitting diode (OLED) device (Geomatec, Japan) was subjected to an ultrasonic washing with acetone and isopropanol, sequentially, and was then stored in isopropanol. Next, the ITO substrate was mounted on a substrate holder of a vacuum vapor depositing apparatus. Compound HI-1 was introduced into a cell of said vacuum vapor depositing apparatus, and then the pressure in the chamber of said apparatus was controlled to 10⁻⁶ torr. Thereafter, an electric current was applied to the cell to evaporate the above-introduced material, thereby forming a first hole injection layer having a thickness of 90 nm on the ITO substrate. Compound HI-2 was then introduced into another cell of said vacuum vapor depositing apparatus, and was evaporated by applying an electric current to the cell, thereby forming a second hole injection layer having a thickness of 5 nm on the first hole injection layer. Compound HT-1 was introduced into another cell of said vacuum vapor depositing apparatus, and was evaporated by applying an electric current to the cell, thereby forming a first hole transport layer having a thickness of 10 nm on the second hole injection layer. The second hole transport material of Table 1 below was introduced into another cell of said vacuum vapor depositing apparatus, and was evaporated by applying an electric current to the cell, thereby forming a second hole transport layer having a thickness of 60 nm on the first hole transport layer. After forming the hole injection layers and the hole transport zone, a light-emitting layer was then deposited as follows. Compound H-139 as below was introduced into one cell of the vacuum vapor depositing apparatus as a host of the light-emitting layer, and compound D-39 was introduced into another cell as a dopant. The two materials were evaporated at different rates and were deposited in a doping amount of 2 wt % (the amount of dopant) based on the total amount of the host and dopant to form a light-emitting layer having a thickness of 40 nm on the second hole transport layer. Compound ET-1 and compound EI-1 were then introduced into another two cells, evaporated at the rate of 1:1, and deposited to form an electron transport layer having a thickness of 35 nm on the light-emitting layer. Next, after depositing compound EI-1 as an electron injection layer having a thickness of 2 nm on the electron transport layer, an Al cathode having a thickness of 80 nm was deposited by another vacuum vapor deposition apparatus on the electron injection layer. Thus, an OLED device was produced.

As a result, the driving voltage, luminous efficiency, and CIE color coordinates based on a luminance of 1,000 nits, and the lifespan (measured as the luminance dropped from 100% after 16.7 hours at 5,000 nits and a constant current) of the OLEDs are shown in Table 1 below.

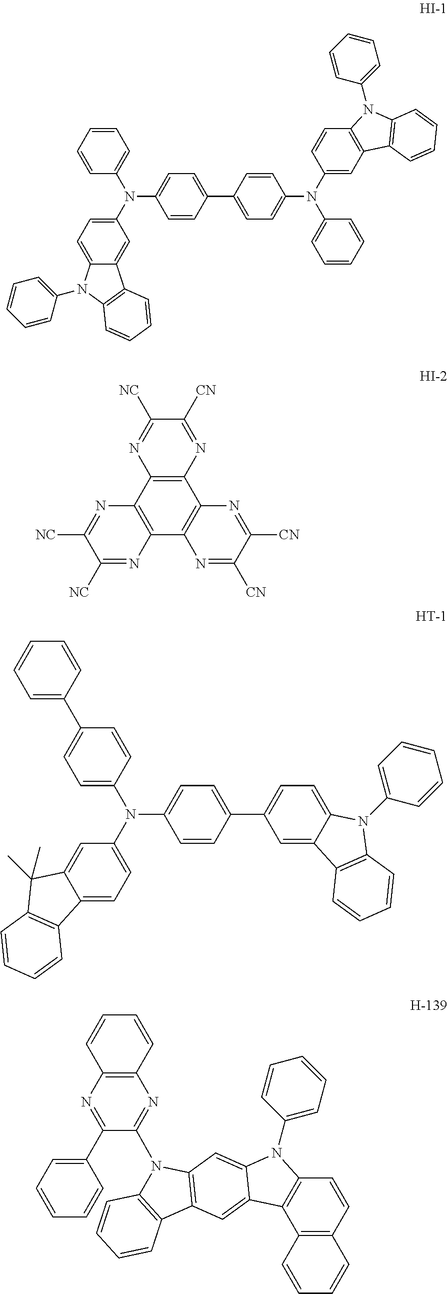 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; N#Cc1nc2c3nc(C#N)c(C#N)nc3c3nc(C#N)c(C#N)nc3c2nc1C#N ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2nc3ccccc3nc2-n2c3ccccc3c3cc4c5c6ccccc6ccc5n(-c5ccccc5)c4cc32)cc1]

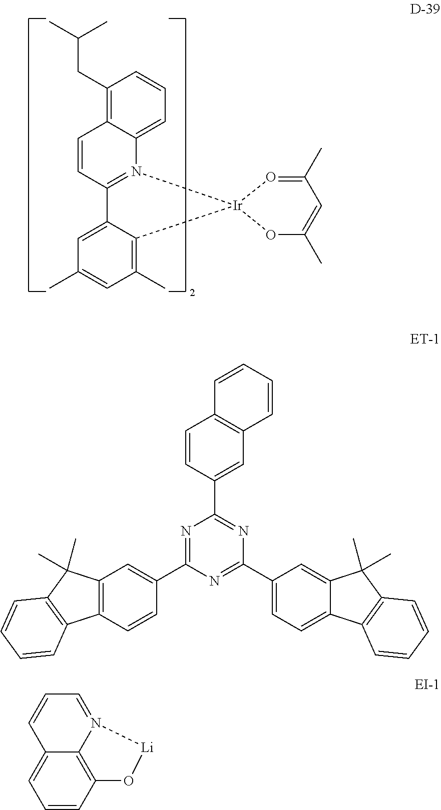

### Comparative Example 1: Production of an OLED Device not According to the Present Disclosure

An OLED device was produced in the same manner as in Device Example 1, except for using another material for the second hole transport material, and the evaluation result of the device is shown in Table 1 below.

TABLE 1

| | Second hole | | Driving voltage | Efficiency | | | |
|---|---|---|---|---|---|---|---|
| | transport | | (V) | (cd/A) | | | Lifespan |
| | layer | Host | (@ 1000 nits) | (@ 1000 nits) | CIE (x, y) | | (%) |
| Device | HT2-1 | H-139 | 3.0 | 25.1 | 0.667 | 0.333 | 99.4 |
| Example 1 | | | | | | | |
| Device | HT2-2 | | 3.6 | 25.4 | 0.667 | 0.333 | 98.9 |
| Example 2 | | | | | | | |
| Device | HT2-3 | | 3.0 | 26.2 | 0.666 | 0.334 | 99.5 |
| Example 3 | | | | | | | |
| Device | HT2-4 | | 3.2 | 23.9 | 0.667 | 0.333 | 99.2 |
| Example 4 | | | | | | | |
| Comparative | R-1 | | 3.2 | 20.1 | 0.660 | 0.340 | 98.3 |
| Example 1 | | | | | | | |

In Table 2 below, the HOMO energy values of the compounds comprised in the second hole transport layer used in Examples 1 to 4 and Comparative Example 1 were compared.

TABLE 2

| | | HOMO |
|---|---|---|
| | | energy |
| | Second hole transport layer | value (eV) |
| Device Example 1 | 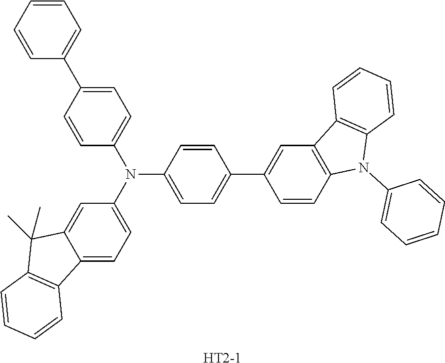 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; "HT2-1"] | −4.688 |
| Device Example 2 | 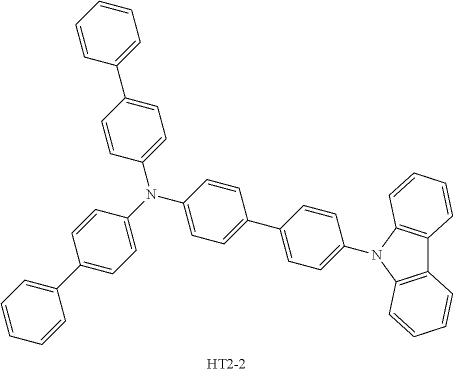 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; "HT2-2"] | −4.942 |
| Device Example 3 | 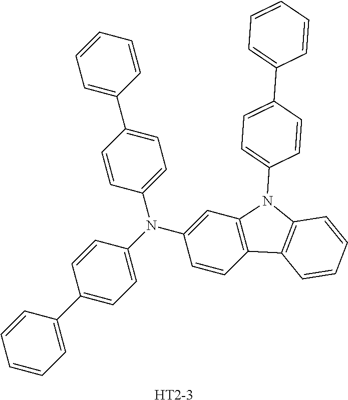 [SMILES: c1ccc(-c2ccc(N(c3ccc(-c4ccccc4)cc3)c3ccc4c5ccccc5n(-c5ccc(-c6ccccc6)cc5)c4c3)cc2)cc1 ; "HT2-3"] | −4.767 |
| Device Example 4 | 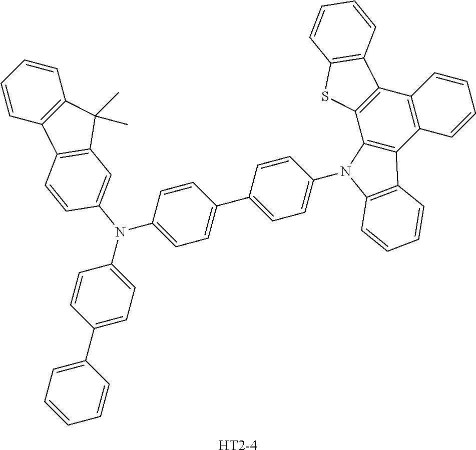 [SMILES: CC1(C)c2ccccc2-c2ccc(N(c3ccc(-c4ccccc4)cc3)c3ccc(-c4ccc(-n5c6ccccc6c6c7ccccc7c7c8ccccc8sc7c65)cc4)cc3)cc21 ; "HT2-4"] | −4.930 |
| Comparative Example 1 | 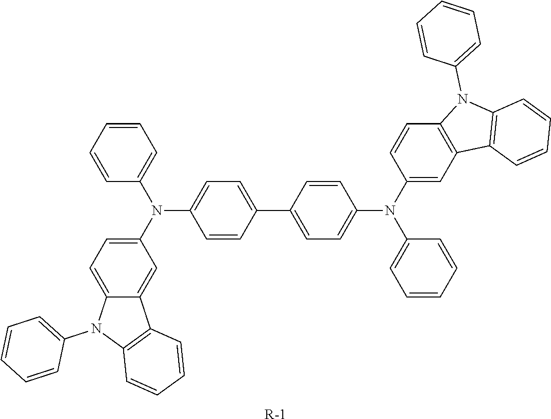 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; "R-1"] | −4.469 |

As shown in Table 2 above, the compounds used in the second hole transport layer of Examples 1 to 4 have lower HOMO energy values than the compound used in the second hole transport layer of Comparative Example 1. This contributes to an increase of the hole transport ability between the second hole transport layer and the light-emitting layer. As a result, it is understood that the second hole transport layers of the organic electroluminescent devices of Examples 1 to 4 have HOMO energy values of −4.6 to −5.0 eV to show superior efficiency characteristic at the condition of equivalent or longer lifespan and equivalent or lower driving voltage compared to Comparative Example 1 (but not limited by the theory).

1. An organic electroluminescent device comprising a first electrode; a second electrode facing the first electrode; a light-emitting layer between the first electrode and the second electrode; and a hole transport zone between the first electrode and the light-emitting layer, wherein the light-emitting layer comprises a compound represented by the following formula 1: 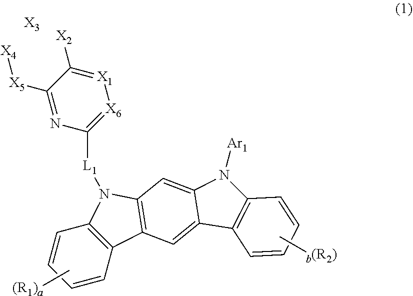
wherein
L₁ represents a single bond, a substituted or unsubstituted (C6-C30)arylene, or a substituted or unsubstituted (5- to 30-membered)heteroarylene;
X₁ to X₆ each independently represent N or CR₃, with a proviso that at least one of X₁ to X₆ represent N;
Ar₁ represents a substituted or unsubstituted (C6-C30)aryl, or a substituted or unsubstituted (5- to 30-membered)heteroaryl;
R₁ to R₃ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₁₁R₁₂, —SiR₁₃R₁₄R₁₅, —SR₁₆, —OR₁₇, a cyano, a nitro, or a hydroxyl, with a proviso that in at least one group of the adjacent two R₁'s and the adjacent two R₂'s groups, the adjacent two R₁'s or the adjacent two R₂'s each independently are linked to each other to form at least one substituted or unsubstituted benzene ring;
R₁₁ to R₁₇ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent(s) to form a substituted or unsubstituted, mono- or polycyclic, (3- to 30-membered) alicyclic or aromatic ring, or the combination thereof, whose carbon atom(s) may be replaced with at least one heteroatom selected from nitrogen, oxygen, and sulfur;
a and b each independently represent an integer of 1 to 4, where if a and b each independently are an integer of 2 or more, each of R₁ and R₂ may be the same or different;
the heteroaryl(ene) contains at least one heteroatom selected from B, N, O, S, Si, and P; and
the heterocycloalkyl contains at least one heteroatom selected from O, S, and N, and
the hole transport zone comprises an arylamine derivative comprising one carbazole or fused carbazole, and the HOMO energy value of the arylamine derivative comprising one carbazole or fused carbazole satisfies the following equation 11:
−5.0 eV≤HOMO≤−4.6 eV (11)

2. The organic electroluminescent device according to claim 1, wherein formula 1 is represented by any one of the following formulas 2 to 7: 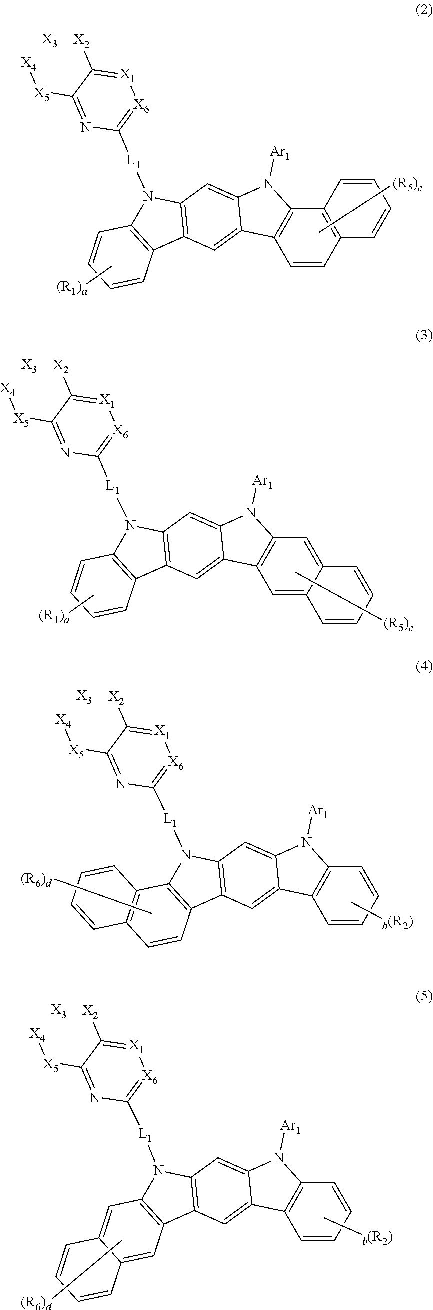 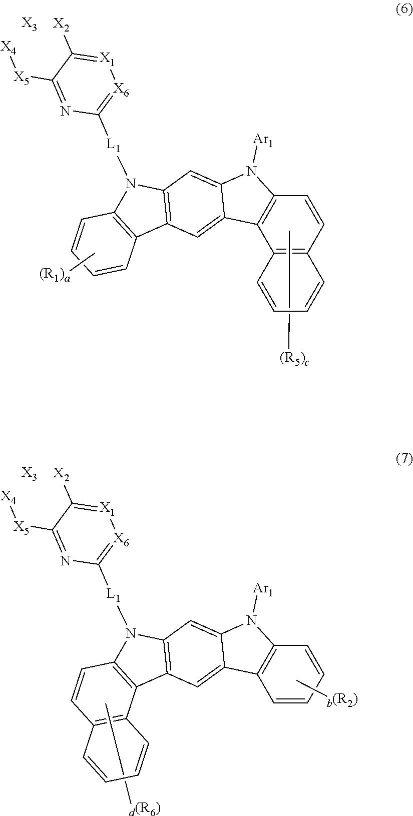
wherein
L₁, Ar₁, R₁, R₂, X₁ to X₆, a, and b are as defined in claim 1,
R₅ and R₆ are each independently identical to the definition of R₁, and
c and d each independently represent an integer of 1 to 6, where if c and d each independently are an integer of 2 or more, each of R₅ and R₆ may be the same or different.

3. The organic electroluminescent device according to claim 1, wherein 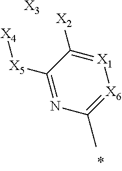
of formula 1 represents a substituted or unsubstituted quinoxalinyl, a substituted or unsubstituted quinazolinyl, a substituted or unsubstituted naphthyridinyl, a substituted or unsubstituted pyridopyrimidinyl, or a substituted or unsubstituted pyridopyrazinyl, in which * represents a bonding site with L₁.

4. The organic electroluminescent device according to claim 1, wherein the arylamine derivative comprising one carbazole or fused carbazole comprises at least one compound represented by the following formula 11 or 12: 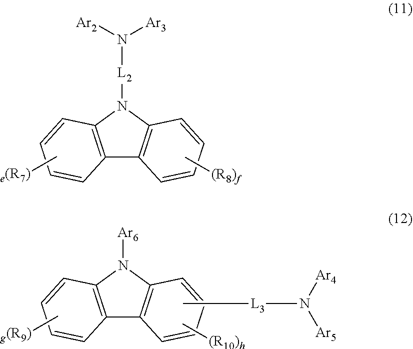
wherein
Ar₂ to Ar₆ each independently represent a substituted or unsubstituted (C6-C30)aryl, or a substituted or unsubstituted (5- to 30-membered)heteroaryl;
L₂ and L₃ each independently represent a single bond, or a substituted or unsubstituted (C6-C30)arylene;
R₇ to R₁₀ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₁₁R₁₂, —SiR₁₃R₁₄R₁₅, —SR₁₆, —OR₁₇, a cyano, a nitro, or a hydroxyl; or may be linked to an adjacent substituent(s) to form a substituted or unsubstituted, mono- or polycyclic, (3- to 30-membered) alicyclic or aromatic ring, or the combination thereof, whose carbon atom(s) may be replaced with at least one heteroatom selected from nitrogen, oxygen, and sulfur;
R₁₁ to R₁₇ each independently represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent(s) to form a substituted or unsubstituted, mono- or polycyclic, (3- to 30-membered) alicyclic or aromatic ring, or the combination thereof, whose carbon atom(s) may be replaced with at least one heteroatom selected from nitrogen, oxygen, and sulfur;
e to g each independently represent an integer of 1 to 4, h represents an integer of 1 to 3, where if e to h each independently are an integer of 2 or more, each of R₇ to R₁₀ may be the same or different; and
the heteroaryl contains at least one heteroatom selected from B, N, O, S, Si, and P.

5. The organic electroluminescent device according to claim 1 comprising a first hole transport layer between the first electrode and the light-emitting layer, and a second hole transport layer between the first hole transport layer and the light-emitting layer, wherein the second hole transport layer comprises an arylamine derivative comprising one carbazole or fused carbazole, and the HOMO energy value of the arylamine derivative comprising one carbazole or fused carbazole satisfies equation 11.

6. The organic electroluminescent device according to claim 1, wherein the HOMO energy value of the arylamine derivative comprising one carbazole or fused carbazole satisfies the following equation 12:
−5.0 eV≤HOMO≤−4.65 eV (12).

7. The organic electroluminescent device according to claim 1, wherein the compound represented by formula 1 is selected from the group consisting of:

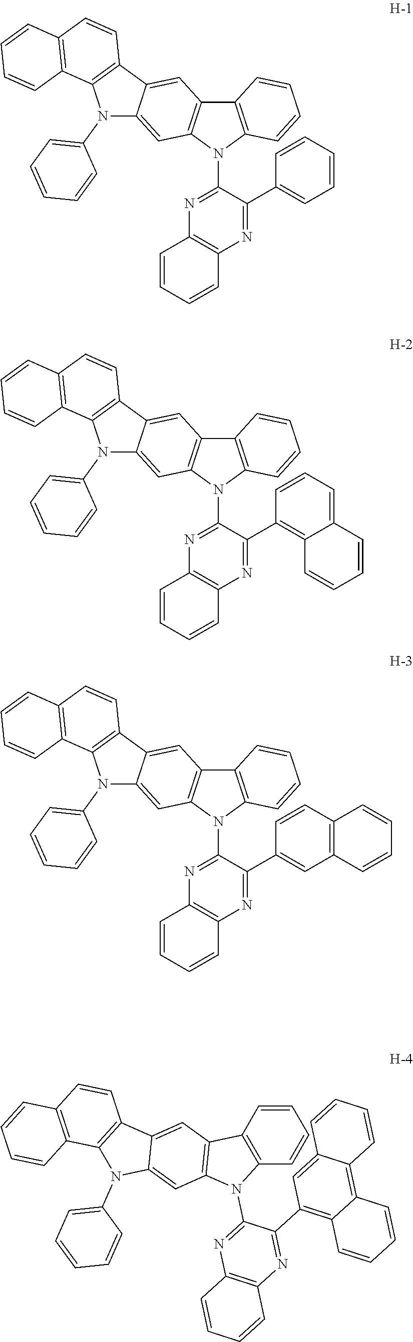 [SMILES: c1ccc(-c2nc3ccccc3nc2-n2c3ccccc3c3cc4c5ccc6ccccc6c5n(-c5ccccc5)c4cc32)cc1 ; c1ccc(-n2c3cc4c(cc3c3ccc5ccccc5c32)c2ccccc2n4-c2nc3ccccc3nc2-c2cccc3ccccc23)cc1 ; c1ccc(-n2c3cc4c(cc3c3ccc5ccccc5c32)c2ccccc2n4-c2nc3ccccc3nc2-c2ccc3ccccc3c2)cc1 ; c1ccc(-n2c3cc4c(cc3c3ccc5ccccc5c32)c2ccccc2n4-c2nc3ccccc3nc2-c2cc3ccccc3c3ccccc23)cc1]

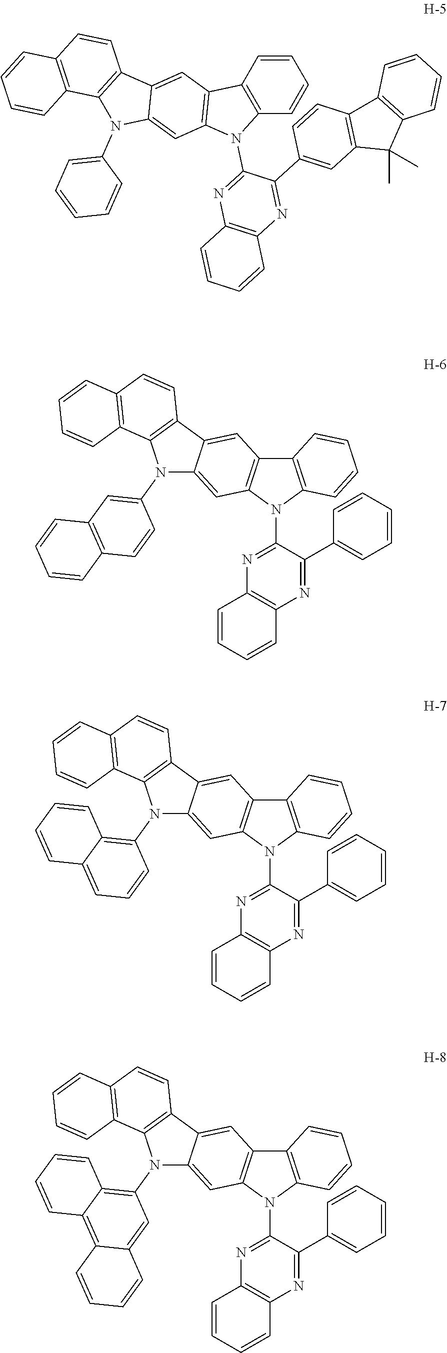 [SMILES: CC1(C)c2ccccc2-c2ccc(-c3nc4ccccc4nc3-n3c4ccccc4c4cc5c6ccc7ccccc7c6n(-c6ccccc6)c5cc43)cc21 ; c1ccc(-c2nc3ccccc3nc2-n2c3ccccc3c3cc4c5ccc6ccccc6c5n(-c5ccc6ccccc6c5)c4cc32)cc1 ; c1ccc(-c2nc3ccccc3nc2-n2c3ccccc3c3cc4c5ccc6ccccc6c5n(-c5cccc6ccccc56)c4cc32)cc1 ; c1ccc(-c2nc3ccccc3nc2-n2c3ccccc3c3cc4c5ccc6ccccc6c5n(-c5cc6ccccc6c6ccccc56)c4cc32)cc1]

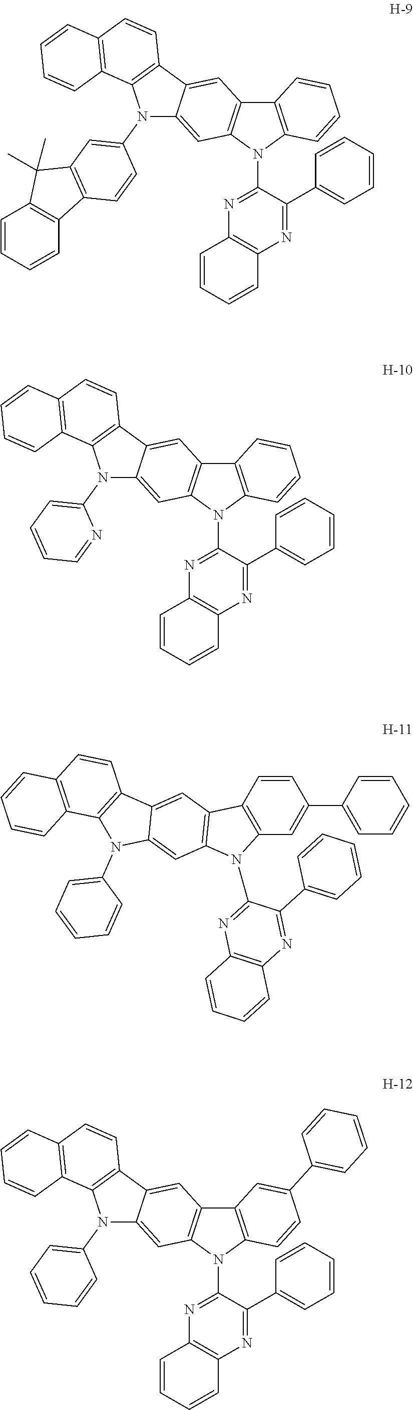 [SMILES: CC1(C)c2ccccc2-c2ccc(-n3c4cc5c(cc4c4ccc6ccccc6c43)c3ccccc3n5-c3nc4ccccc4nc3-c3ccccc3)cc21 ; c1ccc(-c2nc3ccccc3nc2-n2c3ccccc3c3cc4c5ccc6ccccc6c5n(-c5ccccn5)c4cc32)cc1 ; c1ccc(-c2ccc3c4cc5c6ccc7ccccc7c6n(-c6ccccc6)c5cc4n(-c4nc5ccccc5nc4-c4ccccc4)c3c2)cc1 ; c1ccc(-c2ccc3c(c2)c2cc4c5ccc6ccccc6c5n(-c5ccccc5)c4cc2n3-c2nc3ccccc3nc2-c2ccccc2)cc1]

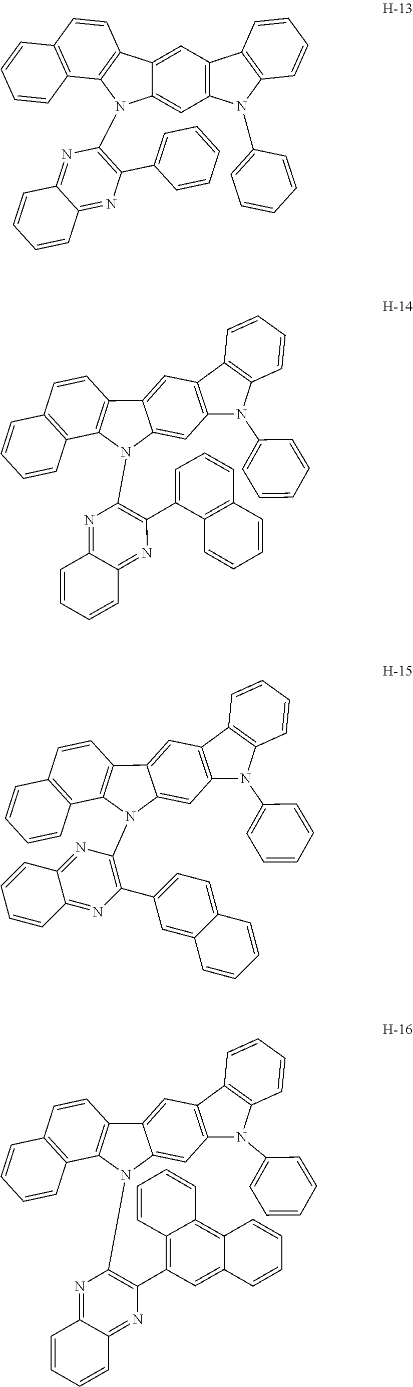 [SMILES: c1ccc(-c2nc3ccccc3nc2-n2c3cc4c(cc3c3ccc5ccccc5c32)c2ccccc2n4-c2ccccc2)cc1 ; c1ccc(-n2c3ccccc3c3cc4c5ccc6ccccc6c5n(-c5nc6ccccc6nc5-c5cccc6ccccc56)c4cc32)cc1 ; c1ccc(-n2c3ccccc3c3cc4c5ccc6ccccc6c5n(-c5nc6ccccc6nc5-c5ccc6ccccc6c5)c4cc32)cc1 ; c1ccc(-n2c3ccccc3c3cc4c5ccc6ccccc6c5n(-c5nc6ccccc6nc5-c5cc6ccccc6c6ccccc56)c4cc32)cc1]

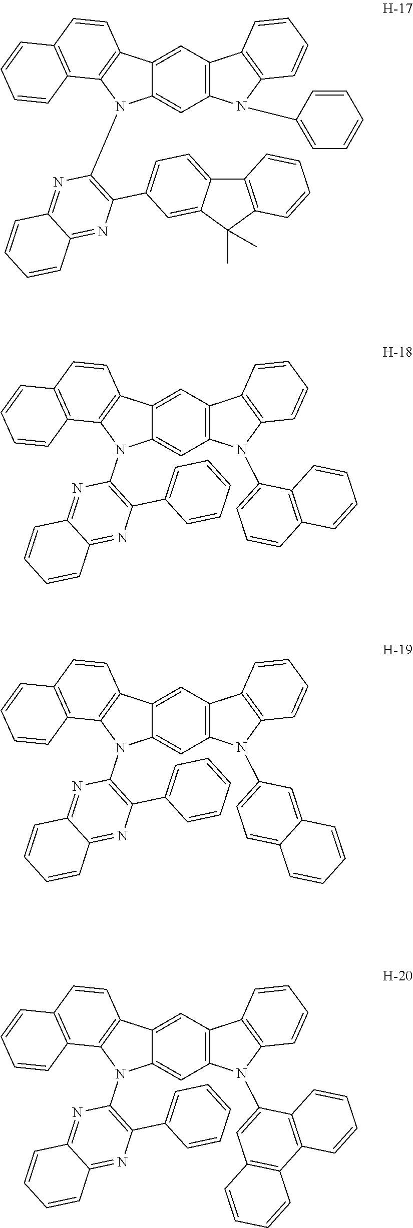 [SMILES: CC1(C)c2ccccc2-c2ccc(-c3nc4ccccc4nc3-n3c4cc5c(cc4c4ccc6ccccc6c43)c3ccccc3n5-c3ccccc3)cc21 ; c1ccc(-c2nc3ccccc3nc2-n2c3cc4c(cc3c3ccc5ccccc5c32)c2ccccc2n4-c2cccc3ccccc23)cc1 ; c1ccc(-c2nc3ccccc3nc2-n2c3cc4c(cc3c3ccc5ccccc5c32)c2ccccc2n4-c2ccc3ccccc3c2)cc1 ; c1ccc(-c2nc3ccccc3nc2-n2c3cc4c(cc3c3ccc5ccccc5c32)c2ccccc2n4-c2cc3ccccc3c3ccccc23)cc1]

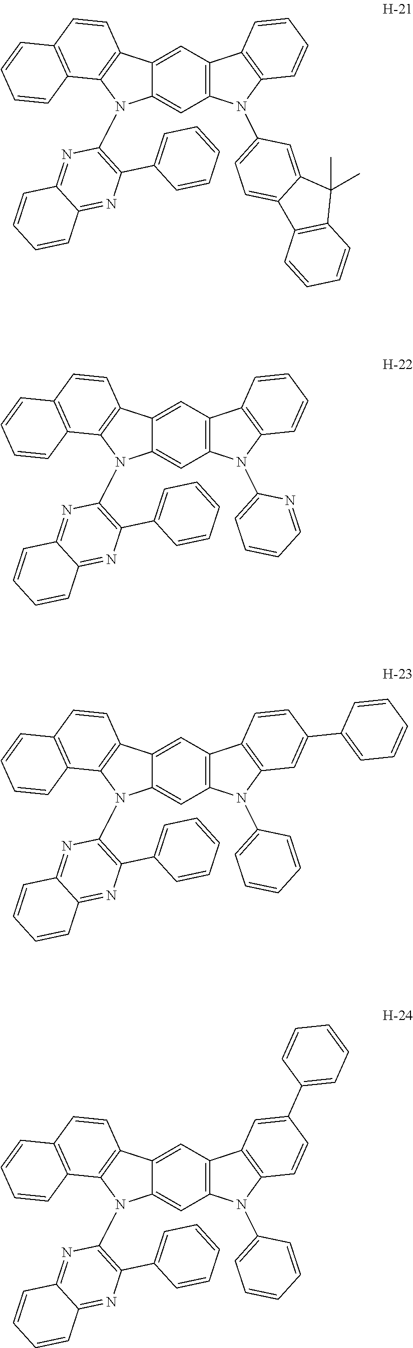 [SMILES: CC1(C)c2ccccc2-c2ccc(-n3c4ccccc4c4cc5c6ccc7ccccc7c6n(-c6nc7ccccc7nc6-c6ccccc6)c5cc43)cc21 ; c1ccc(-c2nc3ccccc3nc2-n2c3cc4c(cc3c3ccc5ccccc5c32)c2ccccc2n4-c2ccccn2)cc1 ; c1ccc(-c2ccc3c4cc5c6ccc7ccccc7c6n(-c6nc7ccccc7nc6-c6ccccc6)c5cc4n(-c4ccccc4)c3c2)cc1 ; c1ccc(-c2ccc3c(c2)c2cc4c5ccc6ccccc6c5n(-c5nc6ccccc6nc5-c5ccccc5)c4cc2n3-c2ccccc2)cc1]

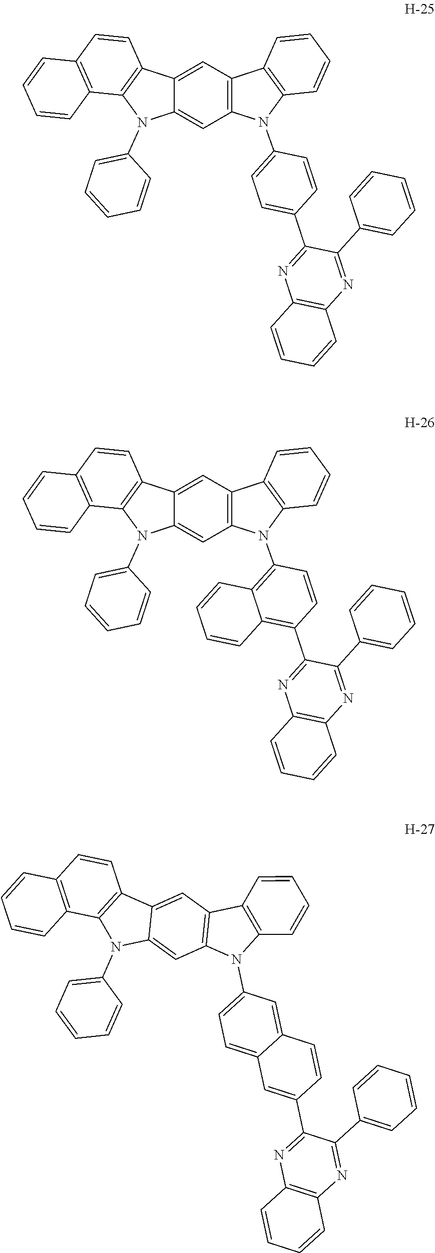 [SMILES: c1ccc(-c2nc3ccccc3nc2-c2ccc(-n3c4ccccc4c4cc5c6ccc7ccccc7c6n(-c6ccccc6)c5cc43)cc2)cc1 ; c1ccc(-c2nc3ccccc3nc2-c2ccc(-n3c4ccccc4c4cc5c6ccc7ccccc7c6n(-c6ccccc6)c5cc43)c3ccccc23)cc1 ; c1ccc(-c2nc3ccccc3nc2-c2ccc3cc(-n4c5ccccc5c5cc6c7ccc8ccccc8c7n(-c7ccccc7)c6cc54)ccc3c2)cc1]

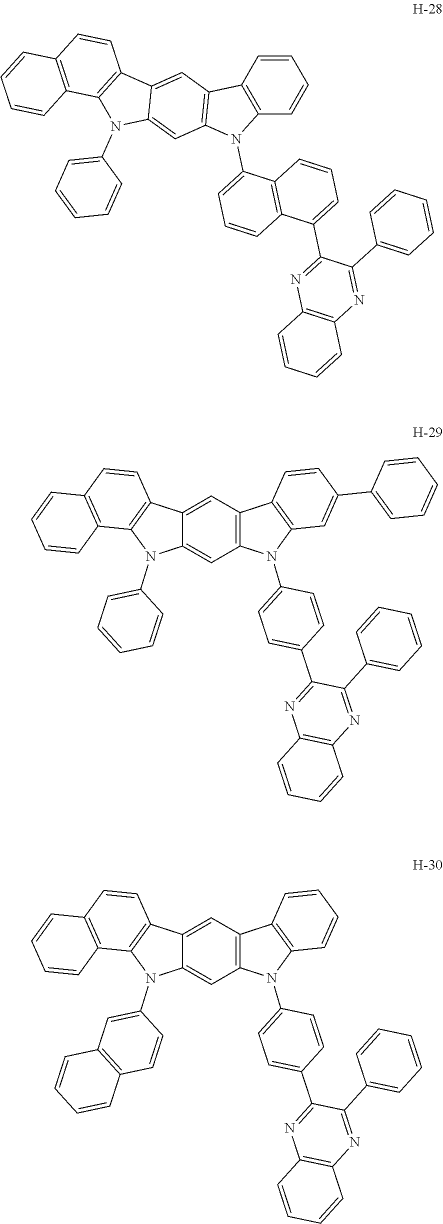 [SMILES: c1ccc(-c2nc3ccccc3nc2-c2cccc3c(-n4c5ccccc5c5cc6c7ccc8ccccc8c7n(-c7ccccc7)c6cc54)cccc23)cc1 ; c1ccc(-c2ccc3c4cc5c6ccc7ccccc7c6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6ccc7ccccc7c6n(-c6ccc7ccccc7c6)c5cc43)cc2)cc1]

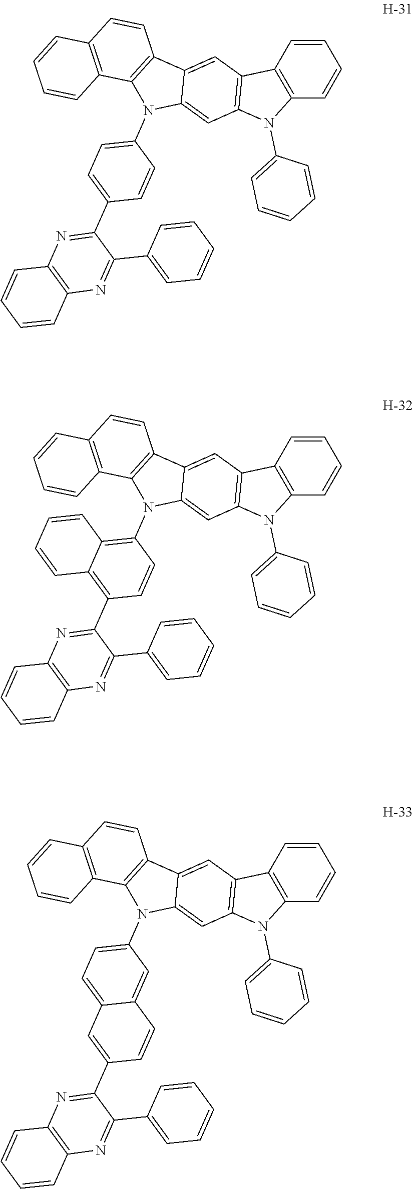 [SMILES: c1ccc(-c2nc3ccccc3nc2-c2ccc(-n3c4cc5c(cc4c4ccc6ccccc6c43)c3ccccc3n5-c3ccccc3)cc2)cc1 ; c1ccc(-c2nc3ccccc3nc2-c2ccc(-n3c4cc5c(cc4c4ccc6ccccc6c43)c3ccccc3n5-c3ccccc3)c3ccccc23)cc1 ; c1ccc(-c2nc3ccccc3nc2-c2ccc3cc(-n4c5cc6c(cc5c5ccc7ccccc7c54)c4ccccc4n6-c4ccccc4)ccc3c2)cc1]

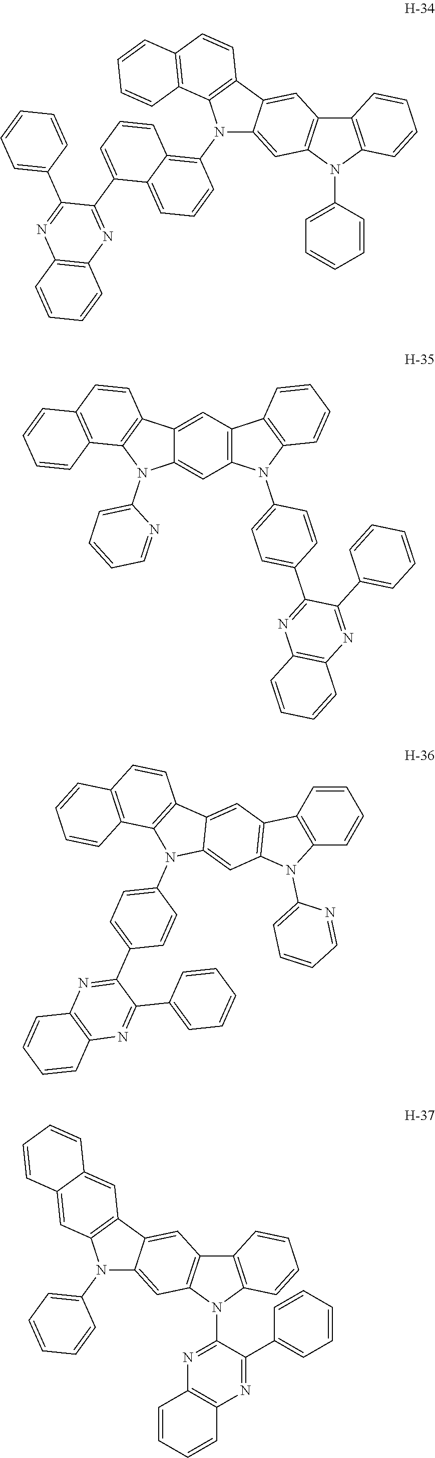 [SMILES: c1ccc(-c2nc3ccccc3nc2-c2cccc3c(-n4c5cc6c(cc5c5ccc7ccccc7c54)c4ccccc4n6-c4ccccc4)cccc23)cc1 ; c1ccc(-c2nc3ccccc3nc2-c2ccc(-n3c4ccccc4c4cc5c6ccc7ccccc7c6n(-c6ccccn6)c5cc43)cc2)cc1 ; c1ccc(-c2nc3ccccc3nc2-c2ccc(-n3c4cc5c(cc4c4ccc6ccccc6c43)c3ccccc3n5-c3ccccn3)cc2)cc1 ; c1ccc(-c2nc3ccccc3nc2-n2c3ccccc3c3cc4c5cc6ccccc6cc5n(-c5ccccc5)c4cc32)cc1]

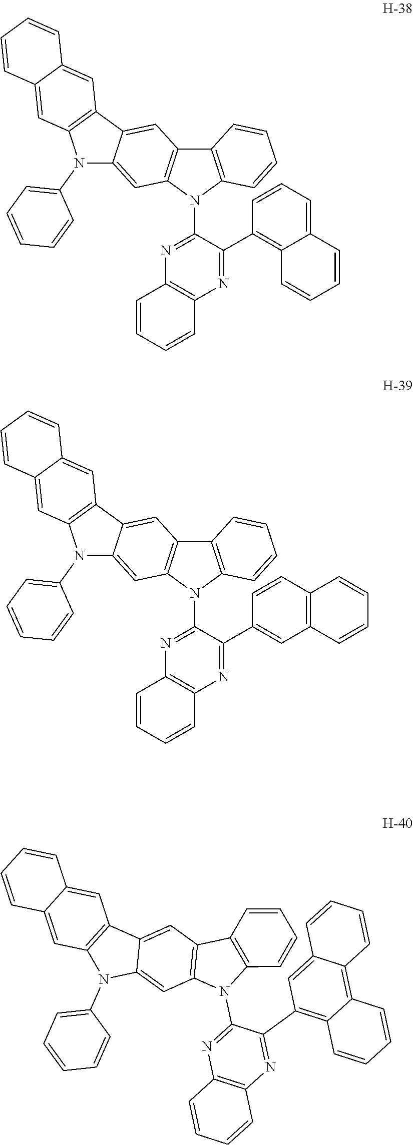 [SMILES: c1ccc(-n2c3cc4ccccc4cc3c3cc4c5ccccc5n(-c5nc6ccccc6nc5-c5cccc6ccccc56)c4cc32)cc1 ; c1ccc(-n2c3cc4ccccc4cc3c3cc4c5ccccc5n(-c5nc6ccccc6nc5-c5ccc6ccccc6c5)c4cc32)cc1 ; c1ccc(-n2c3cc4ccccc4cc3c3cc4c5ccccc5n(-c5nc6ccccc6nc5-c5cc6ccccc6c6ccccc56)c4cc32)cc1]

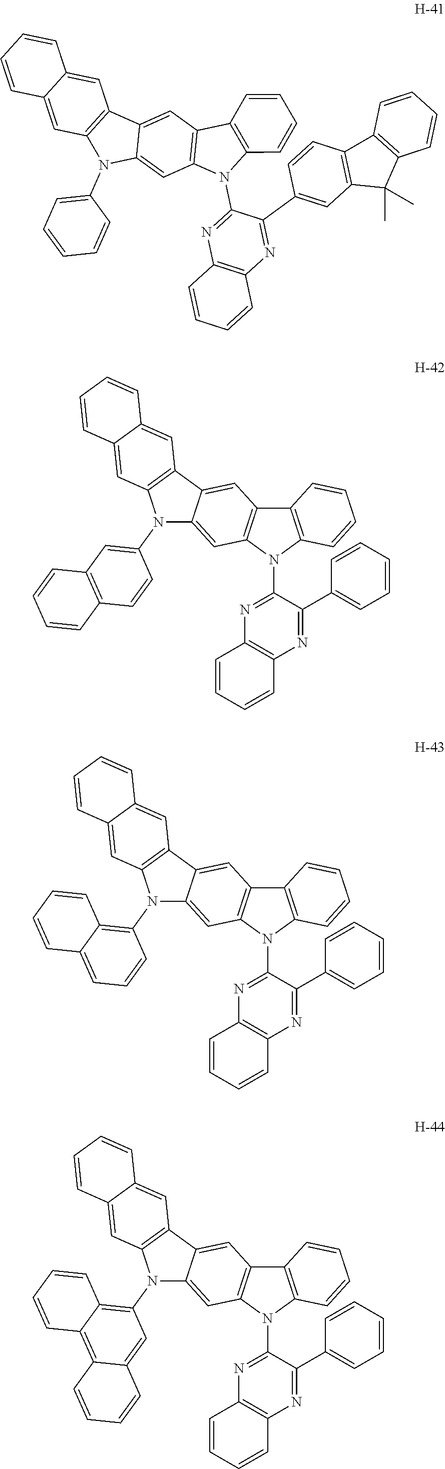 [SMILES: CC1(C)c2ccccc2-c2ccc(-c3nc4ccccc4nc3-n3c4ccccc4c4cc5c6cc7ccccc7cc6n(-c6ccccc6)c5cc43)cc21 ; c1ccc(-c2nc3ccccc3nc2-n2c3ccccc3c3cc4c5cc6ccccc6cc5n(-c5ccc6ccccc6c5)c4cc32)cc1 ; c1ccc(-c2nc3ccccc3nc2-n2c3ccccc3c3cc4c5cc6ccccc6cc5n(-c5cccc6ccccc56)c4cc32)cc1 ; c1ccc(-c2nc3ccccc3nc2-n2c3ccccc3c3cc4c5cc6ccccc6cc5n(-c5cc6ccccc6c6ccccc56)c4cc32)cc1]

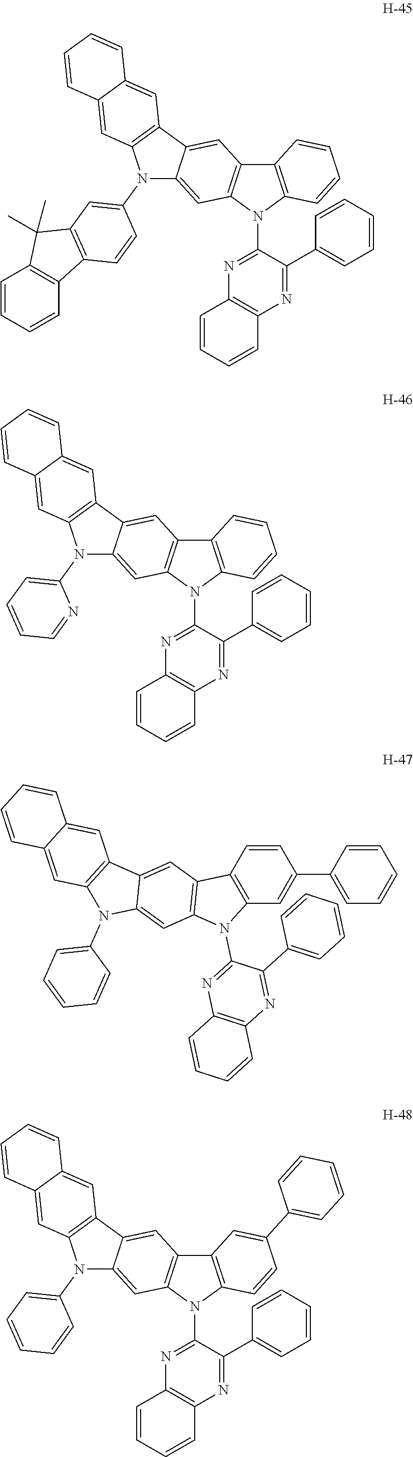 [SMILES: CC1(C)c2ccccc2-c2ccc(-n3c4cc5ccccc5cc4c4cc5c6ccccc6n(-c6nc7ccccc7nc6-c6ccccc6)c5cc43)cc21 ; c1ccc(-c2nc3ccccc3nc2-n2c3ccccc3c3cc4c5cc6ccccc6cc5n(-c5ccccn5)c4cc32)cc1 ; c1ccc(-c2ccc3c4cc5c6cc7ccccc7cc6n(-c6ccccc6)c5cc4n(-c4nc5ccccc5nc4-c4ccccc4)c3c2)cc1 ; c1ccc(-c2ccc3c(c2)c2cc4c5cc6ccccc6cc5n(-c5ccccc5)c4cc2n3-c2nc3ccccc3nc2-c2ccccc2)cc1]

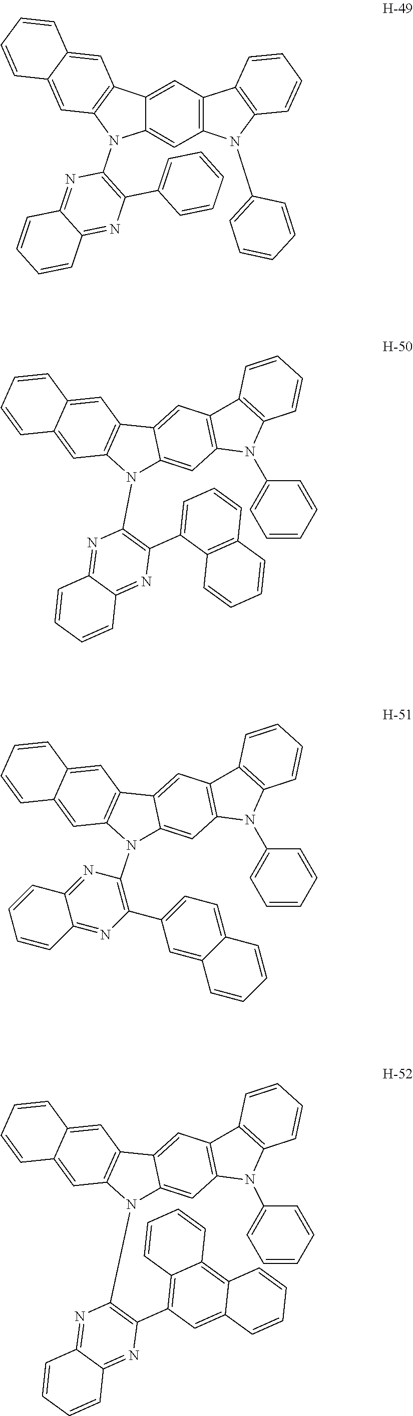 [SMILES: c1ccc(-c2nc3ccccc3nc2-n2c3cc4ccccc4cc3c3cc4c5ccccc5n(-c5ccccc5)c4cc32)cc1 ; c1ccc(-n2c3ccccc3c3cc4c5cc6ccccc6cc5n(-c5nc6ccccc6nc5-c5cccc6ccccc56)c4cc32)cc1 ; c1ccc(-n2c3ccccc3c3cc4c5cc6ccccc6cc5n(-c5nc6ccccc6nc5-c5ccc6ccccc6c5)c4cc32)cc1 ; c1ccc(-n2c3ccccc3c3cc4c5cc6ccccc6cc5n(-c5nc6ccccc6nc5-c5cc6ccccc6c6ccccc56)c4cc32)cc1]

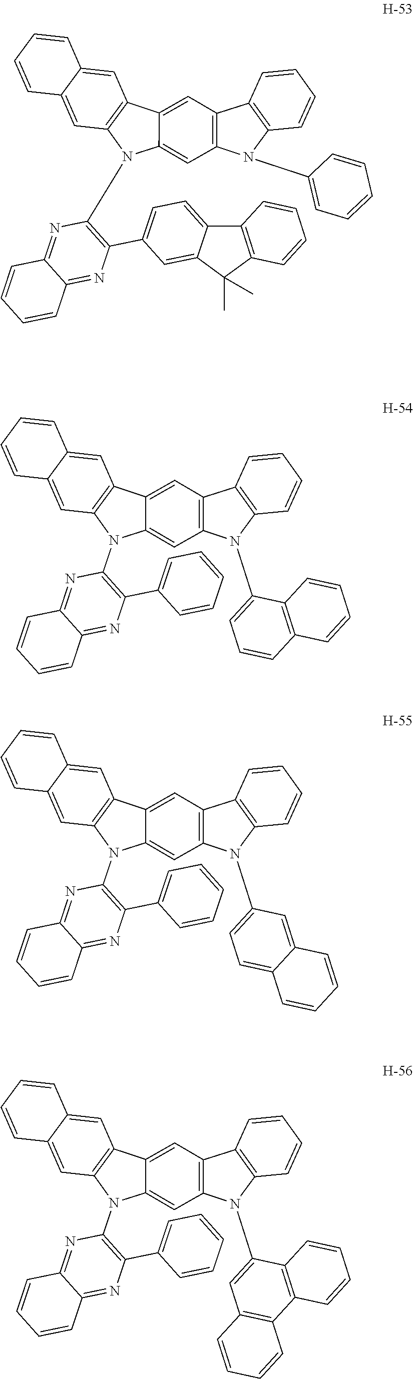 [SMILES: CC1(C)c2ccccc2-c2ccc(-c3nc4ccccc4nc3-n3c4cc5ccccc5cc4c4cc5c6ccccc6n(-c6ccccc6)c5cc43)cc21 ; c1ccc(-c2nc3ccccc3nc2-n2c3cc4ccccc4cc3c3cc4c5ccccc5n(-c5cccc6ccccc56)c4cc32)cc1 ; c1ccc(-c2nc3ccccc3nc2-n2c3cc4ccccc4cc3c3cc4c5ccccc5n(-c5ccc6ccccc6c5)c4cc32)cc1 ; c1ccc(-c2nc3ccccc3nc2-n2c3cc4ccccc4cc3c3cc4c5ccccc5n(-c5cc6ccccc6c6ccccc56)c4cc32)cc1]

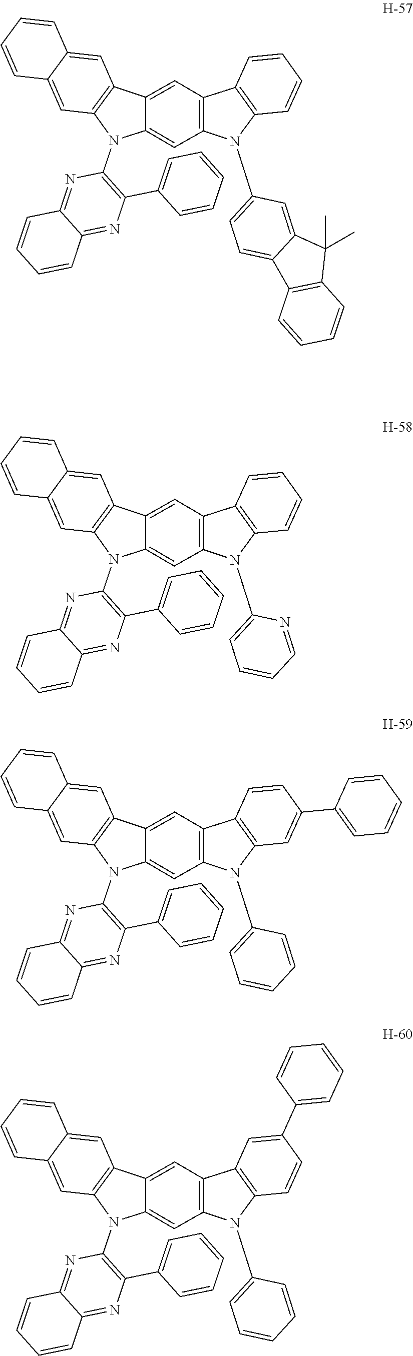 [SMILES: CC1(C)c2ccccc2-c2ccc(-n3c4ccccc4c4cc5c6cc7ccccc7cc6n(-c6nc7ccccc7nc6-c6ccccc6)c5cc43)cc21 ; c1ccc(-c2nc3ccccc3nc2-n2c3cc4ccccc4cc3c3cc4c5ccccc5n(-c5ccccn5)c4cc32)cc1 ; c1ccc(-c2ccc3c4cc5c6cc7ccccc7cc6n(-c6nc7ccccc7nc6-c6ccccc6)c5cc4n(-c4ccccc4)c3c2)cc1 ; c1ccc(-c2ccc3c(c2)c2cc4c5cc6ccccc6cc5n(-c5nc6ccccc6nc5-c5ccccc5)c4cc2n3-c2ccccc2)cc1]

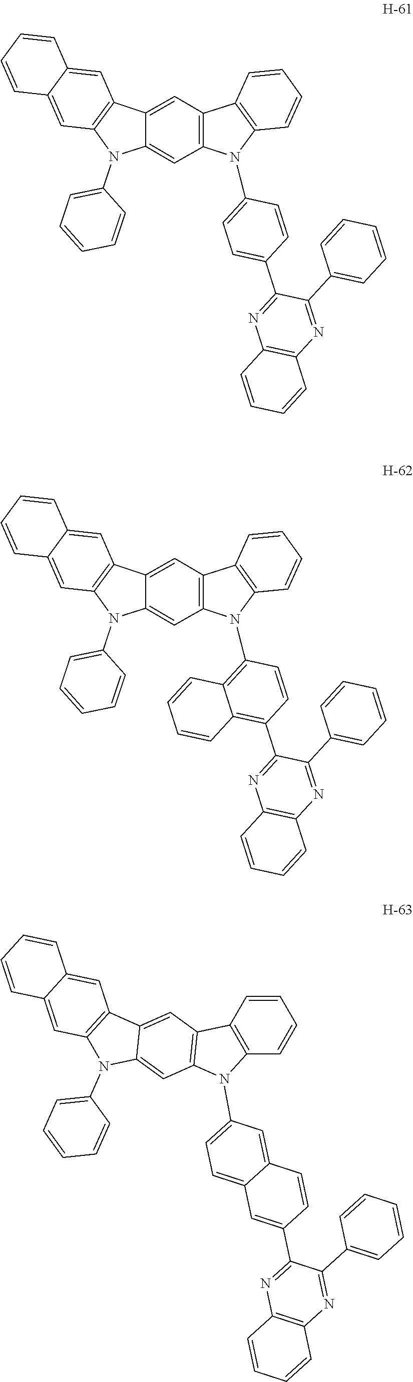 [SMILES: c1ccc(-c2nc3ccccc3nc2-c2ccc(-n3c4ccccc4c4cc5c6cc7ccccc7cc6n(-c6ccccc6)c5cc43)cc2)cc1 ; c1ccc(-c2nc3ccccc3nc2-c2ccc(-n3c4ccccc4c4cc5c6cc7ccccc7cc6n(-c6ccccc6)c5cc43)c3ccccc23)cc1 ; c1ccc(-c2nc3ccccc3nc2-c2ccc3cc(-n4c5ccccc5c5cc6c7cc8ccccc8cc7n(-c7ccccc7)c6cc54)ccc3c2)cc1]

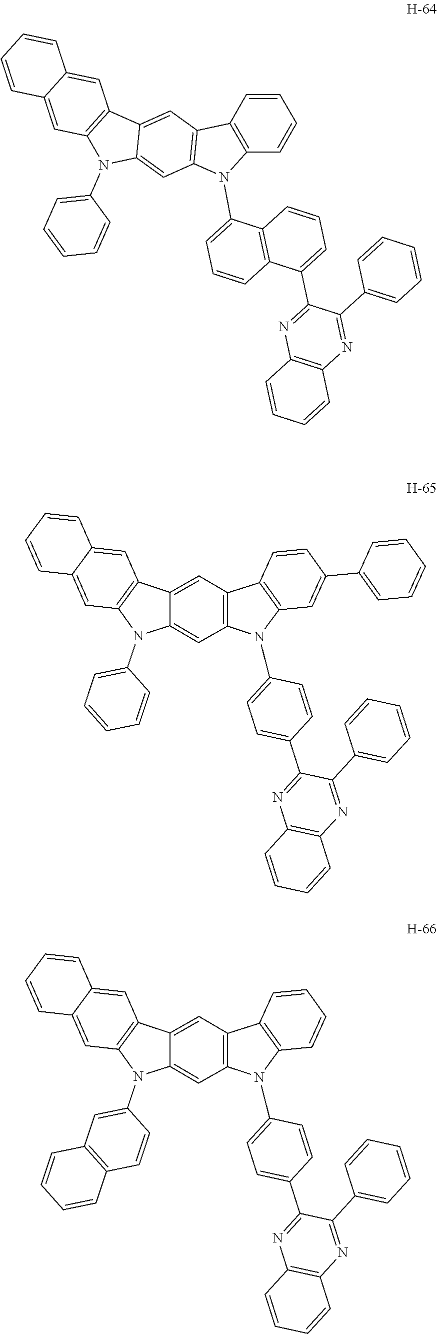 [SMILES: c1ccc(-c2nc3ccccc3nc2-c2cccc3c(-n4c5ccccc5c5cc6c7cc8ccccc8cc7n(-c7ccccc7)c6cc54)cccc23)cc1 ; c1ccc(-c2ccc3c4cc5c6cc7ccccc7cc6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6cc7ccccc7cc6n(-c6ccc7ccccc7c6)c5cc43)cc2)cc1]

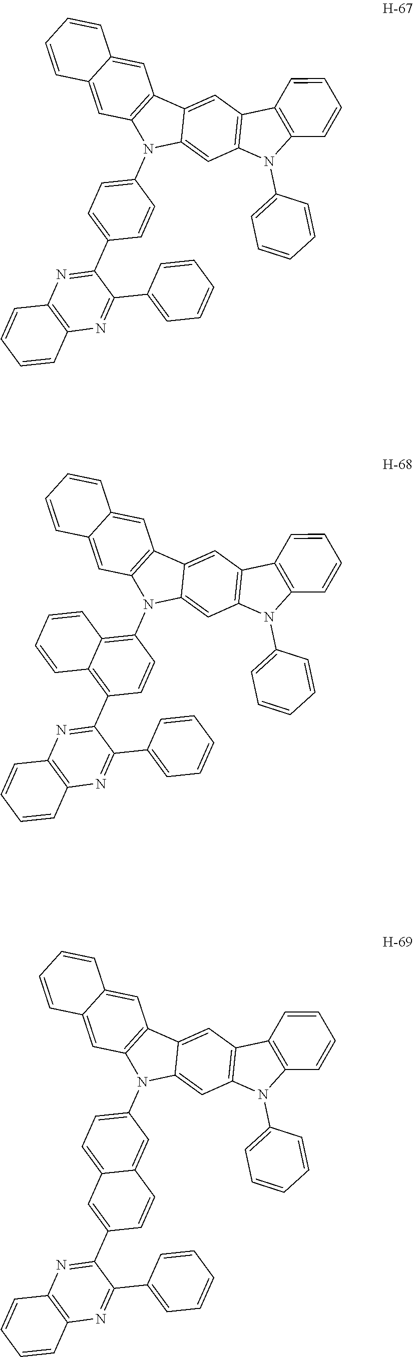 [SMILES: c1ccc(-c2nc3ccccc3nc2-c2ccc(-n3c4cc5ccccc5cc4c4cc5c6ccccc6n(-c6ccccc6)c5cc43)cc2)cc1 ; c1ccc(-c2nc3ccccc3nc2-c2ccc(-n3c4cc5ccccc5cc4c4cc5c6ccccc6n(-c6ccccc6)c5cc43)c3ccccc23)cc1 ; c1ccc(-c2nc3ccccc3nc2-c2ccc3cc(-n4c5cc6ccccc6cc5c5cc6c7ccccc7n(-c7ccccc7)c6cc54)ccc3c2)cc1]

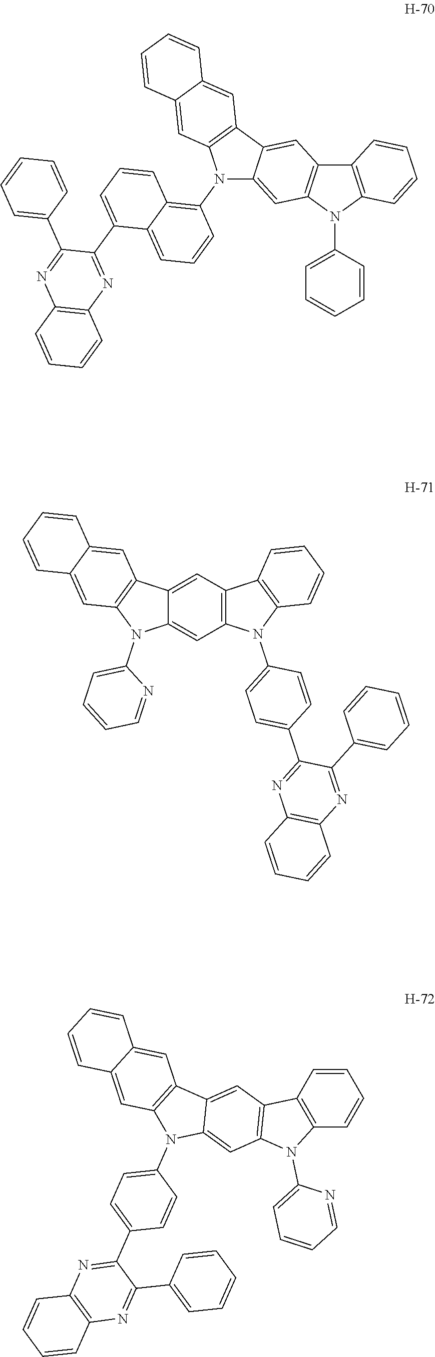 [SMILES: c1ccc(-c2nc3ccccc3nc2-c2cccc3c(-n4c5cc6ccccc6cc5c5cc6c7ccccc7n(-c7ccccc7)c6cc54)cccc23)cc1 ; c1ccc(-c2nc3ccccc3nc2-c2ccc(-n3c4ccccc4c4cc5c6cc7ccccc7cc6n(-c6ccccn6)c5cc43)cc2)cc1 ; c1ccc(-c2nc3ccccc3nc2-c2ccc(-n3c4cc5ccccc5cc4c4cc5c6ccccc6n(-c6ccccn6)c5cc43)cc2)cc1]

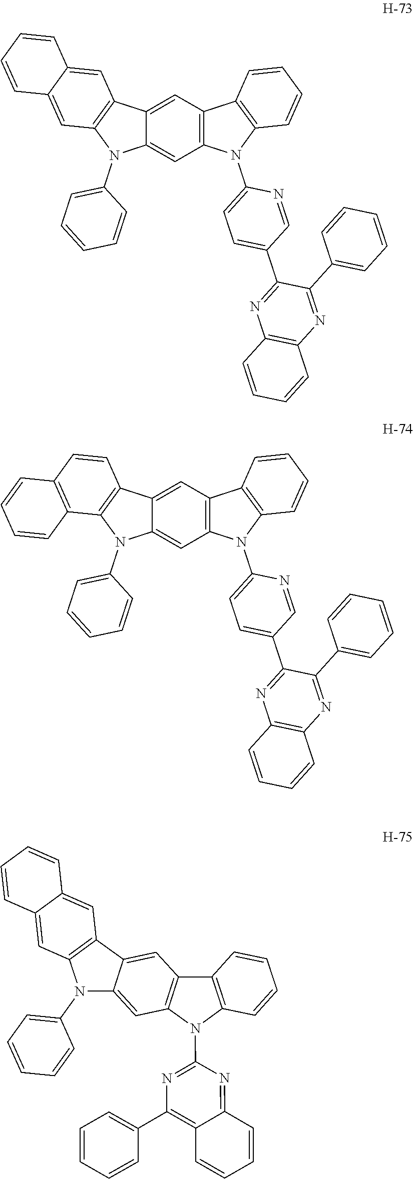 [SMILES: c1ccc(-c2nc3ccccc3nc2-c2ccc(-n3c4ccccc4c4cc5c6cc7ccccc7cc6n(-c6ccccc6)c5cc43)nc2)cc1 ; c1ccc(-c2nc3ccccc3nc2-c2ccc(-n3c4ccccc4c4cc5c6ccc7ccccc7c6n(-c6ccccc6)c5cc43)nc2)cc1 ; c1ccc(-c2nc(-n3c4ccccc4c4cc5c6cc7ccccc7cc6n(-c6ccccc6)c5cc43)nc3ccccc23)cc1]

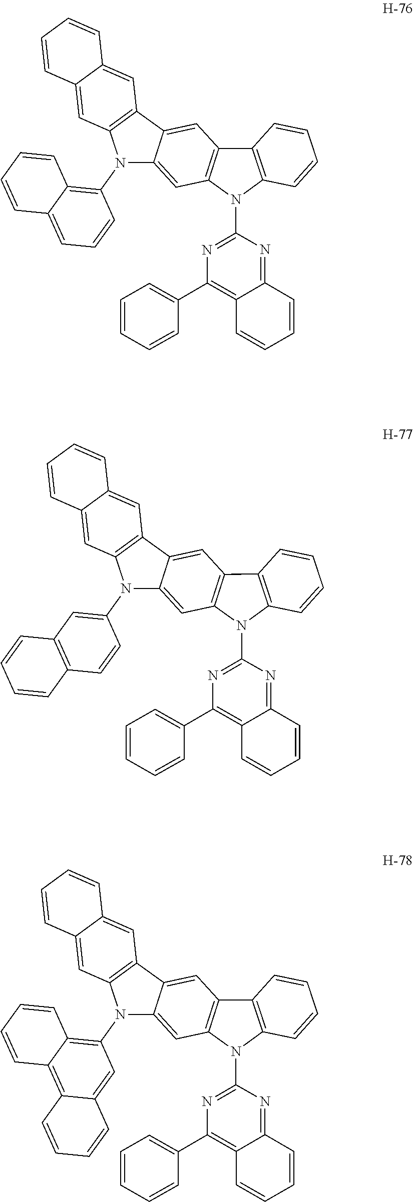 [SMILES: c1ccc(-c2nc(-n3c4ccccc4c4cc5c6cc7ccccc7cc6n(-c6cccc7ccccc67)c5cc43)nc3ccccc23)cc1 ; c1ccc(-c2nc(-n3c4ccccc4c4cc5c6cc7ccccc7cc6n(-c6ccc7ccccc7c6)c5cc43)nc3ccccc23)cc1 ; c1ccc(-c2nc(-n3c4ccccc4c4cc5c6cc7ccccc7cc6n(-c6cc7ccccc7c7ccccc67)c5cc43)nc3ccccc23)cc1]

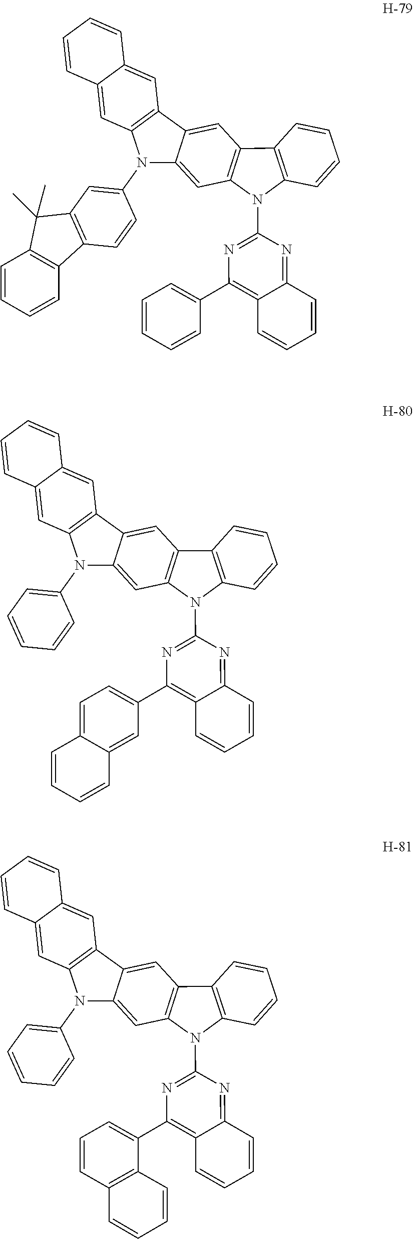 [SMILES: CC1(C)c2ccccc2-c2ccc(-n3c4cc5ccccc5cc4c4cc5c6ccccc6n(-c6nc(-c7ccccc7)c7ccccc7n6)c5cc43)cc21 ; c1ccc(-n2c3cc4ccccc4cc3c3cc4c5ccccc5n(-c5nc(-c6ccc7ccccc7c6)c6ccccc6n5)c4cc32)cc1 ; c1ccc(-n2c3cc4ccccc4cc3c3cc4c5ccccc5n(-c5nc(-c6cccc7ccccc67)c6ccccc6n5)c4cc32)cc1]

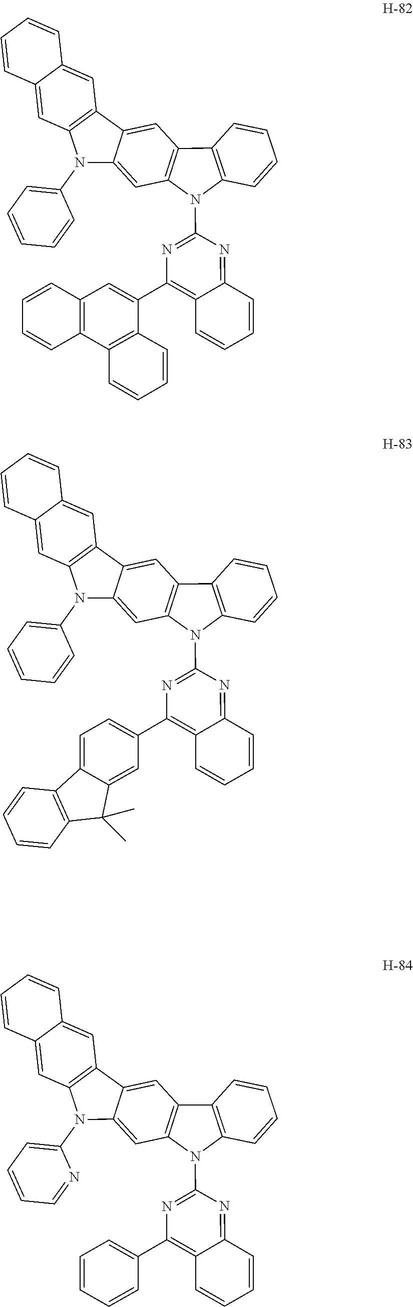 [SMILES: c1ccc(-n2c3cc4ccccc4cc3c3cc4c5ccccc5n(-c5nc(-c6cc7ccccc7c7ccccc67)c6ccccc6n5)c4cc32)cc1 ; CC1(C)c2ccccc2-c2ccc(-c3nc(-n4c5ccccc5c5cc6c7cc8ccccc8cc7n(-c7ccccc7)c6cc54)nc4ccccc34)cc21 ; c1ccc(-c2nc(-n3c4ccccc4c4cc5c6cc7ccccc7cc6n(-c6ccccn6)c5cc43)nc3ccccc23)cc1]

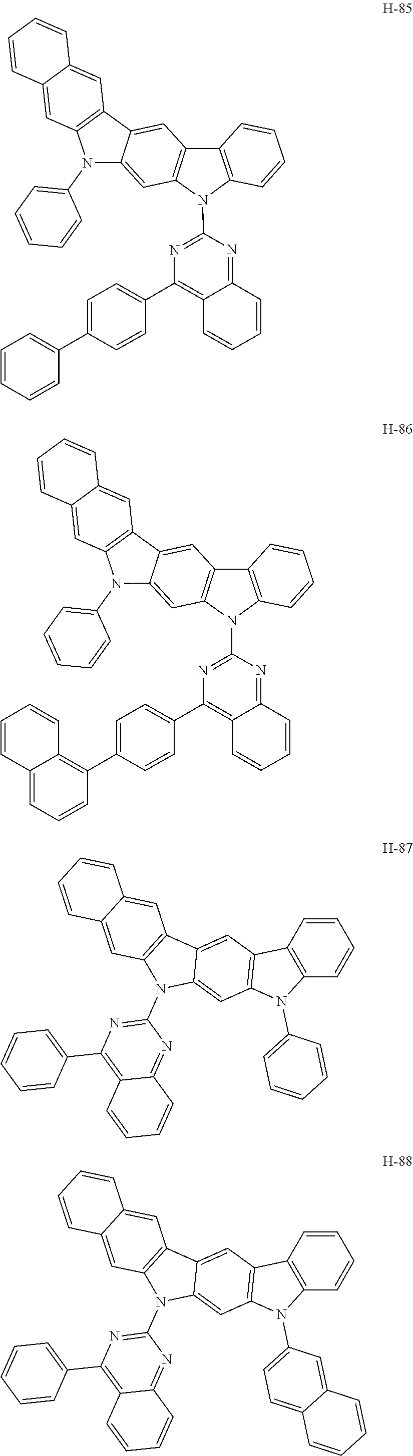

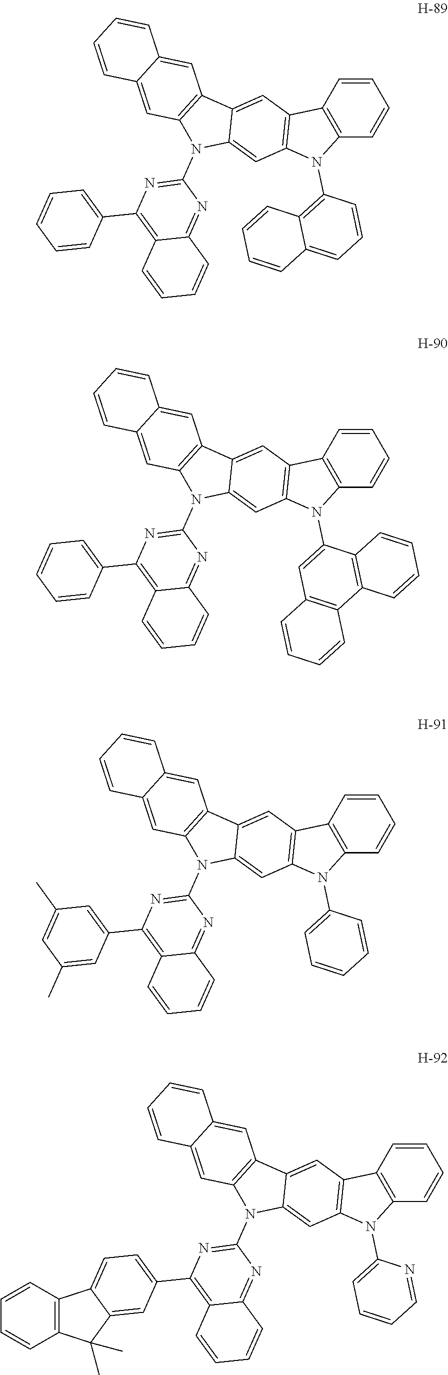 [SMILES: c1ccc(-c2nc(-n3c4cc5ccccc5cc4c4cc5c6ccccc6n(-c6cccc7ccccc67)c5cc43)nc3ccccc23)cc1 ; c1ccc(-c2nc(-n3c4cc5ccccc5cc4c4cc5c6ccccc6n(-c6cc7ccccc7c7ccccc67)c5cc43)nc3ccccc23)cc1 ; Cc1cc(C)cc(-c2nc(-n3c4cc5ccccc5cc4c4cc5c6ccccc6n(-c6ccccc6)c5cc43)nc3ccccc23)c1 ; CC1(C)c2ccccc2-c2ccc(-c3nc(-n4c5cc6ccccc6cc5c5cc6c7ccccc7n(-c7ccccn7)c6cc54)nc4ccccc34)cc21]

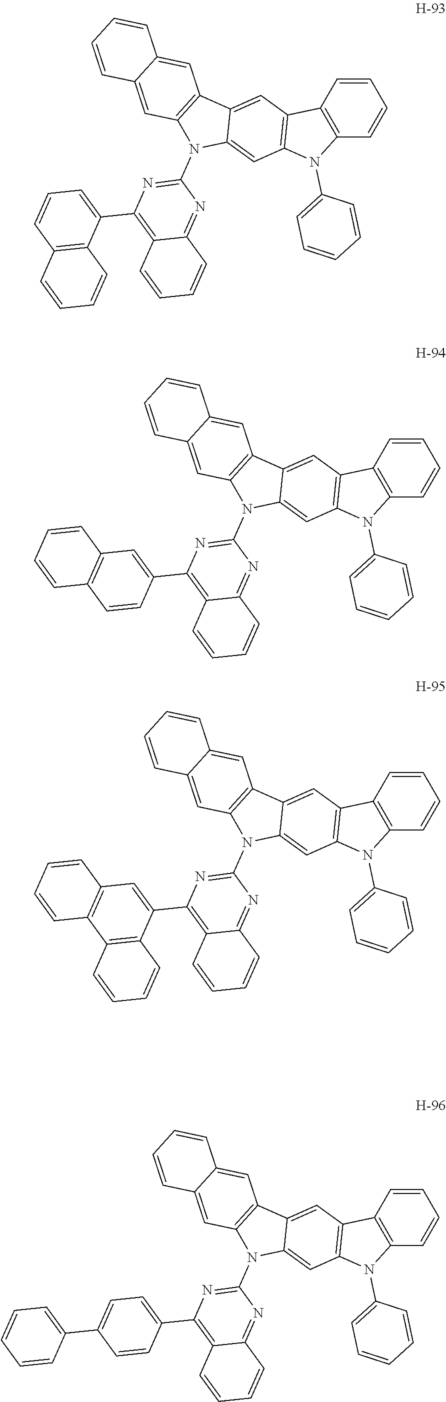 [SMILES: c1ccc(-n2c3ccccc3c3cc4c5cc6ccccc6cc5n(-c5nc(-c6cccc7ccccc67)c6ccccc6n5)c4cc32)cc1 ; c1ccc(-n2c3ccccc3c3cc4c5cc6ccccc6cc5n(-c5nc(-c6ccc7ccccc7c6)c6ccccc6n5)c4cc32)cc1 ; c1ccc(-n2c3ccccc3c3cc4c5cc6ccccc6cc5n(-c5nc(-c6cc7ccccc7c7ccccc67)c6ccccc6n5)c4cc32)cc1 ; c1ccc(-c2ccc(-c3nc(-n4c5cc6ccccc6cc5c5cc6c7ccccc7n(-c7ccccc7)c6cc54)nc4ccccc34)cc2)cc1]

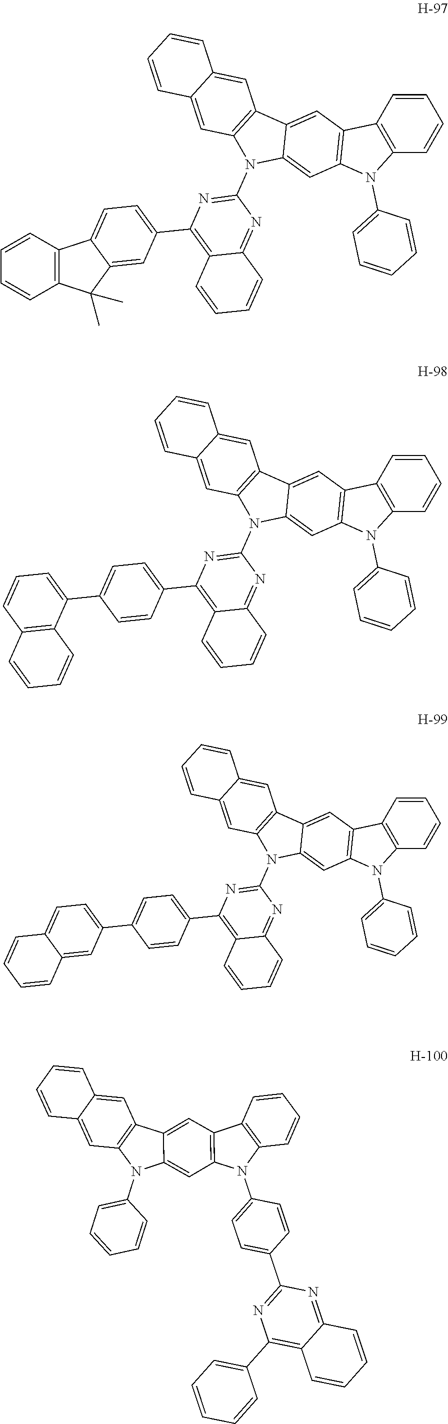 [SMILES: CC1(C)c2ccccc2-c2ccc(-c3nc(-n4c5cc6ccccc6cc5c5cc6c7ccccc7n(-c7ccccc7)c6cc54)nc4ccccc34)cc21 ; c1ccc(-n2c3ccccc3c3cc4c5cc6ccccc6cc5n(-c5nc(-c6ccc(-c7cccc8ccccc78)cc6)c6ccccc6n5)c4cc32)cc1 ; c1ccc(-n2c3ccccc3c3cc4c5cc6ccccc6cc5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7cc8ccccc8cc7n(-c7ccccc7)c6cc54)cc3)nc3ccccc23)cc1]

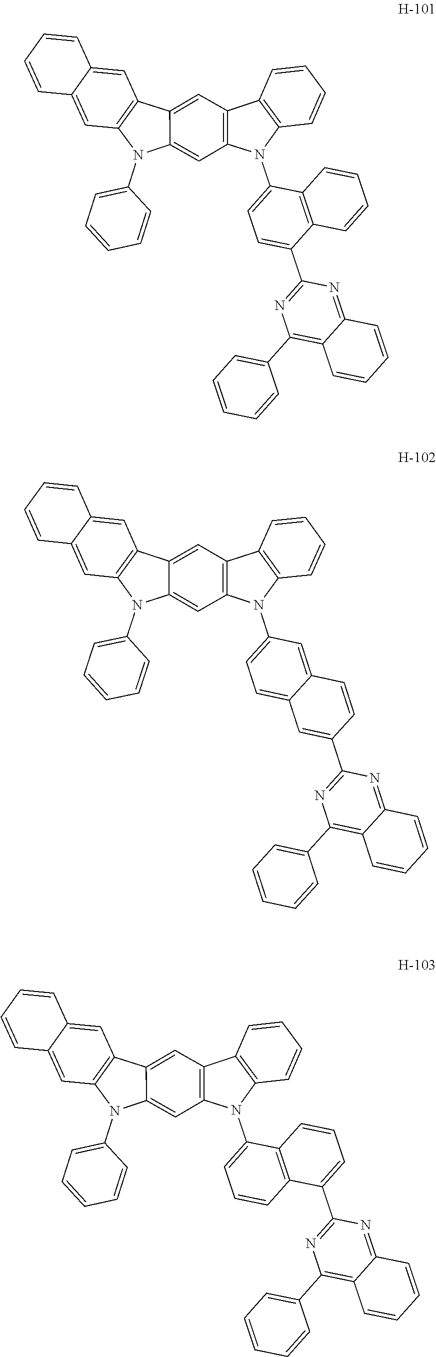 [SMILES: c1ccc(-c2nc(-c3ccc(-n4c5ccccc5c5cc6c7cc8ccccc8cc7n(-c7ccccc7)c6cc54)c4ccccc34)nc3ccccc23)cc1 ; c1ccc(-c2nc(-c3ccc4cc(-n5c6ccccc6c6cc7c8cc9ccccc9cc8n(-c8ccccc8)c7cc65)ccc4c3)nc3ccccc23)cc1 ; c1ccc(-c2nc(-c3cccc4c(-n5c6ccccc6c6cc7c8cc9ccccc9cc8n(-c8ccccc8)c7cc65)cccc34)nc3ccccc23)cc1]

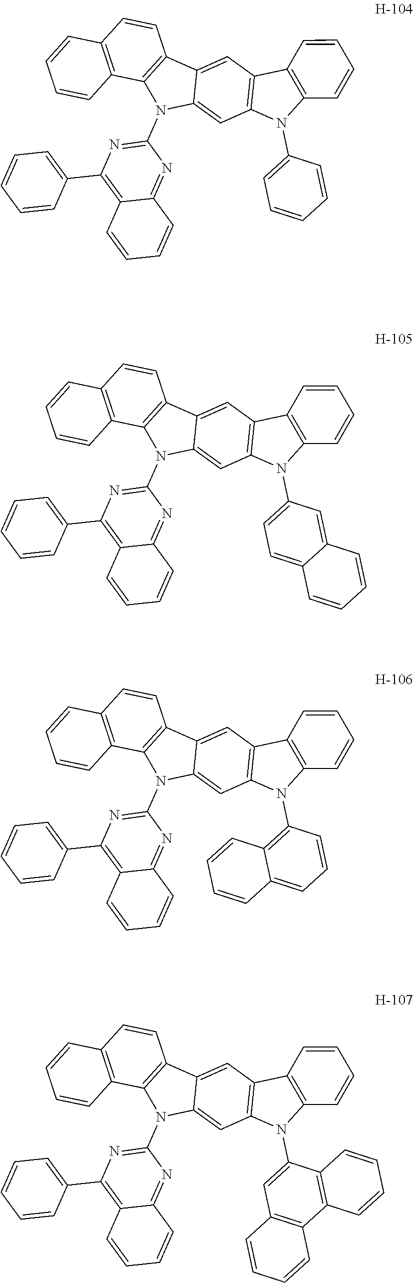 [SMILES: c1ccc(-c2nc(-n3c4cc5c(cc4c4ccc6ccccc6c43)c3ccccc3n5-c3ccccc3)nc3ccccc23)cc1 ; c1ccc(-c2nc(-n3c4cc5c(cc4c4ccc6ccccc6c43)c3ccccc3n5-c3ccc4ccccc4c3)nc3ccccc23)cc1 ; c1ccc(-c2nc(-n3c4cc5c(cc4c4ccc6ccccc6c43)c3ccccc3n5-c3cccc4ccccc34)nc3ccccc23)cc1 ; c1ccc(-c2nc(-n3c4cc5c(cc4c4ccc6ccccc6c43)c3ccccc3n5-c3cc4ccccc4c4ccccc34)nc3ccccc23)cc1]

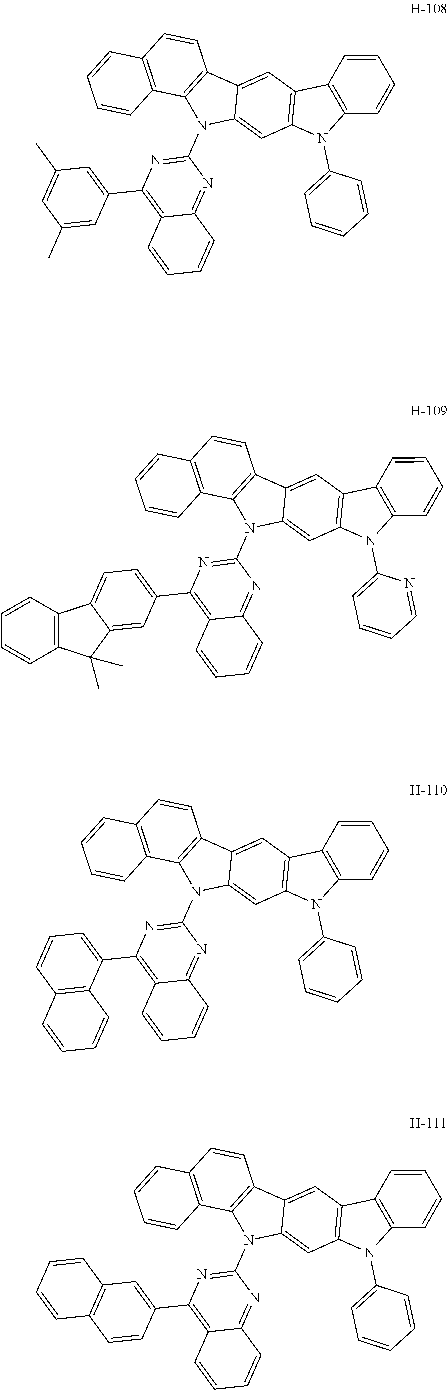 [SMILES: Cc1cc(C)cc(-c2nc(-n3c4cc5c(cc4c4ccc6ccccc6c43)c3ccccc3n5-c3ccccc3)nc3ccccc23)c1 ; CC1(C)c2ccccc2-c2ccc(-c3nc(-n4c5cc6c(cc5c5ccc7ccccc7c54)c4ccccc4n6-c4ccccn4)nc4ccccc34)cc21 ; c1ccc(-n2c3ccccc3c3cc4c5ccc6ccccc6c5n(-c5nc(-c6cccc7ccccc67)c6ccccc6n5)c4cc32)cc1 ; c1ccc(-n2c3ccccc3c3cc4c5ccc6ccccc6c5n(-c5nc(-c6ccc7ccccc7c6)c6ccccc6n5)c4cc32)cc1]

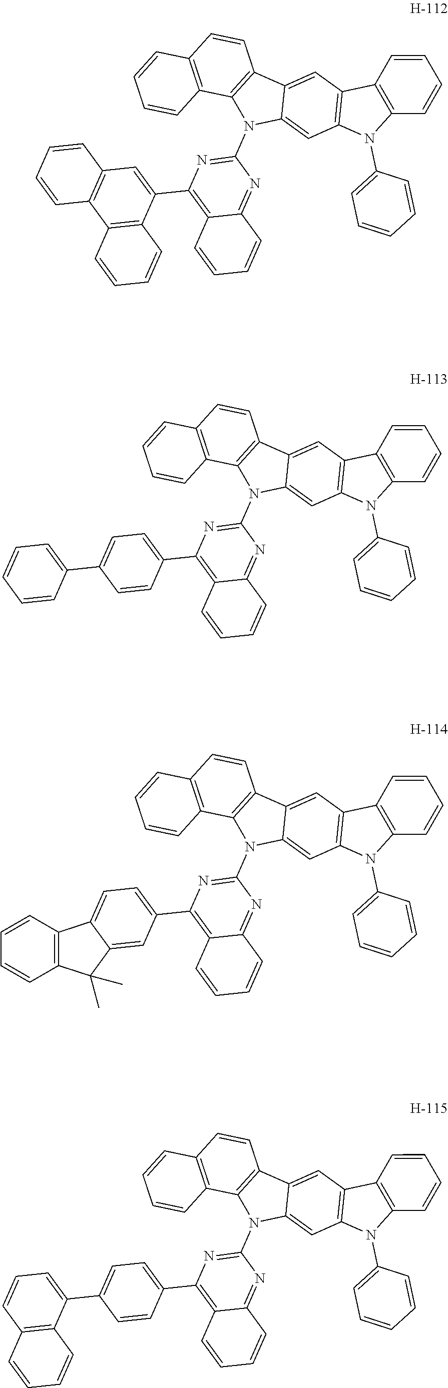 [SMILES: c1ccc(-n2c3ccccc3c3cc4c5ccc6ccccc6c5n(-c5nc(-c6cc7ccccc7c7ccccc67)c6ccccc6n5)c4cc32)cc1 ; c1ccc(-c2ccc(-c3nc(-n4c5cc6c(cc5c5ccc7ccccc7c54)c4ccccc4n6-c4ccccc4)nc4ccccc34)cc2)cc1 ; CC1(C)c2ccccc2-c2ccc(-c3nc(-n4c5cc6c(cc5c5ccc7ccccc7c54)c4ccccc4n6-c4ccccc4)nc4ccccc34)cc21 ; c1ccc(-n2c3ccccc3c3cc4c5ccc6ccccc6c5n(-c5nc(-c6ccc(-c7cccc8ccccc78)cc6)c6ccccc6n5)c4cc32)cc1]

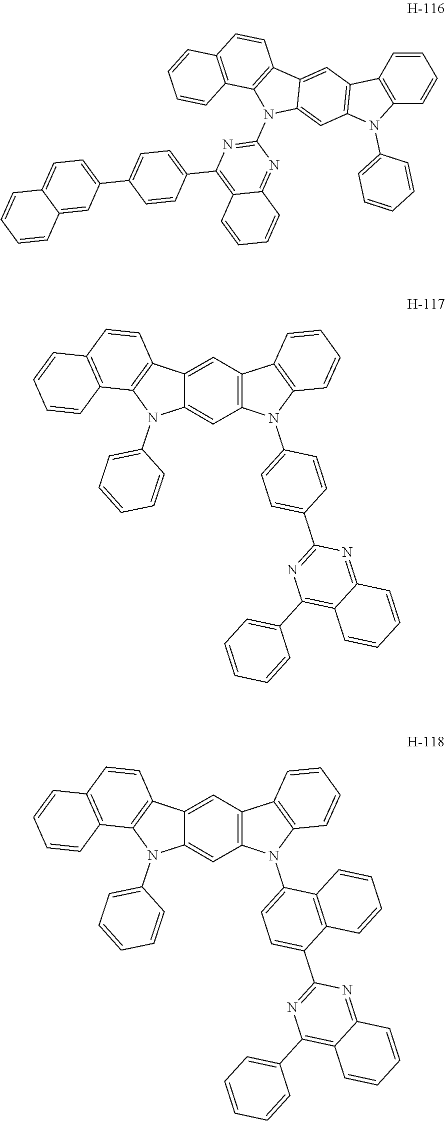 [SMILES: c1ccc(-n2c3ccccc3c3cc4c5ccc6ccccc6c5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7ccc8ccccc8c7n(-c7ccccc7)c6cc54)cc3)nc3ccccc23)cc1 ; c1ccc(-c2nc(-c3ccc(-n4c5ccccc5c5cc6c7ccc8ccccc8c7n(-c7ccccc7)c6cc54)c4ccccc34)nc3ccccc23)cc1]

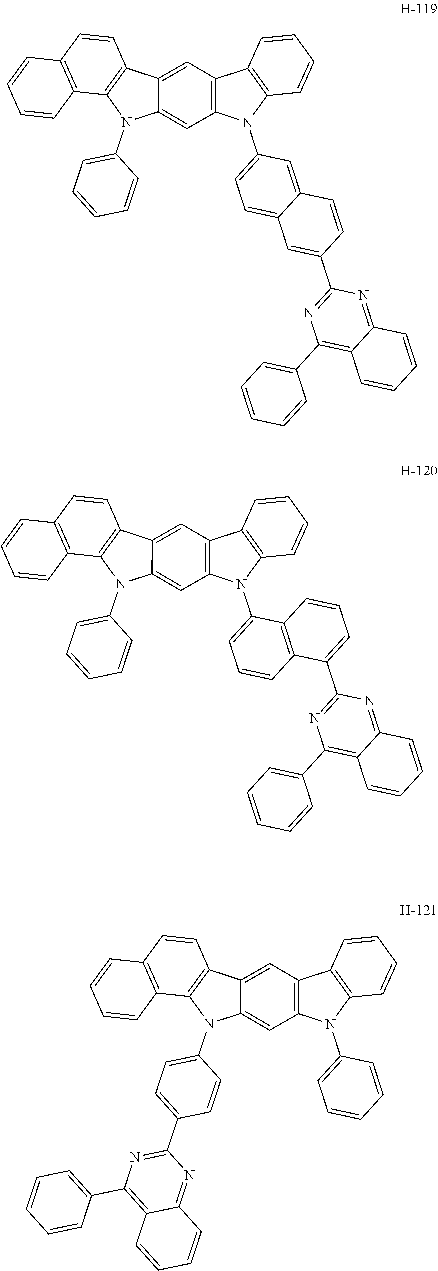 [SMILES: c1ccc(-c2nc(-c3ccc4cc(-n5c6ccccc6c6cc7c8ccc9ccccc9c8n(-c8ccccc8)c7cc65)ccc4c3)nc3ccccc23)cc1 ; c1ccc(-c2nc(-c3cccc4c(-n5c6ccccc6c6cc7c8ccc9ccccc9c8n(-c8ccccc8)c7cc65)cccc34)nc3ccccc23)cc1 ; c1ccc(-c2nc(-c3ccc(-n4c5cc6c(cc5c5ccc7ccccc7c54)c4ccccc4n6-c4ccccc4)cc3)nc3ccccc23)cc1]

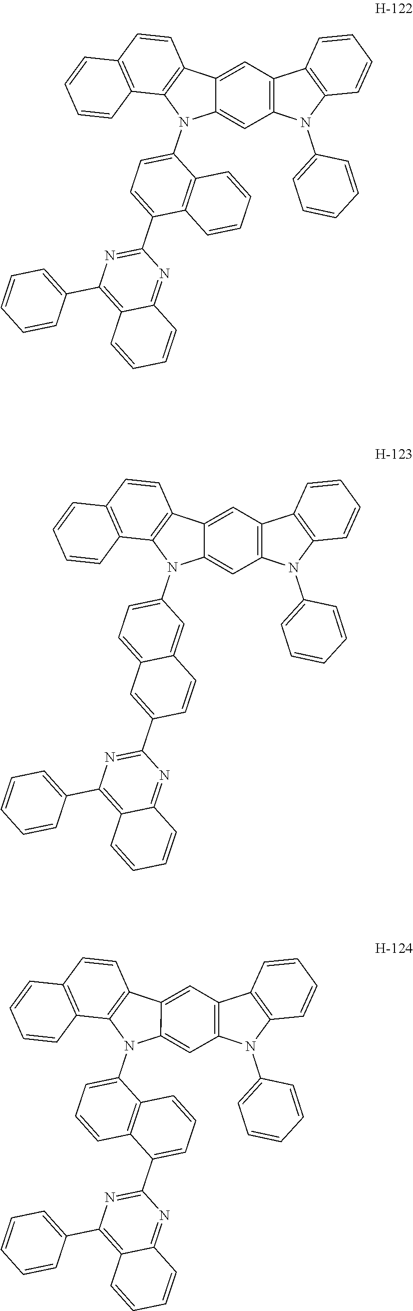 [SMILES: c1ccc(-c2nc(-c3ccc(-n4c5cc6c(cc5c5ccc7ccccc7c54)c4ccccc4n6-c4ccccc4)c4ccccc34)nc3ccccc23)cc1 ; c1ccc(-c2nc(-c3ccc4cc(-n5c6cc7c(cc6c6ccc8ccccc8c65)c5ccccc5n7-c5ccccc5)ccc4c3)nc3ccccc23)cc1 ; c1ccc(-c2nc(-c3cccc4c(-n5c6cc7c(cc6c6ccc8ccccc8c65)c5ccccc5n7-c5ccccc5)cccc34)nc3ccccc23)cc1]

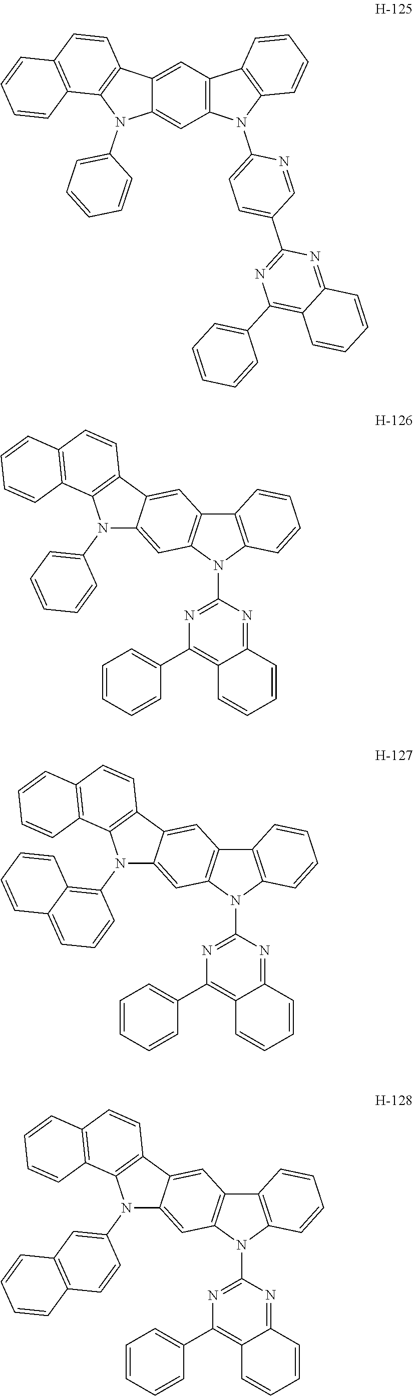 [SMILES: c1ccc(-c2nc(-c3ccc(-n4c5ccccc5c5cc6c7ccc8ccccc8c7n(-c7ccccc7)c6cc54)nc3)nc3ccccc23)cc1 ; c1ccc(-c2nc(-n3c4ccccc4c4cc5c6ccc7ccccc7c6n(-c6ccccc6)c5cc43)nc3ccccc23)cc1 ; c1ccc(-c2nc(-n3c4ccccc4c4cc5c6ccc7ccccc7c6n(-c6cccc7ccccc67)c5cc43)nc3ccccc23)cc1 ; c1ccc(-c2nc(-n3c4ccccc4c4cc5c6ccc7ccccc7c6n(-c6ccc7ccccc7c6)c5cc43)nc3ccccc23)cc1]

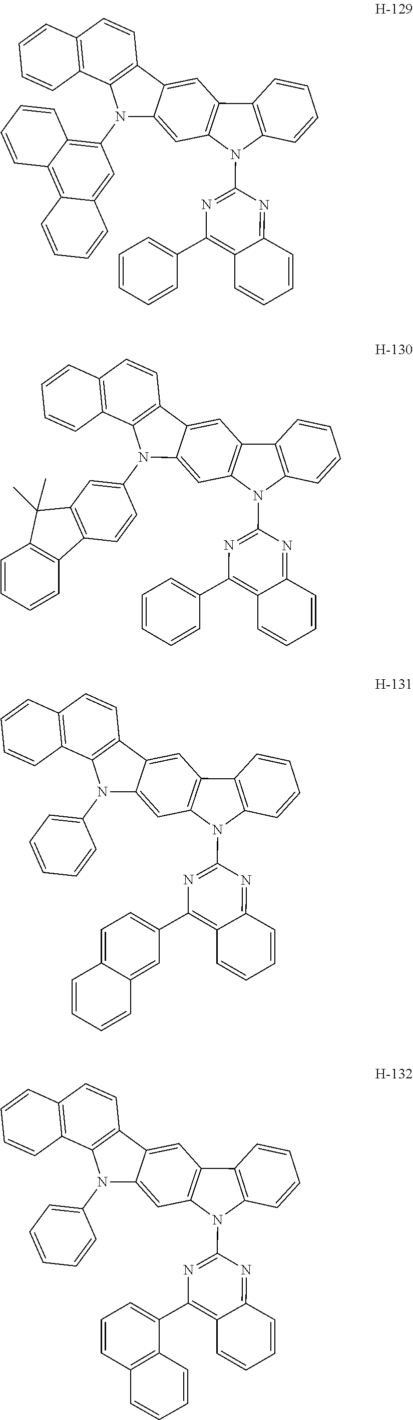 [SMILES: c1ccc(-c2nc(-n3c4ccccc4c4cc5c6ccc7ccccc7c6n(-c6cc7ccccc7c7ccccc67)c5cc43)nc3ccccc23)cc1 ; CC1(C)c2ccccc2-c2ccc(-n3c4cc5c(cc4c4ccc6ccccc6c43)c3ccccc3n5-c3nc(-c4ccccc4)c4ccccc4n3)cc21 ; c1ccc(-n2c3cc4c(cc3c3ccc5ccccc5c32)c2ccccc2n4-c2nc(-c3ccc4ccccc4c3)c3ccccc3n2)cc1 ; c1ccc(-n2c3cc4c(cc3c3ccc5ccccc5c32)c2ccccc2n4-c2nc(-c3cccc4ccccc34)c3ccccc3n2)cc1]

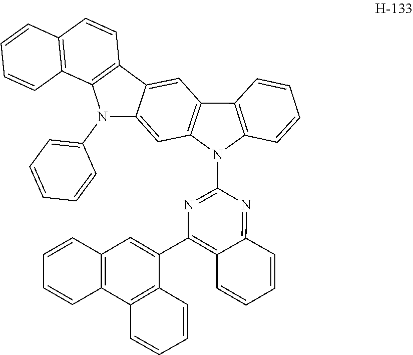 [SMILES: c1ccc(-n2c3cc4c(cc3c3ccc5ccccc5c32)c2ccccc2n4-c2nc(-c3cc4ccccc4c4ccccc34)c3ccccc3n2)cc1]

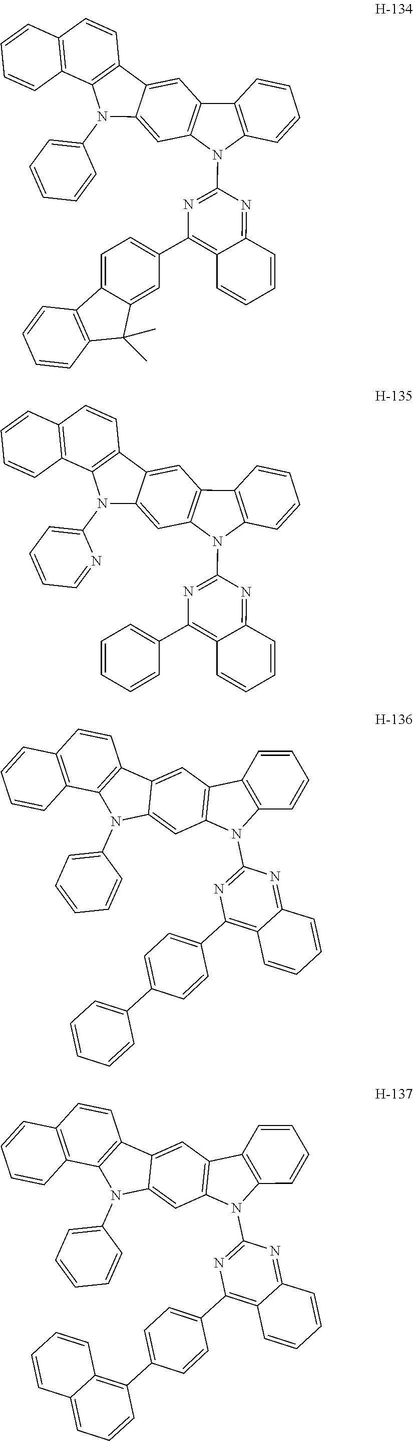

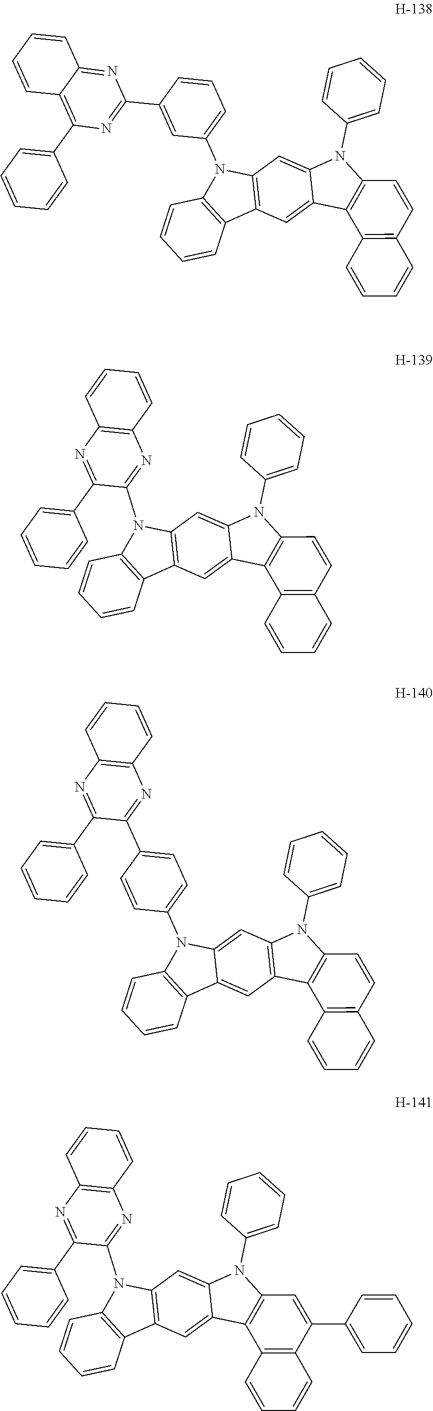 [SMILES: c1ccc(-c2nc(-c3cccc(-n4c5ccccc5c5cc6c7c8ccccc8ccc7n(-c7ccccc7)c6cc54)c3)nc3ccccc23)cc1 ; c1ccc(-c2nc3ccccc3nc2-n2c3ccccc3c3cc4c5c6ccccc6ccc5n(-c5ccccc5)c4cc32)cc1 ; c1ccc(-c2nc3ccccc3nc2-c2ccc(-n3c4ccccc4c4cc5c6c7ccccc7ccc6n(-c6ccccc6)c5cc43)cc2)cc1 ; c1ccc(-c2nc3ccccc3nc2-n2c3ccccc3c3cc4c5c6ccccc6c(-c6ccccc6)cc5n(-c5ccccc5)c4cc32)cc1]

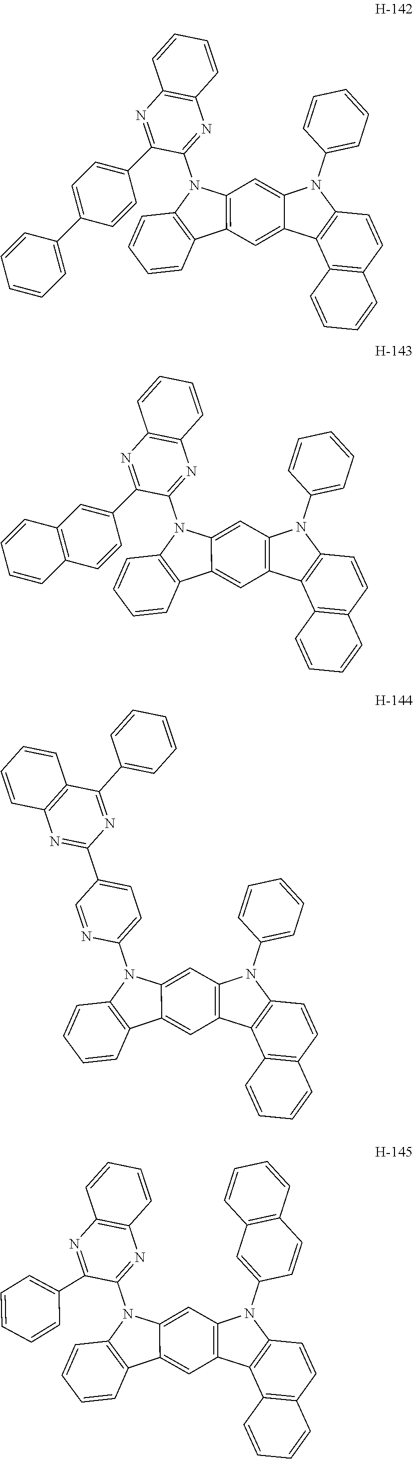

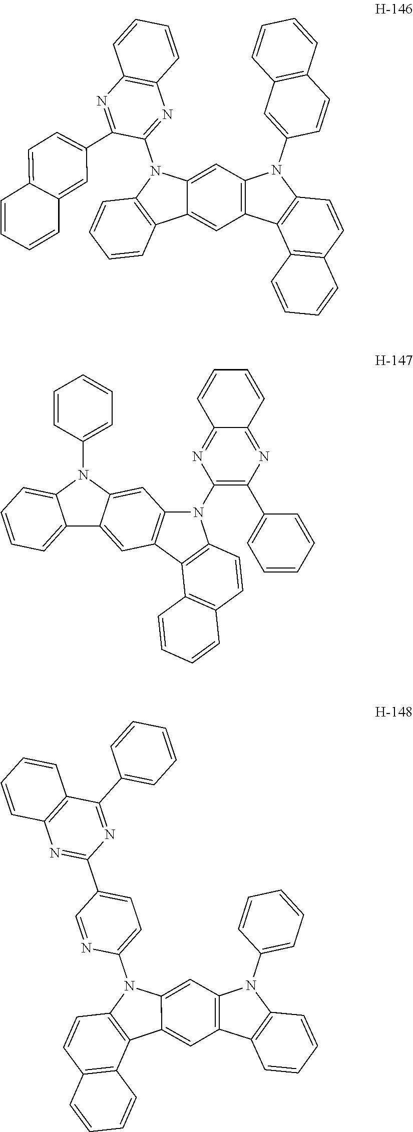 [SMILES: c1ccc2cc(-c3nc4ccccc4nc3-n3c4ccccc4c4cc5c6c7ccccc7ccc6n(-c6ccc7ccccc7c6)c5cc43)ccc2c1 ; c1ccc(-c2nc3ccccc3nc2-n2c3cc4c(cc3c3c5ccccc5ccc32)c2ccccc2n4-c2ccccc2)cc1 ; c1ccc(-c2nc(-c3ccc(-n4c5cc6c(cc5c5c7ccccc7ccc54)c4ccccc4n6-c4ccccc4)nc3)nc3ccccc23)cc1]

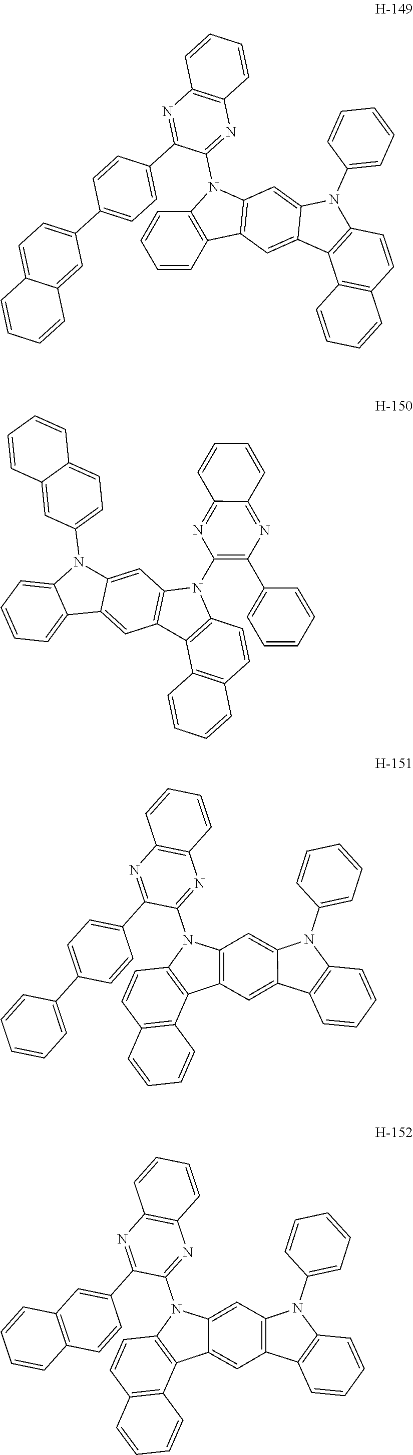 [SMILES: c1ccc(-n2c3cc4c(cc3c3c5ccccc5ccc32)c2ccccc2n4-c2nc3ccccc3nc2-c2ccc(-c3ccc4ccccc4c3)cc2)cc1 ; c1ccc(-c2nc3ccccc3nc2-n2c3cc4c(cc3c3c5ccccc5ccc32)c2ccccc2n4-c2ccc3ccccc3c2)cc1 ; c1ccc(-c2ccc(-c3nc4ccccc4nc3-n3c4cc5c(cc4c4c6ccccc6ccc43)c3ccccc3n5-c3ccccc3)cc2)cc1 ; c1ccc(-n2c3ccccc3c3cc4c5c6ccccc6ccc5n(-c5nc6ccccc6nc5-c5ccc6ccccc6c5)c4cc32)cc1]

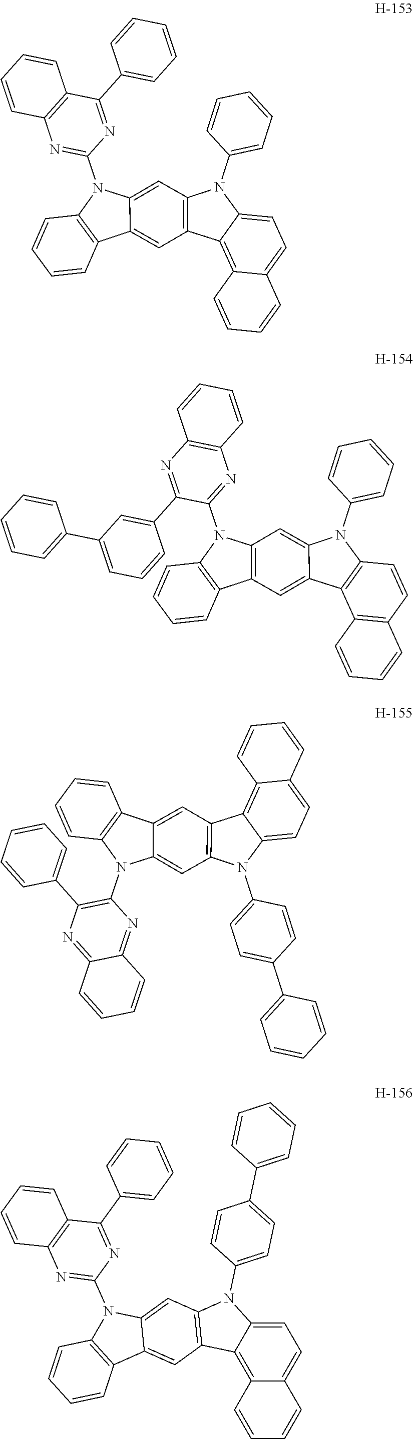 [SMILES: c1ccc(-c2nc(-n3c4ccccc4c4cc5c6c7ccccc7ccc6n(-c6ccccc6)c5cc43)nc3ccccc23)cc1 ; c1ccc(-c2cccc(-c3nc4ccccc4nc3-n3c4ccccc4c4cc5c6c7ccccc7ccc6n(-c6ccccc6)c5cc43)c2)cc1 ; c1ccc(-c2ccc(-n3c4cc5c(cc4c4c6ccccc6ccc43)c3ccccc3n5-c3nc4ccccc4nc3-c3ccccc3)cc2)cc1 ; c1ccc(-c2ccc(-n3c4cc5c(cc4c4c6ccccc6ccc43)c3ccccc3n5-c3nc(-c4ccccc4)c4ccccc4n3)cc2)cc1]

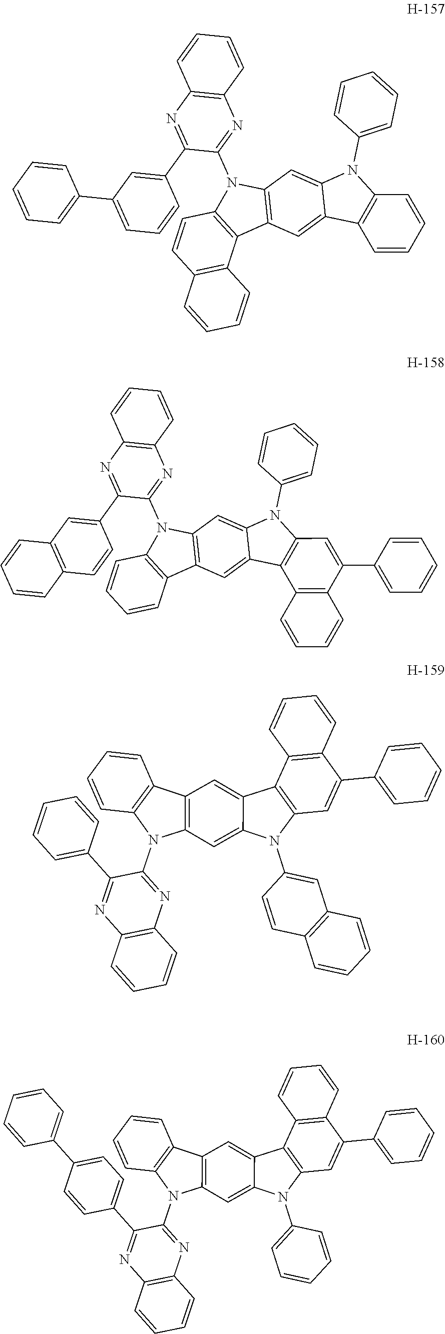 [SMILES: c1ccc(-c2cccc(-c3nc4ccccc4nc3-n3c4cc5c(cc4c4c6ccccc6ccc43)c3ccccc3n5-c3ccccc3)c2)cc1 ; c1ccc(-c2cc3c(c4ccccc24)c2cc4c5ccccc5n(-c5nc6ccccc6nc5-c5ccc6ccccc6c5)c4cc2n3-c2ccccc2)cc1 ; c1ccc(-c2nc3ccccc3nc2-n2c3ccccc3c3cc4c5c6ccccc6c(-c6ccccc6)cc5n(-c5ccc6ccccc6c5)c4cc32)cc1 ; c1ccc(-c2ccc(-c3nc4ccccc4nc3-n3c4ccccc4c4cc5c6c7ccccc7c(-c7ccccc7)cc6n(-c6ccccc6)c5cc43)cc2)cc1]

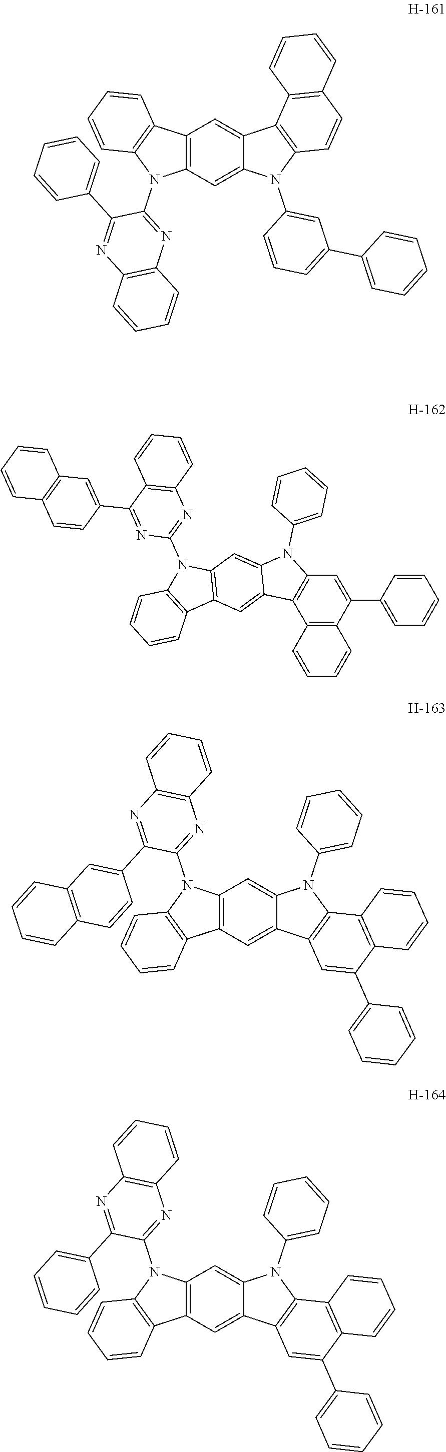 [SMILES: c1ccc(-c2cccc(-n3c4cc5c(cc4c4c6ccccc6ccc43)c3ccccc3n5-c3nc4ccccc4nc3-c3ccccc3)c2)cc1 ; c1ccc(-c2cc3c(c4ccccc24)c2cc4c5ccccc5n(-c5nc(-c6ccc7ccccc7c6)c6ccccc6n5)c4cc2n3-c2ccccc2)cc1 ; c1ccc(-c2cc3c4cc5c6ccccc6n(-c6nc7ccccc7nc6-c6ccc7ccccc7c6)c5cc4n(-c4ccccc4)c3c3ccccc23)cc1 ; c1ccc(-c2nc3ccccc3nc2-n2c3ccccc3c3cc4c5cc(-c6ccccc6)c6ccccc6c5n(-c5ccccc5)c4cc32)cc1]

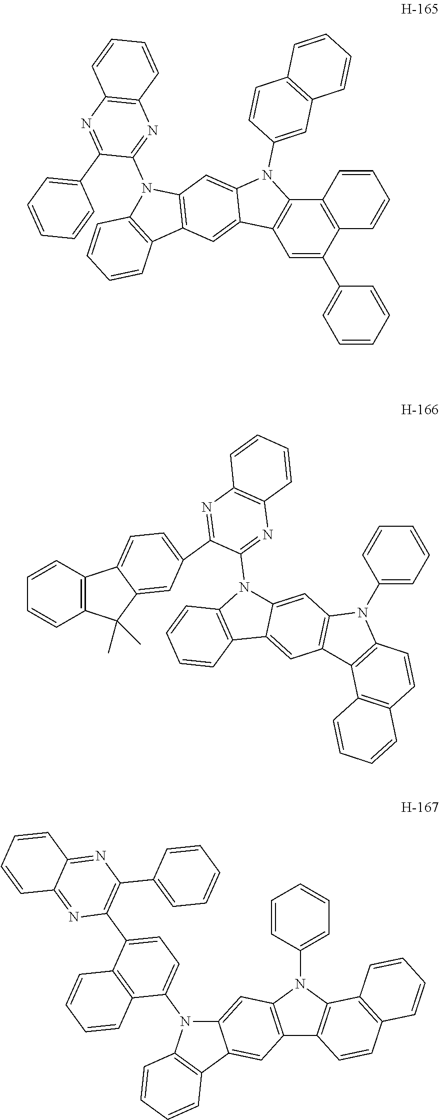 [SMILES: c1ccc(-c2nc3ccccc3nc2-n2c3ccccc3c3cc4c5cc(-c6ccccc6)c6ccccc6c5n(-c5ccc6ccccc6c5)c4cc32)cc1 ; CC1(C)c2ccccc2-c2ccc(-c3nc4ccccc4nc3-n3c4ccccc4c4cc5c6c7ccccc7ccc6n(-c6ccccc6)c5cc43)cc21 ; c1ccc(-c2nc3ccccc3nc2-c2ccc(-n3c4ccccc4c4cc5c6ccc7ccccc7c6n(-c6ccccc6)c5cc43)c3ccccc23)cc1]

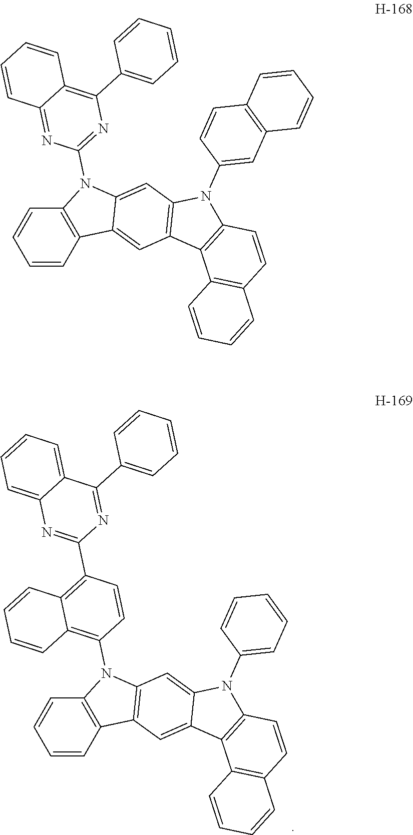 [SMILES: c1ccc(-c2nc(-n3c4ccccc4c4cc5c6c7ccccc7ccc6n(-c6ccc7ccccc7c6)c5cc43)nc3ccccc23)cc1 ; c1ccc(-c2nc(-c3ccc(-n4c5ccccc5c5cc6c7c8ccccc8ccc7n(-c7ccccc7)c6cc54)c4ccccc34)nc3ccccc23)cc1]

8. The organic electroluminescent device according to claim 4, wherein the compound represented by formula 11 or 12 is selected from the group consisting of:

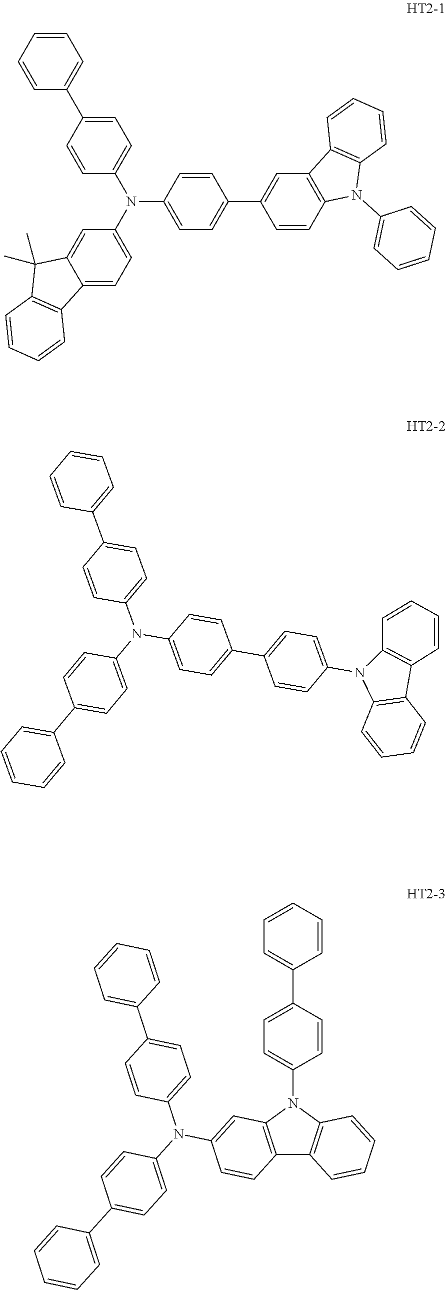 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc4c5ccccc5n(-c5ccc(-c6ccccc6)cc5)c4c3)cc2)cc1]

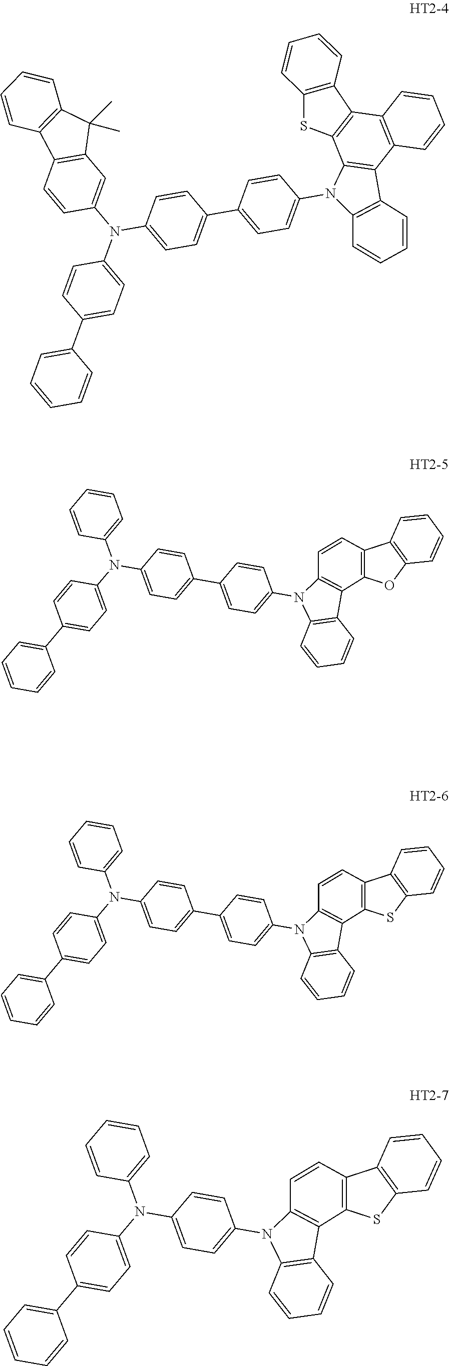 [SMILES: CC1(C)c2ccccc2-c2ccc(N(c3ccc(-c4ccccc4)cc3)c3ccc(-c4ccc(-n5c6ccccc6c6c7ccccc7c7c8ccccc8sc7c65)cc4)cc3)cc21 ; c1ccc(-c2ccc(N(c3ccccc3)c3ccc(-c4ccc(-n5c6ccccc6c6c7oc8ccccc8c7ccc65)cc4)cc3)cc2)cc1 ; c1ccc(-c2ccc(N(c3ccccc3)c3ccc(-c4ccc(-n5c6ccccc6c6c7sc8ccccc8c7ccc65)cc4)cc3)cc2)cc1 ; c1ccc(-c2ccc(N(c3ccccc3)c3ccc(-n4c5ccccc5c5c6sc7ccccc7c6ccc54)cc3)cc2)cc1]

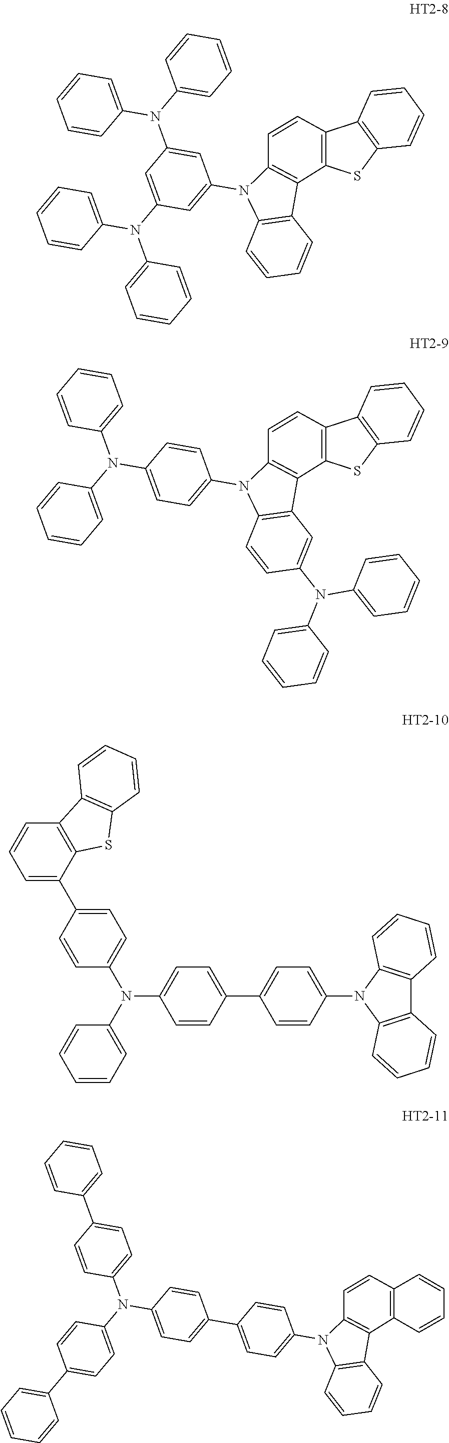 [SMILES: c1ccc(N(c2ccccc2)c2cc(N(c3ccccc3)c3ccccc3)cc(-n3c4ccccc4c4c5sc6ccccc6c5ccc43)c2)cc1 ; c1ccc(N(c2ccccc2)c2ccc(-n3c4ccc(N(c5ccccc5)c5ccccc5)cc4c4c5sc6ccccc6c5ccc43)cc2)cc1 ; c1ccc(N(c2ccc(-c3ccc(-n4c5ccccc5c5ccccc54)cc3)cc2)c2ccc(-c3cccc4c3sc3ccccc34)cc2)cc1 ; c1ccc(-c2ccc(N(c3ccc(-c4ccccc4)cc3)c3ccc(-c4ccc(-n5c6ccccc6c6c7ccccc7ccc65)cc4)cc3)cc2)cc1]

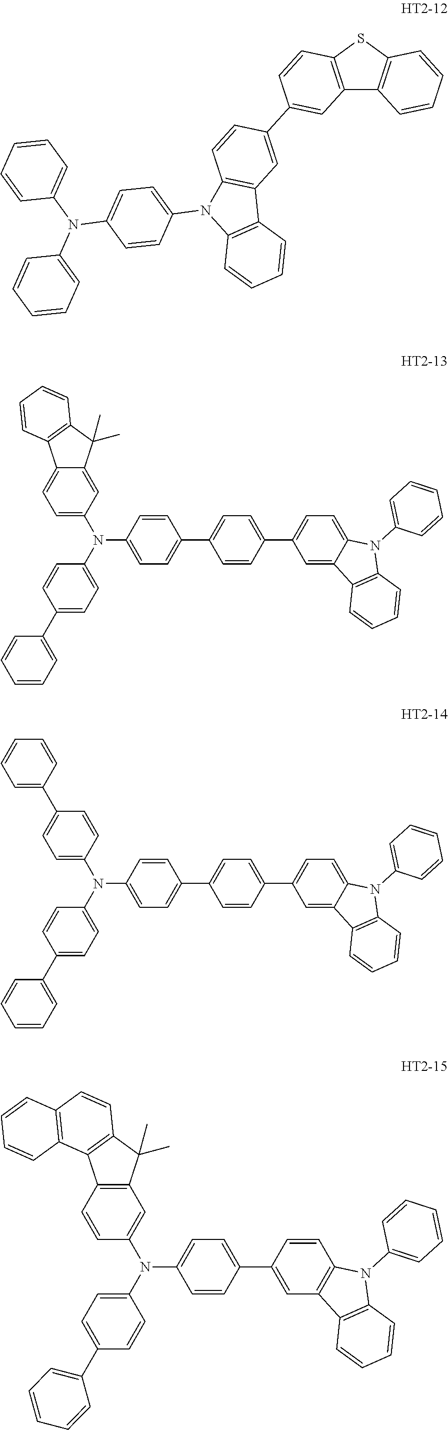 [SMILES: c1ccc(N(c2ccccc2)c2ccc(-n3c4ccccc4c4cc(-c5ccc6sc7ccccc7c6c5)ccc43)cc2)cc1 ; CC1(C)c2ccccc2-c2ccc(N(c3ccc(-c4ccccc4)cc3)c3ccc(-c4ccc(-c5ccc6c(c5)c5ccccc5n6-c5ccccc5)cc4)cc3)cc21 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; CC1(C)c2cc(N(c3ccc(-c4ccccc4)cc3)c3ccc(-c4ccc5c(c4)c4ccccc4n5-c4ccccc4)cc3)ccc2-c2c1ccc1ccccc21]

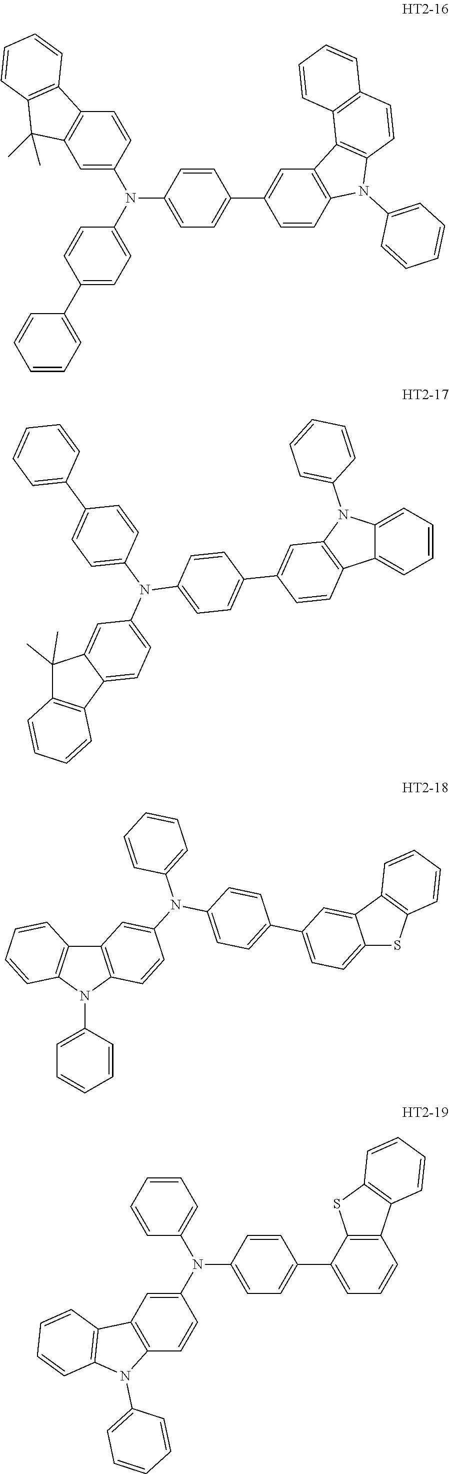 [SMILES: CC1(C)c2ccccc2-c2ccc(N(c3ccc(-c4ccccc4)cc3)c3ccc(-c4ccc5c(c4)c4c6ccccc6ccc4n5-c4ccccc4)cc3)cc21 ; CC1(C)c2ccccc2-c2ccc(N(c3ccc(-c4ccccc4)cc3)c3ccc(-c4ccc5c6ccccc6n(-c6ccccc6)c5c4)cc3)cc21 ; c1ccc(N(c2ccc(-c3ccc4sc5ccccc5c4c3)cc2)c2ccc3c(c2)c2ccccc2n3-c2ccccc2)cc1 ; c1ccc(N(c2ccc(-c3cccc4c3sc3ccccc34)cc2)c2ccc3c(c2)c2ccccc2n3-c2ccccc2)cc1]

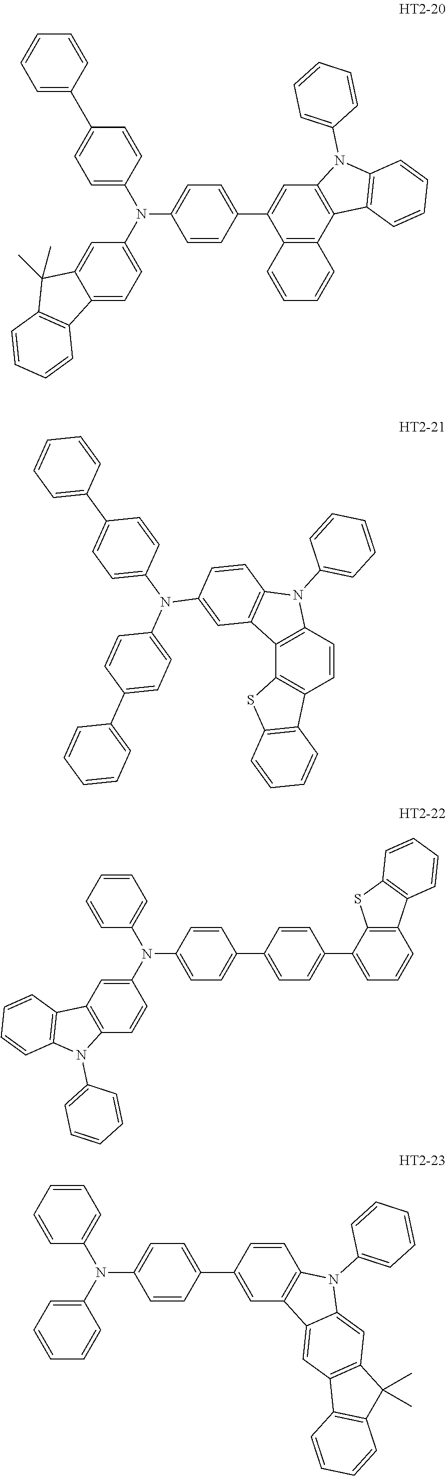

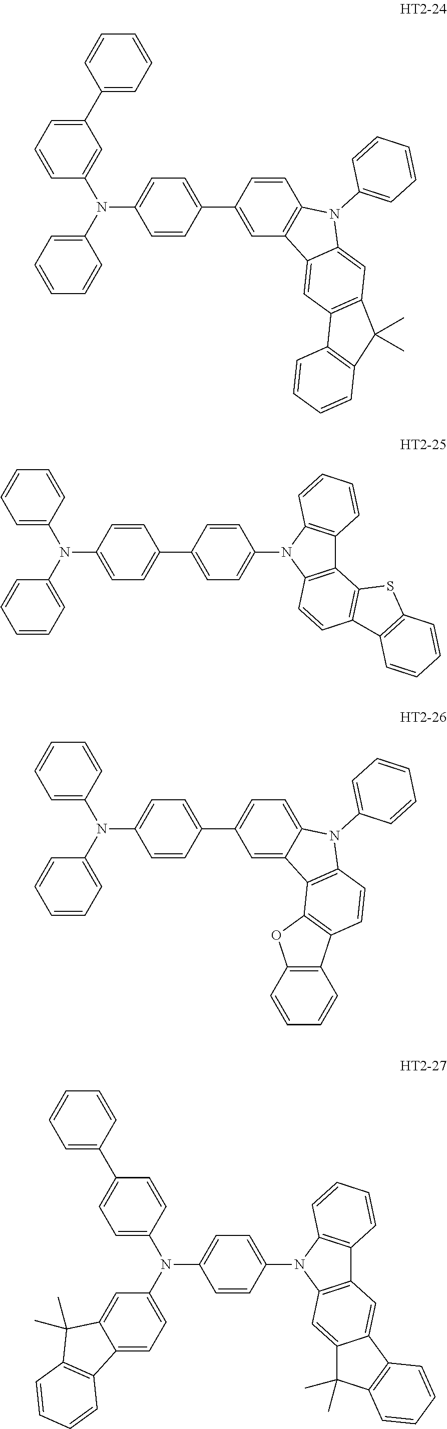 [SMILES: CC1(C)c2ccccc2-c2cc3c4cc(-c5ccc(N(c6ccccc6)c6cccc(-c7ccccc7)c6)cc5)ccc4n(-c4ccccc4)c3cc21 ; c1ccc(N(c2ccccc2)c2ccc(-c3ccc(-n4c5ccccc5c5c6sc7ccccc7c6ccc54)cc3)cc2)cc1 ; c1ccc(N(c2ccccc2)c2ccc(-c3ccc4c(c3)c3c5oc6ccccc6c5ccc3n4-c3ccccc3)cc2)cc1 ; CC1(C)c2ccccc2-c2ccc(N(c3ccc(-c4ccccc4)cc3)c3ccc(-n4c5ccccc5c5cc6c(cc54)C(C)(C)c4ccccc4-6)cc3)cc21]

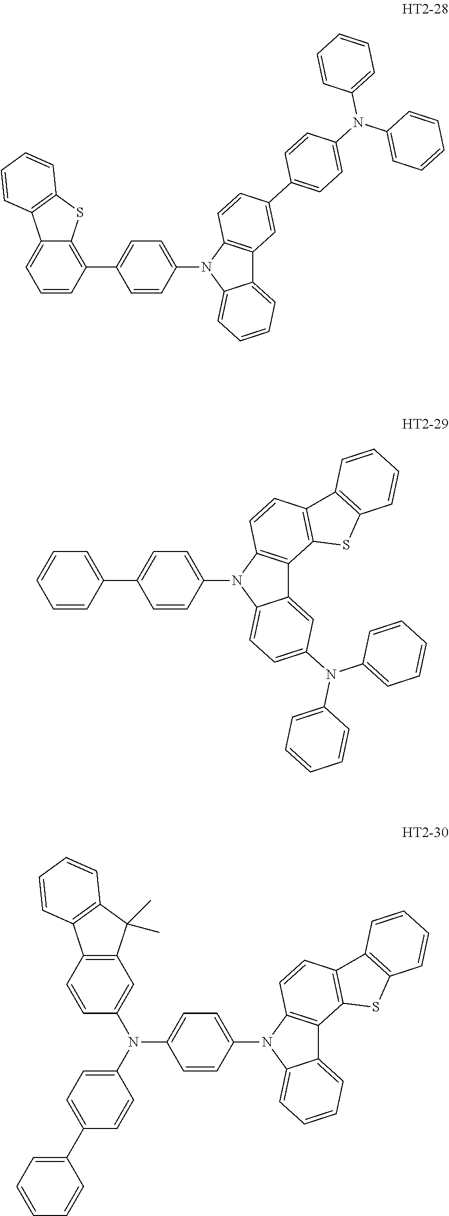 [SMILES: c1ccc(N(c2ccccc2)c2ccc(-c3ccc4c(c3)c3ccccc3n4-c3ccc(-c4cccc5c4sc4ccccc45)cc3)cc2)cc1 ; c1ccc(-c2ccc(-n3c4ccc(N(c5ccccc5)c5ccccc5)cc4c4c5sc6ccccc6c5ccc43)cc2)cc1 ; CC1(C)c2ccccc2-c2ccc(N(c3ccc(-c4ccccc4)cc3)c3ccc(-n4c5ccccc5c5c6sc7ccccc7c6ccc54)cc3)cc21]

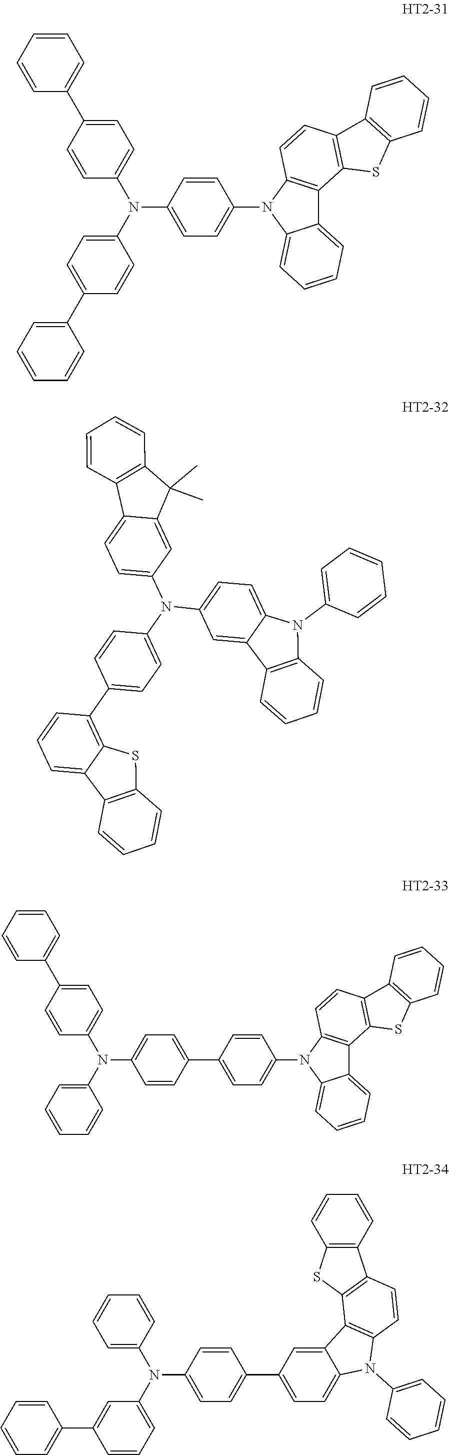 [SMILES: c1ccc(-c2ccc(N(c3ccc(-c4ccccc4)cc3)c3ccc(-n4c5ccccc5c5c6sc7ccccc7c6ccc54)cc3)cc2)cc1 ; CC1(C)c2ccccc2-c2ccc(N(c3ccc(-c4cccc5c4sc4ccccc45)cc3)c3ccc4c(c3)c3ccccc3n4-c3ccccc3)cc21 ; c1ccc(-c2ccc(N(c3ccccc3)c3ccc(-c4ccc(-n5c6ccccc6c6c7sc8ccccc8c7ccc65)cc4)cc3)cc2)cc1 ; c1ccc(-c2cccc(N(c3ccccc3)c3ccc(-c4ccc5c(c4)c4c6sc7ccccc7c6ccc4n5-c4ccccc4)cc3)c2)cc1]

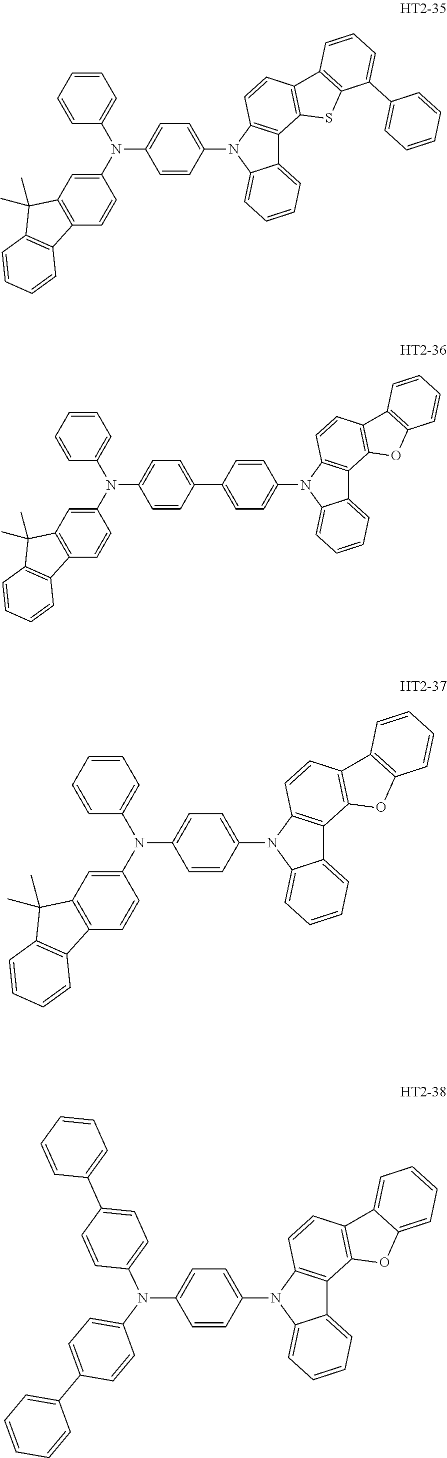 [SMILES: CC1(C)c2ccccc2-c2ccc(N(c3ccccc3)c3ccc(-n4c5ccccc5c5c6sc7c(-c8ccccc8)cccc7c6ccc54)cc3)cc21 ; CC1(C)c2ccccc2-c2ccc(N(c3ccccc3)c3ccc(-c4ccc(-n5c6ccccc6c6c7oc8ccccc8c7ccc65)cc4)cc3)cc21 ; CC1(C)c2ccccc2-c2ccc(N(c3ccccc3)c3ccc(-n4c5ccccc5c5c6oc7ccccc7c6ccc54)cc3)cc21 ; c1ccc(-c2ccc(N(c3ccc(-c4ccccc4)cc3)c3ccc(-n4c5ccccc5c5c6oc7ccccc7c6ccc54)cc3)cc2)cc1]

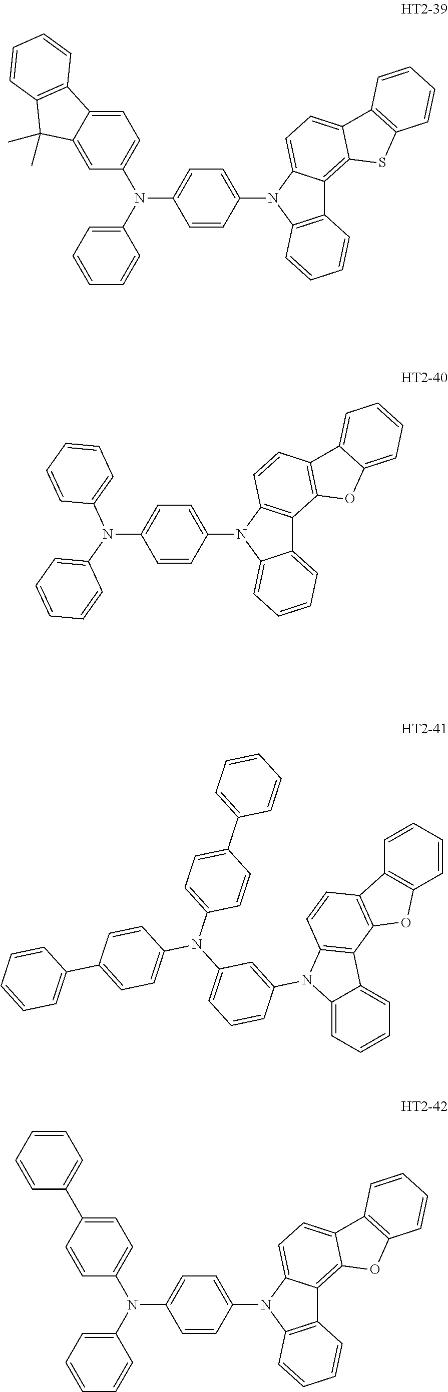 [SMILES: CC1(C)c2ccccc2-c2ccc(N(c3ccccc3)c3ccc(-n4c5ccccc5c5c6sc7ccccc7c6ccc54)cc3)cc21 ; c1ccc(N(c2ccccc2)c2ccc(-n3c4ccccc4c4c5oc6ccccc6c5ccc43)cc2)cc1 ; c1ccc(-c2ccc(N(c3ccc(-c4ccccc4)cc3)c3cccc(-n4c5ccccc5c5c6oc7ccccc7c6ccc54)c3)cc2)cc1 ; c1ccc(-c2ccc(N(c3ccccc3)c3ccc(-n4c5ccccc5c5c6oc7ccccc7c6ccc54)cc3)cc2)cc1]

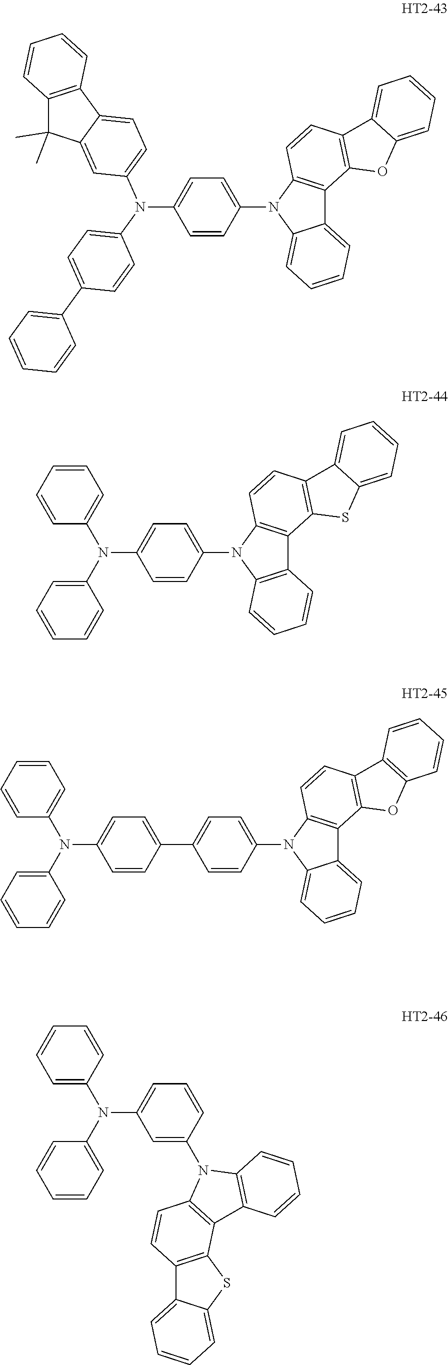 [SMILES: CC1(C)c2ccccc2-c2ccc(N(c3ccc(-c4ccccc4)cc3)c3ccc(-n4c5ccccc5c5c6oc7ccccc7c6ccc54)cc3)cc21 ; c1ccc(N(c2ccccc2)c2ccc(-n3c4ccccc4c4c5sc6ccccc6c5ccc43)cc2)cc1 ; c1ccc(N(c2ccccc2)c2ccc(-c3ccc(-n4c5ccccc5c5c6oc7ccccc7c6ccc54)cc3)cc2)cc1 ; c1ccc(N(c2ccccc2)c2cccc(-n3c4ccccc4c4c5sc6ccccc6c5ccc43)c2)cc1]

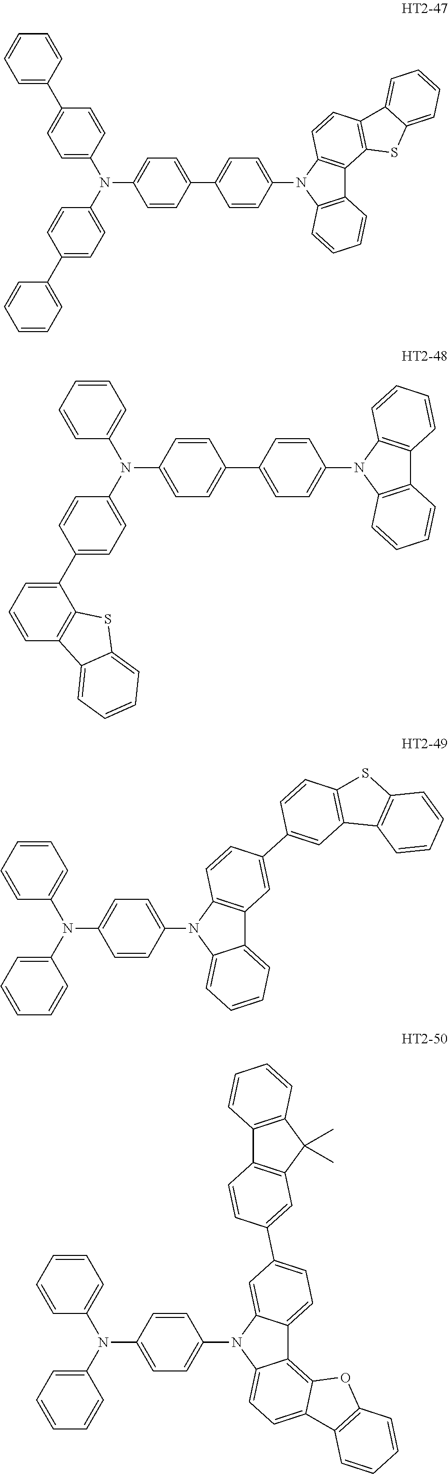 [SMILES: c1ccc(-c2ccc(N(c3ccc(-c4ccccc4)cc3)c3ccc(-c4ccc(-n5c6ccccc6c6c7sc8ccccc8c7ccc65)cc4)cc3)cc2)cc1 ; c1ccc(N(c2ccc(-c3ccc(-n4c5ccccc5c5ccccc54)cc3)cc2)c2ccc(-c3cccc4c3sc3ccccc34)cc2)cc1 ; c1ccc(N(c2ccccc2)c2ccc(-n3c4ccccc4c4cc(-c5ccc6sc7ccccc7c6c5)ccc43)cc2)cc1 ; CC1(C)c2ccccc2-c2ccc(-c3ccc4c5c6oc7ccccc7c6ccc5n(-c5ccc(N(c6ccccc6)c6ccccc6)cc5)c4c3)cc21]

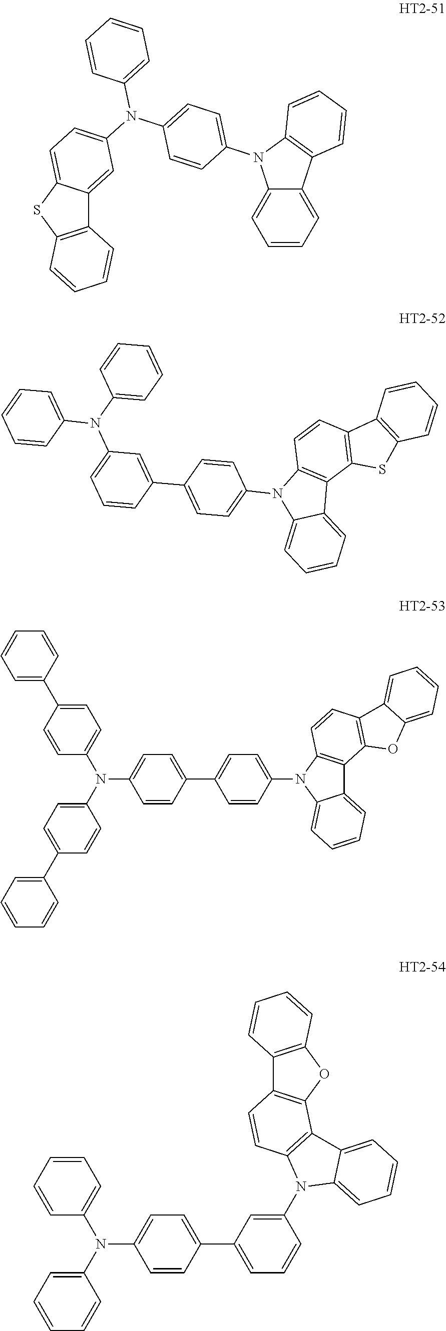 [SMILES: c1ccc(N(c2ccc(-n3c4ccccc4c4ccccc43)cc2)c2ccc3sc4ccccc4c3c2)cc1 ; c1ccc(N(c2ccccc2)c2cccc(-c3ccc(-n4c5ccccc5c5c6sc7ccccc7c6ccc54)cc3)c2)cc1 ; c1ccc(-c2ccc(N(c3ccc(-c4ccccc4)cc3)c3ccc(-c4ccc(-n5c6ccccc6c6c7oc8ccccc8c7ccc65)cc4)cc3)cc2)cc1 ; c1ccc(N(c2ccccc2)c2ccc(-c3cccc(-n4c5ccccc5c5c6oc7ccccc7c6ccc54)c3)cc2)cc1]

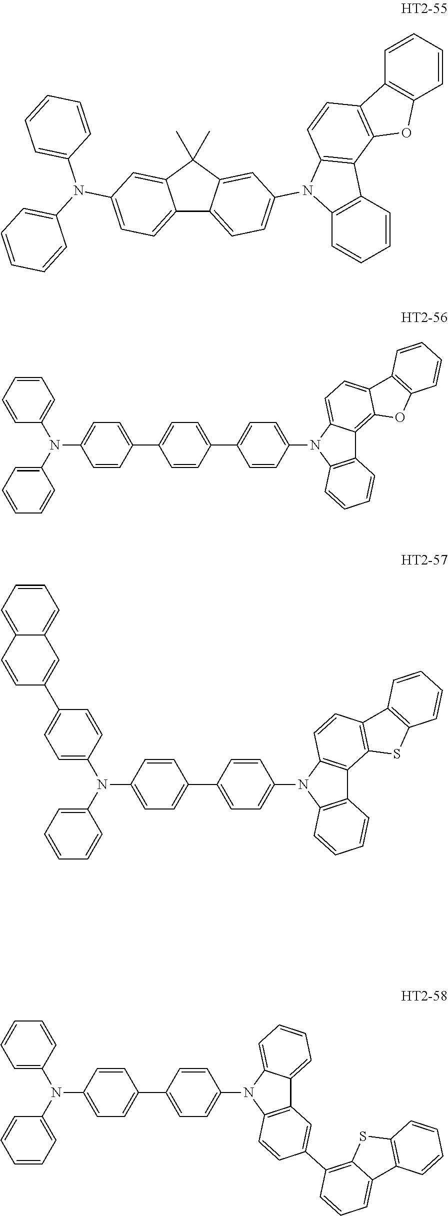 [SMILES: CC1(C)c2cc(N(c3ccccc3)c3ccccc3)ccc2-c2ccc(-n3c4ccccc4c4c5oc6ccccc6c5ccc43)cc21 ; c1ccc(N(c2ccccc2)c2ccc(-c3ccc(-c4ccc(-n5c6ccccc6c6c7oc8ccccc8c7ccc65)cc4)cc3)cc2)cc1 ; c1ccc(N(c2ccc(-c3ccc(-n4c5ccccc5c5c6sc7ccccc7c6ccc54)cc3)cc2)c2ccc(-c3ccc4ccccc4c3)cc2)cc1 ; c1ccc(N(c2ccccc2)c2ccc(-c3ccc(-n4c5ccccc5c5cc(-c6cccc7c6sc6ccccc67)ccc54)cc3)cc2)cc1]

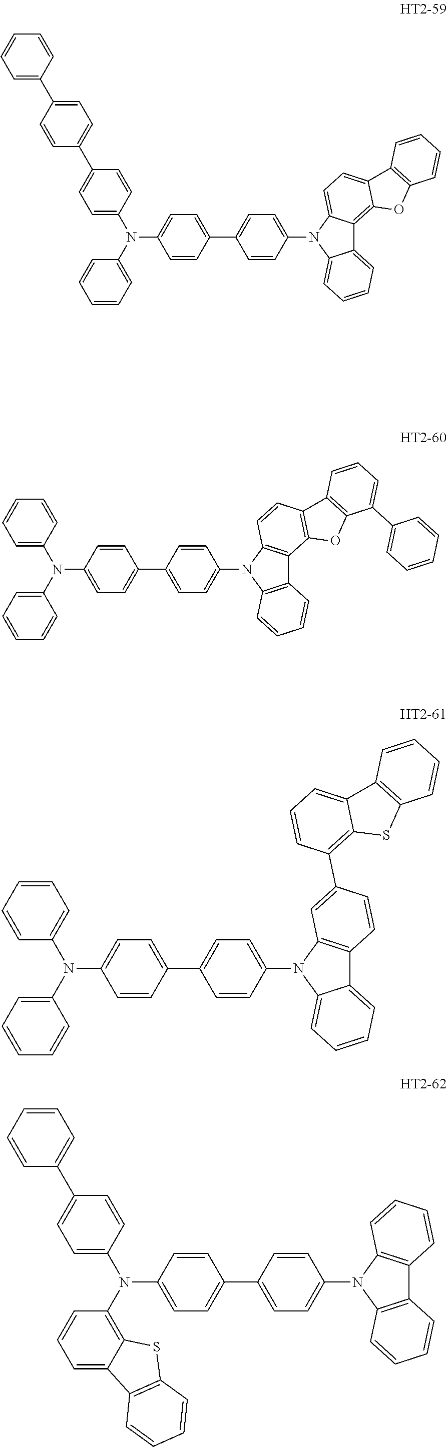 [SMILES: c1ccc(-c2ccc(-c3ccc(N(c4ccccc4)c4ccc(-c5ccc(-n6c7ccccc7c7c8oc9ccccc9c8ccc76)cc5)cc4)cc3)cc2)cc1 ; c1ccc(-c2cccc3c2oc2c3ccc3c2c2ccccc2n3-c2ccc(-c3ccc(N(c4ccccc4)c4ccccc4)cc3)cc2)cc1 ; c1ccc(N(c2ccccc2)c2ccc(-c3ccc(-n4c5ccccc5c5ccc(-c6cccc7c6sc6ccccc67)cc54)cc3)cc2)cc1 ; c1ccc(-c2ccc(N(c3ccc(-c4ccc(-n5c6ccccc6c6ccccc65)cc4)cc3)c3cccc4c3sc3ccccc34)cc2)cc1]

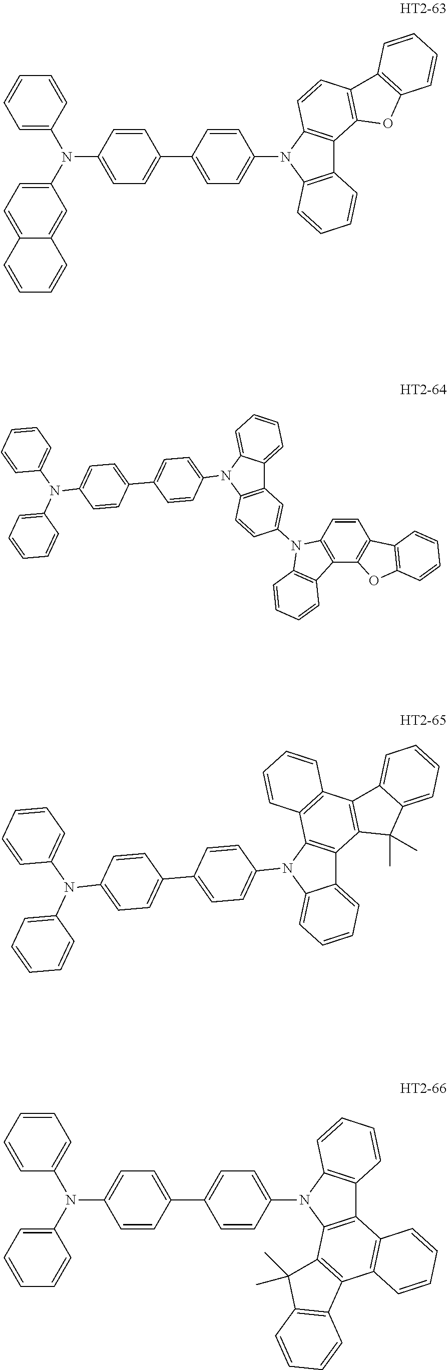 [SMILES: c1ccc(N(c2ccc(-c3ccc(-n4c5ccccc5c5c6oc7ccccc7c6ccc54)cc3)cc2)c2ccc3ccccc3c2)cc1 ; c1ccc(N(c2ccccc2)c2ccc(-c3ccc(-n4c5ccccc5c5cc(-n6c7ccccc7c7c8oc9ccccc9c8ccc76)ccc54)cc3)cc2)cc1 ; CC1(C)c2ccccc2-c2c1c1c3ccccc3n(-c3ccc(-c4ccc(N(c5ccccc5)c5ccccc5)cc4)cc3)c1c1ccccc21 ; CC1(C)c2ccccc2-c2c1c1c(c3ccccc23)c2ccccc2n1-c1ccc(-c2ccc(N(c3ccccc3)c3ccccc3)cc2)cc1]

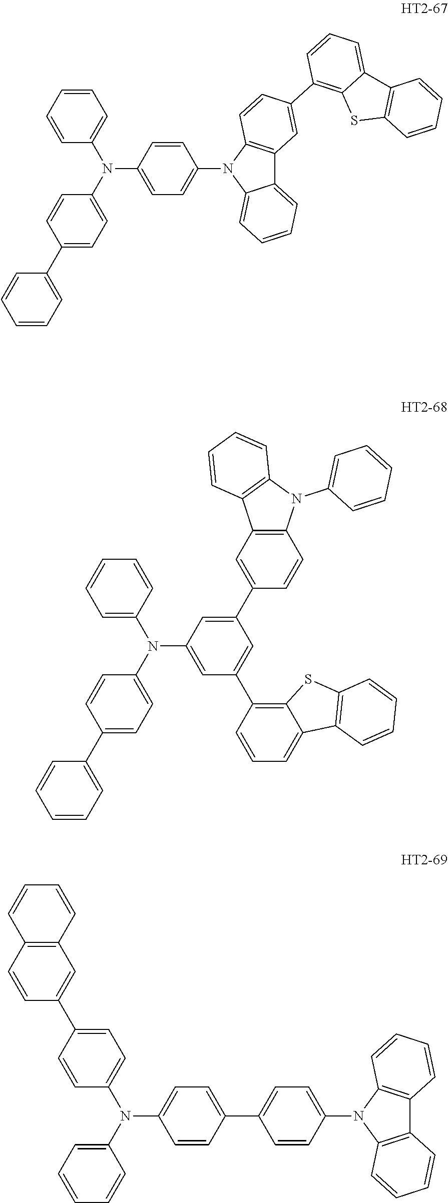 [SMILES: c1ccc(-c2ccc(N(c3ccccc3)c3ccc(-n4c5ccccc5c5cc(-c6cccc7c6sc6ccccc67)ccc54)cc3)cc2)cc1 ; c1ccc(-c2ccc(N(c3ccccc3)c3cc(-c4ccc5c(c4)c4ccccc4n5-c4ccccc4)cc(-c4cccc5c4sc4ccccc45)c3)cc2)cc1 ; c1ccc(N(c2ccc(-c3ccc(-n4c5ccccc5c5ccccc54)cc3)cc2)c2ccc(-c3ccc4ccccc4c3)cc2)cc1]

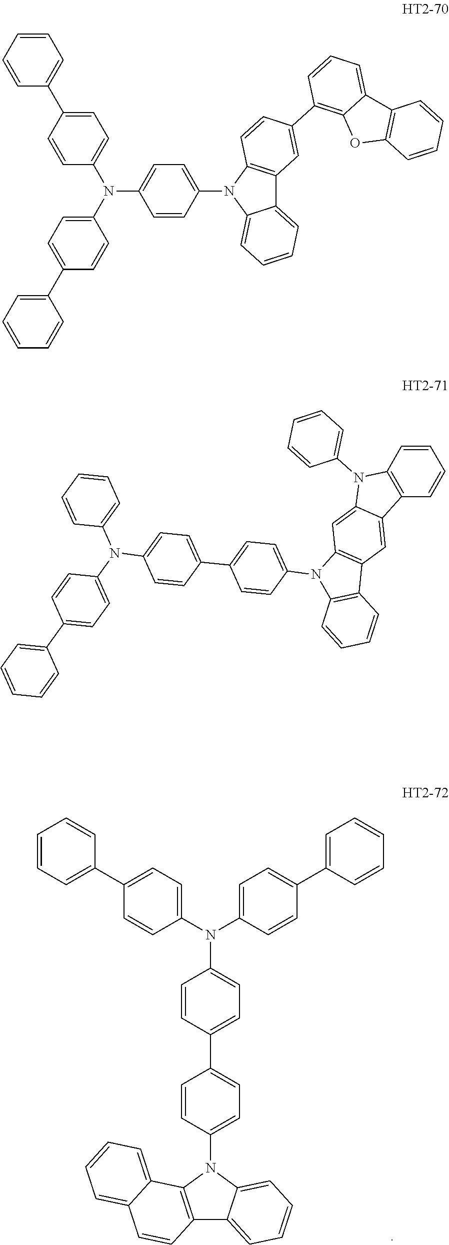 [SMILES: c1ccc(-c2ccc(N(c3ccc(-c4ccccc4)cc3)c3ccc(-n4c5ccccc5c5cc(-c6cccc7c6oc6ccccc67)ccc54)cc3)cc2)cc1 ; c1ccc(-c2ccc(N(c3ccccc3)c3ccc(-c4ccc(-n5c6ccccc6c6cc7c8ccccc8n(-c8ccccc8)c7cc65)cc4)cc3)cc2)cc1 ; c1ccc(-c2ccc(N(c3ccc(-c4ccccc4)cc3)c3ccc(-c4ccc(-n5c6ccccc6c6ccc7ccccc7c65)cc4)cc3)cc2)cc1]

9. A display device comprising the organic electroluminescent device according to claim 1.
